(19) United States
(12) Patent Application Publication
(10) Pub. No.: US 2013/0045443 A1
(43) Pub. Date: Feb. 21, 2013

(54) POLYMER, RESIST COMPOSITION AND METHOD OF FORMING RESIST PATTERN

(71) Applicants: Yoshiyuki Utsumi, Kawasaki-shi (JP); Takahiro Dazai, Kawasaki-shi (JP)

(72) Inventors: Yoshiyuki Utsumi, Kawasaki-shi (JP); Takahiro Dazai, Kawasaki-shi (JP)

(73) Assignee: TOKYO OHKA KOGYO CO., LTD., Kawasaki-shi (JP)

(21) Appl. No.: 13/567,356

(22) Filed: Aug. 6, 2012

(30) Foreign Application Priority Data
Aug. 8, 2011 (JP) P2011-173181

(51) Int. Cl. C08F 224/00; G03F 7/004; G03F 7/20; C08F 228/06

(52) U.S. Cl. 430/270.1; 526/270; 526/257; 430/325

(57) ABSTRACT

A polymer comprising: an anion part which generates acid upon exposure on at least one terminal of the main chain; and a structural unit (a1) containing an acid decomposable group that exhibits increased polarity by the action of acid, wherein the structural unit (a1) comprises two types of structural units, and a difference in an activation energy of the acid decomposable groups within the two types of structural units is at least 3.0 kJ/mol.

Priority is claimed on Japanese Patent Application No. 2011-173181, filed Aug. 8, 2011, the content of which is incorporated herein by reference.

### TECHNICAL FIELD

The present invention relates to a polymer useful for a resist composition, a resist composition containing the polymer, and a method of forming a resist pattern using the resist composition.

### BACKGROUND ART

In lithography techniques, for example, a resist film composed of a resist material is formed on a substrate, and the resist film is subjected to selective exposure of radial rays such as light or electron beam through a mask having a predetermined pattern, followed by development, thereby forming a resist pattern having a predetermined shape on the resist film.

A resist material in which the exposed portions become soluble in a developing solution is called a positive-type, and a resist material in which the exposed portions become insoluble in a developing solution is called a negative-type.

In recent years, in the production of semiconductor elements and liquid crystal display elements, advances in lithography techniques have lead to rapid progress in the field of pattern miniaturization.

Typically, these miniaturization techniques involve shortening the wavelength (increasing the energy) of the exposure light source. Conventionally, ultraviolet radiation typified by g-line and i-line radiation has been used, but nowadays KrF excimer lasers and ArF excimer lasers are starting to be introduced in mass production. Furthermore, research is also being conducted into lithography techniques that use an exposure light source having a wavelength shorter (energy higher) than these excimer lasers, such as electron beam, extreme ultraviolet radiation (EUV), and X ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes a base material component that exhibits a changed solubility in a developing solution under the action of acid and an acid-generator component that generates acid upon exposure.

For example, in the case where the developing solution is an alkali developing solution (alkali developing process), a chemically amplified positive resist which contains, as a base component (base resin), a resin which exhibits increased solubility in an alkali developing solution under action of acid, and an acid generator is typically used. If the resist film formed using the resist composition is selectively exposed during formation of a resist pattern, then within the exposed portions, acid is generated from the acid-generator component, and the action of this acid causes an increase in the solubility of the resin component in an alkali developing solution, making the exposed portions soluble in the alkali developing solution. In this manner, the unexposed portions remain to form a positive resist pattern. The base resin used exhibits increased polarity by the action of acid, thereby exhibiting increased solubility in an alkali developing solution, whereas the solubility in an organic solvent is decreased. When such a base resin is applied to a process using a developing solution containing an organic solvent (organic developing solution) (hereafter, this process is referred to as “solvent developing process” or “negative tone-developing process”) instead of an alkali developing process, the solubility of the exposed portions in an organic developing solution is decreased. As a result, in the solvent developing process, the unexposed portions of the resist film are dissolved and removed by the organic developing solution, and a negative resist pattern in which the exposed portions are remaining is formed. The negative tone-developing process and the resist composition used for the process is proposed, for example, in Patent Document 1.

Currently, resins that contain structural units derived from (meth)acrylate esters within the main chain (acrylic resins) are now widely used as base resins for resist compositions that use ArF excimer laser lithography, as they exhibit excellent transparency in the vicinity of 193 nm (for example, see Patent Document 2).

The base resin contains a plurality of structural units for improving lithography properties and the like. For example, in the case of a resin component which exhibits increased polarity by the action of acid, a base resin containing a structural unit having an acid decomposable group which is decomposed by the action of an acid generated from the acid generator to increase the polarity, a structural unit having a hydrophilic group, a structural unit having a lactone structure, and the like is typically used.

The polymer used in the base resin is generally provided by a polymerization of monomers having a variety of functions. As a polymerization method, a radical polymerization or an anionic polymerization can be used. For example, a radcal polymerization is generally used for producting an acrylic resins. As a polymerization initiator used in the radical polymerization, azo-type polymerization initiators such as azobisisobutyronitrile (AIBN) and dimethyl 2,2′-azobis(2-methylpropionate) has been commonly used.

Azo-type polymerization initiators are decomposed by heat or light to provide a radical and nitrogen gas. Then, a polymer is synthesized by addition polymerization of monomers to each other by the action of the radical. Therefore, at the terminal of the synthesized polymer, the partial structure of azo-type polymerization initiator has been introduced.

In recent years, noticing the partial structure of the polymerization initiator introduced at the terminal of the polymer, a polymerization initiator having a base dissociable group which is a function group as the partial structure, and a polymer obtained using the polymerization initiator are disclosed (see Patent Document 6).

As miniaturization of resist patterns progressed, further improvement will be demanded for resist materials with respect to various lithography properties such as exposure latitude, mask reproducibility, roughness and the pattern shape (rectangularity of the cross-sectional shape) as well as sensitivity and resolution.

In order to satisfying these demand, for example, in Patent Documents 4 to 7, a method in which a polymer compound containing a plurality of acid decomposable groups is used as a base resin is proposed in order to improve lithography properties and pattern shape.

### DOCUMENTS OF RELATED ART

### Patent Document

[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. 2010-37528
[Patent Document 4] Japanese Unexamined Patent Application, First Publication No. 2006-169319
[Patent Document 5] Japanese Unexamined Patent Application, First Publication No. 2009-265332
[Patent Document 6] Japanese Unexamined Patent Application, First Publication No. 2010-170053
[Patent Document 7] Japanese Unexamined Patent Application, First Publication No. 2010-250064

### SUMMARY OF THE INVENTION

However, even if the polymeric compound disclosed in Patent Documents 4 to 7 were used, the improvement of lithography properties was not sufficient, and there was still room for improvement in lithography properties.

As further progress is made in lithography techniques and the application field for lithography techniques is expanded, development of a novel material which can be used in lithography and can satisfy the aforementioned demands will be desired.

The present invention takes the above circumstances into consideration, with an object of providing a resist composition which exhibits excellent lithography properties, a new polymer useful for the resist composition, and a method of forming a resist pattern using the resist composition.

As a result of intensive studies of the present inventors, they have found that the aforementioned problems can be solved by using a polymer containing an anion part which generates acid upon exposure on at least one terminal of the main chain, in addition to two types of structural units containing an acid decomposable group in which a difference in an activation energy of the acid decomposable group is at least a predetermined value. The present invention has been completed based on this finding.

A first aspect of the present invention is a polymer which contains an anion part which generates acid upon exposure on at least one terminal of the main chain, and a structural unit (a1) containing an acid decomposable group that exhibits increased polarity by the action of acid, wherein the structural unit (a1) contains two types of structural units, and a difference in an activation energy of the acid decomposable groups (that is, an activation energy difference between the acid decomposable groups) within the two types of structural units is at least 3.0 kJ/mol.

A second aspect of the present invention is a resist composition containing the polymer of the first aspect of the present invention.

A third aspect of the present invention is a resist composition including: a base component (A) which exhibits changed solubility in a developing solution under action of acid; and an acid-generator component (B) which generates acid upon exposure, provided that the base component (A) is excluded, wherein the base component (A) contains the polymer according to the first aspect of the present invention.

A fourth aspect of the present invention is a method of forming a resist pattern, including applying a resist composition according to the second aspect or third aspect on a substrate to form a resist film, subjecting the resist film to exposure, and subjecting the resist film to developing to form a resist pattern.

In the present description and claims, the term “exposure” is used as a general concept that includes irradiation with any form of radiation.

The term “structural unit” refers to a monomer unit that contributes to the formation of a polymeric compound (resin, polymer, copolymer).

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic, divalent saturated hydrocarbon, unless otherwise specified.

A “halogenated alkyl group” is a group in which part or all of the hydrogen atoms of an alkyl group is substituted with a halogen atom, and a “halogenated alkylene group” is a group in which part or all of the hydrogen atoms of an alkylene group is substituted with a halogen atom. Examples of the halogen atom include a fluorine atom, a chlorine atom, a bromine atom and an iodine atom.

The fluorinated alkyl group is a group in which part or all of the hydrogen atoms of an alkyl group is substituted with a fluorine atom, and a “fluorinated alkylene group” is a group in which part or all of the hydrogen atoms of an alkylene group is substituted with a fluorine atom.

According to the present invention, there are provided a resist composition which exhibits excellent lithography properties and enable formation of a resist pattern having an excellent shape, a new polymer useful for the resist composition, and a method of forming a resist pattern using the resist composition.

### DETAILED DESCRIPTION OF THE INVENTION

### <<Polymer>>

The polymer of the present invention contains an anion part which generates acid upon exposure on at least one terminal of the main chain.

Here, the terminal of the main chain is a start point or end point of the molecular chain which grows by a polymerization, such as a radical polymerization and an anionic polymerization. To the terminal of the main chain of the polymer, a residue derived from a polymerization initiator, a chain transfer agent or a polymerization inhibitor is bonded. For example, in a radical polymerization, a radical generated by the decomposition of a radical polymerization initiator initiates a polymerization of the monomer. Therefore, the residue derived from the radical polymerization initiator (a radical portion generated by the decomposition of the radical polymerization initiator) is bonded to the terminal of the main chain. In this regard, the term “at least one terminal of the main chain” is distinctly different from the terminal of the side chain branched from the main chain (i.e., the terminal of the structure which forms a structural unit).

That is, in the present invention, an “anion part which generates acid upon exposure” on at least one terminal of the main chain of the polymer is not a structure derived from a monomer. The anion part is preferably a residue derived from a polymerization initiator. Examples of the “residue derived from a polymerization initiator”, discussed further below, include a residue derived from a polymerization initiator containing an anion part; and a group formed by reacting a compound containing an anion part with a residue derived from a polymerization initiator not containing an anion part.

The polymer according to the present invention includes a structural unit (a1) containing an acid decomposable group that exhibits increased polarity by the action of acid, wherein the structural unit (a1) comprises two types of structural units with an activation energy difference of at least 3.0 kJ/mol.

The term “acid decomposable group”, discussed further below, refers to a group in which at least a part of the bond within the structure thereof is cleaved by the action of acid generated from the anion part on the terminal of the main chain or the component (B) described later upon exposure.

The term “activation energy of acid decomposable group” is an energy required for bond cleavage as described above. In the present invention, a value calculated by the following method is referred to as “activation energy of acid decomposable group” in the structural unit.

### (Method of Calculating Activation Energy)

A monomer which derives the structural unit (2.73×10⁻⁴ mol) and benzoic acid (2.73×10⁻⁴ mol) are dissolved in 0.69 mL of tetrachloroethane in a vessel. Then the solution is respectively heated to 110° C., 120° C. and 130° C. Each of the solutions is sampled before starting the heating, 10 seconds after starting the heating, 50 seconds after starting the heating, 100 seconds after starting the heating, 200 seconds after starting the heating, 300 seconds after starting the heating, and 600 seconds after starting the heating. Then, each sample is cooled, followed by analyzing by ¹H-NMR or the like, thereby determining the decomposition ratio of the acid decomposable group within a monomer. The reaction rate constant is calculated from the decomposition ratio of the acid decomposable group. From the reaction rate constant, an activation energy can be calculated according to Arrhenius equation.

The “monomer which derives a structural unit” refers to a monomer which forms a desired structural unit by a polymerization reaction.

The decomposition ratio of the acid decomposable group within a monomer can be calculated from the concentration of decomposition products caused by the decomposition of the acid decomposable group and the concentration of the monomer (undecomposed residue) in the sample, according to the following formula.

Decomposition ratio=Concentration of decomposed products(mol %)/(Concentration of the undecomposed residues+Concentration of decomposed products(mol %))

By virtue of containing an anion part which generates acid upon exposure on at least one terminal of the main chain, in addition to two types of structural units containing an acid decomposable group with an activation energy difference of at least 3.0 kJ/mol, the resist composition containing the polymer according to the present invention exhibits excellent lithography properties such as exposure latitude (EL), mask reproducibility, roughness and the pattern shape (rectangularity of the cross-sectional shape).

In addition, by virtue of containing an anion part, the polymer of the present invention has an acid generating capacity upon exposure.

In terms of improvement of lithography properties, an activation energy difference (AEa) between the acid decomposable groups within the two of the structural units (a1) is preferably 3.5 kJ/mol or more, more preferably 4 kJ/mol or more, and still more preferably 5 kJ/mol or more.

In addition, in terms of resolution, AEa is preferably 100 kJ/mol or less, more preferably 95 kJ/mol or less, and still more preferably 90 kJ/mol or less.

Hereafter, the polymer according to the present invention will be described in more detail.

### <Anion Part>

Preferable examples the “anion part which generates acid upon exposure” include the same ionic structural part as those in the onium salt acid generator such as a sulfonium salt and an iodonium salt which are commonly used as an acid generator component which generates an acid upon exposure and is used in combination with the base resin in chemically amplified resist composition. The onium salt acid generator is composed of a salt of an acid anion with an onium ion as a countercation, and generates an acid anion by decomposition upon exposure, thereby forming an acid. As an acid anion, a sulfonic acid anion, a carboxylic acid anion, a sulfonylimide anion, a bis(alkylsulfonyl)imide anion, tris(alkylsulfonyl)methide anion are preferred. These acid anions are generated from the terminal of the main chain of the polymer upon exposure.

As an acid anion, a sulfonic acid anion is preferable, and an alkylsulfonic acid anion or a fluoroalkylsulfonic acid anion is more preferred. That is, as the “anion part which generates acid upon exposure”, an anion part which generates a sulfonic acid is preferable, and an anion part which generates an alkylsulfonic acid anion or a fluoroalkylsulfonic acid anion is more preferred.

In particular, the anion part preferably has a group represented by general formula (an1) shown below. The group contains an alkylsulfonic acid salt part which may have a fluorine atom on the terminal thereof, and generates an alkylsulfonic acid which may have a fluorine atom upon exposure. The alkylsulfonic acid can sufficiently decompose the acid decomposable group within a structural unit (a1).

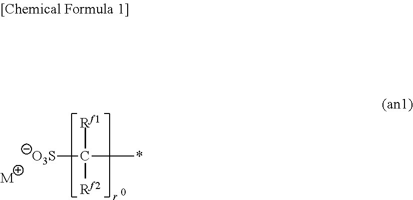

In the formula, each of R^{f1} and R^{f2} independently represents a hydrogen atom, an alkyl group, a fluorine atom or a fluorinated alkyl group; r⁰ represents an integer of 0 to 8; M⁺ represents an organic cation; and * represents a bonding portion with the main chain.

In the formula (an1), the alkyl group for R^{f1} and R^{f2} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f1} and R^{f2} is preferably a group in which part or all of the hydrogen atoms within the aforementioned alkyl group for R^{f1} and R^{f2} have been substituted with a fluorine atom.

Each of R^{f1} and R^{f2} is preferably a fluorine atom or a fluorinated alkyl group.

In the formula (an1), r⁰ is preferably an integer of 1 to 4, and more preferably 1 or 2.

In formula (an1), M⁺ represents an organic cation.

The organic cation for M⁺ is not particularly limited, and an organic cation conventionally known as the cation moiety of a photo-decomposable base used as a quencher for a resist composition or the cation moiety of an onium salt acid generator for a resist composition can be used.

As the organic cation for M⁺, for example, a cation moiety represented by general formula (c-1) or (c-2) shown below can be used.

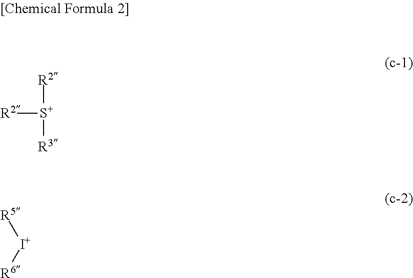

In the formulas, each of R¹″ to R³″, R⁵″ and R⁶″ independently represents an aryl group or an alkyl group, provided that, in formula (c-1), two of R¹″ to R³″ may be mutually bonded to form a ring with the sulfur atom.

In formula (c-1), R¹″ and R³″ each independently represent an aryl group or alkyl group. In formula (c-1), two of R¹″ to R³″ may be bonded to each other to form a ring with the sulfur atom.

It is preferable that at least one of R¹″ and R³″ represent an aryl group. Among R″ to R³″, it is more preferable that two or more groups are aryl groups, and it is particularly preferable that all of R¹″ to R³″ are aryl groups.

The aryl group for R¹″ to R³″ is not particularly limited. For example, an aryl group having 6 to 20 carbon atoms may be used in which part or all of the hydrogen atoms of the aryl group may or may not be substituted with alkyl groups, alkoxy groups, halogen atoms or hydroxyl groups.

The aryl group is preferably an aryl group having 6 to 10 carbon atoms because it can be synthesized at a low cost. Specific examples thereof include a phenyl group and a naphthyl group.

The alkyl group, with which hydrogen atoms of the aryl group may be substituted, is preferably an alkyl group having 1 to 5 carbon atoms, and most preferably a methyl group, an ethyl group, a propyl group, an n-butyl group, or a tert-butyl group.

The alkoxy group, with which hydrogen atoms of the aryl group may be substituted, is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

The halogen atom, with which hydrogen atoms of the aryl group may be substituted, is preferably a fluorine atom.

The alkyl group for R¹″ to R³″ is not particularly limited and includes, for example, a linear, branched or cyclic alkyl group having 1 to 10 carbon atoms. In terms of achieving excellent resolution, the alkyl group preferably has 1 to 5 carbon atoms. Specific examples thereof include a methyl group, an ethyl group, an n-propyl group, an isopropyl group, an n-butyl group, an isobutyl group, an n-pentyl group, a cyclopentyl group, a hexyl group, a cyclohexyl group, a nonyl group, and a decyl group, and a methyl group is most preferable because it is excellent in resolution and can be synthesized at a low cost.

When two of R¹″ to R³″ in formula (c-1) are bonded to each other to form a ring with the sulfur atom, it is preferable that the two of R″ to R³″ form a 3- to 10-membered ring including the sulfur atom, and it is particularly preferable that the two of R¹″ to R³″ form a 5- to 7-membered ring including the sulfur atom.

When two of R¹″ to R³″ in formula (c-1) are bonded to each other to form a ring with the sulfur atom, the remaining one of R¹″ to R³″ is preferably an aryl group. As examples of the aryl group, the same aryl groups as those described above for R″ to R³″ can be used.

As preferable examples of the cation moiety represented by general formula (c-1), those represented by formulas (c-1) to (c-1-32) shown below can be given.

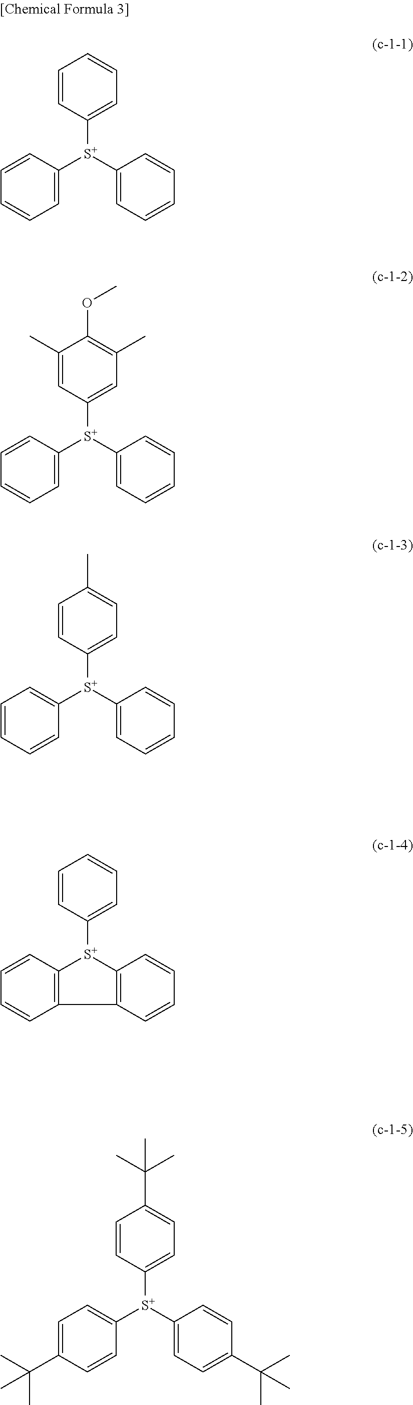

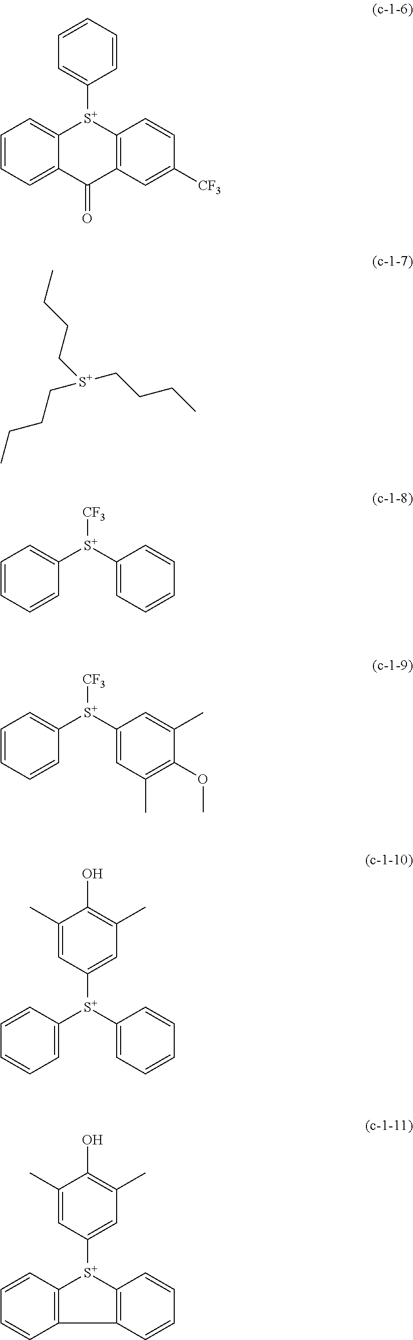

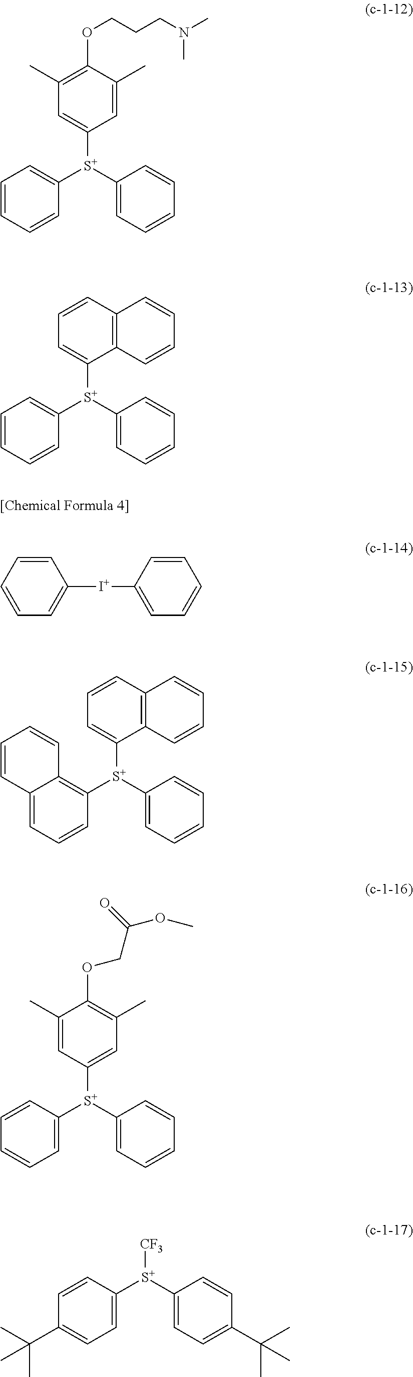

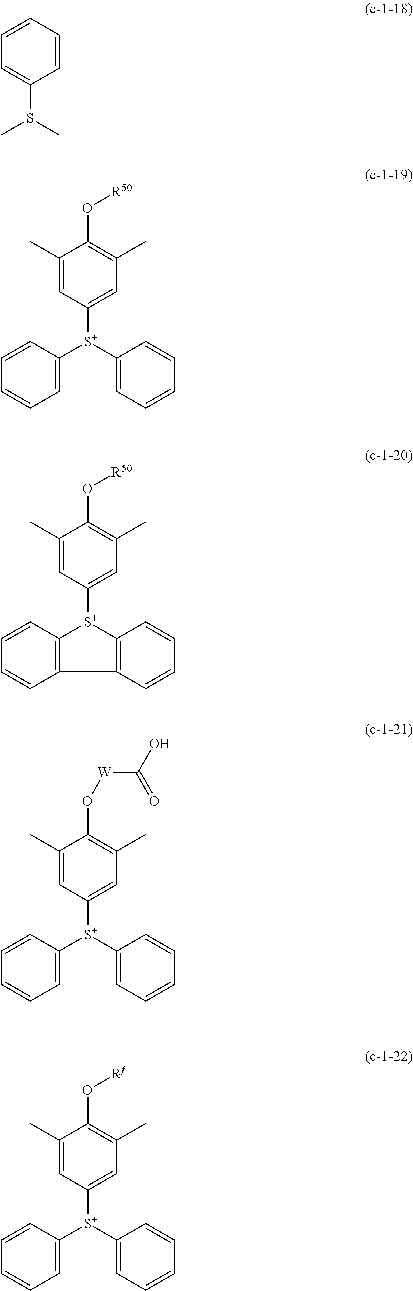

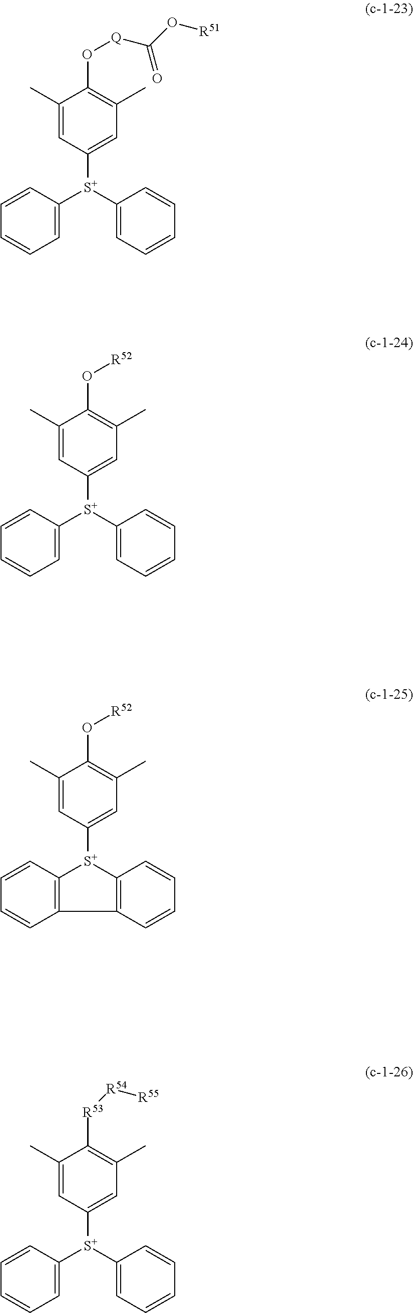

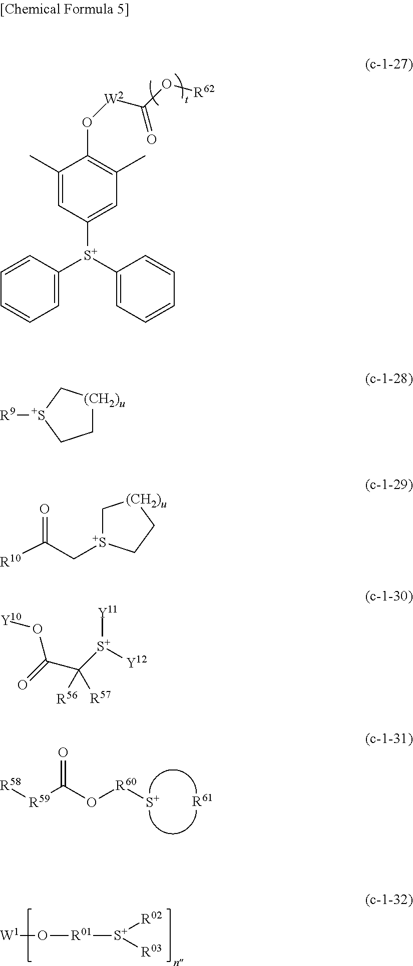

In formulas (c-19) and (c-1-20), R⁵⁰ represents a group containing an acid dissociable group, and is preferably a group represented by the formula (p1), (p1-1) or (p2) described late in the explanation of the structural unit (a1), or a group in which the oxygen atom of —R⁹¹—C(═O)—O— is bonded to a group represented by the formula (I-1) to (1-9) or (2-1) to (2-6) described later in the explanation of the structural unit (a1). Here, R⁹¹ represents a single bond or a linear or branched alkylene group, and the alkylene group preferably has 1 to 5 carbon atoms.

In general formula (c-21), W represents a divalent linking group.

The divalent linking group is not particularly limited, and preferable examples thereof include a divalent hydrocarbon group which may have a substituent and a divalent linking group containing a hetero atom.

### (Divalent Hydrocarbon Group Which May Have a Substituent)

A hydrocarbon “has a substituent” means that part or all of the hydrogen atoms within the hydrocarbon group is substituted with a substituent (a group or an atom other than hydrogen).

The hydrocarbon group may be either an aliphatic hydrocarbon group or an aromatic hydrocarbon group.

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

As specific examples of the aliphatic hydrocarbon group, a linear or branched aliphatic hydrocarbon group, and an aliphatic hydrocarbon group containing a ring in the structure thereof can be given.

The linear or branched aliphatic hydrocarbon group preferably has 1 to 10 carbon atoms, more preferably 1 to 8, and still more preferably 1 to 5.

As the linear aliphatic hydrocarbon group, a linear alkylene group is preferable, and specific examples include a methylene group [—CH₂—], an ethylene group [—(CH₂)₂], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂— and —C (CH₂CH₃)₂—CH₂—; alkyltrimethylene groups such as —CH(CH₃)CH₂CH₂— and —CH₂CH(CH₃)CH₂—; and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms, and an oxo group (═O).

As examples of the hydrocarbon group containing a ring in the structure thereof, a cyclic aliphatic hydrocarbon group (a group in which two hydrogen atoms have been removed from an aliphatic hydrocarbon ring), and a group in which the cyclic aliphatic hydrocarbon group is bonded to the terminal of the linear or branched aliphatic hydrocarbon group or interposed within the aforementioned linear aliphatic hydrocarbon group, can be given. Examples of the linear or branched aliphatic hydrocarbon group include the same groups as described above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which 2 hydrogen atoms have been removed from a monocycloalkane is preferable. The monocycloalkane preferably has 3 to 6 carbon atoms, and specific examples thereof include cyclopentane and cyclohexane. As the polycyclic aliphatic hydrocarbon group, a group in which two hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxo group (═O).

The aromatic hydrocarbon group is a hydrocarbon group having an aromatic ring.

The aromatic hydrocarbon group as a divalent hydrocarbon group for W more preferably has 5 to 30, still more preferably 5 to 20, particularly preferably 6 to 15, and most preferably 6 to 10. Here, the number of carbon atoms within a substituent(s) is not included in the number of carbon atoms of the aromatic hydrocarbon group.

Examples of the aromatic ring in the aromatic hydrocarbon group include aromatic hydrocarbon rings such as benzene, biphenyl, fluorene, naphthalene, anthracene and phenanthrene and aromatic heterocycles in which part of the carbon atoms of the aromatic hydrocarbon ring have been substituted with a hetero atom. Examples of hetero atoms within the aromatic heterocycle include an oxygen atom, a nitrogen atom, and a sulfur atom.

Specific examples of the aromatic hydrocarbon group include a group in which two hydrogen atoms have been removed from the aromatic hydrocarbon ring or aromatic hetero ring (arylene group or heteroarylene group); a group in which one of hydrogen atom of the group in which one hydrogen atom has been removed from the aromatic hydrocarbon group or aromatic hetero ring (aryl group or heteroaryl group) is substituted with an alkylene group (for example, a group in which one hydrogen atom is removed from an arylalkyl group such as a benzyl group, a phenethyl group, a 1-naphthylmethyl group, a 2-naphthylmethyl group, a 1-naphthylethyl group, or a 2-naphthylethyl group). The alkylene group bonded to the aryl group or heteroaryl group preferably has 1 to 4 carbon atom, more preferably 1 or 2, and most preferably 1.

The aromatic hydrocarbon group may or may not have a substituent. For example, one or more of the hydrogen atoms bonded to the aromatic hydrocarbon ring in the aromatic hydrocarbon group may be substituted with a substituent. Examples of substituents include an alkyl group, an alkoxy group, a halogen atom, a halogenated alkyl group, a hydroxyl group and an oxo group (═O).

The alkyl group as the substituent is preferably an alkyl group of 1 to 5 carbon atoms, and a methyl group, an ethyl group, a propyl group, an n-butyl group or a tert-butyl group is particularly preferred.

The alkoxy group as the substituent is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

### (Divalent Linking Group Containing a Hetero Atom)

With respect to a divalent linking group containing a hetero atom, a hetero atom is an atom other than carbon and hydrogen, and examples thereof include an oxygen atom, a nitrogen atom, a sulfur atom and a halogen atom.

Specific examples of the divalent linking group containing a hetero atom include non-hydrocarbon linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)— and ═N—; and a combination of any one of these non-hydrocarbon linking groups with a divalent hydrocarbon group. As examples of the divalent hydrocarbon group, the same groups as those described above for the divalent hydrocarbon group which may have a substituent can be given, and a linear or branched aliphatic hydrocarbon group is preferable.

The hydrogen atom included in —NH— within —C(═O)—NH—, —NH— or —NH— within —NH—C(═NH)— may be substituted with a substitutent such as an alkyl group or an acyl group. The substituent preferably has 1 to 10 carbon atoms, more preferably 1 to 8 carbon atoms, and most preferably 1 to 5 carbon atoms.

Examples of the divalent linking group which is a combination of a non-hydrocarbon linking group and a divalent hydrocarbon group include —Y²¹—O—Y²²—, —[Y²¹—C(═O)—O]ₘ—Y²²— and —Y²¹—O—C(═O)—Y²²— (provided that each of Y²¹ and Y²² independently a divalent hydrocarbon group which may have a substituent; O represents an oxygen atom; and m′ represents an integer of 0 to 3.)

In the —Y²¹—O—Y²²—, [Y²¹—C(═O)—O]ₘ—Y²²— or —Y²¹—O—C(═O)—Y²²—, each of Y²¹ and Y²² independently represents a divalent hydrocarbon group which may have a substituent. Examples of the divalent hydrocarbon group include the same groups as those described above for the “divalent hydrocarbon group which may have a substituent”.

As Y²¹, a linear aliphatic hydrocarbon group is preferable, more preferably a linear alkylene group, still more preferably a linear alkylene group of 1 to 5 carbon atoms, and a methylene group or an ethylene group is particularly preferred.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]ₘ′—Y²²—, m′ represents an integer of 0 to 3, preferably an integer of 0 to 2, more preferably 0 or 1, and most preferably 1. Namely, it is particularly preferably that the group represented by the formula—[Y²¹—C(═O)—O]ₘ′—Y²²— is a group represented by the formula —Y²¹—C(═O)—O—Y²²—. In particular, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group for W, a linear or branched alkylene group, a divalent aliphatic cyclic group or a divalent linking group containing a hetero atom is preferable, a linear or branched alkylene group is more preferable, and a linear alkylene group is still more preferable.

In formula (c-22), R^{f} represents a fluorinated alkyl group, i.e., a group in which an unsubstituted alkyl group has part or all of the hydrogen atoms substituted with fluorine atoms. The unsubstituted alkyl group is preferably a linear or branched alkyl group, and more preferably a linear alkyl group.

In formula (c-23), Q represents a divalent linking group, and R⁵¹ represents an organic group having a carbonyl group, an ester bond or a sulfonyl group.

Examples of the divalent linking group for Q include the same divalent linking groups as those described above for X³ in the formula (c-21). As Q, an alkylene group or a divalent linking group containing an ester bond is preferable, and an alkylene group or —R⁹²—C(═O)—O—R⁹³— [each of R⁹² and R⁹³ independently represents an alkylene group] is more preferable.

R⁵¹ represents an organic group having a carbonyl group, an ester bond or a sulfonyl group. The organic group having a carbonyl group, an ester bond or a sulfonyl group for R⁵¹ may be either an aromatic hydrocarbon group or a aliphatic hydrocarbon group. Examples of the aromatic hydrocarbon group and the aliphatic hydrocarbon group include the same groups as those described below for X³. Among these, as the organic group having a carbonyl group, an ester bond or a sulfonyl group for R⁵¹, an aliphatic hydrocarbon group is preferable, a bulky aliphatic hydrocarbon group is more preferable, and a cyclic saturated hydrocarbon group is still more preferable. Preferable examples of R⁵¹ include a group represented by any one of the formulas (L1) to (L6) and (S1) to (S4) described below, the same groups as those described below for X³, and a monocyclic or polycyclic group in which the hydrogen atoms bonded thereto have been substituted with an oxygen atom (═O).

In the formulas (c-24) and (c-1-25), R⁵² represents an alkyl group of 4 to 10 that is not an acid dissociable group. As R⁵², a linear or branched alkyl group is preferable, and a linear alkyl group is more preferable.

In formula (c-26), R⁵³ represents a divalent group having a base dissociable portion, R⁵⁴ represents a divalent linking group, and R⁵⁵ represents a group having an acid dissociable group.

The base dissociable portion within R⁵³ refers to a portion which is dissociable by the action of an alkali developing solution (e.g., a 2.38% by weight aqueous solution of tetramethylammonium hydroxide (TMAH) at 23° C.). By the dissociation of the base dissociable portion, the solubility in an alkali developing solution is increased. The alkali developing solution may be any one of those generally used in the fields of lithography. It is preferable that the base dissociable portion is dissociated by the action of a 2.38% by weight aqueous solution of tetramethylammonium hydroxide at 23° C.

The R⁵³ group may be either a group constituted of only a base dissociable portion, or a group in which a base dissociable portion is boned to a group or atom which is not base dissociable.

The base dissociable portion within the R⁵³ group is most preferably an ester group.

Examples of the group or atom which is not base dissociable for R⁵³ include the divalent linking groups described above for X in general formula (I-1) and a combination of the linking groups (provided that groups which are base dissociable are excluded). The “combination of the linking groups” refers to a divalent linking group composed of divalent linking groups bonded to each other. As such a “combination of linking groups”, a combination of an alkylene group with a divalent linking group containing a hetero atom is preferable. However, it is preferable that the hetero atom is not adjacent to the atom having a bond cleaved by the action of a base within the base dissociable portion.

The alkylene group is the same those as defined for the linear or branched alkylene group for W in the formula (c-21).

The hetero atom is most preferably an oxygen atom.

Among the above examples, R⁵³ is preferably a group in which a base dissociable portion is boned to a group or atom which is not base dissociable.

R⁵⁴ represents a divalent linking group, and examples thereof include the same divalent linking groups as those described above for W in the formula (c-21). Among these, an alkylene group or a divalent aliphatic cyclic group is preferable, and an alkylene group is particularly preferred.

R⁵⁵ represents a group having an acid dissociable group.

Here, the acid dissociable group is an organic group which can be dissociated by the action of an acid. The acid dissociable group is not particularly limited, and any group which has been proposed as an acid dissociable group within a base resin for a chemically amplified resist can be used. Specific examples include the same acid dissociable groups as those within the structural unit (a1) described below, such as a cyclic or chain-like tertiary alkyl ester-type acid dissociable group or an acetal-type acid dissociable group (e.g., an alkoxyalkyl group). Among these, a tertiary alkyl ester-type acid dissociable group is particularly preferred.

The group having an acid dissociable group may be either the acid dissociable group itself, or a group in which an acid dissociable group is bonded to a group or atom which is not acid dissociable (a group or atom which remains bonded to the acid generator even after the dissociation of the acid dissociable group). Examples of the group or atom which is not acid dissociable include the same divalent linking groups as those described above for Win the formula (c-21).

In formula (c-27), W² represents a single bond or a divalent linking group, t represents 0 or 1, and R⁶² represents a group which is not dissociable by acid (hereafter, referred to as “acid non-dissociable group”).

As the divalent linking group for W², examples thereof include the same divalent linking groups as those described above for W in the formula (c-21). Among these, as W², a single bond is preferable.

t is preferably 0.

The acid non-dissociable group for R⁶² is not particularly limited as long as it is a group which is not dissociable by acid. The acid non-dissociable group is preferably an acid non-dissociable hydrocarbon group which may have a substituent, more preferably a cyclic hydrocarbon group which may have a substituent, and still more preferably a group in which one hydrogen atom has been removed from adamantane.

In formulas (c-28) and (c-1-29), each of R⁹ and R¹⁰ independently represents a phenyl group or naphthyl group which may have a substituent, an alkyl group of 1 to 5 carbon atoms, an alkoxy group or a hydroxy group; and u represents an integer of 1 to 3, most preferably 1 or 2.

In formula (c-30), Y¹⁰ represents a cyclic hydrocarbon group of 5 or more carbon atoms which may have a substituent, and is an acid dissociable group which may be dissociated by the action of an acid; each of R⁵⁶ and R⁵⁷ independently represents a hydrogen atom, an alkyl group or an aryl group, provided that R⁵⁶ and R⁵⁷ may be mutually bonded to form a ring; each of and Y¹² independently represents an alkyl group or an aryl group, provided that Y¹¹ and Y¹² may be mutually bonded to form a ring.

Y¹⁰ represents a cyclic hydrocarbon group of 5 or more carbon atoms which may have a substituent, and is an acid dissociable group which may be dissociated by the action of an acid. By virtue of the Y¹⁰ group being a cyclic hydrocarbon group of 5 or more carbon atoms which may have a substituent, and being an acid dissociable group which may be dissociated by the action of an acid, various lithography properties such as resolution, LWR, exposure latitude (EL margin) and resist pattern are improved.

Examples of Y¹⁰ include groups which form a cyclic tertiary alkyl ester with —C(R⁵⁶)(R⁵⁷)—C(═O)—O—.

A “tertiary alkyl ester” refers to a structure in which a tertiary carbon atom within a cyclic hydrocarbon group of 5 or more carbon atoms is bonded to the terminal oxygen atom of —C(R⁵⁶)(R⁵⁷)—C(═O)—O—. In this tertiary alkyl ester, the action of acid causes cleavage of the bond between the oxygen atom and the tertiary carbon atom.

The cyclic hydrocarbon group may have a substituent, and the carbon atom(s) within the substituent is not included in the number of carbon atoms of the “carbon atom of 5 or more carbon atoms”.

The cyclic hydrocarbon group having 5 or more carbon atoms is preferably an aliphatic cyclic group.

Examples of the “aliphatic cyclic group” include monocyclic groups or polycyclic groups which have no aromaticity, and polycyclic groups are preferable.

The “aliphatic cyclic group” may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

As such aliphatic cyclic groups, groups in which two or more hydrogen atoms have been removed from a monocycloalkane or a polycycloalkane such as a bicycloalkane, tricycloalkane or tetracycloalkane which may or may not be substituted with an alkyl group of 1 to 5 carbon atoms, a fluorine atom or a fluorinated alkyl group, may be used. Specific examples include groups in which two or more hydrogen atoms have been removed from a monocycloalkane such as cyclopentane and cyclohexane; and groups in which two or more hydrogen atoms have been removed from a polycycloalkane such as adamantane, norbornane, isobornane, tricyclodecane or tetracyclododecane.

Each of R⁵⁶ and R⁵⁷ independently represents a hydrogen atom, an alkyl group or an aryl group.

Examples of the alkyl group or aryl group for R⁵⁶ and R⁵⁷ include the same alkyl groups and aryl groups as those described above for R¹″ to R³″. Further, R⁵⁶ and R⁵⁷ may be mutually bonded to form a ring, like in the case of the aforementioned R¹″ to R³″.

Among the above-mentioned examples, it is particularly preferable that both R⁵⁶ and R⁵⁷ represent a hydrogen atom.

Each of Y¹¹ and Y¹² independently represents an alkyl group or an aryl group.

Examples of the alkyl group or aryl group for Y^{1l} and Y¹² include the same alkyl groups and aryl groups as those described above for R¹″ to R³″.

It is particularly preferable that each of Y¹¹ and Y¹² represents a phenyl group or a naphthyl group. Further, Y¹¹ and Y¹² may be mutually bonded to form a ring, like in the case of the aforementioned R¹″ to R³″.

In formula (c-31), R⁵⁸ represents an aliphatic cyclic group; R⁵⁹ represents a single bond or an alkylene group which may have a substituent; R⁶⁰ represents an arylene group which may have a substituent; and R⁶¹ represents an alkylene group of 4 or 5 carbon atoms which may have a substituent.

The aliphatic cyclic group for R⁵⁸ may be either a monocyclic group or a polycyclic group, but is preferably a polycyclic group, more preferably a group in which one or more hydrogen atoms have been removed from a polycycloalkane, and most preferably a group in which one or more hydrogen atoms have been removed from adamantane.

The alkylene group for R⁵⁹ which may have a substituent is preferably a linear or branched alkylene group. As R⁵⁹, a single bond or an alkylene group of 1 to 3 carbon atoms is preferable.

The arylene group for R⁶⁰ preferably has 6 to 20 carbon atoms, more preferably 6 to 14 carbon atoms, and still more preferably 6 to 10 carbon atoms. Examples of the arylene group include a phenylene group, a biphenylene group, a fluorenylene group, a naphthylene group, an anthrylene group and a phenanthrene group. In terms of synthesis at low cost, a phenylene group or a naphthylene group is preferable.

In formula (c-32), R⁰¹ represents an arylene group or an alkylene group; each of le and R⁰³ independently represents an aryl group or an alkyl group, provided that R⁰² and R⁰³ may be mutually bonded to form a ring with the sulfur atom, and at least one of R⁰¹ to R⁰³ represents an arylene group or an aryl group; W¹ represents a linking group having a valency of n″; and n″ represents 2 or 3.

The arylene group for R″ is not particularly limited, and examples thereof include arylene groups of 6 to 20 carbon atoms in which part or all of the hydrogen atoms may be substituted. The alkylene group for R″ is not particularly limited, and examples thereof include linear, branched or cyclic alkylene groups of 1 to 10 carbon atoms.

The aryl group for R⁰² and R⁰³ is not particularly limited, and examples thereof include aryl groups of 6 to 20 carbon atoms in which part or all of the hydrogen atoms may be substituted. The alkyl group for R⁰² and R⁰³ is not particularly limited, and examples thereof include linear, branched or cyclic alkyl groups of 1 to 10 carbon atoms.

Examples of the divalent linking group for W¹ include the same divalent linking groups as those described above for Win the formula (c-21). The divalent linking group may be linear, branched or cyclic, but is preferably cyclic. Among these, an arylene group having two carbonyl groups, each bonded to the terminal thereof is preferable.

Examples of the trivalent linking group for W¹ include a group in which one hydrogen atom has been removed from the aforementioned divalent linking group, or a group in which a hydrogen atom within the aforementioned divalent linking group has been substituted with a divalent linking group. The trivalent linking group for W¹ is preferably an arylene group combined with three carbonyl groups.

In formula (c-2), R⁵″ and R⁶″ each independently represent an aryl group or alkyl group. Among R⁵″ and R³″, it is more preferable that at least one of R⁵″ and R⁶″ is aryl groups, and it is particularly preferable that all of R⁵″ and R⁶″ are aryl groups.

As the aryl group for R⁵″ and R⁶″, the same aryl groups as those described above for R¹″ to R³″ can be used.

As the alkyl group for R⁵″ to R⁶″, the same alkyl groups as those described above for R¹″ to R³″ can be used.

It is particularly preferable that both of R⁵″ and R⁶″ represents a phenyl group.

Further, as examples of the organic cation for M⁺, organic cations represented by general formula (c-3) shown below can also be given.

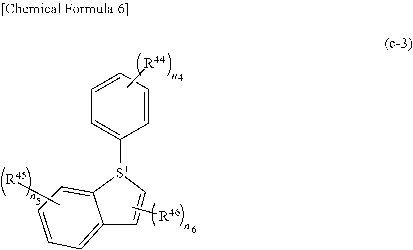

In formulas, each of R⁴⁴ to R⁴⁶ independently represents an alkyl group, an acetyl group, an alkoxy group, a carboxy group, a hydroxyl group or a hydroxyalkyl group; each of n₄ and n₅ independently represents an integer of 0 to 3; and n₆ represents an integer of 0 to 2.

With respect to R⁴⁴ to R⁴⁶, the alkyl group is preferably an alkyl group of 1 to 5 carbon atoms, more preferably a linear or branched alkyl group, and most preferably a methyl group, an ethyl group, a propyl group, an isopropyl group, an n-butyl group or a tert-butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁴⁴ to R⁴⁶ group, as indicated by the corresponding value of n₄ to n₆, then the two or more of the individual R⁴⁴ to R⁴⁶ group may be the same or different from each other.

n₄ is preferably 0 to 2, and more preferably 0 or 1.

n₅ is preferably 0 or 1, and more preferably 0.

n₆ is preferably 0 or 1, and more preferably 1.

The polymer of the present invention preferably contains a group represented by general formula (I-1) shown below on at least one terminal of the main chain (hereafter referred to as “terminal group (1-1)”), in terms of excellent improvement effect in lithography properties.

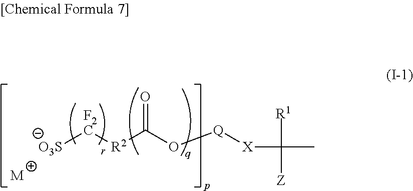

wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 1 to 3;
Q represents a hydrocarbon group having a valency of (p+1), provided that, p represents 1, Q may represent a single bond;
R² represents a single bond, an alkylene group which may have a substituent or an aromatic group which may have a substituent; q represents 0 or 1; r represents an integer of 0 to 8; and M⁺ represents an organic cation.

In formula (I-1), M⁺ is the same as defined for M⁺ in the aforementioned formula (an1).

R¹ represents an alkylene group of 1 to 10 carbon atoms. The hydrocarbon group of 1 to 10 carbon atoms may be either an aliphatic hydrocarbon group or an aromatic hydrocarbon group, an aliphatic hydrocarbon group is preferable, and a monovalent saturated aliphatic hydrocarbon group (alkyl group) is more preferable.

As specific examples of the alkyl group, a linear or branched alkyl group, and an aliphatic hydrocarbon group containing a ring in the structure thereof can be given.

The linear alkyl group preferably has 1 to 8 carbon atoms, more preferably 1 to 5, and most preferably 1 to 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 5 carbon atoms. Specific examples of such branched alkyl groups include an isopropyl group, an isobutyl group, a tert-butyl group, an isopentyl group and a neopentyl group, and an isopropyl group or a tert-butyl group is particularly preferred.

As examples of the hydrocarbon group containing a ring in the structure thereof, a cyclic aliphatic hydrocarbon group (a group in which one hydrogen atom has been removed from an aliphatic hydrocarbon ring), and a group in which the cyclic aliphatic hydrocarbon group is bonded to the terminal of the aforementioned chain-like aliphatic hydrocarbon group or interposed within the aforementioned chain-like aliphatic hydrocarbon group, can be given.

The cyclic aliphatic hydrocarbon group preferably has 3 to 8 carbon atoms, and more preferably 4 to 6 carbon atoms. Specific examples include groups in which one or more hydrogen atoms have been removed from a monocycloalkane such as cyclopentane or cyclohexane.

The cyclic aliphatic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

In general formula (I-1), Z represents a hydrocarbon group of 1 to 10 carbon atoms or a cyano group.

As the hydrocarbon group of 1 to 10 carbon atoms for Z, the same hydrocarbon groups of 1 to 10 carbon atoms as those described above for R¹ can be used.

R¹ and Z may be bonded to each other to form a ring. Specifically, R¹ and Z each independently represents a linear or branched alkylene group, and the terminal of R¹ may be bonded to the terminal of Z to form a ring. As the ring to be formed, a ring of 3 to 8 carbon atoms is preferable, and cyclopentane, cyclohexane, cycloheptane or cyclooctane is particularly preferred.

In particular, as a combination of R¹ and Z, a combination of a methyl group with a methyl group, a combination of an ethyl group with an ethyl group, a combination of a methyl group with a cyano group, a combination of an ethyl group with a cyano group, and a group in which two carbon atoms have been removed from a cyclopentane which is formed by mutually bonding R¹ and X to each other are preferable, and a combination of a methyl group for R¹ with a cyano group for Z is particularly preferred.

In the formula (I-1), X represents a divalent linking group having —O—C(═O)—, —NH—C(═O)— or —NH—C(═NH)— on at least the terminal bonded to Q in the formula.

The terminal bonded to Q in the formula means the terminal bonded to —(C(═O)—O)_{q}—, R², —CF₂— or SO₃⁻ in the formula (I-1), when Q is a single bond. The divalent linking group for X may be a group consisting of —O—C(═O)—, —NH—C(═O)— or —NH—C(═NH)—. In addition, X may contain —O—C(═O)—, —NH—C(═O)— or —NH—C(═NH)—in addition to on the terminal bonded to Q.

Preferable examples of the divalent linking group for X include a group consisting of —O—C(═O)—, —NH—C(═O)— or —NH—C(═NH)— and a combination of a divalent hydrocarbon group which may have a substituent or a divalent linking group containing a hetero atom with —O—C(═O)—, —NH—C(═O)— or —NH—C(═NH)—.

As the divalent linking group which may have a substituent and the divalent linking group containing a hetero atom are the same divalent linking groups as those described above in the explanation of the divalent linking group for W in the formula (c-21).

When X consists of any one of —O—C(═O)—, —NH—C(═O)— and —NH—C(═NH)—, X preferably represents —O—C(═O)— or —NH—C(═O)—. The carbon atom in —O—C(═O)— or the carbon atom within —NH—C(═O)— is preferably directly bonded to the carbon atom which is bonded to R¹ and Z.

When X is a combination of the aforementioned divalent group with any one of —O—C(═O)—, —NH—C(═O)— and —NH—C(═NH)—, X is preferably a combination of a linear or branched aliphatic hydrocarbon group of 1 to 5 carbon atoms or divalent linking group containing a hetero atom with any one of —O—C(═O)—, —NH—C(═O)— and —NH—C—(═NH)—, more preferably a combination a linking group selected from a methylene group, ethylene group and divalent linking group having an —NH— with any one of —O—C(═O)—, —NH—C(═O)— and —NH—C—(═NH)—, and particularly preferably a combination of two or more groups selected from an ethylene group, —O—C(═O)— and —NH—C(═O)—.

In formula (I-1), p represents an integer of 1 to 3, preferably 1.

p may represent 2 or 3. When p is 2 or 3, the amount of the sulfonic acid part (SO₃) which can occur in the polymer and has a function as an acid is increased, and acid-generating capacity can be improved.

In the formula (I-1), Q represents a hydrocarbon group having a valency of (p+1), provided that, when p represents 1, Q may represent a single bond.

When p represents 1, Q represents a single bond or a divalent hydrocarbon group. Examples of the divalent hydrocarbon group include the same groups as the divalent hydrocarbon group which does not have a substituent described above in the explanation for “divalent hydrocarbon group which may have a substituent” for X. In particular, when p is 1, Q preferably represents a single bond or a divalent aliphatic hydrocarbon group, more preferably a single bond or a linear or branched alkylene group, still more preferably a single bond, a methylene group or an ethylene group, and particularly preferably a single bond or an ethylene group.

When p represents 2, Q represents a trivalent hydrocarbon group. When p represents 3, Q represents a tetravalent hydrocarbon group. Examples of the trivalent or tetravalent hydrocarbon group include a group in which one or two hydrogen atom have been removed from the divalent hydrocarbon group which does not have a substituent described above in the explanation of “divalent hydrocarbon group which may have a substituent” for X. Among these, a trivalent or tetravalent aliphatic hydrocarbon group is preferred.

Specific examples of the hydrocarbon group having a valency of (p+1) for Q are shown below.

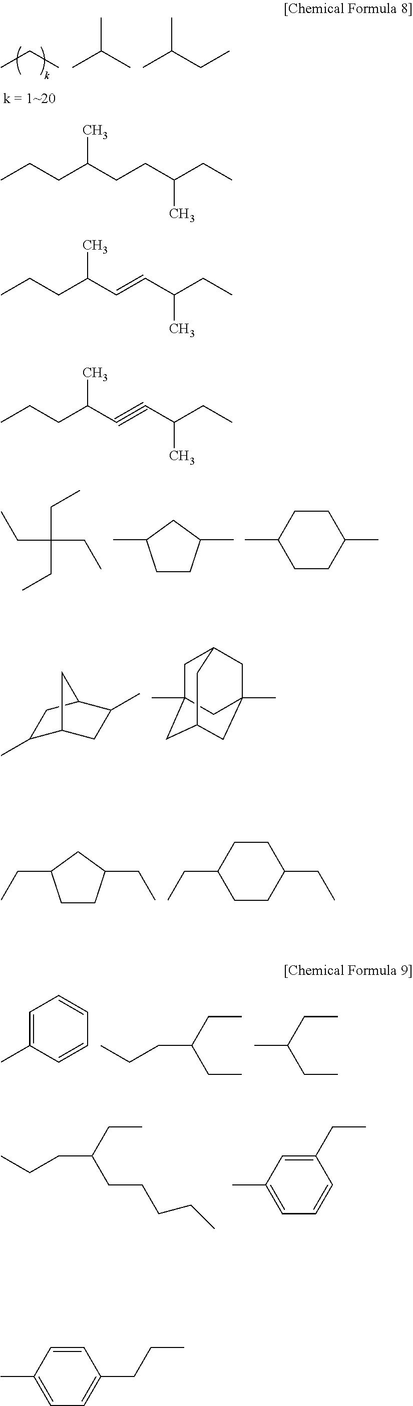

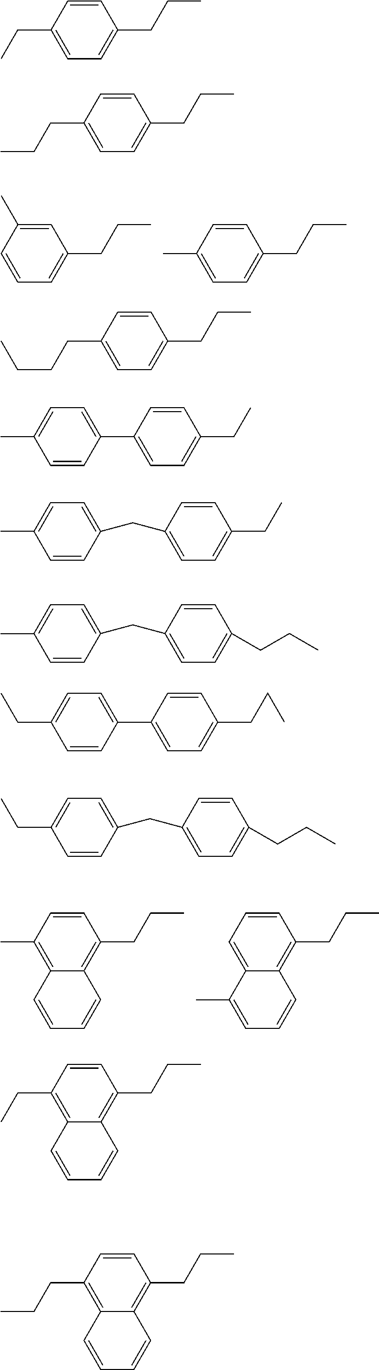

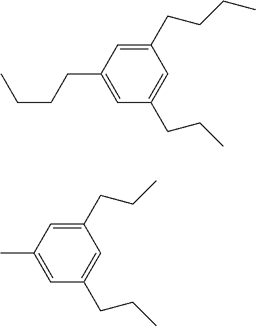

In the formula (I-1), q represents 0 or 1. When q is O, —C(═O)—O)_{q}— in the formula represents a single bond.

q preferably represents 1, when the divalent linking group for X does not contain —O—C(═O)—. q preferably represents 0, when the divalent linking group for X contains —O—C(═O)—

In the formula (I-1), R² represents a single bond, an alkylene group which may have a substituent, or an aromatic group which may have a substituent.

The alkylene group for R² may be linear or branched. Examples of the alkylene group include the same groups as the linear or branched aliphatic hydrocarbon groups and aliphatic hydrocarbon groups containing a ring in the structure thereof described above in the explanation of the divalent hydrocarbon group which may have a substituent for X. Among these, an alkylene group for R² is preferably an alkylene group of 1 to 10 carbon atoms, and a methylene group or an ethylene group is more preferable.

The aromatic group which may have a substituent for R² may be either an aromatic hydrocarbon group or an aromatic group having atoms other than carbon atoms in the ring structure (heterocyclic compound).

Examples of the aromatic hydrocarbon group include the same groups as the aromatic hydrocarbon groups described above in the explanation of the divalent hydrocarbon group which may have a substituent for X. As the aromatic hydrocarbon group for R², a group in which one or more hydrogen atoms have been removed from phenyl group or naphthyl group is preferable. As the aromatic hydrocarbon group for R², a group in which part or all of the hydrogen atoms thereof may be substituted with an alkyl group of 1 to 5 carbon atoms, a fluorine atom, a fluorinated alkyl group of 1 to 5 carbon atoms, and an oxygen atom (═O). Among these, a group in which part or all of the hydrogen atoms thereof are substituted with a fluorine atom is preferred.

As the aromatic group having atoms other than carbon atoms in the ring structure, a group in which two or more hydrogen atoms have been removed from a heterocycle such as quinoline, pyridine, oxole and imidazole is preferred.

Among these, as R², a single bond or an aromatic group which may have a substituent is preferred.

In general formula (I-1), r represents an integer of 0 to 8. When r is O, —(CF₂)ᵣ— in the formula represents a single bond.

When R² represents a single bond or an alkylene group which may have a substituent, r preferably represents an integer of 1 to 8, more preferably an integer of 1 to 4, an still more preferably 1 or 2. When R² represents an aromatic group which may have a substituent, r preferably represents 0.

Specific examples of groups represented by general formula (I-1) are shown below.

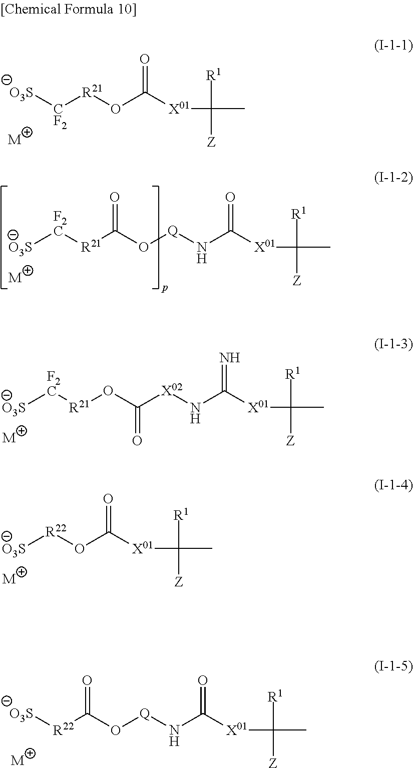

In the formula, R¹, Z, Q, p and M⁺ are the same as those defined above; X⁰¹ represents a single bond or an alkylene group which may have a substituent; R²¹ represents a single bond or an alkylene group which may have a substituent; X⁰² represents an alkylene group which may have a substituent; and R²² represents an aromatic group which may have a substituent.

In the formulas (c-1) to (I-1-5), R¹, Z, Q, p and M⁺ are respectively the same those as R¹, Z, Q, p and M⁺ in the formula (I-1).

In the formulas (c-1) to (I-1-5), X⁰¹ represents a single bond or an alkylene group which may have a substituent. Examples of the alkylene group which may have a substituent include the same groups as the linear or branched aliphatic hydrocarbon groups and aliphatic hydrocarbon groups containing a ring in the structure thereof described above in the explanation of the divalent hydrocarbon group which may have a substituent for X. As X⁰¹, a single bond or an ethylene group is particularly preferred.

In the formulas (c-1) to (I-1-5), R²¹ represents a single bond or an alkylene group which may have a substituent. The alkylene group which may have a substituent for R²¹ is the same one as the alkylene group which may have a substituent for R² in the formula (I-1). As R²¹, a single bond or a methylene group is particularly preferred.

In the formula (c-3), X⁰² represents an alkylene group which may have a substituent. Examples include the same groups as those described above as the linear or branched aliphatic hydrocarbon groups and aliphatic hydrocarbon groups containing a ring in the structure thereof in the explanation of the divalent hydrocarbon group which may have a substituent for X in the formula (I-1). As X⁰², an ethylene group is particularly preferred.

In formulas (c-4) and (I-1-5), R²² represents an aromatic group which may have a substituent. The aromatic group which may have a substituent for R²² is the same one as the aromatic group which may have a substituent for R² in the formula (I-1). As R²², a group in which one or more hydrogen atoms have been removed from a phenyl group or a naphthyl group, or a group in which two or more hydrogen atom have been removed from a quinoline group is particularly preferred.

### <Structural Units Composed of Polymer>

The main chain containing an anion part on at least one terminal thereof in the polymer according to the present invention is not particularly limited, and a main chain which is formed by the cleavage of the ethylenic double bond (C═C) is preferable. That is, the polymer according to the present invention is preferably composed of a structural unit derived from a compound containing an ethylenic double bond.

Here, the “structural unit derived from a compound containing an ethylenic double bond” refers to a structural unit in which the ethylenic double bond of the compound containing an ethylenic double bond is cleavaged to form a single bond.

Examples of the compound containing an ethylenic double bond include an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a stylene or derivative thereof which may have the hydrogen atom bonded to the carbon atom on the α-position substituted with a substituent, a vinylnaphthalene or derivative thereof which may have the hydrogen atom bonded to the carbon atom on the α-position substituted with a substituent, a cycloolefine or derivative thereof, a vinyl sulfonate ester and the like.

Among these, an acrylate or ester thereof which may have the hydrogen atom bonded to the carbon atom on the α-position substituted with a substituent, an acrylamide or derivative thereof which may have the hydrogen atom bonded to the carbon atom on the α-position substituted with a substituent, a stylene or derivative thereof which may have the hydrogen atom bonded to the carbon atom on the α-position substituted with a substituent, or a vinylnaphthalene or derivative thereof which may have the hydrogen atom bonded to the carbon atom on the α-position substituted with a substituent is preferable, and an acrylate ester which may have the hydrogen atom bonded to the carbon atom on the α-position substituted with a substituent is preferable.

An “acrylate ester” refers to a compound in which the terminal hydrogen atom of the carboxy group of acrylic acid (CH₂═CH—COOH) has been substituted with an organic group.

In the present specification, an acrylate ester in which the hydrogen atom bonded to the carbon atom on the α-position has been substituted with a substituent is referred to as an “α-substituted acrylate ester”. Further, acrylate esters and α-substituted acrylate esters are collectively referred to as “(α-substituted) acrylate ester”.

Examples of the substituent bonded to the carbon atom on the α-position of the α-substituted acryl ester include a halogen atom, an alkyl group of 1 to 5 carbon atoms, a halogenated alkyl group of 1 to 5 carbon atoms and a hydroxyalkyl group. With respect to the structural unit derived from an acrylate ester, the α-position (the carbon atom on the α-position) refers to the carbon atom having the carbonyl group bonded thereto, unless specified otherwise.

Examples of the halogen atom as the substituent at the α-position include a fluorine atom, a chlorine atom, a bromine atom and an iodine atom.

Specific examples of the alkyl group of 1 to 5 carbon atoms for the substituent at the α-position include linear or branched alkyl groups such as a methyl group, an ethyl group, a propyl group, an isopropyl group, an n-butyl group, an isobutyl group, a tert-butyl group, a pentyl group, an isopentyl group, and a neopentyl group.

Specific examples of the halogenated alkyl group of 1 to 5 carbon atoms as a substituent on the α-position include groups in which part or all of the hydrogen atoms of the aforementioned alkyl group of 1 to 5 carbon atoms are substituted with halogen atoms. Examples of the halogen atom include a fluorine atom, a chlorine atom, a bromine atom and an iodine atom, and a fluorine atom is particularly preferred.

As the hydroxyalkyl group as a substituent on the α-position, a hydroxyalkyl group of 1 to 5 carbon atoms is preferred. Specific examples thereof include a group in which part or all of the hydrogen atoms of the aforementioned alkyl group of 1 to 5 carbon atoms are substituted with hydroxy groups.

In the present invention, it is preferable that a hydrogen atom, an alkyl group of 1 to 5 carbon atoms or a halogenated alkyl group of 1 to 5 carbon atoms is bonded to the α-position of the (α-substituted) acrylate ester, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most preferred.

The organic group within (α-substituted) acrylate ester is not particularly limited. Examples thereof include an acid dissociable group as described above and an —SO₂-containing cyclic group, a lactone-containing cyclic group, and a polar group-containing hydrocarbon group, a characteristic group such as an aliphatic polycyclic group within an acid non-dissociable group, and a characteristic group-containing group which contains a characteristic group in the structure thereof explained in relation to the structural units (a2) to (a4) described later. Examples of the characteristic group-containing group include a group in which a divalent linking group is bonded to the characteristic group. Examples of the divalent linking group include the same divalent linking groups as those described for Y² in the formula (c-2) described later.

Examples of the “acrylamide and derivative thereof” include an acryl amide which may have the hydrogen atom bonded to the carbon atom on the α-position substituted with a substituent (hereafter, referred to as (α-substituted) acrylamide) and a compound in which one or both of hydrogen atoms on the terminal of the amino group within the (α-substituted) acrylamide is substituted with a subsituent.

As the substituent which may be bonded to the carbon atom on the α-position of an acrylamide or derivatives thereof, the same substituents as those described above for the substituent to be bonded to the carbon atom on the α-position of an α-substituted acrylate ester

As the substituent with which one or both of hydrogen atoms on the terminal of the amino group within (α-substituted) acrylamide is substituted, an organic group is preferable. The organic group is not particularly limited, and examples thereof include the same groups as described for the organic groups within the (α-substituted) acrylate ester.

Examples of the compound in which one or both of hydrogen atoms on the terminal of the amino group within the (α-substituted)acrylamide is substituted with a subsituent include a compound in which —C(═O)—O— bonded to the carbon atom on the α-position of the (α-substituted) acrylamide is substituted with —C(═O)—N(R^{b})— [in the formula, R^{b} represents a hydrogen atom or an alkyl group of 1 to 5 carbon atoms].

In the formula, the alkyl group for R^{b} is preferably a linear or branched alkyl group.

The “styrene and derivative thereof” may have the hydrogen atom bonded to the carbon atom on the α-position substituted with a substituent, and examples thereof include a styrene which may have the hydrogen atom bonded to the benzene ring substituted with a substituent other than the hydroxy group (hereafter, referred to as (α-substituted) styrene), a hydroxystyrene which may have the hydrogen atom bonded to the carbon atom on the α-position substituted with a substituent and may have a hydrogen atom bonded to the benzene ring substituted with a substituent other than a hydroxy group (hereafter, referred to as (α-substituted) hydroxystyrene), a compound in which a hydrogen atom of a hydroxy group within the (α-substituted) hydroxystyrene is substituted with an organic group, a vinylbenzoic acid which may have the hydrogen atom bonded to the carbon atom on the α-position substituted with a substituent and may have a hydrogen atom bonded to the benzene ring substituted with a substituent other than a hydroxy group and carboxy group (hereafter, referred to as (α-substituted) vinylbenzoic acid), and a compound in which a hydrogen atom of carboxy group within the (α-substituted)vinylbenzoic acid is substituted with an organic group.

A hydroxystyrene is a compound which has one vinyl group and at least one hydroxy group bonded to a benzene ring. The number of hydroxy groups bonded to the benzene ring is preferably 1 to 3, and most preferably 1. The bonding position of the hydroxy group on the benzene ring is not particularly limited. When the number of the hydroxy group is 1, a para (4^{th}) position against the bonding position of the vinyl group is preferable. When the number of the hydroxy groups is an integer of 2 or more, an arbitrary combination of the bonding positions can be adopted.

The vinylbenzoic acid is a compound in which one vinyl group is bonded to the benzene ring within the benzoic acid.

The bonding position of the vinyl group on the benzene ring is not particularly limited.

As the substituent which may be bonded to the carbon atom on the α-position of a stylene or derivatives thereof, the same substituents as those described above for the substituent to be bonded to the carbon atom on the α-position of the α-substituted acrylate ester.

The substituent other than a hydroxy group or carboxy group which may be bonded to the benzene ring of an styrene or derivative thereof is not particularly limited, and examples thereof include a halogen atom, an alkyl group of 1 to 5 carbon atoms and a halogneated alkyl group of 1 to 5 carbon atoms. Examples of the halogen atom include a fluorine atom, a chlorine atom, a bromine atom and an iodine atom, and a fluorine atom is particularly preferred.

The organic group within a compound in which the hydrogen atom of the hydroxyl group of the (α-substituted) hydroxystyrene is substituted with an organic group is not particularly limited, and examples thereof include the same groups as described for the organic groups within the (α-substituted) acrylate ester.

The organic group within a compound in which the hydrogen atom of the carboxy group of the (α-substituted) vinylbenzoic acid is substituted with an organic group is not particularly limited, and examples thereof include the same groups as described for the organic groups within the (α-substituted) acrylate ester.

The “vinylnaphthalene and derivative thereof” may have the hydrogen atom bonded to the carbon atom on the α-position substituted with a substituent, and examples thereof include a vinylnaphthalene which may have the hydrogen atom bonded to the naphthalene ring substituted with a substituent other than the hydroxy group (hereafter, referred to as (α-substituted) vinyl naphthalene), a vinyl(hydroxynaphthalene) which may have the hydrogen atom bonded to the carbon atom on the α-position substituted with a substituent and may have a hydrogen atom bonded to the naphthalene ring substituted with a substituent other than a hydroxy group (hereafter, referred to as (α-substituted) vinyl(hydroxynaphthalene) and a compound in which a hydrogen atom of hydroxy group within the (α-substituted) vinyl(hydroxynaphthalene) is substituted with a substituent.

A vinyl(hydroxynaphthalene) is a compound which has one vinyl group and at least one hydroxy group bonded to a naphthalene ring. The vinyl group may be bonded to the 1st or 2nd position of the naphthalene ring. The number of hydroxy groups bonded to the naphthalene ring is preferably 1 to 3, and particularly preferably 1. The bonding position of the hydroxy group on the naphthalene ring is not particularly limited. When the vinyl group is bonded to the 1st or 2nd position of the naphthalene ring, the hydroxy group is preferably bonded to either one of the 5th to 8th position of the naphthalene ring. In particular, when the number of hydroxy group is 1, the hydroxy group is preferably bonded to either one of the 5th to 7th position of the naphthalene ring, and more preferably the 5th or 6th position. When the number of the hydroxy group is an integer of 2 or more, an arbitrary combination of the bonding positions can be adopted.

As the substituent which may be bonded to the carbon atom on the α-position of a vinylnaphthalene or derivatives thereof, the same substituents as those described above for the substituent to be bonded to the carbon atom on the α-position of an α-substituted acrylate ester.

As the substituent which may be bonded to the naphthanlene ring of the vinylnaphthalene or derivative thereof, the same substituents as those described above for the substituent other than a hydroxy group which may be bonded to the benzene ring of the (α-substituted) styrene can be mentioned.

The organic group within a compound in which the hydrogen atom within the hydroxyl group of the (α-substituted) vinyl(hydroxystyrene) is substituted with an organic group is not particularly limited, and examples thereof include the same groups as described for the organic groups within the (α-substituted) acrylate ester.

Specific examples of the structural unit derived from the (α-substituted) acrylic acid or ester thereof include a structural unit represented by the general formula (I).

Specific examples of the structural unit derived from the (α-substituted) acrylamide or derivative thereof include a structural unit represented by the general formula (II).

Specific examples of the structural unit derived from the (α-substituted) styrene or derivative thereof include a structural unit represented by the general formula (III).

Specific examples of the structural unit derived from the (α-substituted)vinylnaphthalene or derivative thereof include a structural unit represented by the general formula (IV).

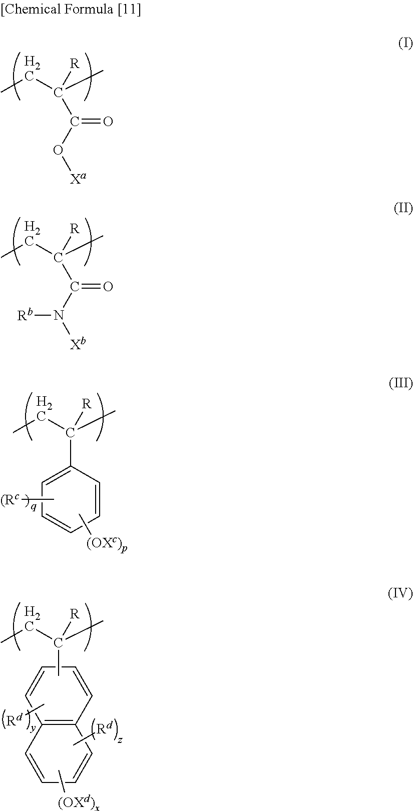

In the formula, R represents a hydrogen atom, an alkyl group of 1 to 5 carbon atoms or a halogenated alkyl group of 1 to 5 carbon atoms; each of X^{a} to X^{d} independently represents a hydrogen atom or an organic group; R^{b} represents a hydrogen atom or an alkyl group of 1 to 5 carbon atoms; each of R^{c} and R^{d} independently represents a halogen atom, —COOX^{c} (wherein, X^{c} represents a hydrogen atom or an organic group), an alkyl group of 1 to 5 carbon atoms or a halogenated alkyl group of 1 to carbon atoms; p represents an integer of 0 to 3; q represents an integer of 0 to 5, with the provision that p+q=0 to 5; provided that when q is an integer of 2 or more, the plurality of R^{c} group may be the same or different from each other; x represents an integer of 0 to 3; y represents an integer of 0 to 3; and z represents an integer of 0 to 4, with the provision that x+y+z=0 to 7, provided that when y+z is an integer of 2 or more, the plurality of R^{d} may be the same or different from each other.

(Structural Unit (a1))

The polymer according to the present invention includes at least one structural unit (a1) containing an acid decomposable group which exhibits increased polarity by the action of acid, as a structural unit which constitutes the polymer.

The term “acid decomposable group” refers to a group in which at least a part of the bond within the structure thereof is cleaved by the action of acid generated from the anion part on the terminal of the main chain or the component (B) described later upon exposure.

Examples of acid decomposable groups which exhibit increased polarity by the action of an acid include groups which are decomposed by the action of an acid to form a polar group.

Examples of the polar group include a carboxy group, a hydroxy group, an amino group and a sulfo group (—SO₃H). Among these, a polar group containing —OH in the structure thereof (hereafter, referred to as “OH-containing polar group”) is preferable, a carboxy group or a hydroxy group is more preferable, and a carboxy group is particularly preferred.

Specific examples of an acid decomposable group include a group in which the aforementioned polar group has been protected with an acid dissociable group (such as a group in which the hydrogen atom of the OH-containing polar group has been protected with an acid dissociable group) can be given.

An “acid dissociable group” is a group in which at least the bond between the acid dissociable group and the atom adjacent to the acid dissociable group is cleaved by the action of acid generated from the anion part on the terminal of the main chain or the component (B) upon exposure. It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group having a higher polarity than that of the acid dissociable group is generated, thereby increasing the polarity. As a result, the polarity of the entire polymer is increased. When the polarity of the polymer is increased, the solubility of the polymer in a developing solution is relatively changed. In the case that the developing solution is an alkali developing solution, the solubility is increased. On the other hand, in the case that the developing solution is a developing solution containing an organic solvent (organic developing solution), the solubility is decreased.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxy group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and aliphatic cyclic group-containing acid dissociable groups.

The term “aliphatic branched” refers to a branched structure having no aromaticity. The “aliphatic branched, acid dissociable group” is not limited to be constituted of only carbon atoms and hydrogen atoms (not limited to hydrocarbon groups), but is preferably a hydrocarbon group. Further, the “hydrocarbon group” may be either saturated or unsaturated, but is preferably saturated.

As an example of the aliphatic branched, acid dissociable group, for example, a group represented by the formula —C(R⁷¹)(R⁷²)(R⁷³) can be given. in the formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly preferred.

The term “aliphatic cyclic group” refers to a monocyclic group or polycyclic group that has no aromaticity.

In the “aliphatic cyclic group-containing acid dissociable group”, the “aliphatic cyclic group” may or may not have a substituent. Examples of the substituent include an alkyl group of 1 to 5 carbon atoms, an alkoxyl group of 1 to 5 carbon atoms, a fluorine atom, a fluorinated alkyl group of 1 to 5 carbon atoms, and an oxygen atom (═O).

The basic ring of the “aliphatic cyclic group” exclusive of substituents is not limited to be constituted from only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either a monocyclic group or a polycyclic group.

The aliphatic cyclic group preferably has 3 to 30 carbon atoms, more preferably 5 to 30, still more preferably 5 to 20, particularly preferably 6 to 15, and most preferably 6 to 12. As the monocyclic aliphatic cyclic group, a group in which one or more hydrogen atoms have been removed from a monocycloalkane is preferable. The monocycloalkane preferably has 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycyclic group preferably has 7 to 12 carbon atoms. Examples of the polycycloalkane include adamantane, norbornane, isobornane, tricyclodecane and tetracyclododecane. In these aliphatic cyclic groups, part of the carbon atoms constituting the ring may be replaced with an ethereal oxygen atom (—O—).

Examples of aliphatic cyclic group-containing acid dissociable groups include

(i) a monovalent aliphatic cyclic group in which a substituent (a group or an atom other than hydrogen) is bonded to the carbon atom on the ring skeleton to which an atom adjacent to the acid dissociable group (e.g., “—O—” within “—C(═O)—O— group”) is bonded to form a tertiary carbon atom; and

(ii) a group which has a branched alkylene group containing a tertiary carbon atom, and a monovalent aliphatic cyclic group to which the tertiary carbon atom is bonded.

In the group (i), as the substituent bonded to the carbon atom to which an atom adjacent to the acid dissociable group on the ring skeleton of the aliphatic cyclic group, an alkyl group can be mentioned. Examples of the alkyl group include the same groups as those represented by R¹⁴ in formulas (I-1) to (1-9) described later.

Specific examples of the group (i) include groups represented by general formulas (1-1) to (1-9) shown below.

Specific examples of the group (ii) include groups represented by general formulas (2-1) to (2-6) shown below.

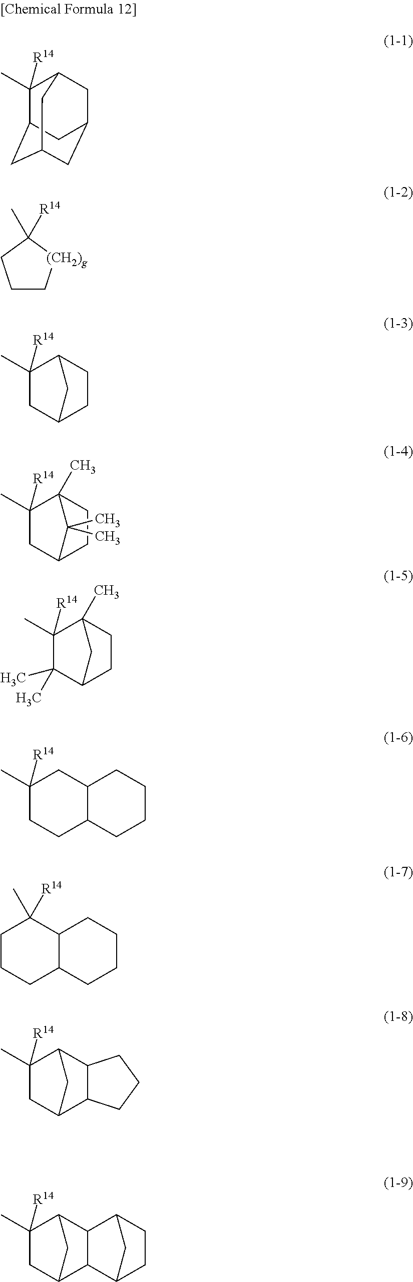

In the formulas above, R¹⁴ represents an alkyl group; and g represents an integer of 0 to 8.

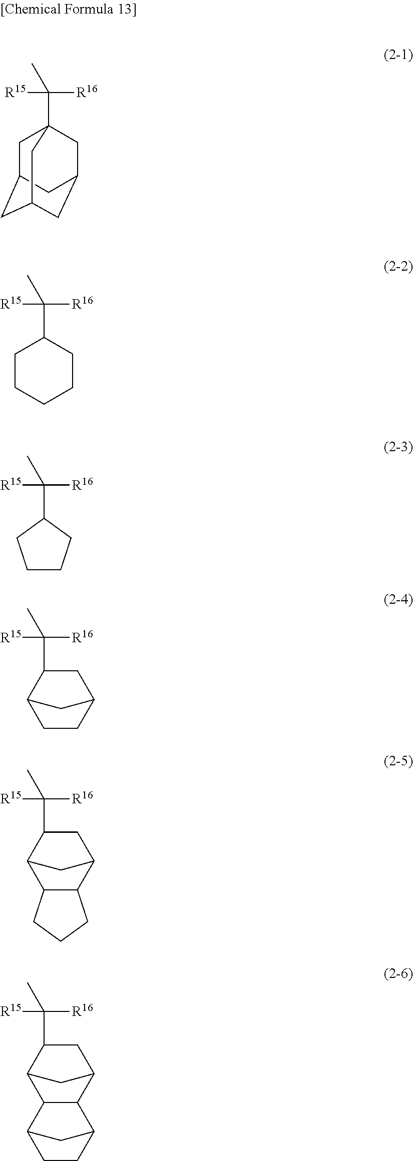

In the formulas above, each of R¹⁵ and R¹⁶ independently represents an alkyl group.

In formulas (1-1) to (1-9), the alkyl group for R¹⁴ may be linear, branched or cyclic, and is preferably linear or branched.

The linear alkyl group preferably has 1 to 5 carbon atoms, more preferably 1 to 4, and still more preferably 1 or 2. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5. Specific examples of such branched alkyl groups include an isopropyl group, an isobutyl group, a tert-butyl group, an isopentyl group and a neopentyl group, and an isopropyl group is particularly preferred.

g is preferably an integer of 0 to 3, more preferably 1 to 3, and still more preferably 1 or 2.

In formulas (2-1) to (2-6), as the alkyl group for R¹⁵ and R¹⁶, the same alkyl groups as those for R″ can be used.

In formulas (1-1) to (1-9) and (2-1) to (2-6), part of the carbon atoms constituting the ring may be replaced with an ethereal oxygen atom (—O—).

Further, in formulas (1-1) to (1-9) and (2-1) to (2-6), one or more of the hydrogen atoms bonded to the carbon atoms constituting the ring may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxy group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxy group or a hydroxy group.

Examples of acetal-type acid dissociable groups include groups represented by general formula (p1) shown below.

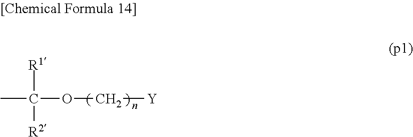

In the formula, R¹′ and R²′ each independently represent a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R¹′ and R²′, the same alkyl groups as those described above in the explanation of the alkyl groups as the substituent on the α-position of the aforementioned alkylester can be used, although a methyl group or ethyl group is preferable, and a methyl group is particularly preferred.

In the present invention, it is preferable that at least one of R¹′ and R²′ be a hydrogen atom. That is, it is preferable that the acid dissociable group (p1) is a group represented by general formula (p1-1) shown below.

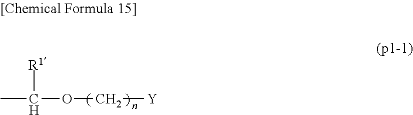

In the formula, R¹″, n and Y are the same as defined above.

As the alkyl group for Y, the same alkyl groups as those described above for the substituent which may be bonded to the carbon atom on the α-position of the aforementioned alkylester can be mentioned.

As the aliphatic cyclic group for Y, any of the aliphatic monocyclic/polycyclic groups which have been proposed for conventional ArF resists and the like can be appropriately selected for use. For example, the same aliphatic cyclic groups described above in connection with the “acid dissociable group containing an aliphatic cyclic group” can be used.

Further, as the acetal-type, acid dissociable group, groups represented by general formula (p2) shown below can also be used.

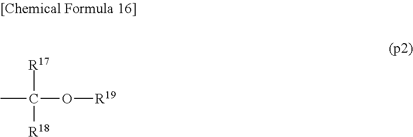

In the formula, R¹⁷ and R¹⁸ each independently represent a linear or branched alkyl group or a hydrogen atom; and R¹⁹ represents a linear, branched or cyclic alkyl group; or R¹⁷ and R¹⁹ each independently represents a linear or branched alkylene group, and the R¹⁷ group may be bonded to the R¹⁹ group to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly preferable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. As examples of the cycloalkyl group, the same aliphatic cyclic group as those described above, such as groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Among these, a group in which one or more hydrogen atoms have been removed from adamantane is preferable.

In general formula (p2) above, R¹⁷ and R¹⁸ may each independently represent a linear or branched alkylene group (preferably an alkylene group of 1 to 5 carbon atoms), and the R¹⁹ group may be bonded to the R¹⁷ group.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4 to 7-membered ring, and more preferably a 4 to 6-membered ring. Specific examples of the cyclic group include tetrahydropyranyl group and tetrahydrofuranyl group.

With respect to the structural unit (a1), the partial structure other than the acid decomposable group is not particularly limited as long as the structural unit (a1) having an acid decomposable group. Examples of the structural unit (a1) include a structural unit (a11) which derived from an acrylate ester which may have the hydrogen atom bonded to the carbon atom on the α-position substituted with a substituent and contains an acid decomposable group which exhibits increased polarity by the action of acid, a structural unit (a12) in which at least part of the hydrogen atoms of the hydroxy group in a structural unit derived from a hydroxystyrene or derivative thereof is protected with an acid decomposable group or a substituent containing an acid decomposable group, and a structural unit (a13) in which at least part of the hydrogen atom of —C(═O)—OH in a structural unit derived from a vinylbenzoic acid or derivative thereof is protected with an acid decomposable group or a substituent containing an acid decomposable group.

As the acid decomposable group and acid dissociable group in the structural units (a11) to (a13), the same groups as those described above can be used.

Among these, as the structural unit (a1), a structural unit (a11) is preferred.

[Structural Unit (a11)]

Specific examples of the structural unit (a11) include a structural unit represented by general formula (a11-0-1) shown below and a structural unit represented by general formula (a11-0-2) shown below.

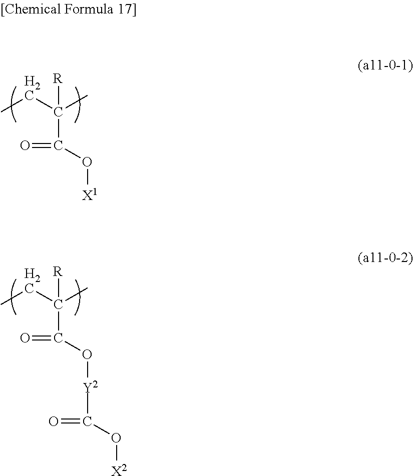

In the formulas, R represents a hydrogen atom, an alkyl group of 1 to 5 carbon atoms or a halogenated alkyl group of 1 to 5 carbon atoms; X¹ represents an acid dissociable group; Y² represents a divalent linking group; and X² represents an acid dissociable group.

In general formula (c-1), the alkyl group and the halogenated alkyl group for R are respectively the same as defined for the alkyl group and the halogenated alkyl group for the substituent which may be bonded to the carbon atom on the α-position of the aforementioned substituted acrylate ester. R is preferably a hydrogen atom, an alkyl group of 1 to 5 carbon atoms or a fluorinated alkyl group of 1 to 5 carbon atoms, and most preferably a hydrogen atom or a methyl group.

X¹ is not particularly limited as long as it is an acid dissociable group. Examples thereof include the aforementioned tertiary alkyl ester-type acid dissociable groups and acetal-type acid dissociable groups, and tertiary alkyl ester-type acid dissociable groups are preferable.

In general formula (a11-0-2), R is the same as defined above. X² is the same as defined for X¹ in general formula (a11-0-1).

The divalent linking group for Y² is not particularly limited, and preferable examples thereof include a divalent hydrocarbon group which may have a substituent and a divalent linking group containing a hetero atom.

As the divalent linking group which may have a substituent and the divalent linking group containing a hetero atom are the same divalent linking groups as those described above for Win the formula (c-21).

As Y², a linear or branched alkylene group, a divalent alicyclic hydrocarbon group or a divalent linking group containing a hetero atom is particularly preferred.

When Y² represents a linear or branched alkylene group, it preferably has 1 to 10 carbon atoms, more preferably 1 to 6, still more preferably 1 to 4, and most preferably 1 to 3. Specific examples include the same linear alkylene groups and branched alkylene groups as those described above for the aliphatic hydrocarbon group represented by R¹. When Y² represents a divalent alicyclic hydrocarbon group, as the alicyclic hydrocarbon group, the same alicyclic hydrocarbon groups as those described above for the “aliphatic hydrocarbon group containing a ring in the structure thereof” explained above in relation to Y² can be used.

As the alicyclic hydrocarbon group, a group in which two or more hydrogen atoms have been removed from cyclopentane, cyclohexane, norbornane, isobornane, adamantane, tricyclodecane or tetracyclododecane, is particularly preferred.

When Y² represents a divalent linking group containing a hetero atom, preferably examples of the divalent linking group containing a hetero atom include —O—, —C(═O)—O—, —C(═O)—, —O—C(═O)—O—, —C(═O)—NH—, —NH— (H may be substituted with a substituent such as an alkyl group or an acyl group), —S—, —S(═O)₂—, —S(═O)₂—O—, —Y²¹—O—Y²²—, —[Y²¹—C(═O)—)]ₘ—Y²²— or —Y²¹—O—C(═O)—Y²² [in the formulas, each of Y²¹ and Y²² independently represents a divalent hydrocarbon group which may have a substituent, O represents an oxygen atom, and m′ represents an integer of 0 to 3].

When Y² represents —NH—, H may be substituted with a substituent such as an alkyl group, an aryl group (an aromatic group) or the like. The substituent (an alkyl group, an aryl group or the like) preferably has 1 to 10 carbon atoms, more preferably 1 to 8, and most preferably 1 to 5.

In the formula —Y²¹—O—Y²²—, —[Y²¹—C(═O)—O]_{m′}—Y²²— or —Y²¹—O—C(═O)—Y²²—, each of Y²¹ and Y²² independently represents a divalent hydrocarbon group which may have a substituent. As the divalent hydrocarbon group, the same groups as those described above for the “divalent hydrocarbon group which may have a substituent” for Y², can be mentioned.

As Y²¹, a linear aliphatic hydrocarbon group is preferable, more preferably a linear alkylene group, still more preferably a linear alkylene group of 1 to 5 carbon atoms, and a methylene group or an ethylene group is particularly preferred.

As Y²², a linear or branched aliphatic hydrocarbon group is preferable, and a methylene group, an ethylene group or an alkylmethylene group is more preferable. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]ₘ′—Y²²—, m′ represents an integer of 0 to 3, preferably an integer of 0 to 2, more preferably 0 or 1, and most preferably 1. Namely, it is particularly preferable that the group represented by the formula —[Y²¹—C(═O)—O]ₘ′—Y²²— is a group represented by the formula —Y²¹—C(═O)—O—Y²²—. Among these, a group represented by the formula —(CH₂)_{a′}—C(═O)—O—(CH₂)_{b′}— is preferable. In the formula, a′ is an integer of 1 to 10, preferably an integer of 1 to 8, more preferably an integer of 1 to 5, still more preferably 1 or 2, and most preferably 1. b′ is an integer of 1 to 10, preferably an integer of 1 to 8, more preferably an integer of 1 to 5, still more preferably 1 or 2, and most preferably 1.

As the divalent linking group containing a hetero atom for Y², an organic group which is constituted of a combination of at least one of non-hydrocarbon groups and a divalent hydrocarbon group can be mentioned. In particular, as the divalent linking group containing a hetero atom, a linear group containing an oxygen atom as the hetero atom e.g., a group containing an ether bond or an ester bond is preferable, and a group represented by the aforementioned formula —Y²¹—O—Y²²—, —[Y²¹—C(═O)—O]_{m′}—Y²²— or —Y²¹—O—C(═O)—Y²²— is more preferable, and —Y²¹—C(═O)_{m′}—Y²²— or —Y²¹—O—C(═O)—Y²²— is still more preferable.

Among these, as for Y², a linear or branched alkylene group or a divalent linking group containing a hetero atom is preferable, and a linear or branched alkylene group, a group represented by the formula —Y²¹—O—Y²²—, a group represented by the formula —[Y²¹—C(═O)—O]_{m′}—Y²²— or a group represented by the formula —Y²¹—O—C(═O)—Y²²— is more preferable.

Specific examples of the structural unit (a11) include structural units represented by general formulas (a1-1) to (a1-4) shown below.

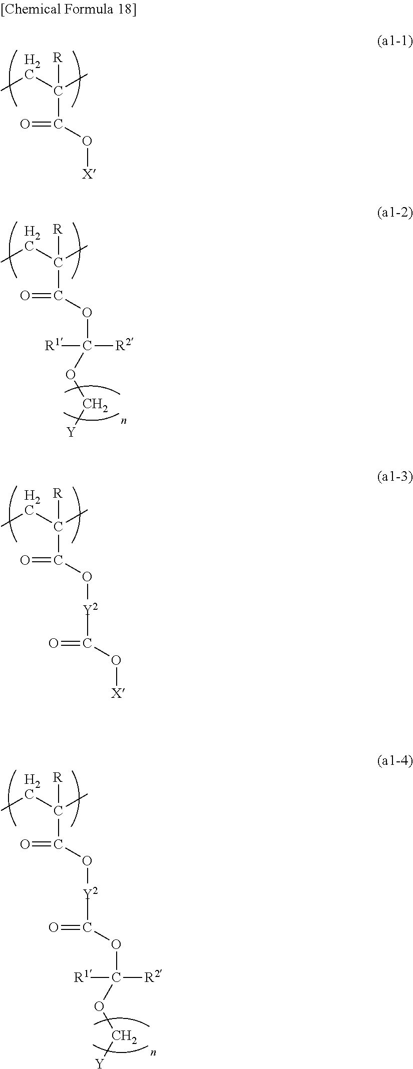

In the formulas, R, R¹′, R²′, n, Y and Y² are the same as defined above; and X′ represents a tertiary alkyl ester-type acid dissociable group.

In the formulas, the tertiary alkyl ester-type acid dissociable group for X′ include the same tertiary alkyl ester-type acid dissociable groups as those described above.

As R¹′, R²′, n and Y are respectively the same as defined for R¹, R²′, n and Y in general formula (p1) described above in connection with the “acetal-type acid dissociable group”.

Y² is the same as defined for Y² in general formula (c-2).

Specific examples of structural units represented by general formula (a1-1) to (a1-4) are shown below.

In the formulas shown below, R^{α} represents a hydrogen atom, a methyl group or a trifluoromethyl group.

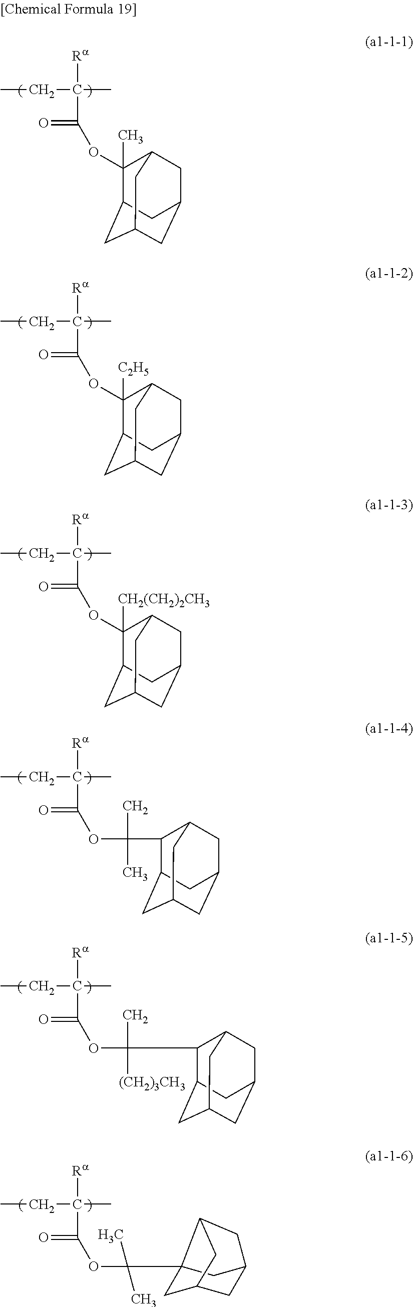

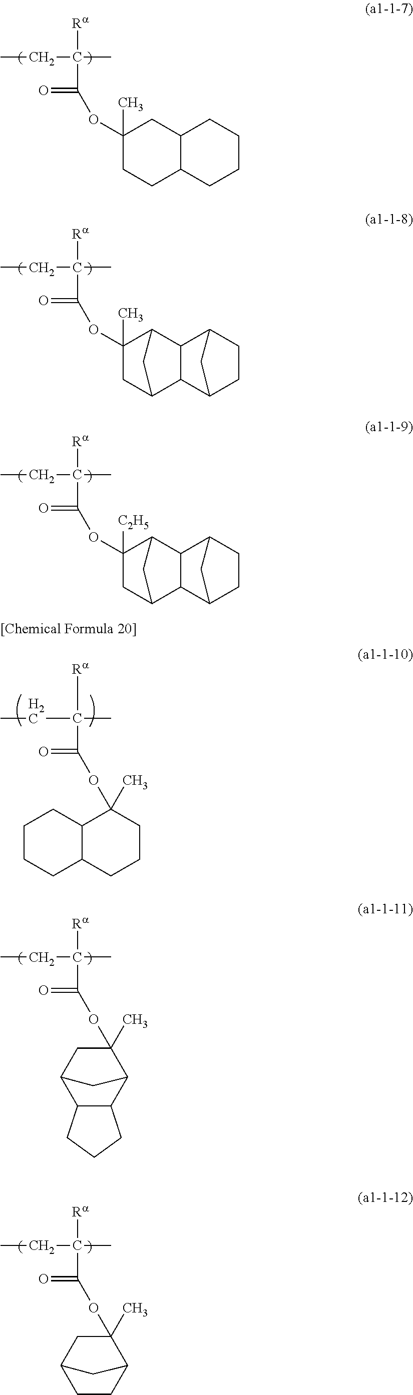

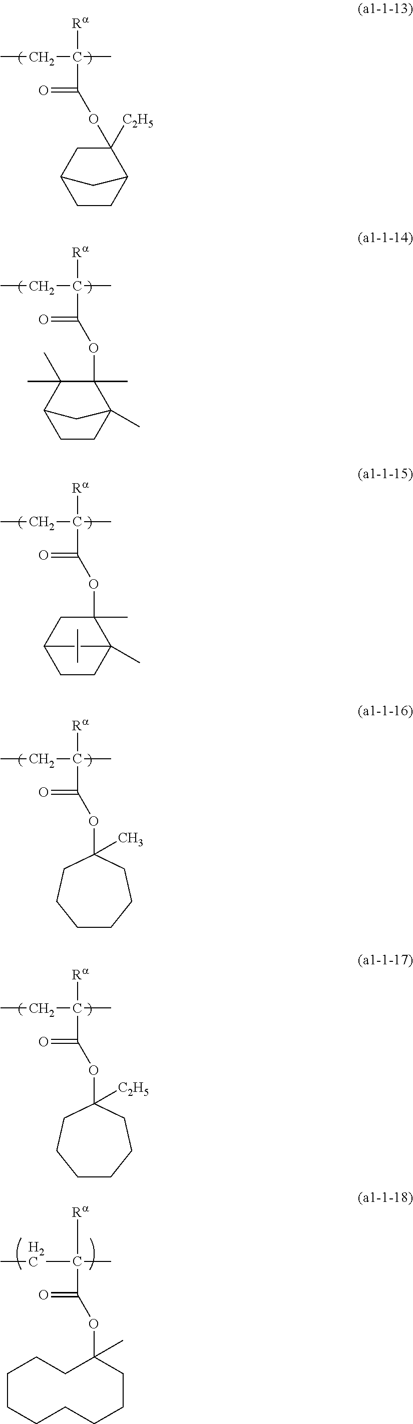

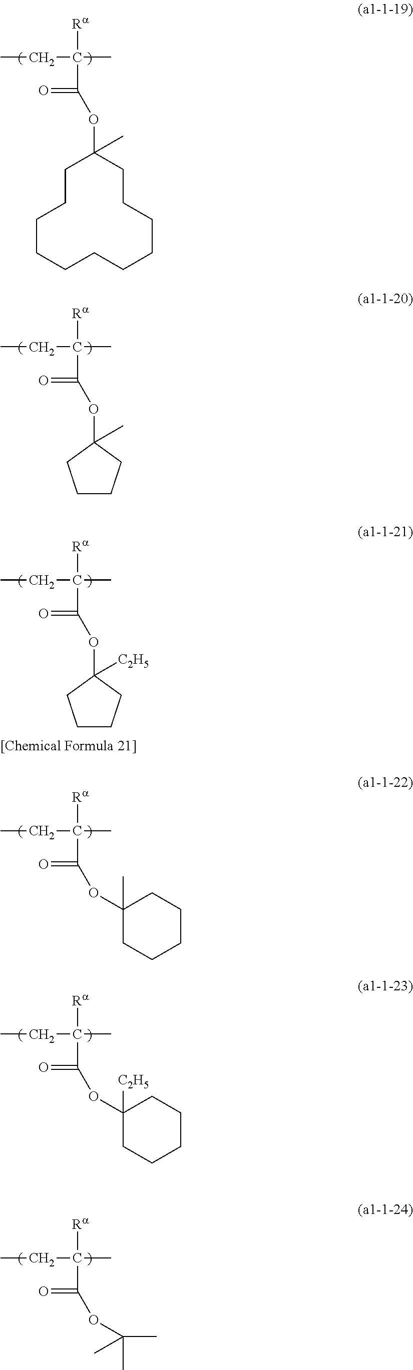

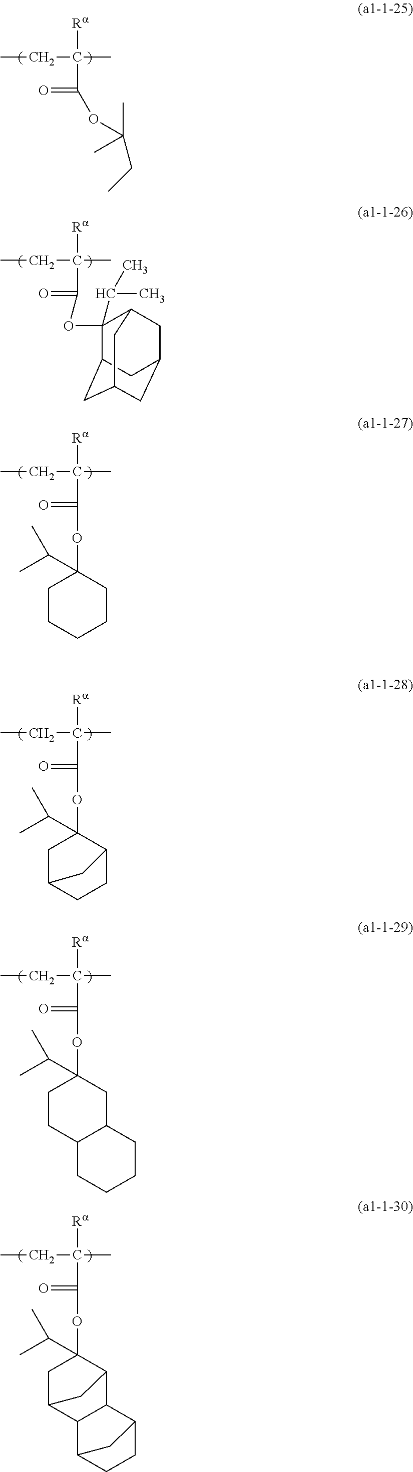

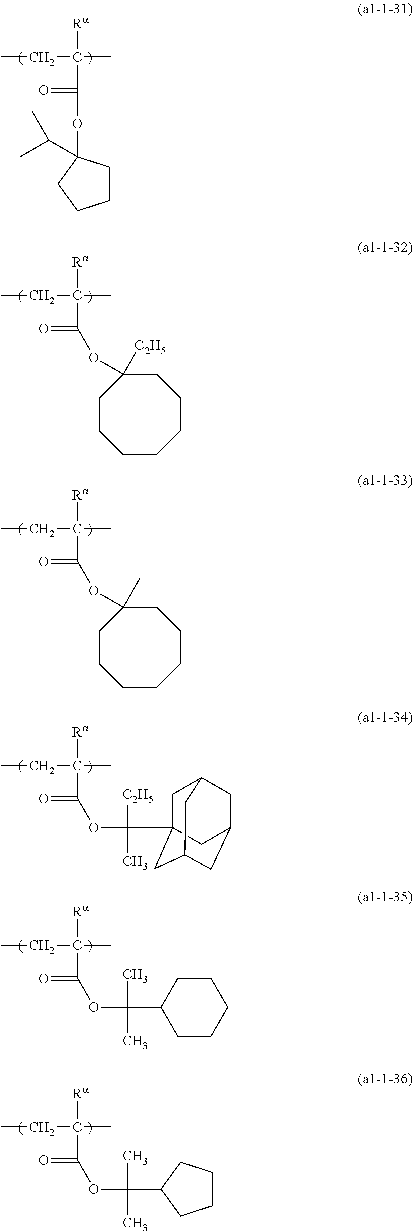

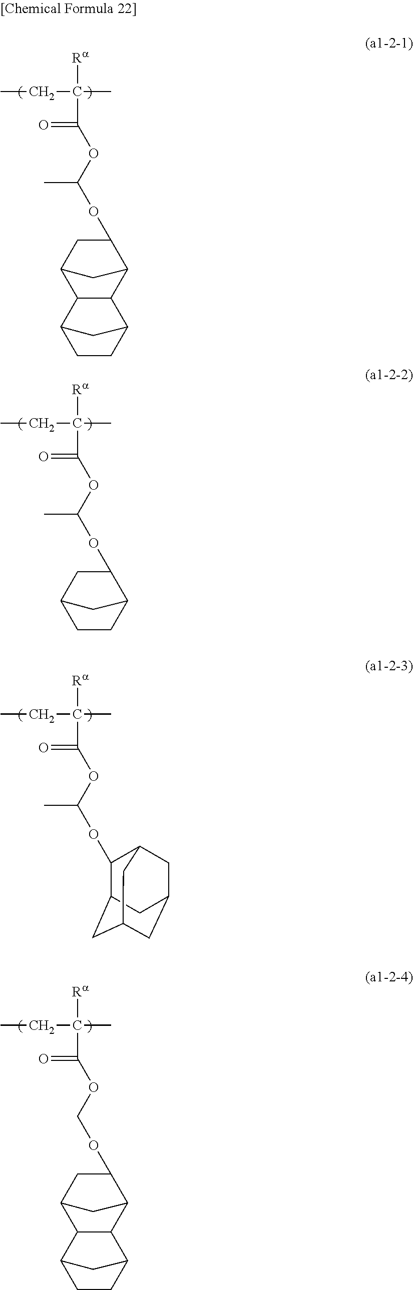

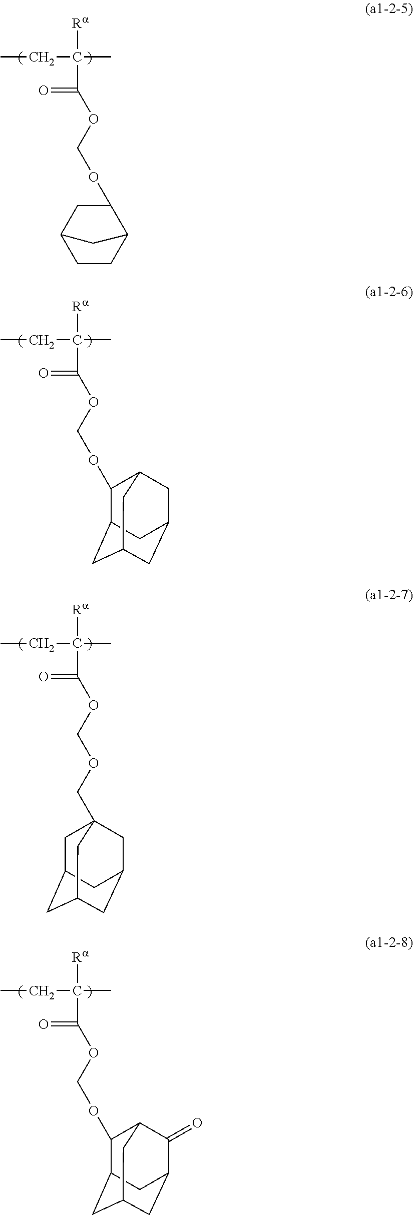

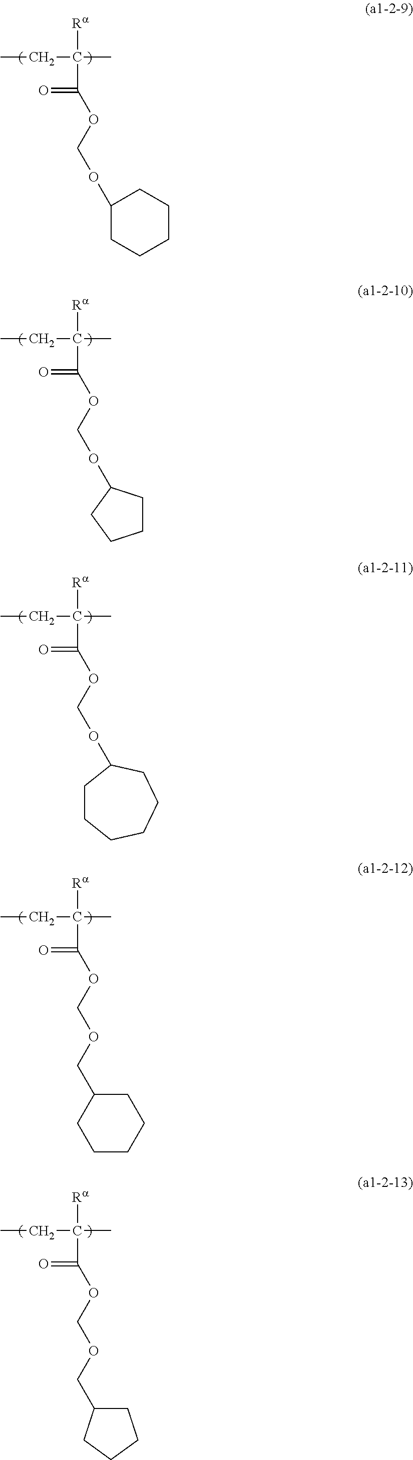

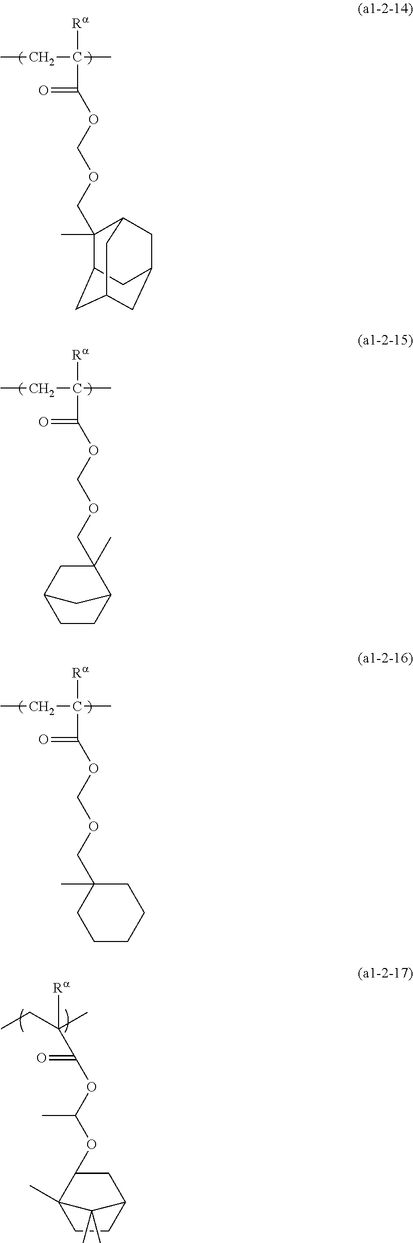

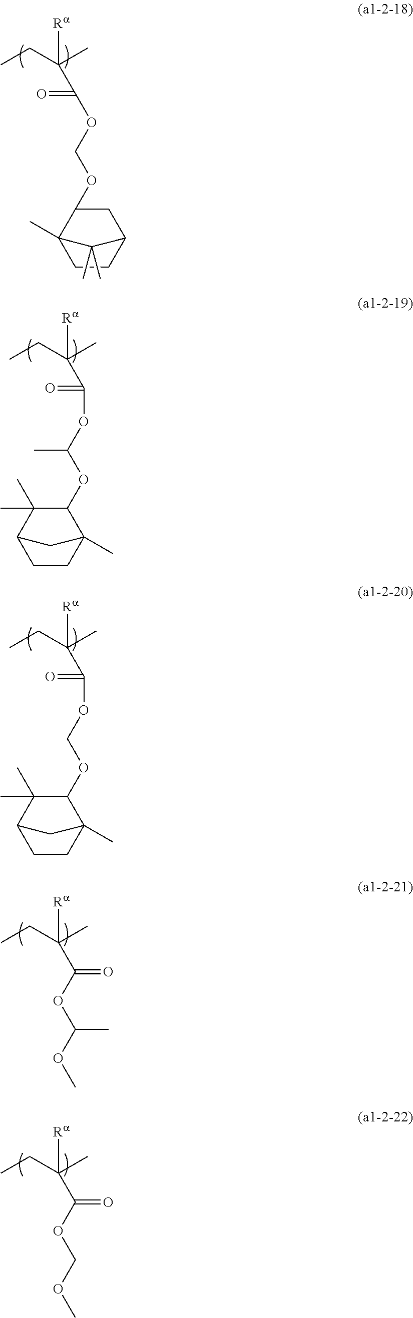

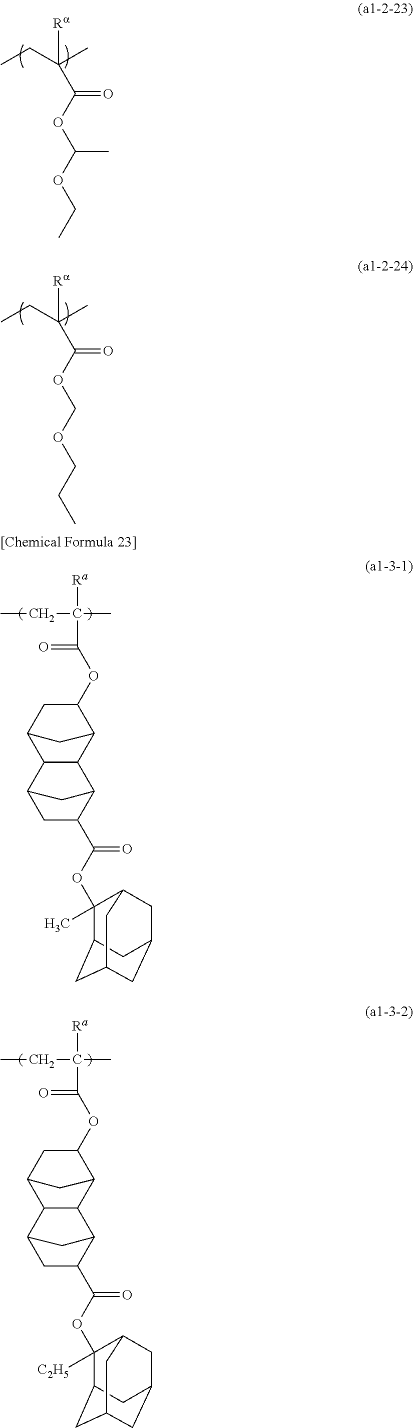

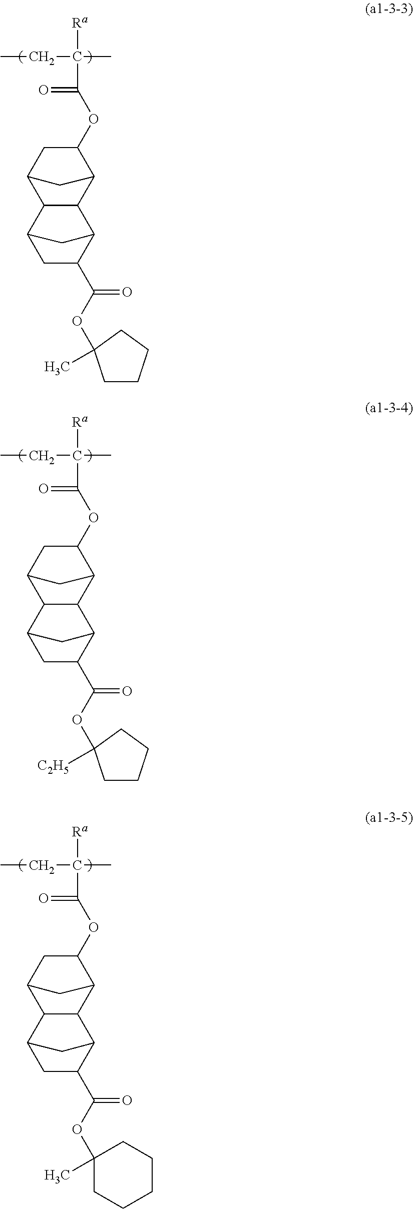

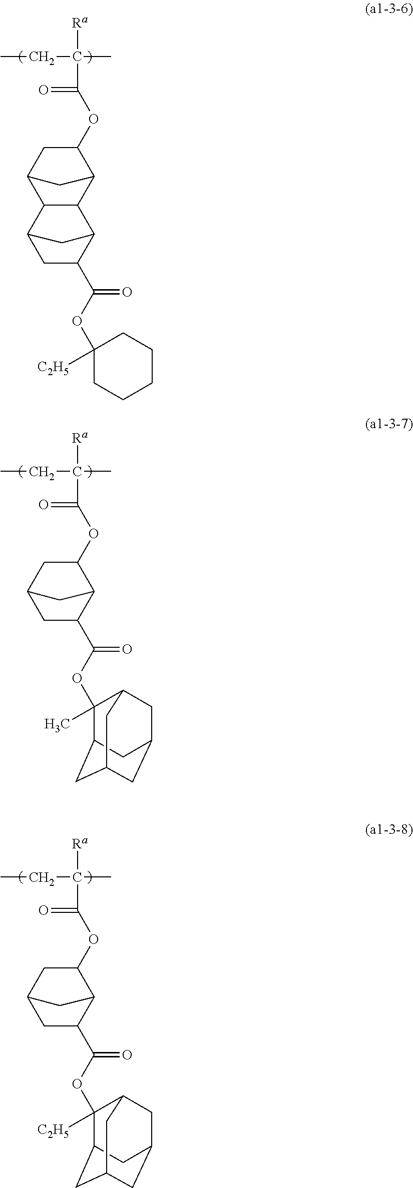

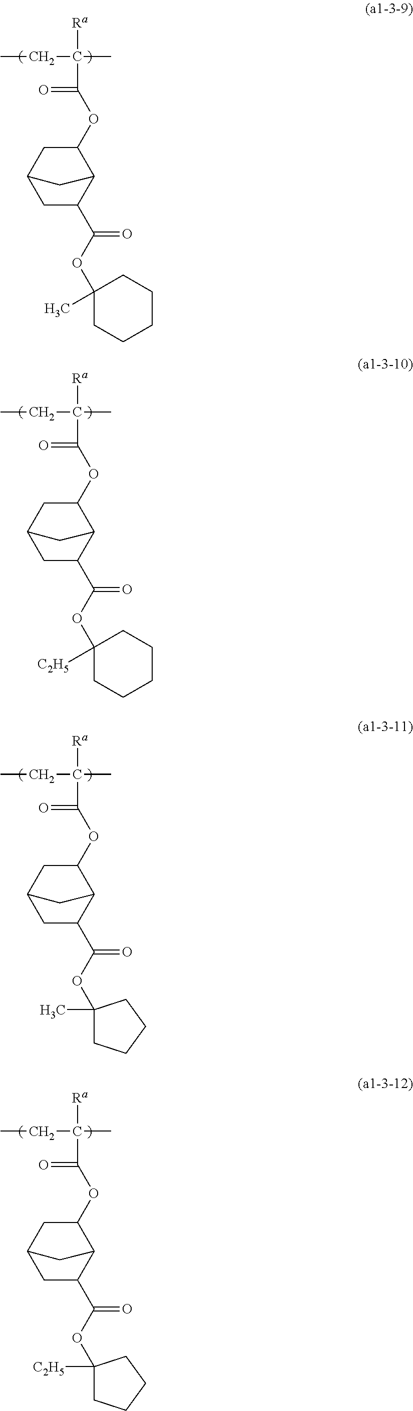

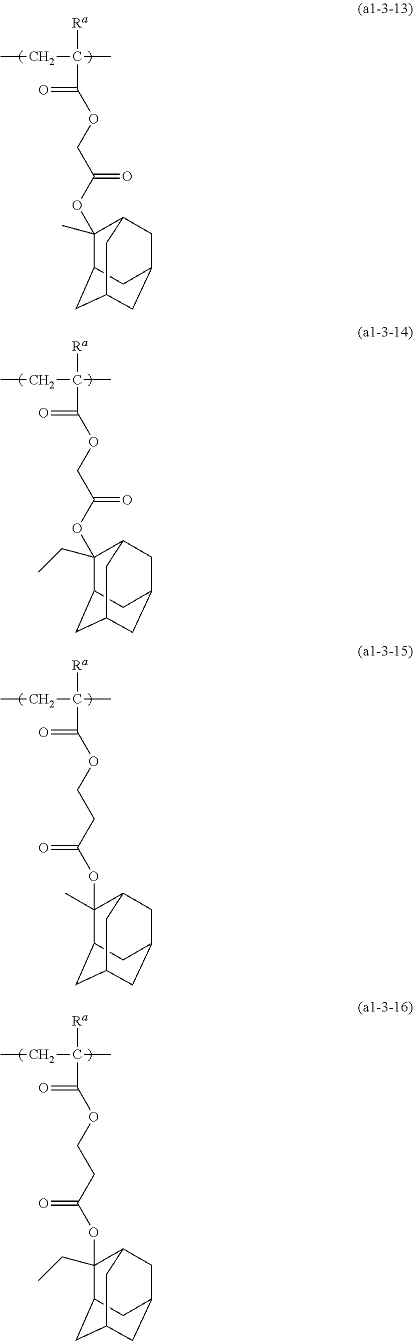

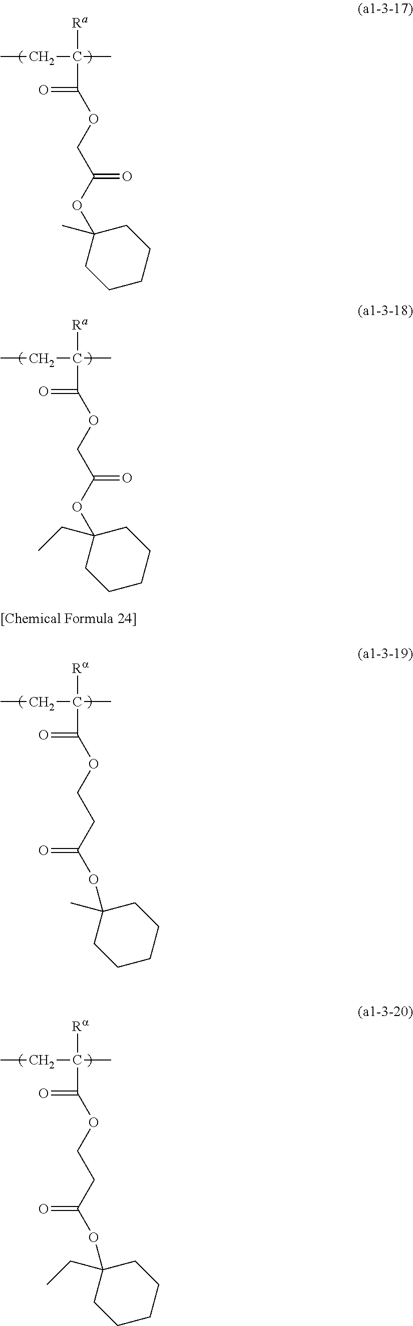

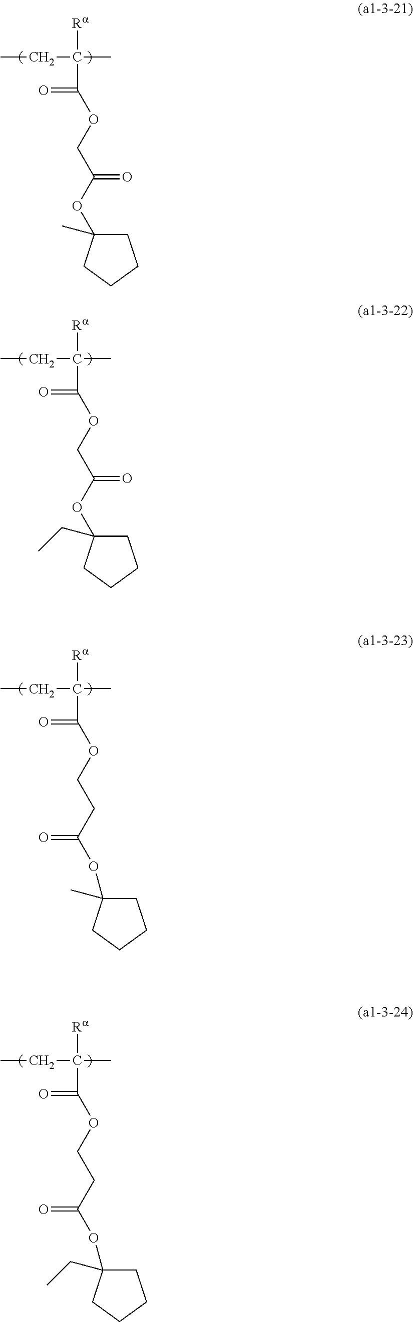

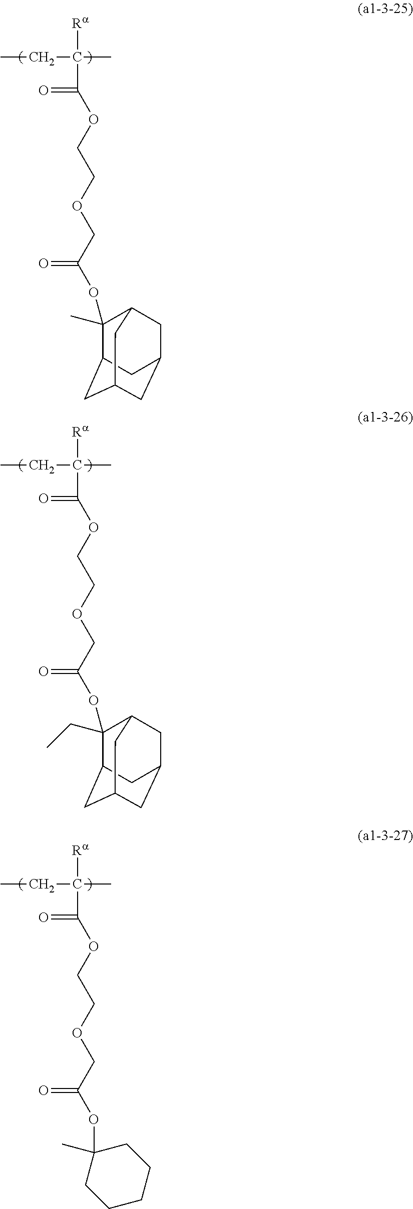

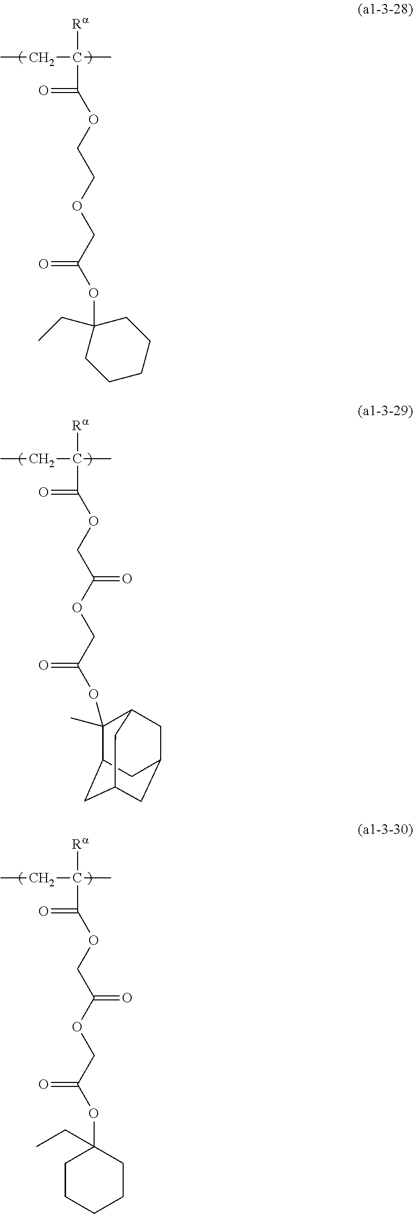

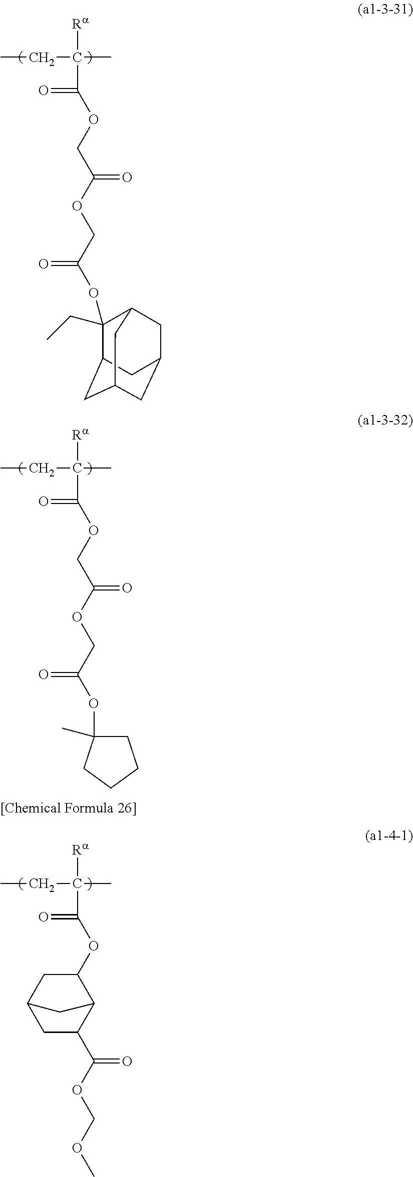

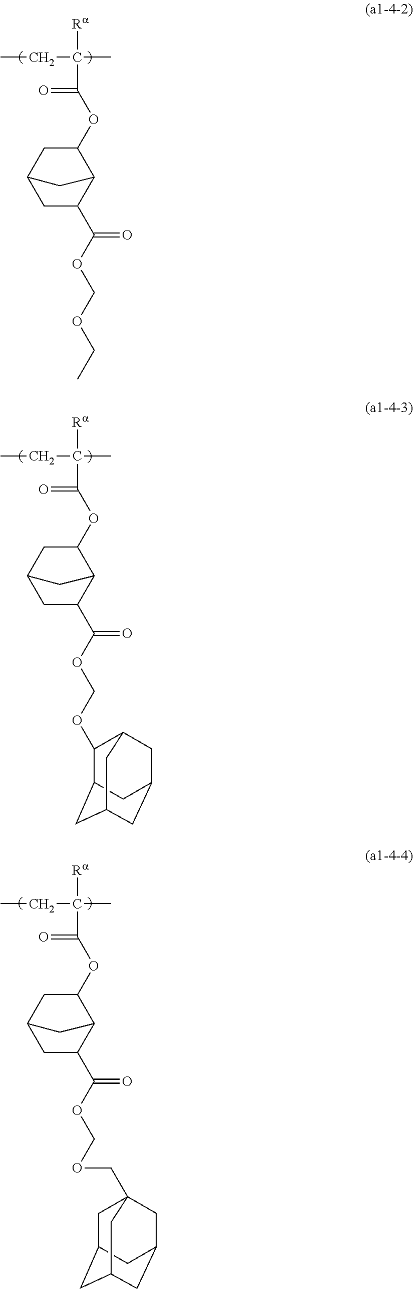

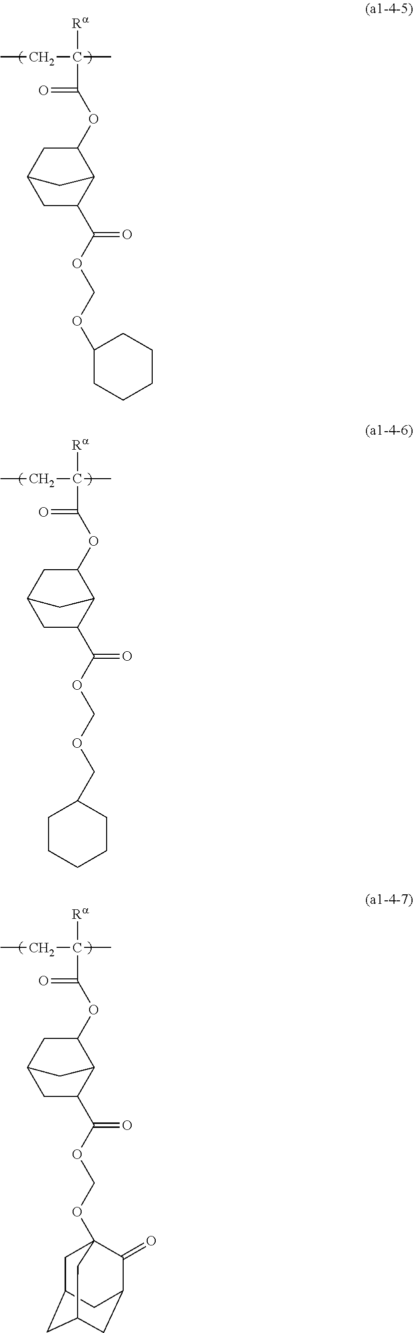

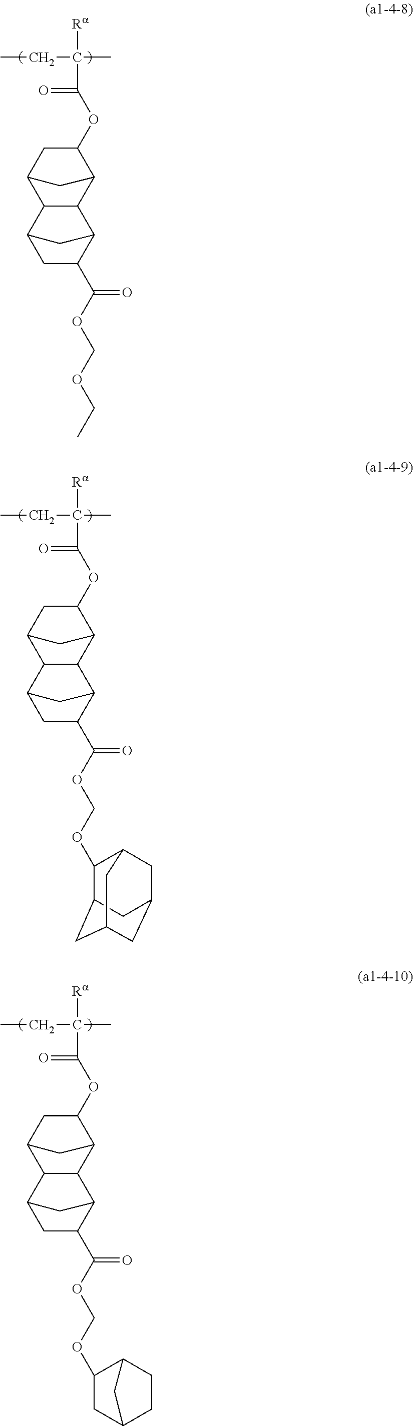

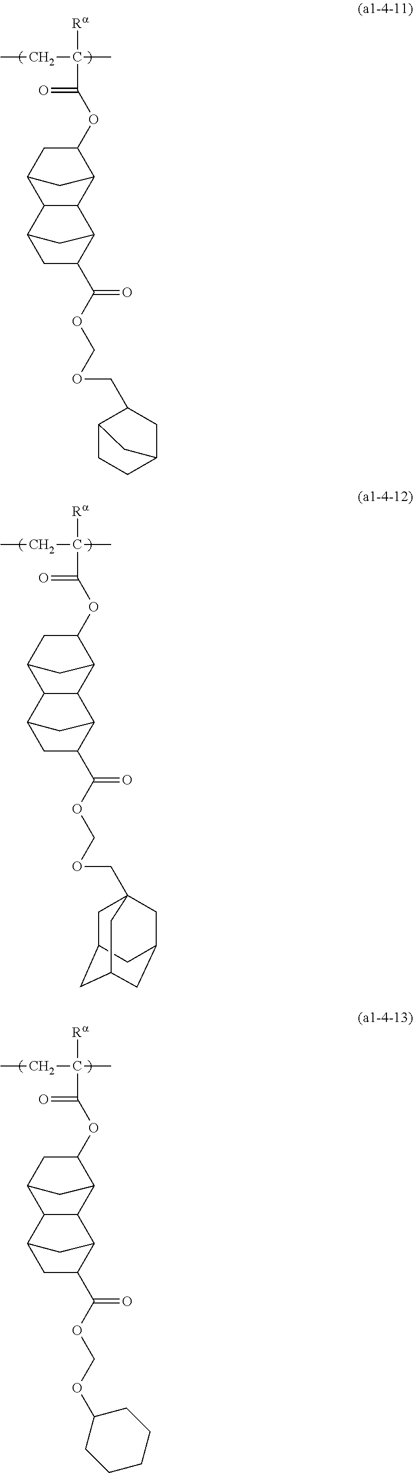

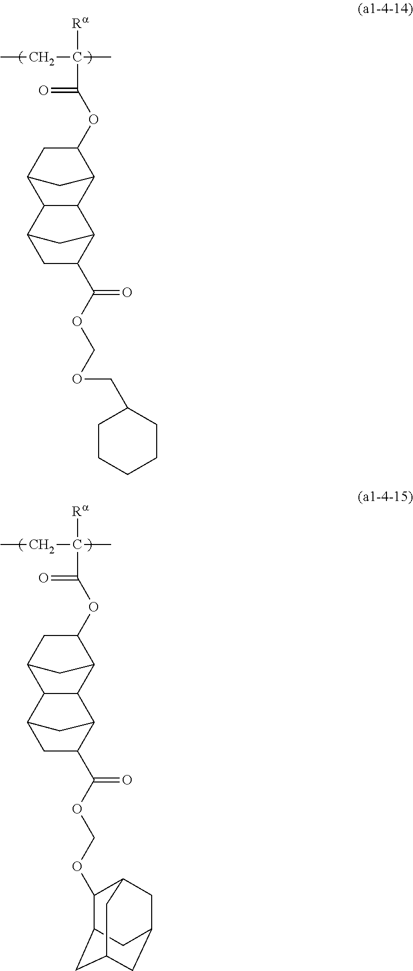

In the present invention, as a structural unit (a11), it is preferable to include two types of structural units with an activation energy difference between the acid decomposable groups within the two types of structural units of at least 3.0 kJ/mol, wherein the two types of structural units are selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below, a structural unit represented by general formula (a11-0-15) shown below, a structural unit represented by general formula (a11-0-10) shown below and a structural unit represented by general formula (a11-0-2) shown below.

Among these, it is preferable to include two types of structural units with an activation energy difference between the acid decomposable groups within the two types of structural units of at least 3.0 kJ/mol, wherein the two types of structural units are selected from the group consisting of a structural unit represented by general formula (a11-0-11) shown below, a structural unit represented by general formula (a11-0-12) shown below, a structural unit represented by general formula (a11-0-13) shown below, a structural unit represented by general formula (a11-0-14) shown below and a structural unit represented by general formula (a11-0-15) shown below.

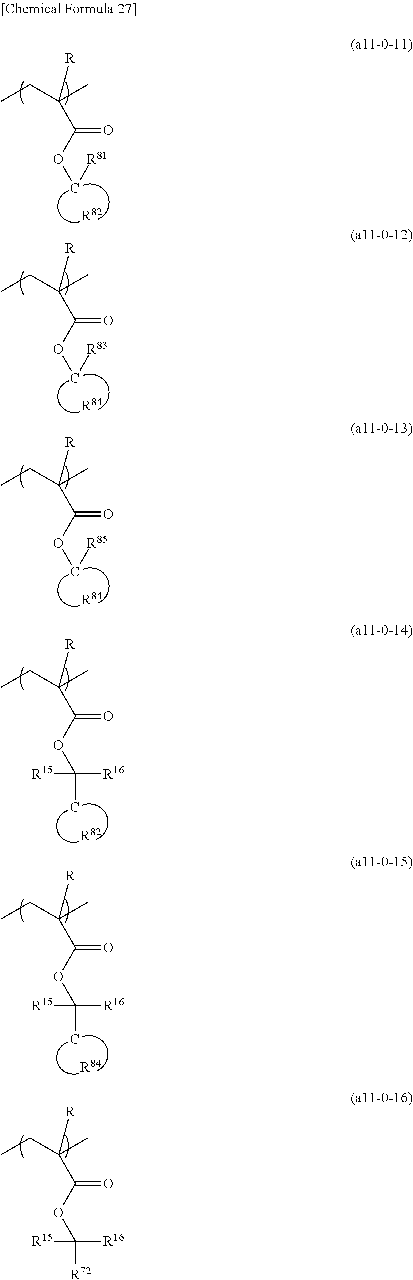

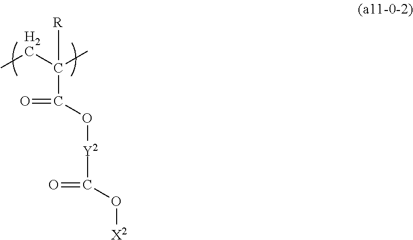

In the formulas, R represents a hydrogen atom, an alkyl group of 1 to 5 carbon atoms or a halogenated alkyl group of 1 to 5 carbon atoms; R⁸¹ represents an alkyl group; R⁸² represents a group which forms an aliphatic monocyclic group with the carbon atom to which R⁸² is bonded; R⁸³ represents a branched alkyl group; R⁸⁴ represents a group which forms an aliphatic polycyclic group with the carbon atom to which R⁸⁴ is bonded; R⁸⁵ represents a linear alkyl group of 1 to 5 carbon atoms; each of R¹⁵ and R¹⁶ independently represents an alkyl group; each of R⁷¹ to R⁷³ independently represents a linear alkyl group of 1 to 5 carbon atoms; Y² represents a divalent linking group; and X² represents an acid dissociable group.

In the formulas, R, Y² and X² are the same as defined above.

In general formula (a11-0-11), as the alkyl group for R⁸¹, the same alkyl groups as those described above for R¹⁴ in formulas (1-1) to (1-9) can be used, preferably a methyl group, an ethyl group or an isopropyl group.

As the aliphatic monocyclic group formed by R⁸² and the carbon atoms to which R⁸² is bonded, the same aliphatic cyclic groups as those described above for the aforementioned tertiary alkyl ester-type acid dissociable group and which are monocyclic can be used. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and most preferably a 5- or 6-membered ring.

The monocycloalkane may or may not have part of the carbon atoms constituting the ring replaced with an ether bond (—O—).

Further, the monocycloalkane may have a substituent such as an alkyl group of 1 to 5 carbon atoms, a fluorine atom or a fluorinated alkyl group of 1 to 5 carbon atoms.

As an examples of R⁸² constituting such an aliphatic cyclic group, an alkylene group which may have an ether bond (—O—) interposed between the carbon atoms can be given.

Specific examples of structural units represented by general formula (a1-0-11) include structural units represented by the aforementioned formulas (c-16) to (a1-1-23), (a1-1-27) and (a1-1-31). Among these, a structural unit represented by general formula (a1-1-02) shown below which includes the structural units represented by the aforementioned formulas (c-16), (a1-1-17), (a1-1-20) to (a1-1-23), (a1-1-27), (a1-1-31), (a1-1-32) and (a1-1-33) is preferable. Further, a structural unit represented by general formula (a11-1-02′) shown below is also preferable.

In the formulas, h represents an integer of 1 to 4, and is preferably 1 or 2.

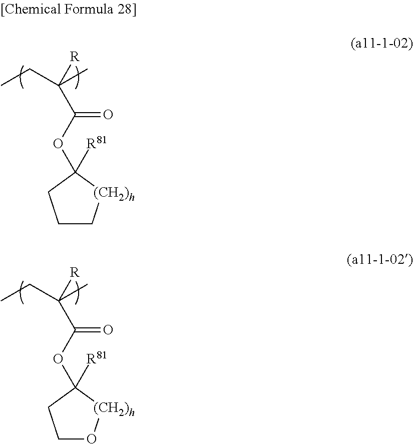

In the formulas, R and R⁸¹ are the same as defined above; and h represents an integer of 1 to 4.

In general formula (a11-0-12), as the branched alkyl group for R⁸³, the same alkyl groups as those described above for R¹⁴ in formulas (1-1) to (1-9) which are branched can be used, and an isopropyl group is most preferred.

As the aliphatic polycyclic group formed by R⁸⁴ and the carbon atoms to which R⁸⁴ is bonded, the same aliphatic cyclic groups as those described above for the aforementioned tertiary alkyl ester-type acid dissociable group and which are polycyclic can be used.

Specific examples of structural units represented by general formula (a1-0-12) include structural units represented by the aforementioned formulas (a1-1-26) and (a1-1-28) to (a1-1-30).

As the structural unit (a11-0-12), a structural unit in which the aliphatic polycyclic group formed by R⁸⁴ and the carbon atom to which R⁸⁴ is bonded is a 2-adamantyl group is preferable, and a structural unit represented by the aforementioned formula (a1-1-26) is particularly preferred.

In general formula (a11-0-13), R and R⁸⁴ are the same as defined above.

As the linear alkyl group for R⁸⁵, the same linear alkyl groups as those described above for R¹⁴ in the aforementioned formulas (1-1) to (1-9) can be mentioned, and a methyl group or an ethyl group is particularly preferred.

Specific examples of structural units represented by general formula (a11-0-13) include structural units represented by the aforementioned formulas (a1-1-1), (a1-1-2) and (a1-1-7) to (a1-1-15) which were described above as specific examples of the structural unit represented by general formula (a1-1).

As the structural unit (a11-0-13), a structural unit in which the aliphatic polycyclic group formed by R⁸⁴ and the carbon atom to which R⁸⁴ is bonded is a 2-adamantyl group is preferable, and a structural unit represented by the aforementioned formula (a1-1-1) or (a1-1-2) is particularly preferred.

As the aliphatic polycyclic group formed by R⁸⁴ and the carbon atom to which R⁸⁴ is bonded is preferably a group in which one or more hydrogen atoms have been removed from tetracyclododecane, and a structural unit represented by the aforementioned formula (a1-1-8), (a1-1-9) or (a1-1-30) is also preferred.

In general formula (a11-0-14), R and R⁸² are the same as defined above. R¹⁵ and R¹⁶ are the same as defined for R¹⁵ and R¹⁶ in the general formulas (2-1) to (2-6).

Specific examples of structural units represented by general formula (a11-0-14) include structural units represented by the aforementioned formulas (a1-1-35) and (a1-1-36) which were described above as specific examples of the structural unit represented by general formula (a1-1).

In general formula (a11-0-15), R and R⁸⁴ are the same as defined above. R¹⁵ and R¹⁶ are the same as defined for R¹⁵ and R¹⁶ in the general formulas (2-1) to (2-6).

Specific examples of structural units represented by general formula (a11-0-15) include structural units represented by the aforementioned formulas (a1-1-4) to (a1-1-6) and (a1-1-34) which were described above as specific examples of the structural unit represented by general formula (a1-1).

Examples of structural units represented by general formula (a11-0-2) include structural units represented by the aforementioned formulas (a1-3) and (a1-4), and a structural unit represented by formula (a1-3) is preferable.

As a structural unit represented by general formula (a11-0-2), those in which Y^{2 is a group represented by the aforementioned formula —Y}²¹—O—Y²²— or —Y²¹—C(═O)—Y²²— is particularly preferred.

Preferable examples of such structural units include a structural unit represented by general formula (a1-3-01) shown below, a structural unit represented by general formula (a1-3-02) shown below, and a structural unit represented by general formula (a1-3-03) shown below.

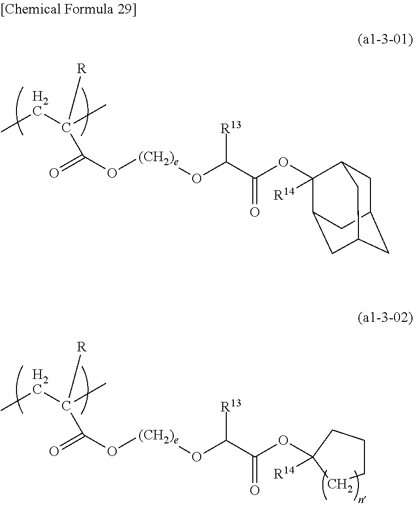

In the formulas, R is the same as defined above; R¹³ represents a hydrogen atom or a methyl group; R¹⁴ represents an alkyl group; e represents an integer of 1 to 10; and n′ represents an integer of 0 to 3.

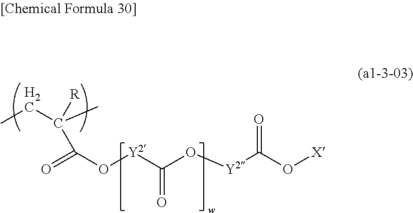

In the formula, R is as defined above; each of Y²′ and Y²″ independently represents a divalent linking group; X′ represents an acid dissociable group; and w represents an integer of 0 to 3.

In general formulas (a1-3-01) and (a1-3-02), R¹³ is preferably a hydrogen atom.

R¹⁴ is the same as defined for R¹⁴ in the aforementioned formulas (1-1) to (1-9).

e is preferably an integer of 1 to 8, more preferably 1 to 5, and most preferably 1 or 2.

n′ is preferably 1 or 2, and most preferably 2.

Specific examples of structural units represented by general formula (a1-3-01) include structural units represented by the aforementioned formulas (a1-3-25) and (a1-3-26).

Specific examples of structural units represented by general formula (a1-3-02) include structural units represented by the aforementioned formulas (a1-3-27) and (a1-3-28).

In general formula (a1-3-03), as the divalent linking group for Y²′ and Y²″, the same groups as those described above for Y² in general formula (a1-3) can be used.

As Y²′, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly preferred.

As Y²″, a divalent hydrocarbon group which may have a substituent is preferable, a linear aliphatic hydrocarbon group is more preferable, and a linear alkylene group is still more preferable. Among linear alkylene groups, a linear alkylene group of 1 to 5 carbon atoms is preferable, and a methylene group or an ethylene group is particularly preferred.

As the acid dissociable group for X′, the same groups as those described above can be used. X′ is preferably a tertiary alkyl ester-type acid dissociable group, more preferably the aforementioned group (i) in which a substituent is bonded to the carbon atom to which an atom adjacent to the acid dissociable group is bonded to on the ring skeleton to form a tertiary carbon atom. Among these, a group represented by the aforementioned general formula (1-1) is particularly preferred.

w represents an integer of 0 to 3, preferably an integer of 0 to 2, more preferably 0 or 1, and most preferably 1.

As the structural unit represented by general formula (a1-3-03), a structural unit represented by general formula (a1-3-03-1) or (a1-3-03-2) shown below is preferable, and a structural unit represented by general formula (a1-3-03-1) is particularly preferred.

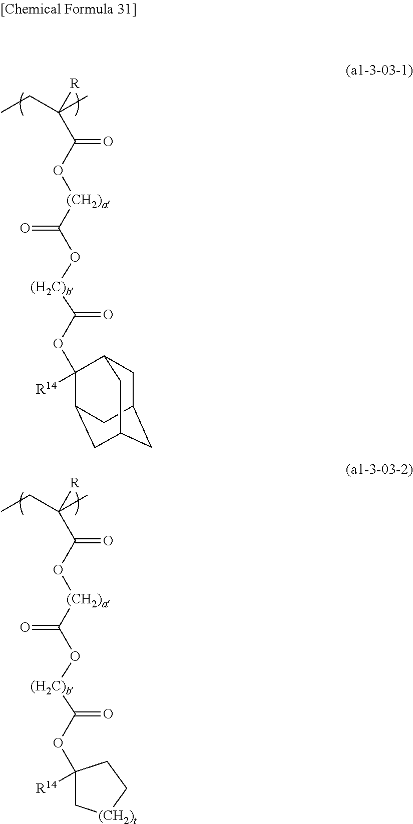

In the formulas, R and R¹⁴ are the same as defined above; a′ represents an integer of 1 to 10; b′ represents an integer of 1 to 10; and t represents an integer of 0 to 3.

In general formulas (a1-3-03-1) and (a1-3-03-2), a′ is preferably an integer of 1 to 8, more preferably 1 to 5, and most preferably 1 or 2.

b′ is preferably an integer of 1 to 8, more preferably 1 to 5, and most preferably 1 or 2.

t is preferably an integer of 1 to 3, and most preferably 1 or 2.

Specific examples of structural units represented by general formula (a1-3-03-1) or (a1-3-03-2) include structural units represented by the aforementioned formulas (a1-3-29) to (a1-3-32).

Structural Unit (a12) and Structural Unit (a13)

In the present specification, the structural unit (a12) is a structural unit in which at least part of the hydrogen atoms of the phenolic hydroxy group in a structural unit derived from a hydroxystyrene or derivative thereof is protected with an acid dissociable group or a substituent containing an acid decomposable group.

In addition, a structural unit (a13) is a structural unit in which at least part of the hydrogen atom of —C(═O)—OH in a structural unit derived from a vinylbenzoic acid or derivative thereof is protected with an acid dissociable group or a substituent containing an acid dissociable group.

In the structural unit (a12) and structural unit (a13), preferable examples of the acid dissociable group include the aforementioned tertiary alkyl ester-type acid dissociable groups and acetal-type acid dissociable groups. As the substituent containing an acid dissociable group, a group constituted of an acid dissociable group and a divalent linking group. As the divalent linking group, the same the divalent linking group which may have a substituent as described for Y² in the general formula (a11-0-1) can be mentioned.

As described above, the polymer according to the present invention includes two types of structural units (a1) with an activation energy difference between the acid decomposable groups within the two types of structural units of at least 3.0 kJ/mol.

The preferable combination of two types of structural units (a1) included in the polymer according to the present invention can be suitably selected in order to be within the desired value of an activation energy difference. The combination of two types of structural units (a1) is not particularly limited, and the following combinations can be mentioned as preferable examples.

Combination 1: a combination of a structural unit represented by the formula (a11-0-12) with a structural unit represented by the formula (a11-0-11);

Combination 2: a combination of a structural unit represented by the formula (a11-0-12) with a structural unit represented by the formula (a11-0-13);

Combination 3: a combination of a structural unit represented by the formula (a11-0-12) with a structural unit represented by the formula (a11-0-14);

Combination 4: a combination of a structural unit represented by the formula (a11-0-12) with a structural unit represented by the formula (a11-0-15);

Combination 5: a combination of a structural unit represented by the formula (a11-0-12) with a structural unit represented by the formula (a11-0-16);

Combination 6: a combination of a structural unit represented by the formula (a11-0-12) with a structural unit represented by the formula (a11-0-2);

Combination 7: a combination of a structural unit represented by the formula (a11-0-2) with a structural unit represented by the formula (a11-0-11);

Combination 8: a combination of a structural unit represented by the formula (a11-0-2) with a structural unit represented by the formula (a11-0-13);

Combination 9: a combination of a structural unit represented by the formula (a11-0-15) with a structural unit represented by the formula (a11-0-11);

Combination 10: a combination of a structural unit represented by the formula (a11-0-15) with a structural unit represented by the formula (a11-0-16); and

Combination 11: a combination of a structural unit represented by the formula (a11-0-11) with a structural unit represented by the formula (a11-0-16).

It should be noted that the aforementioned activation energy varies depending on the structure of the acid decomposable group, or depending on the bond structure of the acid decomposable group within the side chains of the structural units. With respect to activation energy of acid decomposable group, the discussion has been already made in the literature.

In the polymer of the present invention, the amount of the structural unit (a1) (that is, the total amount of two type of structural units (a1)) based on the combined total of all structural units constituting the polymer is preferably 15 to 70 mol %, more preferably 15 to 60 mol % and still more preferably 20 to 55 mol %.

When the amount of the structural unit (a1) is at least as large as the lower limit of the above-mentioned range, a pattern can be easily formed using a resist composition containing the polymer, and various lithography properties such as sensitivity, resolution, LWR and the like are improved. On the other hand, when the amount of the structural unit (a1) is no more than the upper limit of the above-mentioned range, a good balance can be achieved with the other structural units.

The polymer of the present invention may also have a structural unit other than the above-mentioned structural unit (a1), as long as the effects of the present invention are not impaired.

As such a structural unit, any other structural unit which cannot be classified as the aforementioned structural units can be used without any particular limitation, and any of the multitude of conventional structural units used within resist resins for ArF excimer lasers or KrF excimer lasers (and particularly for ArF excimer lasers) can be used. Examples of such a structural unit include a structural unit (a2) containing a —SO₂— containing cyclic group or a lactone-containing cyclic group; a structural unit (a3) containing a polar group; and a structural unit (a4) containing an acid non-dissociable cyclic group.

(Structural Unit (a2))

By virtue of the structural unit (a2) containing a —SO₂— containing cyclic group or a lactone-containing cyclic group, a resist composition containing the polymer of the present invention is capable of improving the adhesion of a resist film to a substrate, and increasing the compatibility with the developing solution containing water (especially in the case of alkali developing process), thereby contributing to improvement of lithography properties.

Here, an “—SO₂— containing cyclic group” refers to a cyclic group having a ring containing —SO₂— within the ring structure thereof, i.e., a cyclic group in which the sulfur atom (S) within —SO₂— forms part of the ring skeleton of the cyclic group. The ring containing —SO₂— within the ring skeleton thereof is counted as the first ring. A cyclic group in which the only ring structure is the ring that contains —SO₂— in the ring skeleton thereof is referred to as a monocyclic group, and a group containing other ring structures is described as a polycyclic group regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S—within the —O—SO₂— group forms part of the ring skeleton thereof is particularly preferred.

The —SO₂— containing cyclic group preferably has 3 to 30 carbon atoms, more preferably 4 to 20, still more preferably 4 to 15, and most preferably 4 to 12. Herein, the number of carbon atoms refers to the number of carbon atoms constituting the ring skeleton, excluding the number of carbon atoms within a substituent.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton has been substituted with a —SO₂— group or a —O—SO₂— group and has at least one hydrogen atom removed from the aliphatic hydrocarbon ring. Specific examples include an aliphatic hydrocarbon ring in which a —CH₂— group constituting the ring skeleton thereof has been substituted with a —SO₂— group and has at least one hydrogen atom removed therefrom; and an aliphatic hydrocarbon ring in which a —CH₂—CH₂— group constituting the ring skeleton has been substituted with a —O—SO₂— group and has at least one hydrogen atom removed therefrom.

The alicyclic hydrocarbon ring preferably has 3 to 20 carbon atoms, and more preferably 3 to 12 carbon atoms.

The alicyclic hydrocarbon ring may be either a monocyclic group or a polycyclic group. As the monocyclic group, a group in which two hydrogen atoms have been removed from a monocycloalkane of 2 to 6 carbon atoms is preferable. Examples of the monocycloalkane include cyclopentane and cyclohexane. As the polycyclic alicyclic hydrocarbon ring, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of substituents include an alkyl group, an alkoxy group, a halogen atom, a halogenated alkyl group, a hydroxy group, an oxygen atom (═O), —COOR″, —OC(═O)R″, a hydroxyalkyl group and a cyano group.

The alkyl group for the substituent is preferably an alkyl group of 1 to 6 carbon atoms. Further, the alkyl group is preferably a linear alkyl group or a branched alkyl group. Specific examples include a methyl group, ethyl group, propyl group, isopropyl group, n-butyl group, isobutyl group, tert-butyl group, pentyl group, isopentyl group, neopentyl group and hexyl group. Among these, a methyl group or ethyl group is preferable, and a methyl group is particularly preferred.

As the alkoxy group for the substituent, an alkoxy group of 1 to 6 carbon atoms is preferable. Further, the alkoxy group is preferably a linear alkoxy group or a branched alkyl group. Specific examples of the alkoxy groups include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

As examples of the halogenated lower alkyl group for the substituent, groups in which part or all of the hydrogen atoms of the aforementioned alkyl groups for the substituent have been substituted with the aforementioned halogen atoms can be given. As the halogenated alkyl group, a fluorinated alkyl group is preferable, and a perfluoroalkyl group is particularly preferred.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxy group. More specific examples of the —SO₂— containing cyclic group include groups represented by general formulas (3-1) to (3-4) shown below.

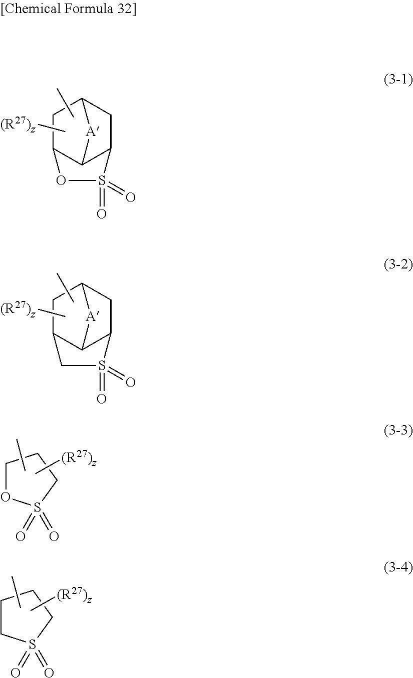

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In general formulas (3-1) to (3-4) above, A′ represents an oxygen atom (—O—), a sulfur atom (—S—) or an alkylene group of 1 to 5 carbon atoms which may contain an oxygen atom or a sulfur atom.

As the alkylene group of 1 to 5 carbon atoms for A′, a linear or branched alkylene group is preferable, and examples thereof include a methylene group, an ethylene group, an n-propylene group and an isopropylene group.

Examples of alkylene groups that contain an oxygen atom or a sulfur atom include the aforementioned alkylene groups in which —O— or —S— is bonded to the terminal of the alkylene group or interposed within the alkyl group. Specific examples of such alkylene groups include —O—CH₂—, —CH₂—O—CH₂—, —S—CH₂— and —CH₂S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

When z is 2, the plurality of R²⁷ may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent for the —SO₂— containing cyclic group can be mentioned.

Specific examples of the cyclic groups represented by general formulas (3-1) to (3-4) are shown below. In the formulas shown below, “Ac” represents an acetyl group.

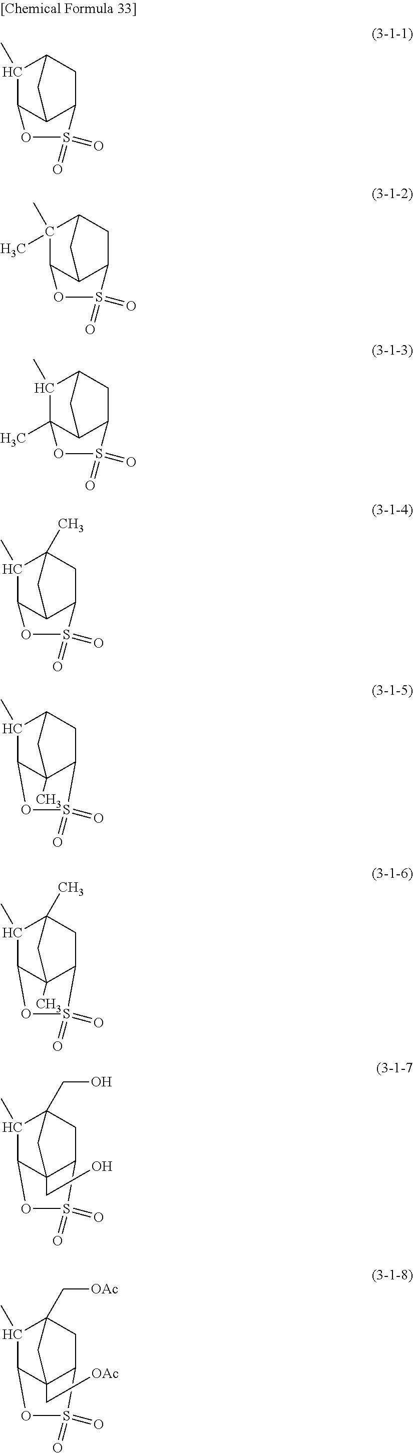

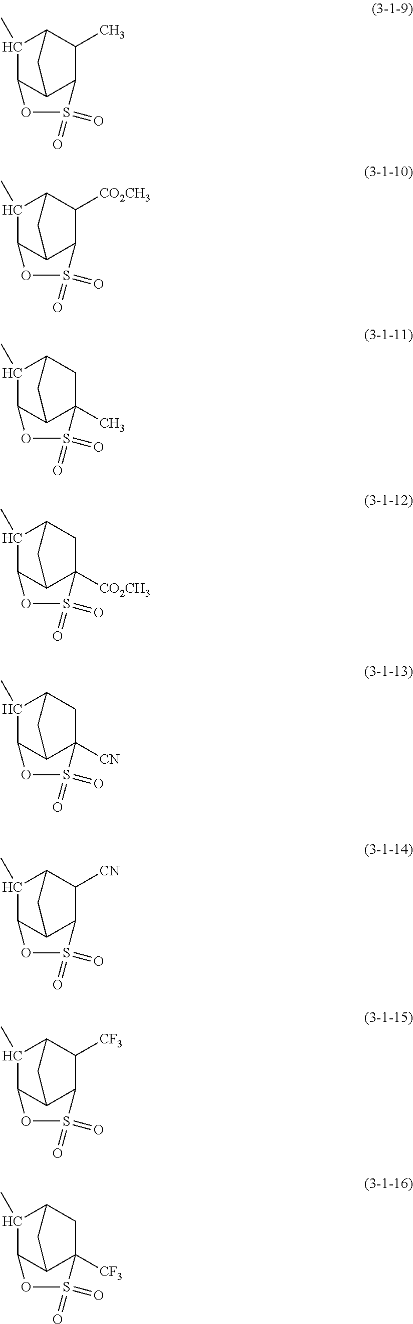

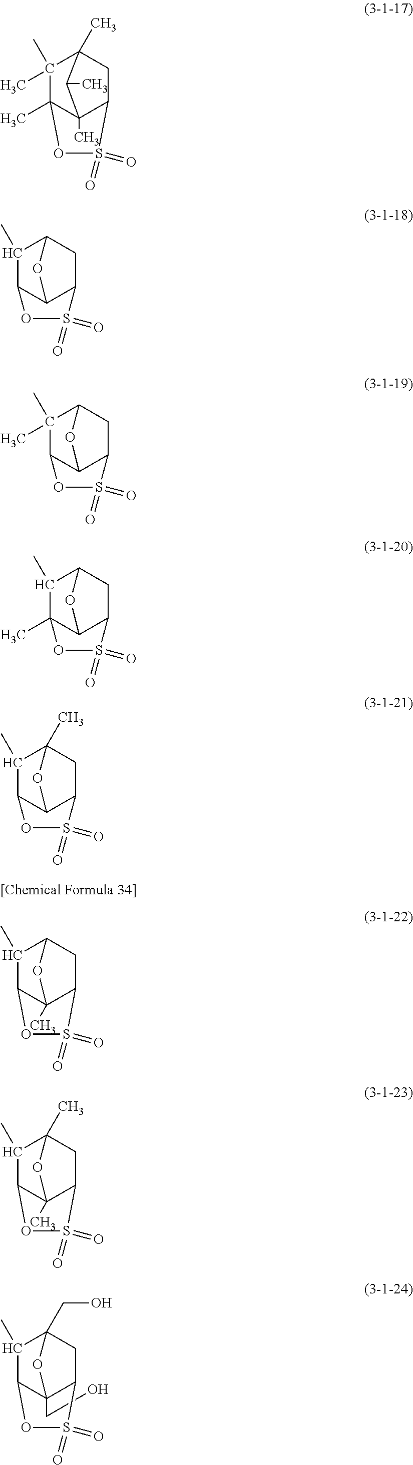

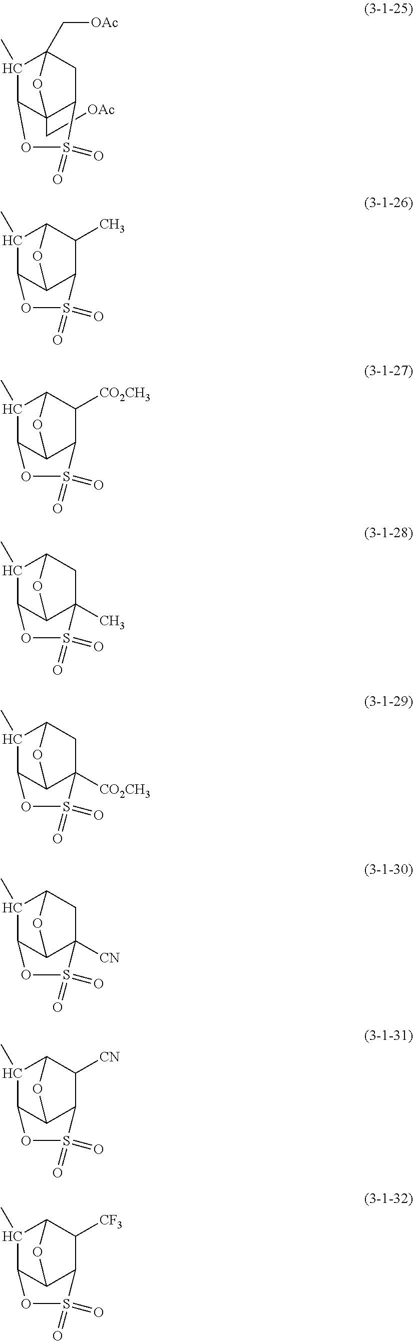

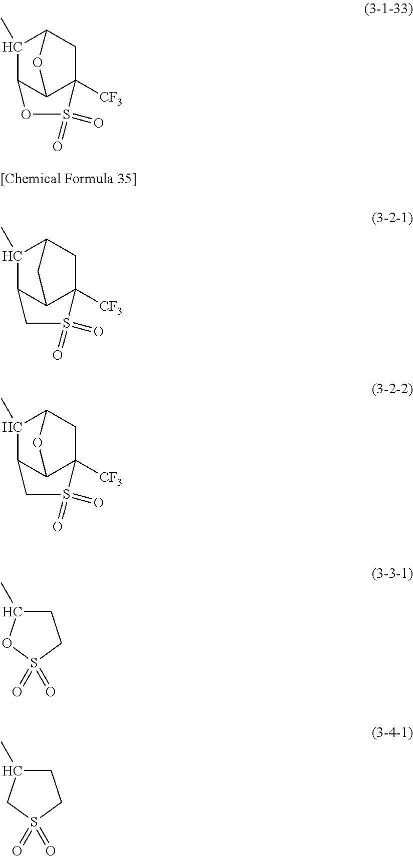

As the —SO₂— containing cyclic group, a group represented by the aforementioned general formula (3-1) is preferable, at least one member selected from the group consisting of groups represented by the aforementioned chemical formulas (c-1), (3-1-18), (3-3-1) and (3-4-1) is more preferable, and a group represented by chemical formula (3-1-1) is most preferable.

The term “lactone-containing cyclic group” refers to a cyclic group including a ring containing a —O—C(═O)— structure (lactone ring). The term “lactone ring” refers to a single ring containing a —O—C(═O)— structure, and this ring is counted as the first ring. A lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

The lactone-containing cyclic group for the structural unit (a2^{L}) is not particularly limited, and an arbitrary structural unit may be used. Specific examples of lactone-containing monocyclic groups include a group in which one hydrogen atom has been removed from a 4- to 6-membered lactone ring, such as a group in which one hydrogen atom has been removed from β-propionolatone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

With respect to the structural unit (a2), the partial structure other than the —SO₂-containing cyclic group or a lactone-containing cyclic group is not particularly limited as long as the structural unit (a2) having an —SO₂— containing cyclic group or a lactone-containing cyclic group. The structural unit (a2) is preferably at least one structural unit selected from the group consisting of a structural unit derived from an acrylate ester which may have the hydrogen atom bonded to the carbon atom on the α-position substituted with a substituent and contains an —SO₂— containing cyclic group (hereafter, referred to as “structural unit (a2^{s})”), and a structural unit derived from an acrylate ester which may have the hydrogen atom bonded to the carbon atom on the α-position substituted with a substituent and contains a lactone-containing cyclic group (hereafter, referred to as “structural unit (a2^{L}”).

Structural Unit (a2^{s}):

More specific examples of the structural unit (a2^{s}) include structural units represented by general formula (a2-0) shown below.

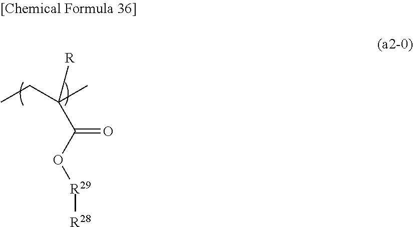

In the formula, R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

In genera formula (a2-0), R is the same as defined above.

R²⁸ is the same as defined for the aforementioned —SO₂— containing group.

R²⁹ may be either a single bond or a divalent linking group. In terms of the effects of the present invention, a divalent linking group is preferable.

The divalent linking group for R²⁹ is not particularly limited, and examples thereof include the same divalent linking groups as those described above for W in the aforementioned formula (c-1-21). Among these, an alkylene group or a divalent linking group containing an ester bond (—C(═O)—O—) is preferable.

As the alkylene group, a linear or branched alkylene group is preferable. Specific examples include the same linear alkylene groups and branched alkylene groups as those described above for the aliphatic hydrocarbon group for Y².

As the divalent linking group containing an ester bond, a group represented by general formula: —R³⁰—C(═O)—O— (in the formula, R³⁰ represents a divalent linking group) is particularly preferred. That is, the structural unit (a2^{s}) is preferably a structural unit represented by general formula (a2-0-1) shown below.

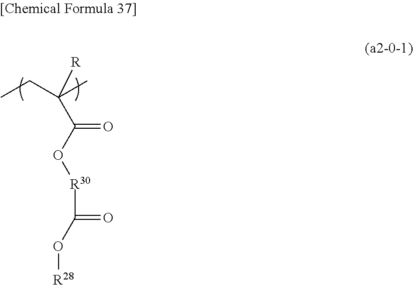

In the formula, R and R²⁸ are the same as defined above; and R³⁰ represents a divalent linking group.

R³⁰ is not particularly limited, and examples thereof include the same divalent linking groups as those described above for Win the aforementioned formula (c-1-21).

As the divalent linking group for R³⁰, an alkylene group, an alicyclic hydrocarbon group containing a ring in the structure thereof or a divalent linking group containing a hetero atom is preferable.

As the linear or branched alkylene group, the aliphatic hydrocarbon group containing a ring in the structure thereof and the divalent linking group containing a hetero atom, the same linear or branched alkylene group, aliphatic hydrocarbon group containing a ring in the structure thereof and divalent linking group containing a hetero atom as those described above as preferable examples of W in the formula (c-1-21) can be mentioned.

Among these, a linear or branched alkylene group, or a divalent linking group containing an oxygen atom as a hetero atom is more preferable.

As the linear alkylene group, a methylene group or an ethylene group is preferable, and a methylene group is particularly preferred.

As the branched alkylene group, an alkylmethylene group or an alkylethylene group is preferable, and —CH(CH₃)—, —C(CH₃)₂— or —C(CH₃)₂CH₂ is particularly preferred.

As the divalent linking group containing a hetero atom, a divalent linking group containing an ether bond or an ester bond is preferable, and a group represented by the aforementioned formulas —Y²¹—O—Y²²—, —[Y²¹—C(O)—O]_{m′}—Y²²— or —Y²¹—O—C(═O)—Y²²— is more preferable. Each of Y²¹ and Y²² independently represents a divalent hydrocarbon group which may have a substituent, and m′ represents an integer 0 to 3.

Among these, a group represented by the formula —Y²¹—O—C(═O)—Y²²— is preferable, a group represented by the formula —(CH₂)_{c}—O—C(═O)—(CH₂)_{d}— is particularly preferred. c represents an integer of 1 to 5, and preferably 1 or 2. d represents an integer of 1 to 5, and preferably 1 or 2.

In particular, as the structural unit (a2^{s}), a structural unit represented by general formula (a2-0-11) or (a2-0-12) shown below is preferable, and a structural unit represented by general formula (a2-0-12) shown below is more preferable.

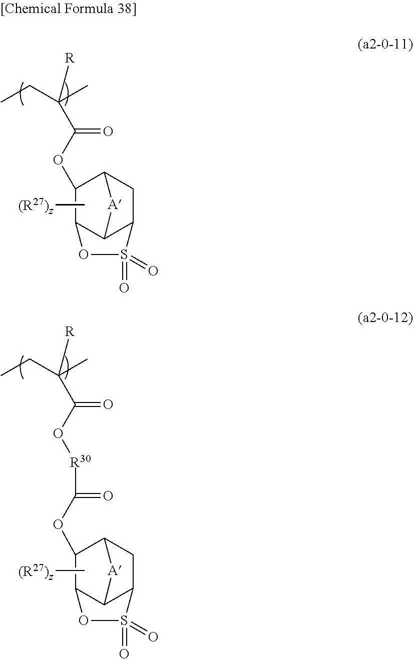

In the formulas, R, A′, R²⁷, z and R³⁰ are the same as defined above.

In general formula (a2-0-11), A′ is preferably a methylene group, an oxygen atom (—O—) or a sulfur atom (—S—).

As R³⁰, a linear or branched alkylene group or a divalent linking group containing an oxygen atom is preferable. As the linear or branched alkylene group and the divalent linking group containing an oxygen atom for R³⁰, the same linear or branched alkylene groups and the divalent linking groups containing an oxygen atom as those described above can be mentioned.

As the structural unit represented by general formula (a2-0-12), a structural unit represented by general formula (a2-0-12a) or (a2-0-12b) shown below is particularly preferred.

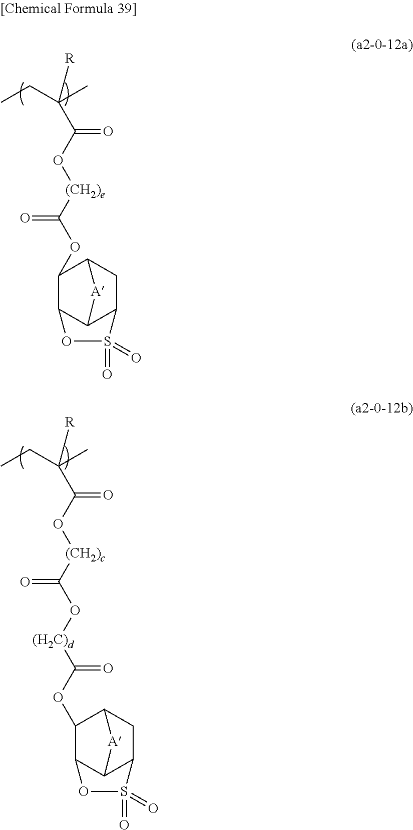

In the formulas, R and A′ are the same as defined above; and each of c to e independently represents an integer of 1 to 3.

Structural Unit (a2^{L}):

Examples of the structural unit (a2^{L}) include structural units represented by the aforementioned general formula (a2-0) in which the R²⁸ group has been substituted with a lactone-containing cyclic group. Specific examples include structural units represented by general formulas (a2-1) to (a2-5) shown below.

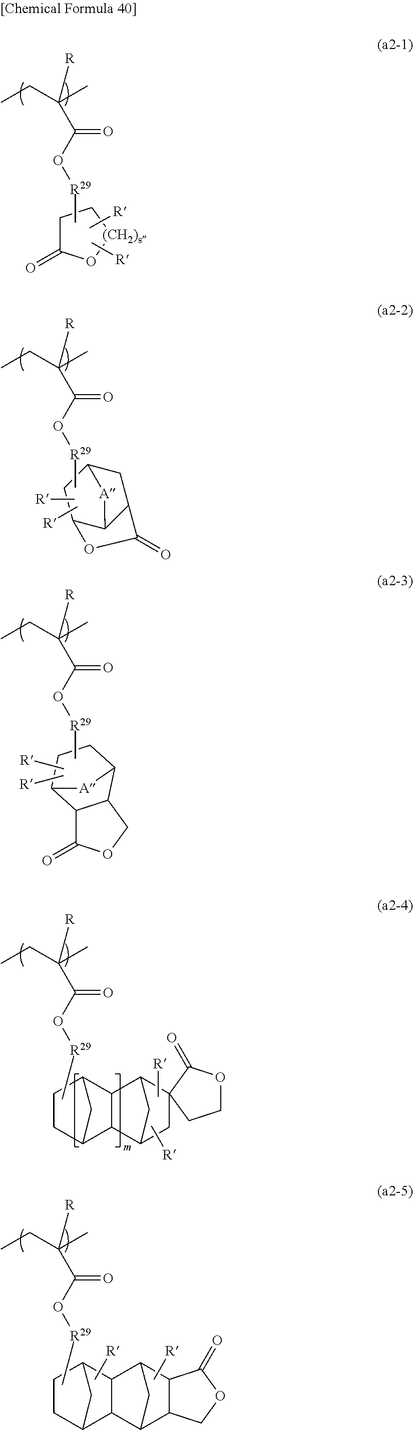

In the formulas, R represents a hydrogen atom, an alkyl group of 1 to 5 carbon atoms or a halogenated alkyl group of 1 to 5 carbon atoms; each R′ independently represents a hydrogen atom, an alkyl group of 1 to 5 carbon atoms, an alkoxy group of 1 to 5 carbon atoms or —COOR″, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-1) to (a2-5), R is the same as defined above.

Examples of the alkyl group of 1 to 5 carbon atoms for R′ include a methyl group, an ethyl group, a propyl group, an n-butyl group and a tert-butyl group.

Examples of the alkoxy group of 1 to 5 carbon atoms for R′ include a methoxy group, an ethoxy group, an n-propoxy group, an iso-propoxy group, an n-butoxy group and a tert-butoxy group.

In terms of industrial availability, R′ is preferably a hydrogen atom.

The alkyl group for R″ may be any of linear, branched or cyclic.

When R″ is a linear or branched alkyl group, it preferably has 1 to 10 carbon atoms, more preferably 1 to 5 carbon atoms.

When R″ is a cyclic alkyl group (cycloalkyl group), it preferably has 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Examples of such groups include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

As examples of A″, the same groups as those described above for A′ in general formula (3-1) can be given. A″ is preferably an alkylene group of 1 to 5 carbon atoms, an oxygen atom (—O—) or a sulfur atom (—S—), and more preferably an alkylene group of 1 to 5 carbon atoms or —O—. As the alkylene group of 1 to 5 carbon atoms, a methylene group or a dimethylethylene group is preferable, and a methylene group is particularly preferred.

R²⁹ is the same as defined for R²⁹ in the aforementioned general formula (a2-0).

In formula (a2-1), s″ is preferably 1 or 2.

Specific examples of structural units represented by general formulas (a2-1) to (a2-5) are shown below. In the formulas shown below, R^{a} represents a hydrogen atom, a methyl group or a trifluoromethyl group.

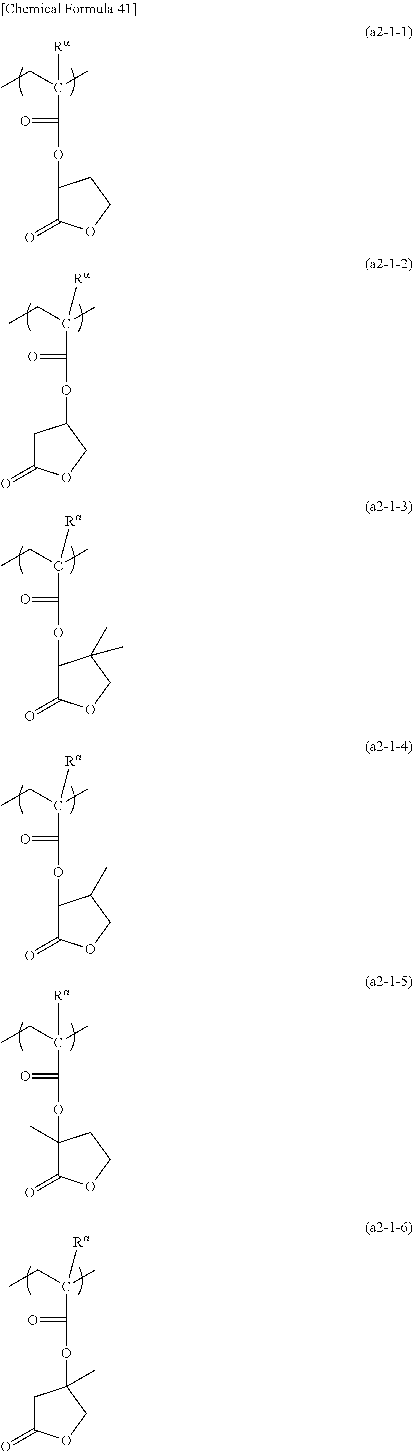

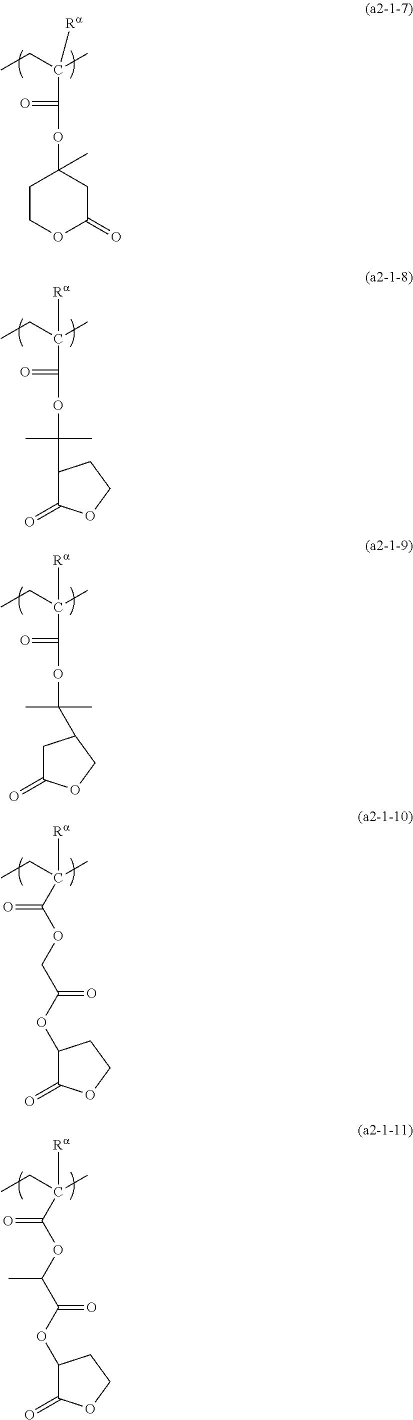

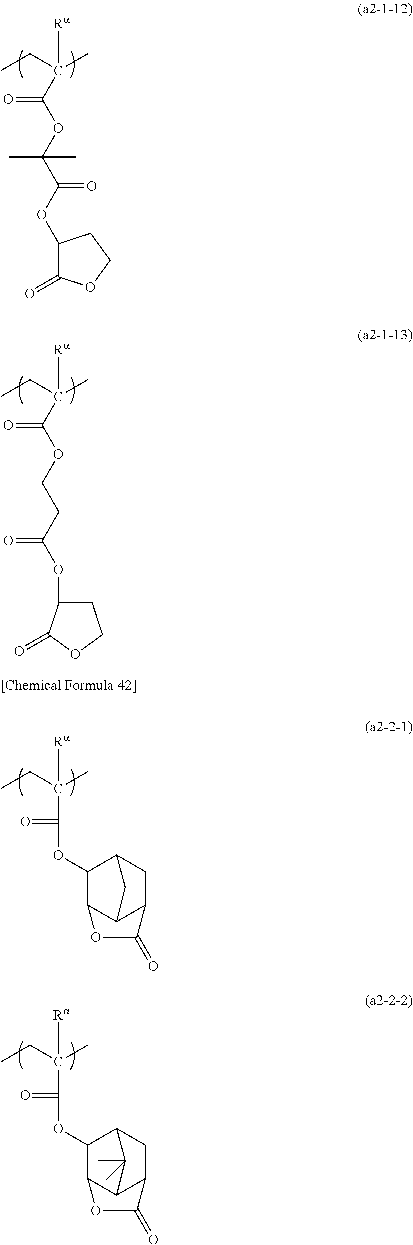

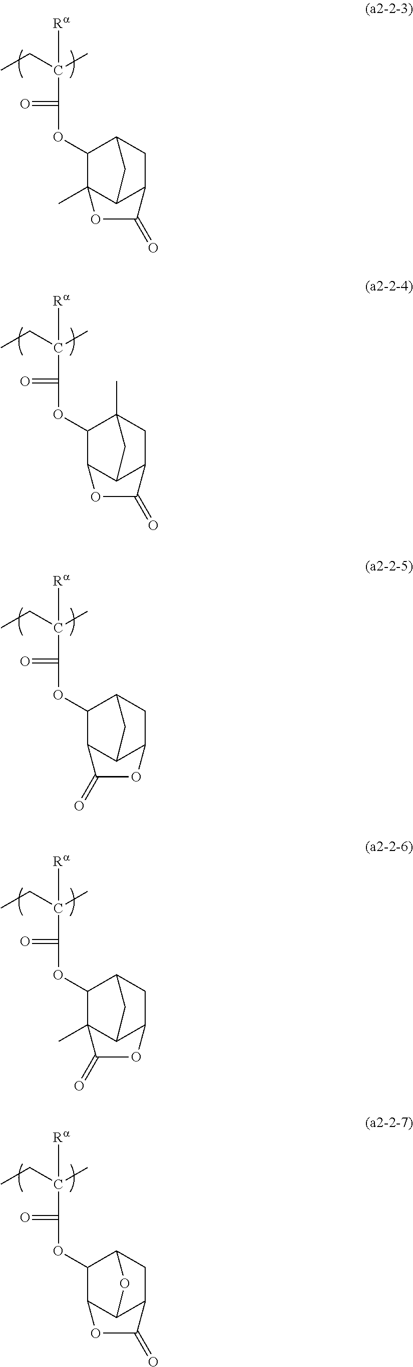

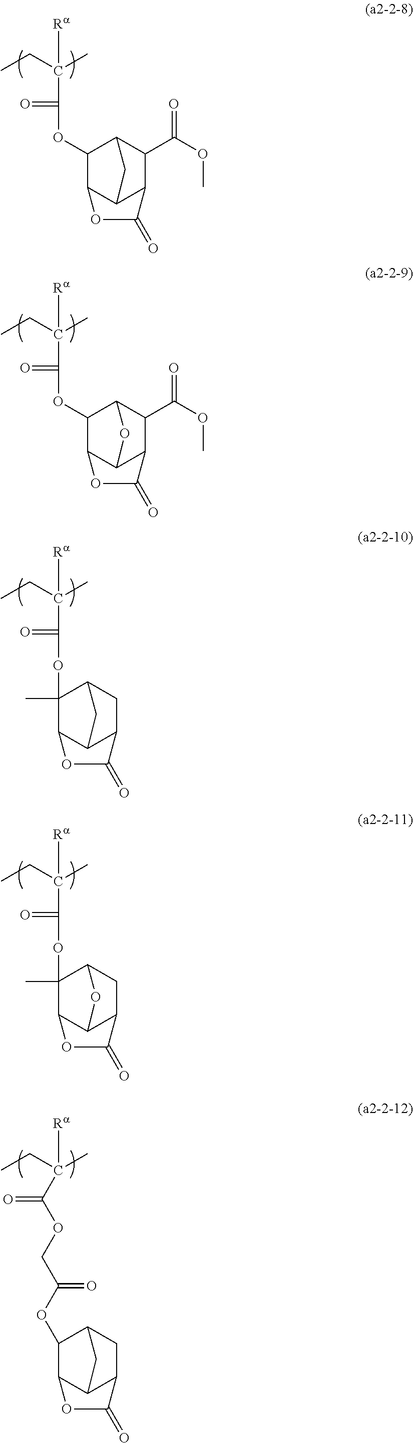

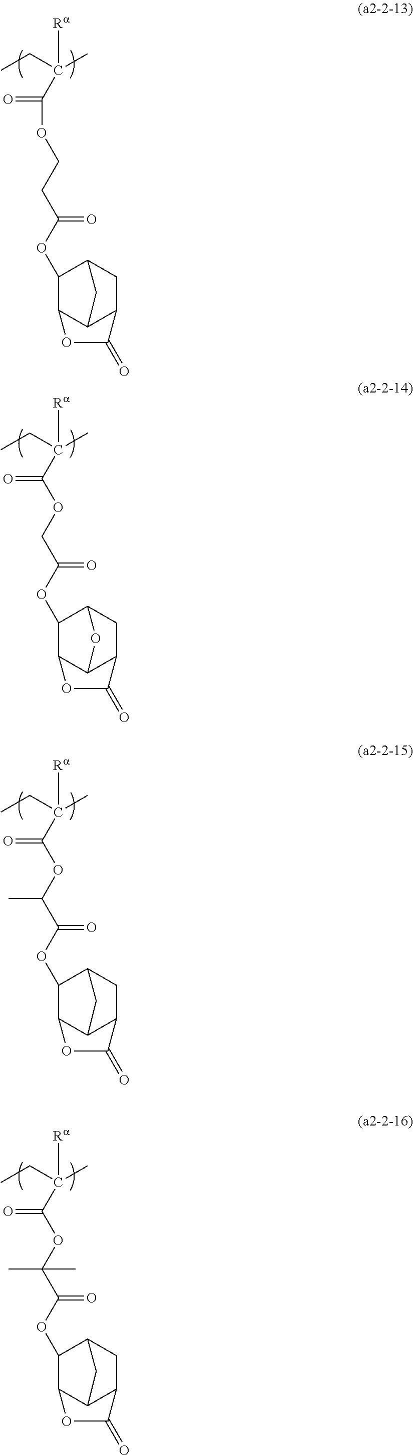

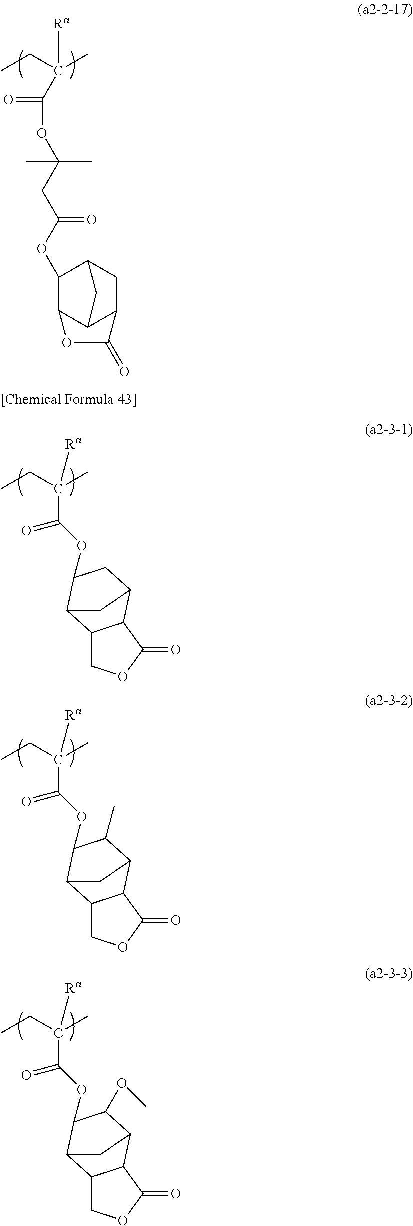

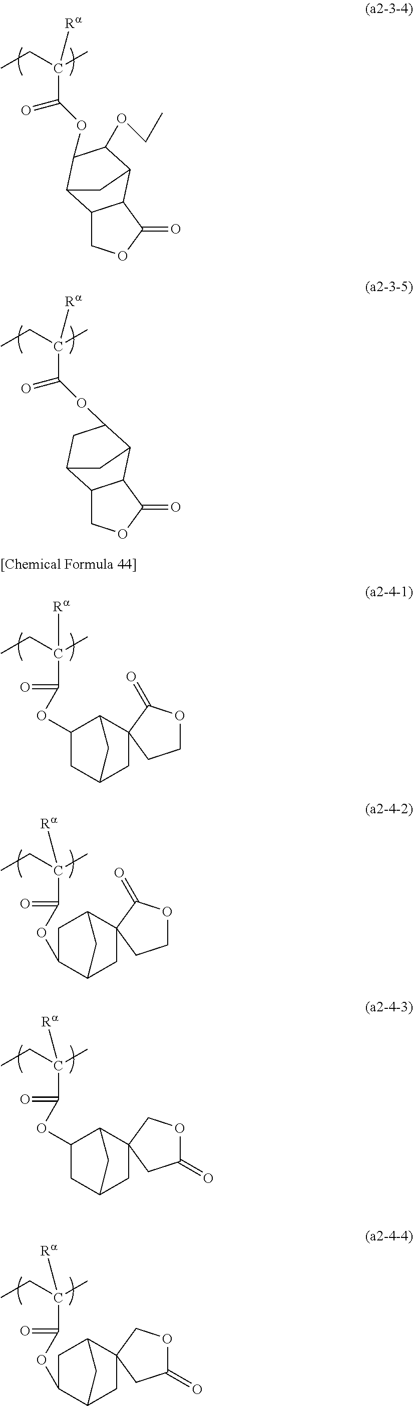

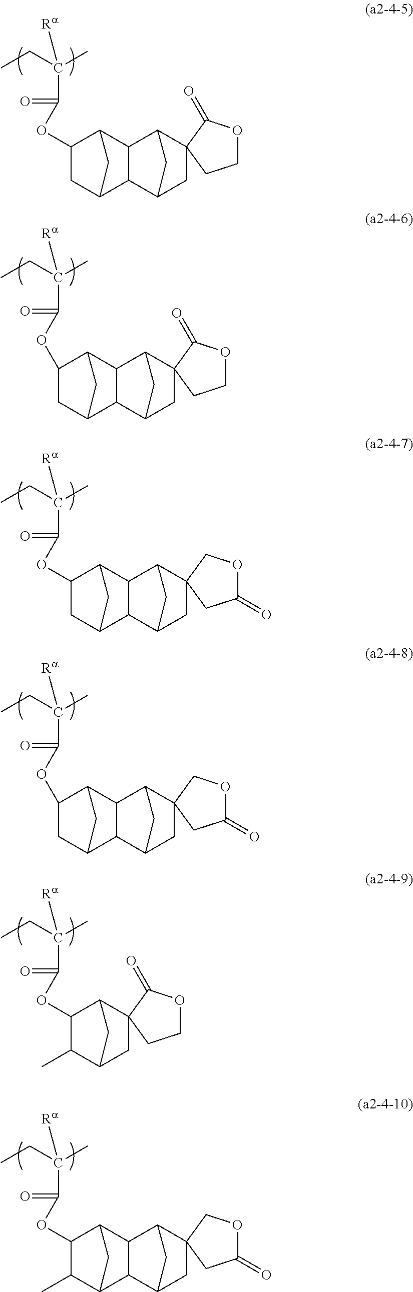

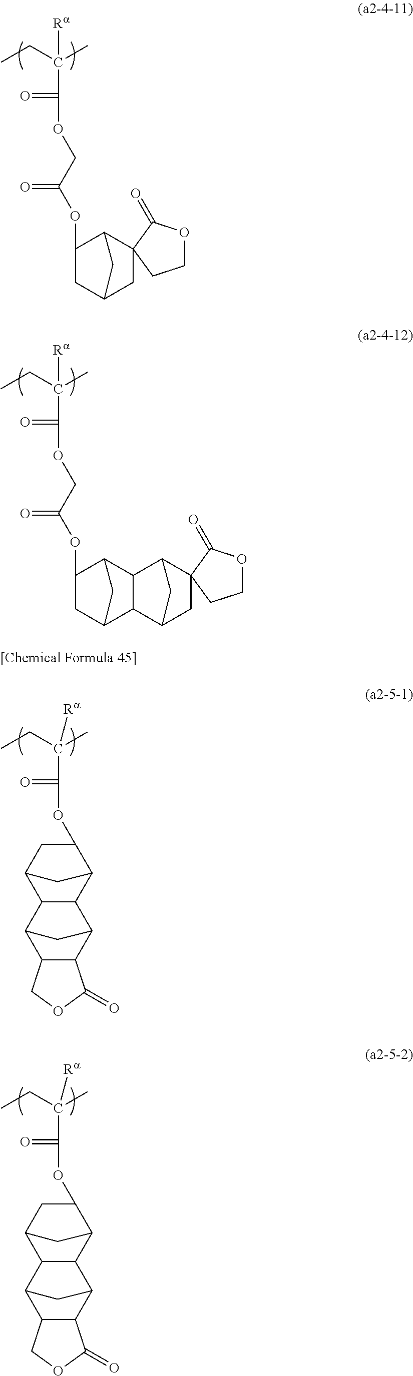

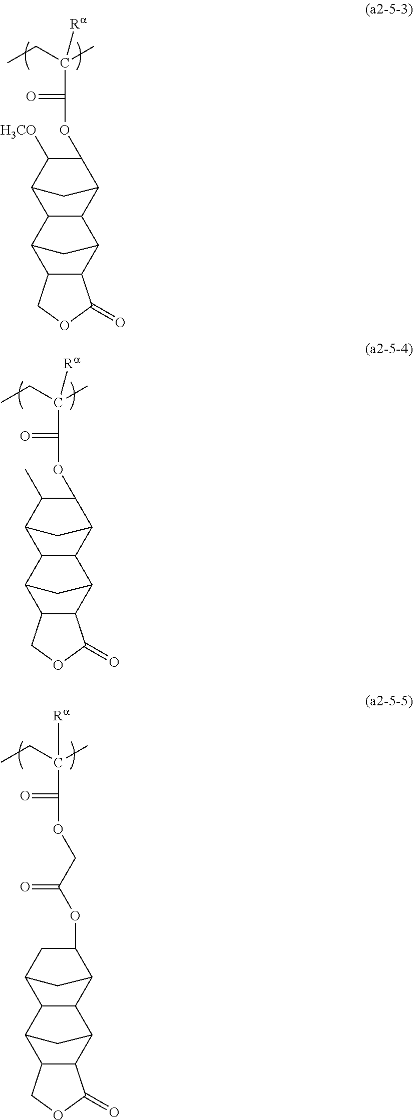

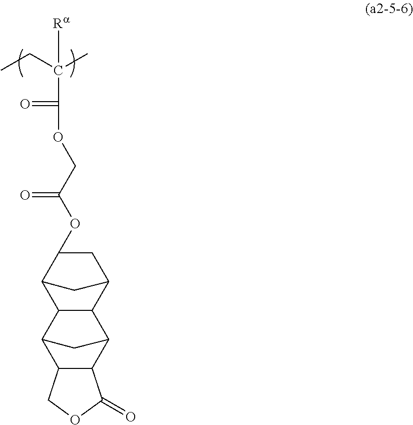

As the structural unit (a2^{L}), it is preferable to include at least one structural unit selected from the group consisting of structural units represented by the aforementioned general formulas (a2-1) to (a2-5), more preferably at least one structural unit selected from the group consisting of structural units represented by the aforementioned general formulas (a2-1) to (a2-3), and particularly preferably at least one structural unit selected from the group consisting of structural units represented by the aforementioned general formulas (a2-1) and (a2-3).

Specifically, it is preferable to use at least one structural unit selected from the group consisting of formulas (a2-1-1), (a2-1-2), (a2-2-1), (a2-2-7), (a2-2-12), (a2-2-14), (a2-3-1) and (a2-3-5).

Furthermore, as the structural unit (a2^{L}), structural units represented by general formulas (a2-6) and (a2-7) are also preferable.

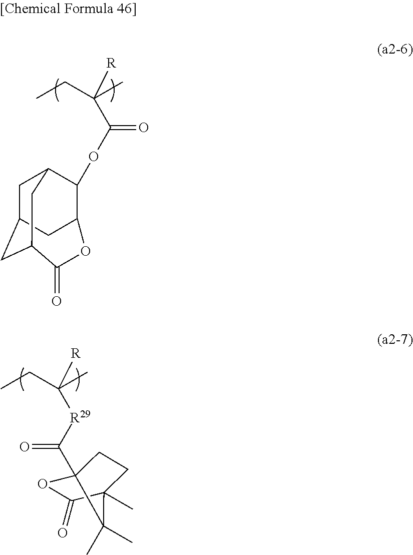

In the formula, R²⁹ is the same as those defined above.

In the polymer according to the present invention, as the structural unit (a2), one type of structural unit may be used, or two or more types may be used in combination. For example, as the structural unit (a2), a structural unit (a2^{s}) may be used alone, or a structural unit (a2^{L}), or a combination of these structural units may be used.

Further, as the structural unit (a2^{s}) or the structural unit (a2^{L}), either a single type of structural unit may be used, or two or more types may be used in combination.

In the polymer according to the present invention, the amount of the structural unit (a2) based on the combined total of all structural units constituting the polymer is preferably 1 to 80 mol %, more preferably 10 to 70 mol %, still more preferably 10 to 65 mol %, and particularly preferably 10 to 60 mol %.

When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

(Structural Unit (a3))

The structural unit (a3) is a structural unit having a polar group. When the polymer includes the structural unit (a3), the hydrophilicity of the polymer is enhanced, thereby contributing to improvement in resolution.

Examples of the polar group include —OH, —COOH, —CN, —SO₂NH₂ and —CONH₂.

The structural unit (a3) is a structural unit containing a hydrocarbon group in which part of the hydrogen atoms within the hydrocarbon group is substituted with the polar group. The hydrocarbon group may be either an aliphatic hydrocarbon group or an aromatic hydrocarbon group. Among these, the hydrocarbon group is preferably an aliphatic hydrocarbon group.

Examples of the aliphatic hydrocarbon group in the hydrocarbon group include linear or branched hydrocarbon groups (preferably alkylene groups) of 1 to 10 carbon atoms, and aliphatic cyclic groups (monocyclic groups and polycyclic groups).

These aliphatic cyclic groups (monocyclic groups and polycyclic groups) can be selected appropriately from the multitude of groups that have been proposed for the resins of resist compositions designed for use with ArF excimer lasers. The aliphatic cyclic group preferably has 3 to 30 carbon atoms, more preferably 5 to 30, still more preferably 5 to 20, particularly preferably 6 to 15, and most preferably 6 to 12. As the aliphatic cyclic group, a group in which two or more hydrogen atoms have been removed from a monocycloalkane or a polycycloalkane such as a bicycloalkane, tricycloalkane or tetracycloalkane can be used. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane. The aliphatic cyclic group may or may not have a substituent. Examples of the substituent include an alkyl group of 1 to 5 carbon atoms, a fluorine atom and a fluorinated alkyl group of 1 to 5 carbon atoms.

The aromatic hydrocarbon group in the hydrocarbon group is a hydrocarbon group containing a aromatic ring, and more preferably has 5 to 30 carbon atoms, still more preferably 6 to 20, particularly preferably 6 to 15, and most preferably 6 to 10. Here, the number of carbon atoms within a substituent(s) is not included in the number of carbon atoms of the aromatic hydrocarbon group. Examples of the aromatic ring in the aromatic hydrocarbon group include aromatic hydrocarbon rings such as benzene, biphenyl, fluorene, naphthalene, anthracene and phenanthrene.

Specific examples of the aromatic hydrocarbon group include a group in which two or more hydrogen atom have been removed from the aromatic hydrocarbon ring (arylene group); a group in which one of hydrogen atom of the group in which one hydrogen atom has been removed from the aromatic hydrocarbon group (aryl group) is substituted with an alkylene group (for example, a group in which one hydrogen atom is removed from an arylalkyl group such as a benzyl group, a phenethyl group, a 1-naphthylmethyl group, a 2-naphthylmethyl group, a 1-naphthylethyl group, or a 2-naphthylethyl group). The alkylene group (alkyl chain within the arylalkyl group) preferably has 1 to 4 carbon atom, more preferably 1 or 2, and most preferably 1.

The aromatic hydrocarbon group may or may not have a substituent. For example, one or more of the hydrogen atoms bonded to the aromatic hydrocarbon ring in the aromatic hydrocarbon group may be substituted with a substituent. Examples of the substituent include an alkyl group, a halogen atom and a halogenated alkyl group.

The alkyl group as the substituent is preferably an alkyl group of 1 to 5 carbon atoms, and a methyl group, an ethyl group, a propyl group, an n-butyl group or a tert-butyl group is particularly preferred.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms within the aforementioned alkyl groups has been substituted with the aforementioned halogen atoms.

Among these, as the structural unit (a3), a structural unit represented by general formula (a3-1) is preferable.

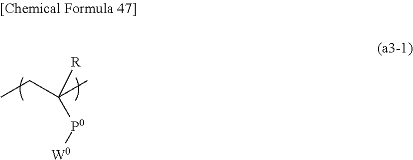

In the formula, R represents a hydrogen atom, an alkyl group of 1 to 5 carbon atoms or a halogenated alkyl group of 1 to 5 carbon atoms; P⁰ represents —C(═O)—O—, —C(═O)—NR⁰— (wherein R⁰ represents a hydrogen atom or an alkyl group of 1 to 5 carbon atoms) or a single bond; and W⁰ represents a hydrocarbon group containing at least one group selected from the group consisting of —OH, —COOH, —CN, —SO₂NH₂ and —CONH₂, and may contain an oxygen atom or a sulfur atom at an arbitrary position.

As the alkyl group for R in the formula (a3-1), a linear or branched alkyl group is preferable, and specific examples include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl groups for R. Examples of the halogen atom include a fluorine atom, a chlorine atom, a bromine atom and an iodine atom, and a fluorine atom is particularly preferred.

As R, a hydrogen atom, an alkyl group of 1 to 5 carbon atoms or a fluorinated alkyl group of 1 to 5 carbon atoms is preferable, and a hydrogen atom or a methyl group is particularly preferred.

P⁰ in the formula (a3-1) represents —C(═O)—O—, —C(═O)—NR⁰— (wherein R⁰ represents a hydrogen atom or an alkyl group of 1 to 5 carbon atoms) or a single bond. The alkyl group for R⁰ is the same as defined above for the alkyl group for R.

W⁰ in the formula (a3-1) is a hydrocarbon group containing at least one group selected from the group consisting of —OH, —COOH, —CN, —SO₂NH₂ and —CONH₂ and may includes an oxygen atom or a sulfur atom at an arbitrary position.

A “hydrocarbon group which have a substituent” means that part or all of the hydrogen atoms within the hydrocarbon group is substituted with a substituent.

The hydrocarbon group for W⁰ may be either an aliphatic hydrocarbon group, or an aromatic hydrocarbon group.

Examples of the aliphatic hydrocarbon group for W⁰ include linear or branched hydrocarbon groups (preferably alkylene groups) of 1 to 10 carbon atoms, and aliphatic cyclic groups (monocyclic groups and polycyclic groups), and these definitions are the same as those described above.

The aromatic hydrocarbon group for W⁰ is a hydrocarbon group having an aromatic ring, and these definitions are the same as those described above.

W⁰ may include an oxygen atom or a sulfur atom at an arbitrary position. The group “may include an oxygen atom or a sulfur atom at an arbitrary position” means that a group in which part of the carbon atom constituting the hydrocarbon group or hydrocarbon group containing a substituent may be substituted with an oxygen atom or a sulfur atom, or a hydrogen atom bonded to the hydrocarbon group may be substituted with an oxygen atom or a sulfur atom.

Examples of W⁰ containing an oxygen atom at an arbitrary position are shown below.

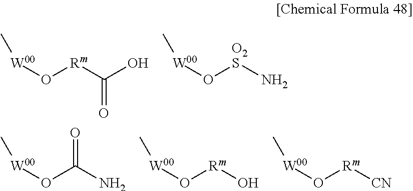

In the formula, W⁰⁰ represents a hydrocarbon group; and R^{m} represents an alkylene group of 1 to 5 carbon atoms.

In the formula, W⁰⁰ represents a hydrocarbon group, and the same hydrocarbon group as those described for W⁰ in the formula (a3-1). W⁰⁰ is preferably an aliphatic hydrocarbon group, more preferably an aliphatic cyclic group (monocyclic group and polycyclic group).

R^{m} is preferably a linear or branched group, preferably an alkylene group of 1 to 3 carbon atoms, and more preferably a methylene group or an ethylene group.

Specific examples of preferable structural units as the structural unit (a3) include structural units represented by general formulas (a3-11) to (a3-13) shown below.

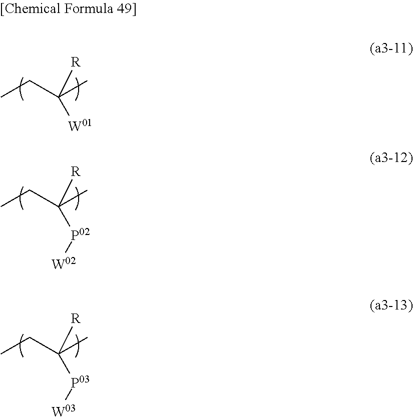

In the formula, R represents a hydrogen atom, an alkyl group of 1 to 5 carbon atoms or a halogenated alkyl group of 1 to 5 carbon atoms; W⁰¹ is an aromatic hydrocarbon group containing at least one group selected from the group consisting of —OH, —COOH, —CN, —SO₂NH₂ and —CONH₂; each of P⁰² and P⁰³ represents —C(═O)—O— or —C(═O)—NR⁰— (wherein R⁰ represents a hydrogen atom or an alkyl group of 1 to 5 carbon atoms); W⁰ is a cyclic hydrocarbon group containing at least one group selected from the group consisting of —OH, —COOH, —CN, —SO₂NH₂ and —CONH₂ and may includes an oxygen atom or a sulfur atom at an arbitrary position; and W⁰³ is a linear hydrocarbon group containing at least one group selected from the group consisting of —OH, —COOH, —CN, —SO₂NH₂ and —CONH₂.

(Structural Unit Represented by General Formula (a3-11))

In general formula (a3-11), R is the same as defined for R in general formula (a3-1).

The aromatic hydrocarbon group for W⁰¹ is the same as defined for the aromatic hydrocarbon group for W⁰ in general formula (a3-1).

Specific examples of structural units represented by general formula (a3-11) are shown below. In the formulas shown below, R^{a} represents a hydrogen atom, a methyl group or a trifluoromethyl group.

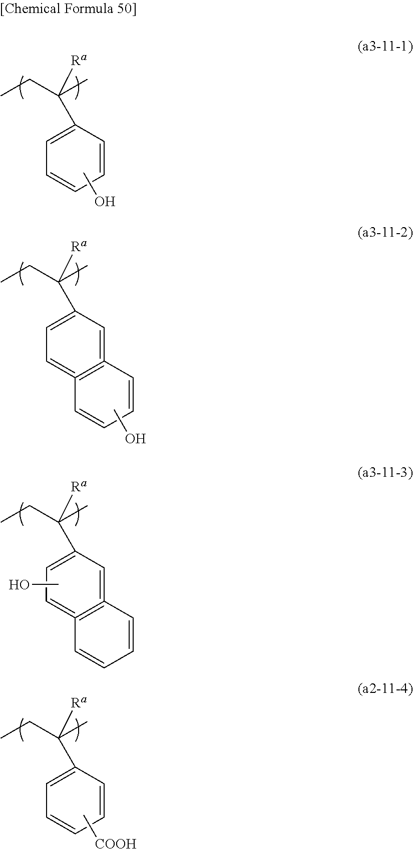

(Structural Unit Represented by General Formula (a3-12))

In general formula (a3-12), R is the same as defined for R in general formula (a3-1).

p⁰² represents —C(═O)—O— or —C(═O)—NR⁰— (wherein R⁰ represents a hydrogen atom or an alkyl group of 1 to 5 carbon atoms), and preferably —C(═O)—O—. The alkyl group for R⁰ is the same the alkyl group as defined above for R.

The cyclic hydrocarbon group for W⁰² is the same as defined for the aliphatic cyclic group (monocyclic group and polycyclic group) and aromatic hydrocarbon group for W⁰ in general formula (a3-1).

W⁰² may include an oxygen atom or a sulfur atom at an arbitrary position, and the definition is the same as defined for W⁰ in the formula (a3-1).

Specific examples of structural units represented by general formula (a3-12) are shown below. In the formulas shown below, R^{a} represents a hydrogen atom, a methyl group or a trifluoromethyl group.

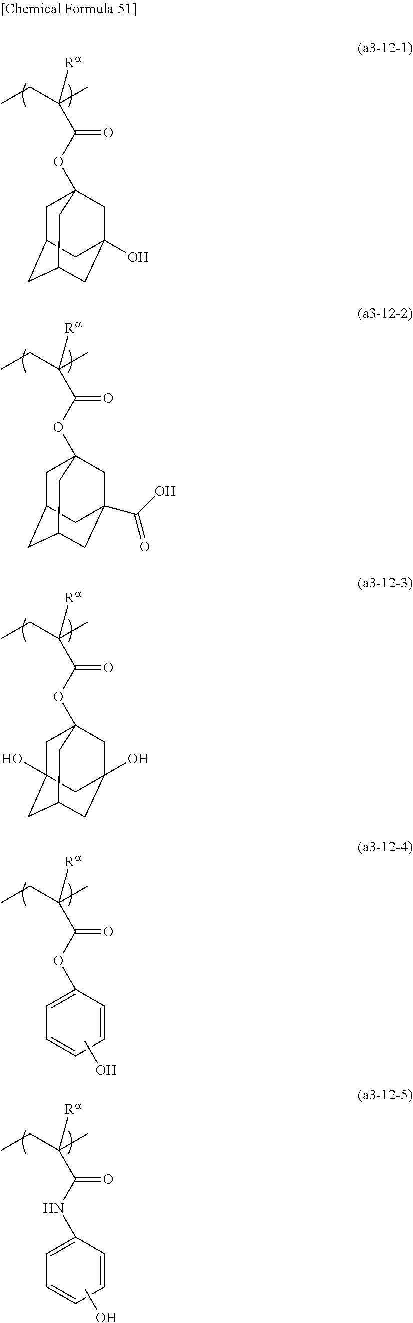

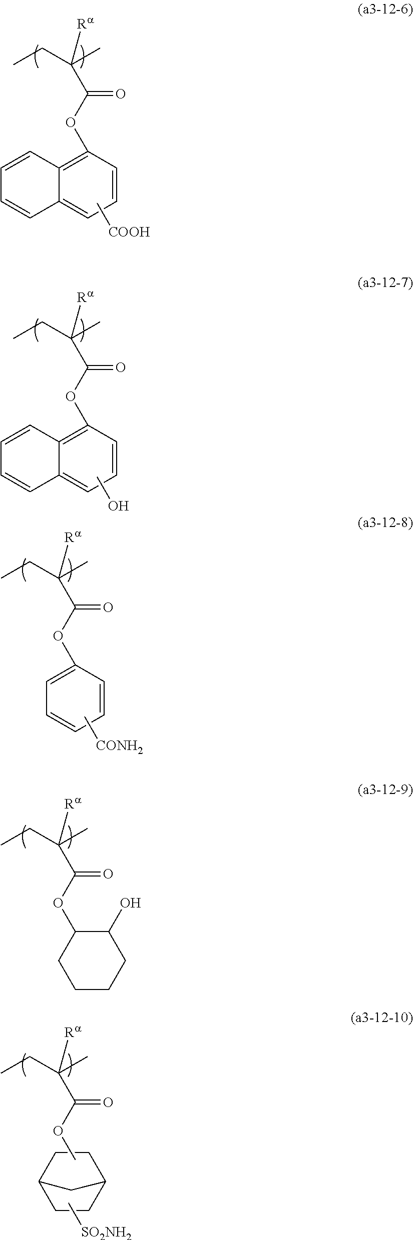

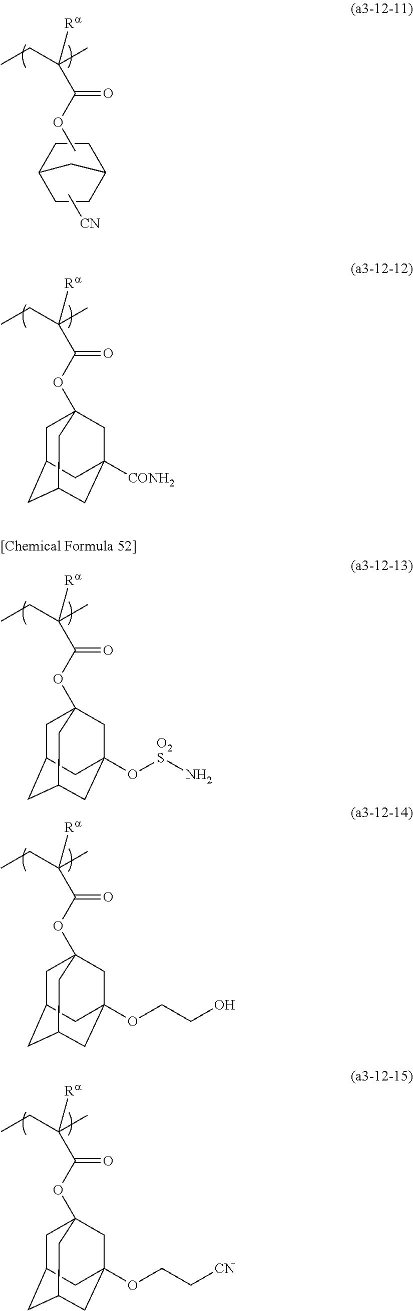

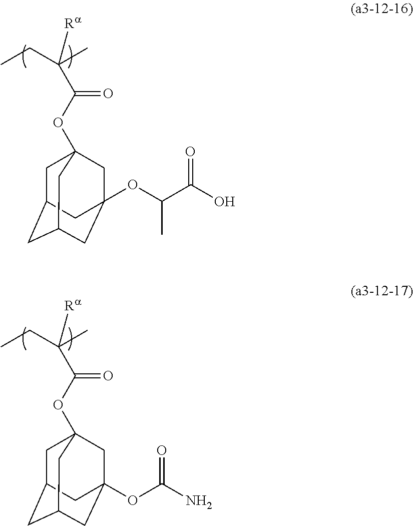

(Structural Unit Represented by General Formula (a3-13))

In general formula (a3-13), R is the same as defined for R in general formula (a3-1).

P⁰³ represents —C(═O)—O— or —C(═O)—NR⁰— (wherein R⁰ represents a hydrogen atom or an alkyl group of 1 to 5 carbon atoms), and preferably —C(═O)—O—. The alkyl group for R⁰ is the same as the alkyl group described above for R.

The linear hydrocarbon group for W⁰³ preferably has 1 to 10 carbon atoms, more preferably 1 to 5 carbon atoms, and still more preferably 1 or 3 carbon atoms.

The linear hydrocarbon group for W⁰³ may have a substituent (a) other than —OH, —COOH, —CN, —SO₂NH₂ and —CONH₂. Examples of the substituent (a) include an alkyl group of 1 to 5 carbon atoms, an aliphatic cyclic group (monocyclic group and polycyclic group), a fluorine atom and a fluorinated alkyl group of 1 to 5 carbon atoms. The aliphatic cyclic group (monocyclic group and polycyclic group) for the substituent (a) preferably has 3 to 30 carbon atoms, more preferably 5 to 30, still more preferably 5 to 20, particularly more preferably 6 to 15, and most preferably 6 to 12. As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

In addition, the linear hydrocarbon group for W⁰³ may have a plurality of substituents (a), and the plurality of substituents (a) may be bonded to each other to form a ring, as in the structural unit represented by the general formula (a3-13-a).

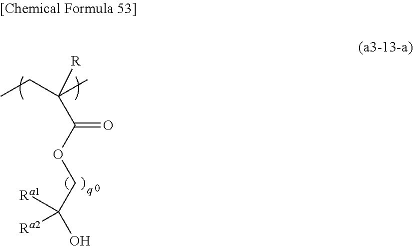

In the formula, R represents a hydrogen atom, an alkyl group of 1 to 5 carbon atoms or a halogenated alkyl group of 1 to 5 carbon atoms; each of R^{a1} and R^{a2} independently represents an alkyl group of 1 to 5 carbon atom, an aliphatic cyclic group (monocyclic group and polycyclic group), a fluorine atom or a fluorinated alkyl group of 1 to 5 carbon atoms, provided that R^{a1} and R^{a2} may be bonded to each other to form a ring; and q⁰ represents an integer of 1 to 4.

In general formula (a3-13-a), R is the same as defined for R in general formula (a3-1).

The aliphatic cyclic group (monocyclic group and polycyclic group) for R^{a1} and R^{a2} is the same aliphatic cyclic group (monocyclic group and polycyclic group) for substituent (a) as described above.

R^{a1} and R^{a2} may be bonded to each other to form a ring. In such a case, a cyclic group is formed by R^{a1}, R^{a2} and the carbon atom having R^{a1} and R^{a2} bonded thereto. The cyclic group may be either a monocyclic group or a polycyclic group. Specific examples include groups in which one or more hydrogen atoms have been removed from a monocycloalkane or polycycloalkane which is exemplified in the explanation of the aliphatic cyclic group (monocyclic group and polycyclic group) for the substituent (a).

q⁰ is preferably 1 or 2, and more preferably 1.

Specific examples of structural units represented by general formula (a3-13) are shown below. In the formulas shown below, R⁺ represents a hydrogen atom, a methyl group or a trifluoromethyl group.

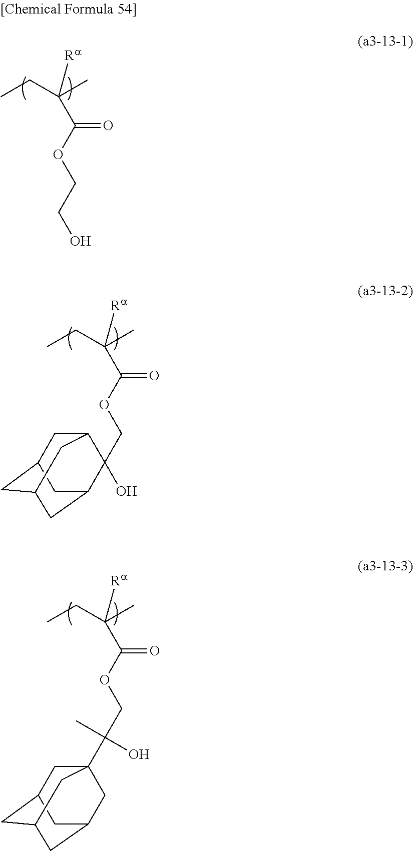

As the structural unit (a3) contained in the polymer of the present invention, 1 type of structural unit may be used, or 2 or more types may be used.

In the polymer according to the present invention, the amount of the structural unit (a3) based on the combined total of all structural units constituting the polymer is preferably 1 to 40 mol %, more preferably 1 to 35 mol %, still more preferably 3 to 30 mol %, and particularly preferably 5 to 25 mol %.

When the amount of the structural unit (a3) is at least as large as the lower limit of the above-mentioned range, the effect of using the structural unit (a3) (such as improvement effect in resolution, lithography properties and pattern shape) can be satisfactorily achieved. On the other hand, when the amount of the structural unit (a3) is no more than the upper limit of the above-mentioned range, a good balance can be achieved with the other structural units.

(Structural Unit (a4))

The structural unit (a4) is a structural unit having an acid non-dissociable cyclic group. By including the structural unit (a4), the dry etching resistance of the resist pattern formed using a resist composition containing the polymer can be improved. The hydrophobicity of the polymer is enhanced. In particular, in the case of conducting the development using a developing solution containing an organic solvent, improvement of hydrophobicity of the polymer contributes to improve resolution, resist pattern shape, and the like.

An “acid non-dissociable, aliphatic cyclic group” in the structural unit (a4) refers to a cyclic group which is not dissociated by the action of the acid generated from the anion part on the terminal of the main chain or an acid generator component (B) described below upon exposure, and remains in the structural unit. The cyclic group may be either an aliphatic cyclic group or an aromatic cyclic group, and is preferably an aliphatic cyclic group. The aliphatic cyclic group may be either a monocyclic group or a polycyclic group. In terms of the aforementioned effects, a polycyclic group is preferable.

Examples of the acid non-dissociable cyclic group include a non-acid-dissociable aliphatic cyclic group and a group in which at least one of R¹⁵ and R¹⁶ in the formulas (2-1) to (2-6) in the structural unit (a1) is a hydrogen atom.

Specific examples of the acid non-dissociable aliphatic polycyclic group include monovalent aliphatic polycyclic groups in which the carbon atom having an atom adjacent to the aliphatic polycyclic group (e.g., —O— within —C(═O)—O—) bonded thereto has no substituent (a group or an atom other than hydrogen). The aliphatic cyclic group is not particularly limited as long as it is acid non-dissociable, and any of the multitude of conventional polycyclic groups used within the resin component of resist compositions for ArF excimer lasers or KrF excimer lasers (and particularly for ArF excimer lasers) can be used. The aliphatic cyclic group may be either saturated or unsaturated, preferably saturated.

Specific examples include groups in which one hydrogen atom has been removed from the cycloalkanes (such as monocycloalkanes and polycycloalkanes) described above in the explanation of the aliphatic cyclic group for the structural unit (a1).

The aliphatic cyclic group may be either a monocyclic group or a polycyclic group. In terms of the aforementioned effects, a polycyclic group is preferable. In particular, a bi-, tri- or tetracyclic group is preferable. In consideration of industrial availability and the like, at least one polycyclic group selected from amongst a tricyclodecyl group, an adamantyl group, a tetracyclododecyl group, an isobornyl group and a norbornyl group is particularly preferred.

Specific examples of the acid non-dissociable aliphatic cyclic group include monovalent aliphatic cyclic groups in which the carbon atom having an atom adjacent to the aliphatic cyclic group (e.g., —O— within —C(═O)—O—) bonded thereto has no substituent (a group or an atom other than hydrogen). More specific examples include groups represented by general formulas (1-1) to (1-9) explained above in relation to the structural unit (a1) in which the R¹⁴ group has been substituted with a hydrogen atom; and a cycloalkane having a tertiary carbon atom constituting the ring skeleton and having one hydrogen atom removed from.

The aliphatic cyclic group may have a substituent. Examples of the substituent include an alkyl group of 1 to 5 carbon atoms, a fluorine atom and a fluorinated alkyl group.

Specific examples of the structural unit (a4) include a structural unit in which an acid dissociable group in the structural unit (a1) has been substituted with an acid non-dissociable cyclic group. Among these, a structural unit which is a structural unit derived from an acrylate ester which may have the hydrogen atom bonded to the carbon atom on the α-position substituted with a substituent and contains an acid non-dissociable cyclic group, that is, a structural unit represented by following general formula (a4-0) is preferable. In particular, a structural units represented by following general formulas (a4-1) to (a4-5) is preferable.

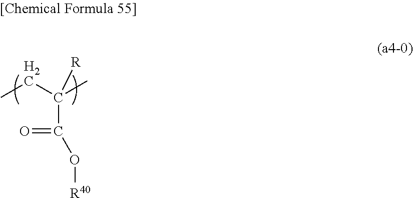

In the formulas, R is the same as defined above; and R⁴⁰ represents an acid non-dissociable aliphatic cyclic group.

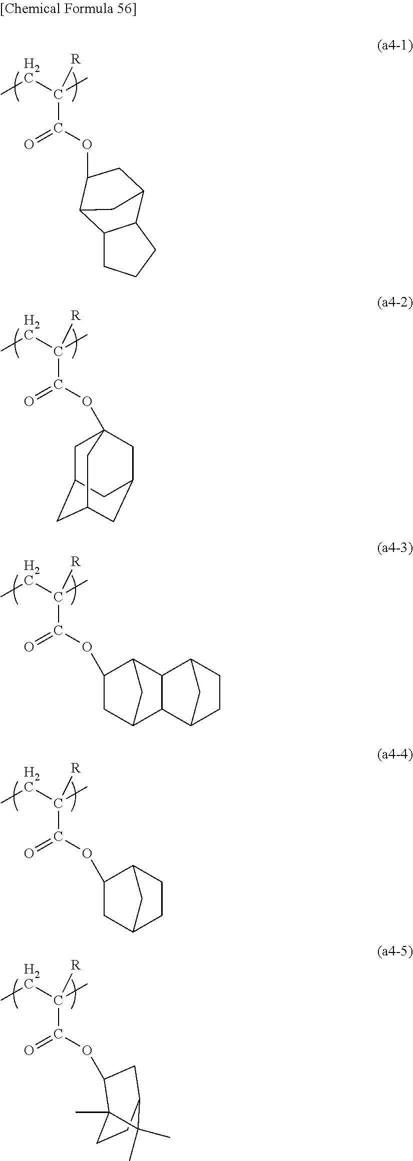

In the formulas, R is the same as defined above.

As the structural unit (a4), one type of structural unit may be used, or two or more types may be used in combination.

When the structural unit (a4) is included in the polymer according to the present invention, the amount of the structural unit (a4) based on the combined total of all the structural units that constitute the polymer is preferably within the range from 1 to 30 mol %, and more preferably from 10 to 20 mol %.

A polymer according to the present invention contains an anion part which generates acid upon exposure on at least one terminal of the main chain, and two types of structural units (a1). The polymer according to the present invention may further contain the structural unit (a2), (a3), (a4) and the like. In particular, the polymer preferably contains at least one structural unit selected from the structural unit (a2) and the structural unit (a3).

Preferable examples of the polymer according to the present invention includes a polymer having two types of structural units (a1) and at least one type of structural unit (a2) as a structural units which constitute the polymer; a polymer having two types of structural units (a1) and at least one type of structural unit (a3) as a structural units which constitute the polymer; a polymer having two types of structural units (a1), at least one type of structural unit (a2) and at least one type of structural unit (a3) as a structural units which constitute the polymer.

Preferable examples of combination of two types of structural units (a1) are the same as described above.

The weight average molecular weight (Mw) (the polystyrene equivalent value determined by gel permeation chromatography) of the polymer according to the present invention is not particularly limited, but is preferably 1,000 to 50,000, more preferably 1,500 to 30,000, and most preferably 2,000 to 20,000. When the weight average molecular weight of the polymer is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the polymer according to the present invention is preferably 1.0 to 5.0, more preferably 1.0 to 3.0, and most preferably 1.2 to 2.5. Here, Mn is the number average molecular weight.

### (Production Method of Polymer)

The polymer according to the present invention can be obtained, for example, by a radical polymerization or an anionic polymerization, using monomers including at least one monomer which derives a structural unit (a1), and using a radical polymerization initiator containing an anion part which generates acid upon exposure. As the monomers, commercially available monomers may be used, or the monomers may be synthesized by a conventional method.

The polymer of the present invention is preferably a radical polymer obtained by radial polymerization using a radical polymerization initiator including a compound represented by general formula (I).

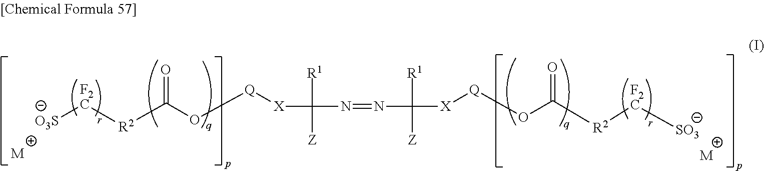

wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 1 to 3;
Q represents a hydrocarbon group having a valency of (p+1), provided that, p represents 1, Q may represent a single bond;
R² represents a single bond, an alkylene group which may have a substituent or an aromatic group which may have a substituent; q represents 0 or 1; r represents an integer of 0 to 8; and M⁺ represents an organic cation; provided that the plurality of R¹, Z, X, p, Q, R², q, r and M⁺ may be the same or different from each other.
In the formula (I), R¹, Z, X, p, Q, R², q, r and M⁺ are respectively the same as defined for R¹, Z, X, p, Q, R², q, r, M⁺ in the formula (I-1).

The monomers to be polymerized by a radical polymerization include at least two types of monomers which derive structural units (a1), and may include other monomers. As the other monomers, any monomers which can polymerize with a monomer deriving a structural unit (a1) can be used. These monomers can be appropriately selected according to the polymer to be produced.

The radical polymerization can be conducted by a conventional method, expect that a compound represented by the formula (I) is used as a radical polymerization initiator.

In the radical polymerization, as the radical polymerization initiator, one type may be used alone, or two or more types may be used in combination.

Production examples of the polymer of the present invention are shown below. With respect to the production example described below, a synthetic route in which the monomer represented by the formula (a) (a vinyl compound having a characteristic group such as an acid decomposable group; hereafter, referred to as “monomer (a)”) is subjected to a radical polymerization using a radical polymerization initiator composed of the compound represented by the formula (I) (hereafter, referred to as “radical polymerization initiator (I)”) is schematically described. The monomers (a) include at least two types of monomers which derive structural units (a1).

However, the synthetic route of the polymer is not limited to the following production examples.

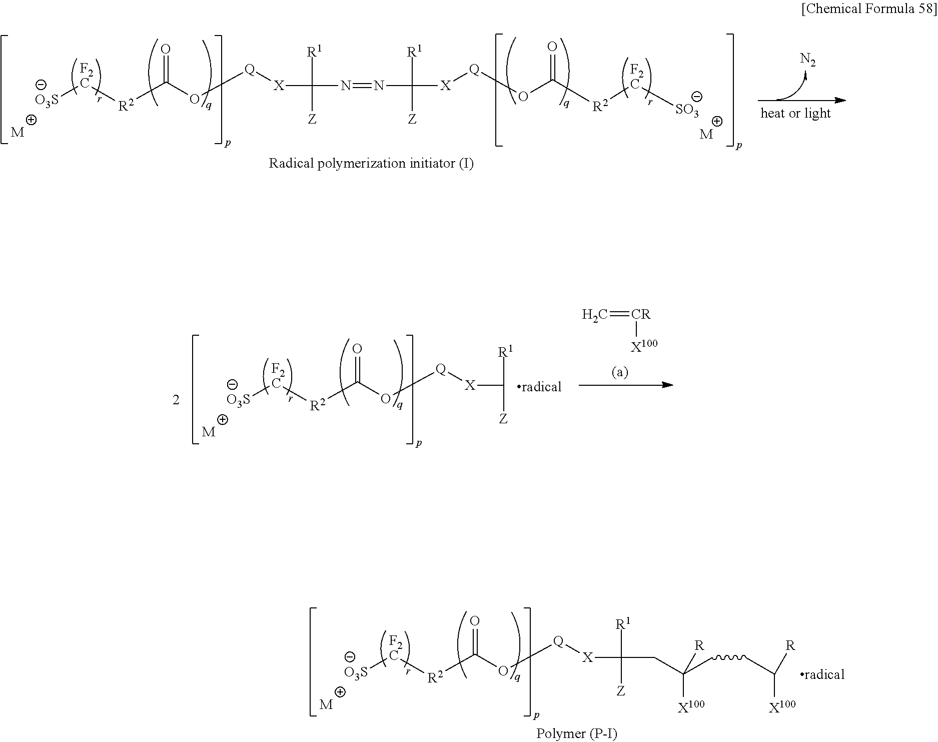

In the formula, R¹, Z, X, p, Q, R², q, r and M⁺ are the same as defined for R¹, Z, X, p, Q, R², q, r and M⁺ in the formula (I-1); R represents an alkyl group of 1 to 5 carbon atoms or a halogenated alkyl group of 1 to 5 carbon atoms; and X¹⁰⁰ represents an organic group containing a characteristic group.

In the synthetic route, the radical polymerization initiator (I) is decomposed by the action of heat or light, thereby generating nitrogen gas (N₂) and a carbon radical. Next, the carbon radical acts on the monomer (a), and the polymerization of monomers (a) is proceeded, thereby obtaining the polymer (P—I).

The resulting polymer (P—I) contains an anion part which generates acid upon exposure on at least one terminal of the main chain, and the “anion part which generates acid upon exposure” is the residue derived from a radical polymerization initiator (I) (aforementioned terminal group (I-1)).

As the radial polymerization initiator (I), a compound represented by any one of general formulas (I1) to (I5) shown below is preferable.

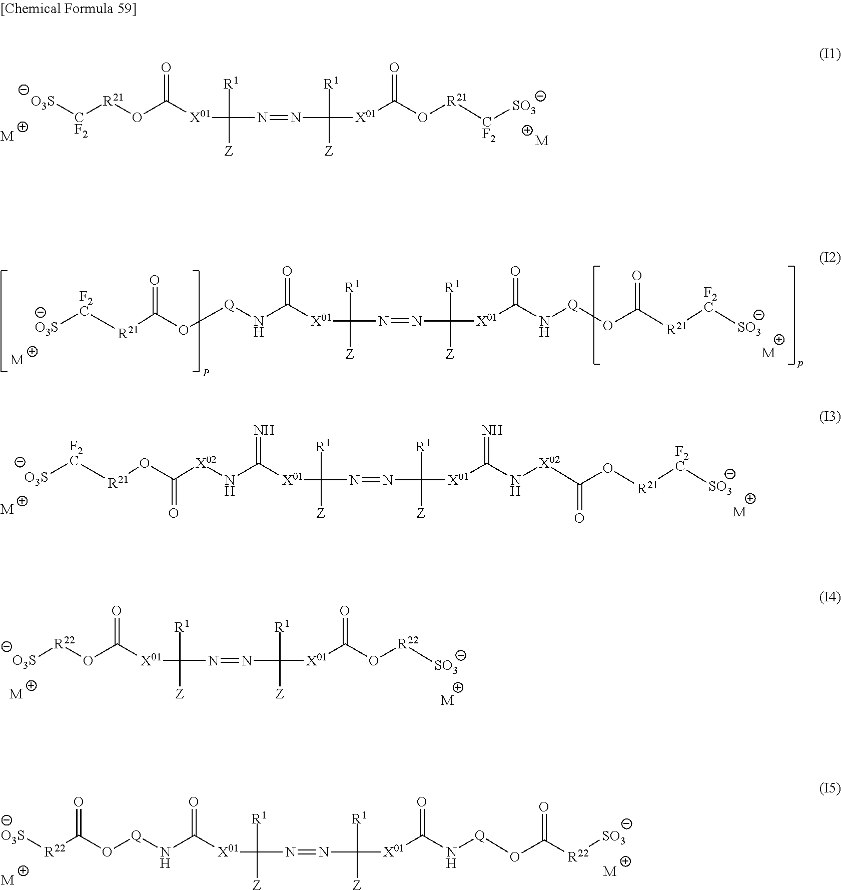

In the formula, R¹, Z, Q, p and M⁺ are the same as defined above; X⁰¹ represents a single bond or an alkylene group which may have a substituent; R²¹ represents a single bond or an alkylene group which may have a substituent; X⁰² represents an alkylene group which may have a substituent; and R²² represents an aromatic group which may have a substituent, provided that the plurality of R¹, Z, Q, p, M⁺, X⁰¹, R²¹, X⁰² and R²² may be the same or different from each other.

In the formulas (I1) to (I5), R¹, Z, X⁰¹, Q, p and M⁺ are respectively the same as R¹, Z, X⁰¹, Q, p and M⁺ in the formulas (I-1-1) to (I-1-5).

In general formulas (I1) and (I3), R²¹ is the same as defined for R²¹ in general formulas (I-1-1) and (I-1-3).

In general formula (I3), X⁰² is the same as defined for X⁰² in general formula (I-1-3).

In general formulas (I4) and (I5), R²² is the same as defined for R²² in general formulas (I-1-4) and (I-1-5).

Specific examples of structural units represented by general formulas (I1) to (I5) are shown below. In the following formula, M⁺ is the same as defined above.

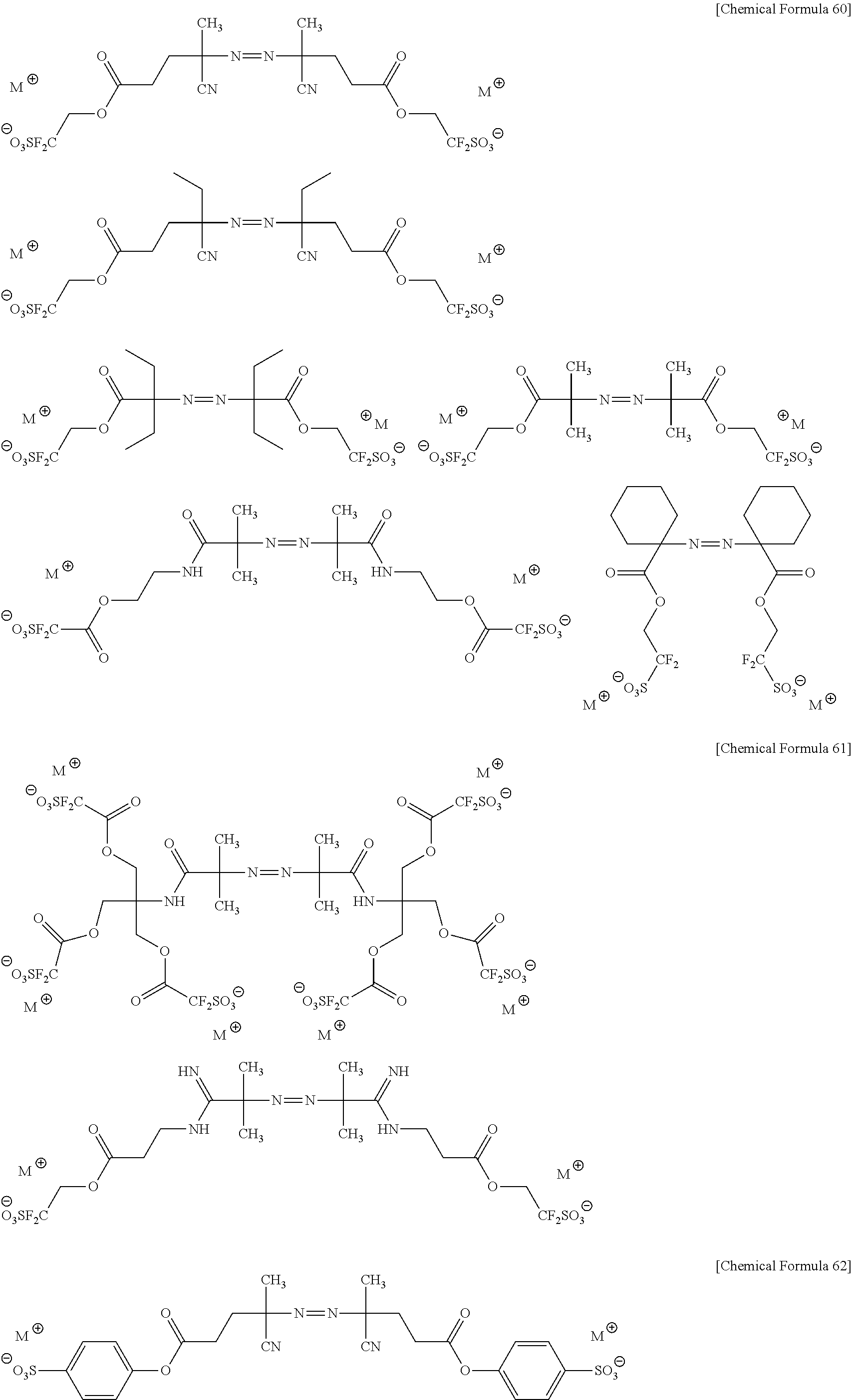

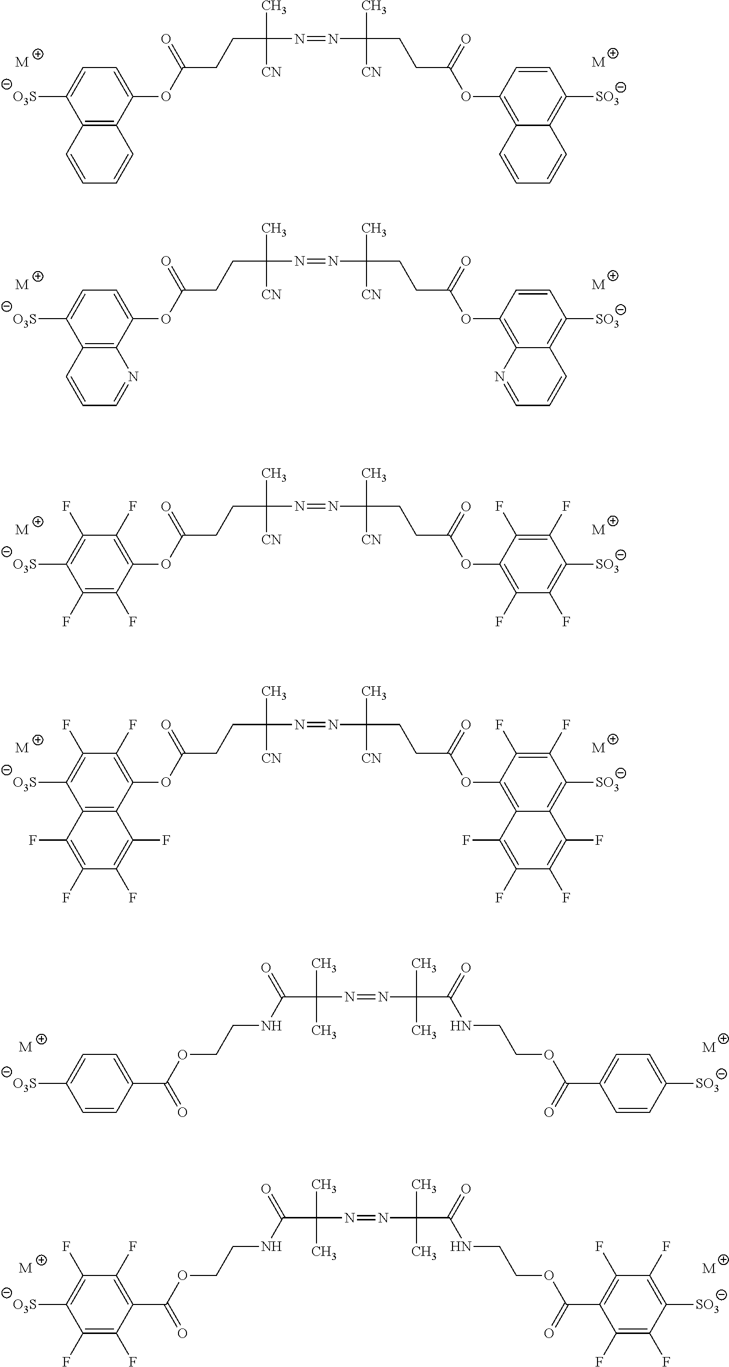

Among these, as the radical polymerization initiator (I), a compound represented by any one of the formulas (I1) to (I5) is preferable, and a compound represented by the formula (I1) is particularly preferable.

In addition, as the organic cation for M⁺, an organic cation represented by the aforementioned formula (c-1), (c2) or (c-3) is preferable, and an organic cation represented by the aforementioned formula (c-1) is particularly preferable.

The production method of the radical polymerization initiator (I) is not particularly limited, although a method containing a step of reacting a compound represented by general formula (i-1) shown below (hereafter referred to as “compound (i-1)”) to a compound represented by general formula (i-2) shown below (hereafter referred to as “compound (i-2)”) can be preferably used.

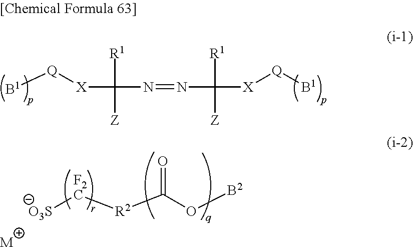

In the formula, R¹, Z, X, Q, p, q, R², r and M⁺ are the same as defined above; and each of B¹ and B² independently represents H or OH; provided that the plurality of Z, X, p, Q and B¹ may be the same or different from each other.

In the formula (i-1), when the terminal of Q bonded to B¹ is an oxygen atom, or when Q represents a single bond and the terminal of Q bonded to B¹ is an oxygen atom, B¹ is preferably H. On the other hand, the terminal of Q bonded to B¹ is not an oxygen atom, or when Q represents a single bond and the terminal of Q bonded to B¹ is not an oxygen atom, B¹ is preferably OH.

In the formula (i-2), when q represents 1, B² is preferably H. On the other hand, q represents 0, B² is preferably OH.

As the compound (i-1) and the compound (i-2), commercially available compounds may be used, or the compounds may be synthesized.

Examples of the method for reacting the compound (i-1) with the compound (i-2) to obtain the radical polymerization initiator (I) include a method containing reacting the compound (i-1) with the compound (i-2) in an organic solvent in the presence of a condensation agent and base, followed by washing and recovering the reaction mixture.

Examples of the condensation agent used in the reaction include compounds containing carbodiimide groups, such as diisopropylcarbodiimide. These compounds may be used individually or in a combination of two or more. The amount of the condensation agent is preferably 0.01 to 10 moles, per 1 mole of the compound (I-2). Examples of the base used in the reaction include potassium carbonate, tertiary amines such as triethylamine and aromatic amines such as pyridine. These bases may be used individually or in a combination of two or more. The amount of the base is preferably 0.01 to 10 moles, per 1 mole of the compound (I-2).

As the organic solvent used in the reaction, chlorinated hydrocarbon solvents such as dichloromethane is preferred. The amount of the organic solvent is preferably 0.5 to 100 moles, and more preferably 0.5 to 20 moles, relative to the compound (I-2). As the organic solvent, one type may be used alone, or two or more types may be used in combination.

In general, when p represents 1, the amount of the compound (i-2) used in the reaction is preferably 0.5 to 5 moles per 1 mole of the compound (i-1), and more preferably 0.8 to 4 moles per 1 mole of the compound (i-1).

The reaction time varies depending on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20 to 200° C., and more preferably 20 to 150° C.

After the reaction, the polymerization initiator (I) within the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the polymerization initiator (I) obtained in the above-described manner can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

As an another method of producing the polymer of the present invention, a method in which a polymer (precursor polymer) having a group represented by the following formula (I-01) on at least one terminal of the main chain can be obtained by a polymerization using a radical polymerization initiator (I0) represented the formula (I0) shown below, thereby inducing a group “—(OCO)_{q}—R²—(CF₂)ᵣ—SO₃⁻M⁺” (wherein, q, R², r and M⁺ are the same as those defined above)” on the terminal of the main chain of the polymer (that is, substituting the hydrogen atom on the terminal of the main chain with the group), can be mentioned. As the compound (I-01), conventional compounds can be used.

Inducing “—(OCO)_{q}—R²—(CF₂)ᵣ—SO₃⁻M⁺” can be conducted by a conventional method, for example, by a method including reacting a precursor polymer with a compound (I-02) represented by general formula (i-02) shown below. The reaction can be conducted in the same manner as the method of reacting the compound (i-1) and the compound (i-2) as described above.

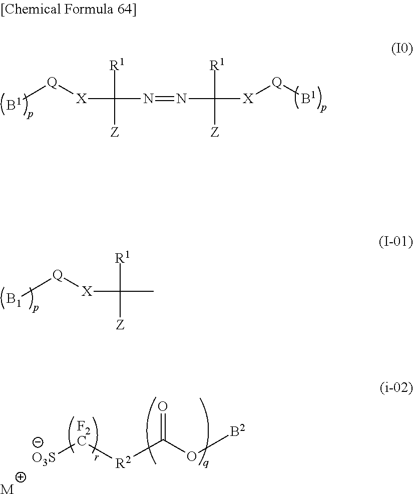

In the formula, R¹, Z, X, Q, p, q, R², r, M⁺ and B¹, B² are the same as defined above.

The polymer according to the present invention as described above further contains an anion part which generates acid upon exposure on at least one terminal of the main chain, the polymer of the present invention is capable of generating an acid upon exposure, in addition to two types of structural units containing an acid decomposable group in which a difference between each activation energy of the acid decomposable groups is no less than a predetermined value. Therefore, the polymer contributes to improvement in various lithography properties (such as exposure latitude (EL margin), mask reproducibility, roughness, pattern shape, and the like) of the resist composition containing the polymer.

Because the polymer according to the present invention contains an anion part which generates acid upon exposure on at least one terminal of the main chain, the polymer of the present invention has an acid generating capacity upon exposure. For example, by virtue of the sulfonium salt part at the end of the group represented by the general formula (an1) (terminal group (I-1)), sulfonic acid is generated upon exposure.

Therefore, the polymer according to the present invention is useful for a resist composition. There are no particular limitations on the resist composition containing the polymer, although a chemically amplified resist composition including a base component that exhibits changed solubility in an alkali developing solution under the action of acid, and an acid generator component that generates acid upon exposure is ideal.

The polymer according to the present invention is useful as a base component for the chemically amplified resist composition, or as an additive component which is arbitrarily blended into a resist composition, and use as a base component is particularly preferable.

### <<Resist Composition>>

The resist composition of the present invention contains the polymer of the present invention. By virtue of the polymer according to the present invention, the resist film formed using the resist composition has a function for generating an acid upon exposure, and a function for increasing polarity by the action of acid, that is, a function for changing solubility in a developing solution under the action of acid.

In addition, by virtue of including the polymer of the present invention in the resist film, it is possible to form a pattern using the components which exhibits a changed solubility under action of acid, even if the resist composition does not additionally contain an acid-generator component On the other hand, when the resist composition contains an acid-generator component other than the polymer of the present invention, the sensitivity thereof is further improved compared to that of a resist composition which does not contain the polymer of the present invention.

The resist composition of the present invention may be either a negative resist composition or a positive resist composition.

In the present specification, a resist composition which forms a positive pattern by dissolving and removing the exposed portions is called a positive resist composition, and a resist composition which forms a negative pattern by dissolving and removing the unexposed portions is called a negative resist composition.

In addition, the resist composition of the present invention may be either a non-chemically amplified type or a chemically amplified type. In particular, the resist composition of the present invention contains a polymer which generates acid from the terminal of the main chain. Therefore, the resist composition of the present invention is preferably a chemically amplified resist composition. In addition, the chemically amplified resist composition is preferable because it can form a resist pattern with high sensitivity and high resolution.

As a chemically amplified composition, a composition including a base material component that exhibits a changed solubility in a developing solution under the action of acid and an acid-generator component that generates acid upon exposure is generally used. When the resist composition is subjected to a selective exposure, acid is generated from the acid-generator component, and the generated acid acts on the base component to change the solubility of the base component in a developing solution. As a result, in the formation of a resist pattern, when a resist film obtained using the resist composition is subjected to selective exposure, the solubility in the alkali developing solution of the exposed portions of the resist film changes (In the case of positive resist composition, the solubility is increased. In the case of negative resist composition, the solubility is decreased), whereas the solubility in the alkali developing solution of the unexposed portions remains unchanged. Therefore, by developing the resist film after exposure, a resist pattern can be formed.

As described above, in the chemically amplified resist composition, a base component which exhibits changed solubility in a developing solution under action of acid is generally used.

Here, the term “base component” refers to an organic compound capable of forming a film, and is preferably an organic compound having a molecular weight of 500 or more. When the organic compound has a molecular weight of 500 or more, the film-forming ability is improved, and a resist pattern of nano level can be easily formed. The “organic compound having a molecular weight of 500 or more” which can be used as a base component is broadly classified into non-polymers and polymers. In general, as a non-polymer, any of those which have a molecular weight in the range of 500 to less than 4,000 is used. Hereafter, a non-polymer having a molecular weight in the range of 500 to less than 4,000 is referred to as a low molecular weight compound. As a polymer, any of those which have a molecular weight of 1,000 or more is generally used. Hereafter, a polymer having a molecular weight of 1,000 or more is referred to as a polymeric compound. With respect to a polymeric compound, the “molecular weight” is the weight average molecular weight in terms of the polystyrene equivalent value determined by gel permeation chromatography (GPC). Hereafter, a polymeric compound is frequently referred to simply as a “resin”.

The resist composition according to the present invention may contain the polymer according to the present invention as a base component which exhibits changed solubility in a developing solution under action of acid, or may contain the polymer according to the present invention in addition to other resin which is included in the base component. That is, because the polymer according to the present invention used in the resist composition according to the present invention contains an acid decomposable group which is decomposed by the action of an acid, the polymer exhibits increased solubility in a developing solution under the action of acid and can be used as a base component. Therefore, the polymer according to the present invention can be used as a base component.

As described above, the polymer according to the present invention contains an anion part which generates acid upon exposure on at least one terminal of the main chain. In addition, the polymer exhibits a changed solubility in a developing solution under the action of acid. The anion part and the part which contributes to change the solubility under the action of acid (specific examples includes the structural unit (a1)) are uniformly distributed within the resist film, and the solubility of the polymer itself is changed by the action of acid which is uniformly generated from the polymer at exposed portions. Therefore, excellent lithography properties can be achieved.

The resist compositions of the present invention functions as a resist material, when the polymer according to the present invention is included, and therefore other components may not necessarily be included. Preferably, the resist composition according to the present invention further includes an acid-generator component (B) which generates acid upon exposure (provided that the base component (A) is excluded).

The resist composition according to the present invention contains a base component (A) which exhibits changed solubility in a developing solution under action of acid, and generates acid upon exposure (hereafter, referred to as “component (A)”), and the component (A) preferably contains the polymer according to the present invention.

The resist composition according to the present invention includes a component (A) and an acid-generator component (B) which generates acid upon exposure (provided that the base component (A) is excluded) (hereafter, referred to as “component (B)”), and the component (A) preferably includes a polymer according to the present invention.

Next, the resist composition containing the polymer of the present invention as a component (A) will be described.

### <Component (A)>

When the resist composition of the present invention is a “negative resist composition for alkali developing process” which forms a negative pattern in an alkali developing process, for example, as the component (A), a base component that is soluble in an alkali developing solution is used, and a cross-linking agent is blended in the negative resist composition.

In the negative resist composition for alkali developing process, when acid is generated from the polymer according to the present invention contained in the component (A) upon exposure, the action of the generated acid causes cross-linking between the base component and the cross-linking agent, and the cross-linked portion becomes insoluble in an alkali developing solution. Therefore, in the formation of a resist pattern, by conducting selective exposure of a resist film formed by applying the negative resist composition onto a substrate, the exposed portions become insoluble in an alkali developing solution, whereas the unexposed portions remain soluble in an alkali developing solution, and hence, a resist pattern can be formed by alkali developing.

Generally, as the component (A) for a negative resist composition for alkali developing process, a resin that is soluble in an alkali developing solution (hereafter, referred to as “alkali-soluble resin”) is used.

Examples of the alkali soluble resin include a resin having a structural unit derived from at least one of α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin which has a sulfonamide group and may have the hydrogen atom bonded to the carbon atom on the α-position substituted with a substituent or polycycloolefin resin having a sulfoneamide group, as disclosed in U.S. Pat. No. 6,949,325; an acrylic resin which may have the hydrogen atom bonded to the carbon atom on the α-position substituted with a substituent and having a fluorinated alcohol, as disclosed in U.S. Pat. No. 6,949,325, Japanese Unexamined Patent Application, First Publication No. 2005-336452 or Japanese Unexamined Patent Application, First Publication No. 2006-317803; and a polycyclolefin resin having a fluorinated alcohol, as disclosed in Japanese Unexamined Patent Application, First Publication No. 2006-259582. These resins are preferable in that a resist pattern can be formed with minimal swelling.

Here, the term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (preferably a hydroxyalkyl group of 1 to 5 carbon atoms) is bonded to the carbon atom on the α-position.

As the cross-linking agent, typically, an amino-based cross-linking agent such as a glycoluril having a methylol group or alkoxymethyl group, or a melamine-based cross-linking agent is preferable, as it enables formation of a resist pattern with minimal swelling. The amount of the cross-linker added is preferably within a range from 1 to 50 parts by weight, relative to 100 parts by weight of the alkali-soluble resin.

In the case where the resist composition of the present invention is a resist composition which forms a positive pattern in an alkali developing process and a negative pattern in a solvent developing process, it is preferable to use a base component (A0) (hereafter, referred to as “component (A0)”) which exhibits increased polarity by the action of acid. By using the component (A0), since the polarity of the base component changes prior to and after exposure, an excellent development contrast can be obtained not only in an alkali developing process, but also in a solvent developing process.

More specifically, in the case of applying an alkali developing process, the component (A0) is substantially insoluble in an alkali developing solution prior to exposure, but when acid is generated from the polymer according to the present invention contained in the component (A) upon exposure, the action of this acid causes an increase in the polarity of the base component, thereby increasing the solubility of the component (A0) in an alkali developing solution. Therefore, in the formation of a resist pattern, by conducting selective exposure of a resist film formed by applying the resist composition to a substrate, the exposed portions change from an insoluble state to a soluble state in an alkali developing solution, whereas the unexposed portions remain insoluble in an alkali developing solution, and hence, a positive resist pattern can be formed by alkali developing.

On the other hand, in the case of a solvent developing process, the component (A0) exhibits high solubility in an organic developing solution prior to exposure, and when acid is generated from the polymer according to the present invention contained in the component (A) upon exposure, the polarity of the component (A0) is increased by the action of the generated acid, thereby decreasing the solubility of the component (A0) in an organic developing solution. Therefore, in the formation of a resist pattern, by conducting selective exposure of a resist film formed by applying the resist composition to a substrate, the exposed portions changes from an soluble state to an insoluble state in an organic developing solution, whereas the unexposed portions remain soluble in an organic developing solution. As a result, by conducting development using an organic developing solution, a contrast can be made between the exposed portions and unexposed portions, thereby enabling the formation of a negative resist pattern.

In the resist composition of the present invention, the component (A) is preferably a base component which exhibits increased polarity by the action of acid (i.e., a component (A0)). That is, the resist composition of the present invention is preferably a chemically amplified resist composition which becomes a positive type in the case of an alkali developing process, and a negative type in the case of a solvent developing process.

In particular, in the resist composition according to the present invention, the component (A) particularly preferably contains a component (A1) composed of the polymer according to the present invention.

In the component (A), as the component (A1), one type may be used, or two or more types of compounds may be used in combination.

In the component (A), the amount of the component (A1) based on the total weight of the component (A) is preferably 5% by weight or more, more preferably 10% by weight or more, still more preferably 15% by weight or more, and may be even 100% by weight. When the amount of the component (A1) is 10% by weight or more, various lithography properties such as EL are improved, and roughness can be reduced.

In the resist composition of the present invention, the amount of the component (A) can be appropriately adjusted depending on the thickness of the resist film to be formed, and the like.

### [Component (A2)]

In the resist composition of the present invention, the component (A) may contain “a base component which exhibits changed solubility in a developing solution under action of acid” other than the component (A1) (hereafter, referred to as “component (A2)”).

Examples of the component (A2) include low molecular weight compounds that have a molecular weight of at least 500 and less than 2,500, contains a hydrophilic group, and also contains an acid dissociable group described above in connection with the component (A1). Specific examples include compounds containing a plurality of phenol skeletons in which a part of the hydrogen atoms within hydroxyl groups have been substituted with the aforementioned acid dissociable groups.

Examples of the component (A2) include low molecular weight phenolic compounds in which a portion of the hydroxyl group hydrogen atoms have been substituted with an aforementioned acid dissociable group, and these types of compounds are known, for example, as sensitizers or heat resistance improvers for use in non-chemically amplified g-line or i-line resists.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers and tetramers of formalin condensation products of phenols such as phenol, m-cresol, p-cresol and xylenol. Needless to say, the low molecular weight phenol compound is not limited to these examples. In particular, a phenol compound having 2 to 6 triphenylmethane skeletons is preferable in terms of resolution and LWR. Also, there are no particular limitations on the acid dissociable group, and suitable examples include the groups described above.

In addition as a component (A2), a base component which exhibits changed solubility in a developing solution under action of acid other than the component (A1) is preferably used. The resin component other than the component (A1) is a polymer other than the polymer according to the present invention. For example, a polymer which is produced not using the aforementioned radical polymerization initiator (I) but using a conventional radical polymerization initiator other than the radical polymerization initiator (I). The polymer is not particularly limited, and preferable examples thereof include a polymer containing the structural units (a3), (a1), (a2^{S}) and (a2^{L}).

As the component (A2), one type of resin may be used, or two or more types of resins may be used in combination.

### <Optional Components>

### [Component (B)]

The resist composition of the present invention may further include an acid-generator component (B) which generates acid upon exposure.

When the resist composition of the present invention includes the component (B), as the component (B), there is no particular limitation, and any of the known acid generators used in conventional chemically amplified resist compositions can be used. Examples of these acid generators are numerous, and include onium salt acid generators such as iodonium salts and sulfonium salts; oxime sulfonate acid generators; diazomethane acid generators such as bisalkyl or bisaryl sulfonyl diazomethanes and poly(bis-sulfonyl)diazomethanes; nitrobenzylsulfonate acid generators; iminosulfonate acid generators; and disulfone acid generators.

As an onium salt acid generator, a compound represented by general formula (b-1) or (b-2) shown below can be used.

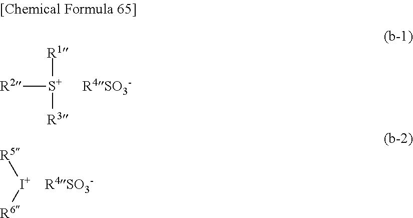

In the formulas above, R¹″ to R³″, R⁵″ and R⁶″ each independently represent an aryl group or alkyl group, wherein two of R″ to R³″ may be bonded to each other to form a ring with the sulfur atom; and R⁴″ represents an alkyl group, a halogenated alkyl group, an aryl group or an alkenyl group which may have a substituent, with the provision that at least one of R¹″ to R³″ represents an aryl group, and at least one of R⁵″ and R⁶″ represents an aryl group.

R¹″ to R³″ in general formula (b-1), and R⁵″ and R⁶″ in general formula (b-2) are each the same as defined for R¹″ to R³″ in the formula (c-1) and R⁵″ and R⁶″ in the formula (c-2).

In formulas (b-1) and (b-2), R⁴″ represents an alkyl group, a halogenated alkyl group, an aryl group or an alkenyl group which may have a substituent.

The alkyl group for R⁴″ may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

As an example of the halogenated alkyl group for R⁴″, a group in which part of or all of the hydrogen atoms of the aforementioned linear, branched or cyclic alkyl group have been substituted with halogen atoms can be given. Examples of the aforementioned halogen atom include a fluorine atom, a chlorine atom, a bromine atom and an iodine atom, and a fluorine atom is preferable.

In the halogenated alkyl group, the percentage of the number of halogen atoms based on the total number of halogen atoms and hydrogen atoms (halogenation ratio (%)) is preferably 10 to 100%, more preferably 50 to 100%, and most preferably 100%. Higher halogenation ratio is preferable because the acid strength increases.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴″ may have one substituent, or two or more substituents.

Examples of the substituent include a halogen atom, a hetero atom, an alkyl group, and a group represented by the formula X³-Q¹- (in the formula, Q¹ represents a divalent linking group containing an oxygen atom; and X³ represents a hydrocarbon group of 3 to 30 carbon atoms which may have a substituent). Examples of halogen atoms and alkyl groups include the same halogen atoms and alkyl groups as those described above with respect to the halogenated alkyl group for R⁴″.

Examples of hetero atoms include an oxygen atom, a nitrogen atom, and a sulfur atom.

In the group represented by formula X³-Q¹-, Q¹ represents a divalent linking group containing an oxygen atom.

Q¹ may contain an atom other than oxygen. Examples of atoms other than oxygen include a carbon atom, a hydrogen atom, a sulfur atom and a nitrogen atom.

Examples of divalent linkage groups containing an oxygen atom include non-hydrocarbon, oxygen atom-containing linkage groups such as an oxygen atom (an ether bond; —O—), an ester bond (—C(═O)—O—), an amido bond (—C(═O)—NH—), a carbonyl group (—C(═O)—) and a carbonate group (—O—C(═O)—O—); and a combination of any of the aforementioned non-hydrocarbon, oxygen atom-containing linkage groups with an alkylene group.

Specific examples of the combinations of the aforementioned non-hydrocarbon, oxygen atom-containing linkage groups with alkylene groups include —R⁹¹—O—, —R⁹²—O—C(═O)— and —C(═O)—O—R⁹³—O—C(═O)— (in the formulas, R⁹¹ to R⁹³ each independently represent an alkylene group).

The alkylene group for R⁹¹ to R⁹³ is preferably a linear or branched alkylene group, and preferably has 1 to 12 carbon atoms, more preferably 1 to 5, and most preferably 1 to 3.

Specific examples of the alkylene group include a methylene group [—CH₂—], alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, a tetramethylene group [—CH₂CH₂CH₂CH₂—], alkyltetramethylene groups such as —CH(CH₃)CH₂CH₂CH₂— and —CH₂CH(CH₃)CH₂CH₂—, and a pentamethylene group [—CH₂CH₂CH₂CH₂CH₂—].

Q¹ is preferably a divalent linking group containing an ester linkage or ether linkage, and more preferably a group of —R⁹¹—O—, —R⁹²—O—C(═O)— or —C(═O)—O—R⁹³—O—C(═O)—.

In the group represented by the formula X³-Q¹-, the hydrocarbon group for X³ may be either an aromatic hydrocarbon group or an aliphatic hydrocarbon group.

The aromatic hydrocarbon group is a hydrocarbon group having an aromatic ring. The aromatic hydrocarbon group preferably has 5 to 30 carbon atoms, more preferably 5 to 20, still more preferably 6 to 15, and most preferably 6 to 12. Here, the number of carbon atoms within a substituent(s) is not included in the number of carbon atoms of the aromatic hydrocarbon group.

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an alkylaryl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atom, more preferably 1 or 2, and most preferably 1.

The aromatic hydrocarbon group may have a substituent. For example, part of the carbon atoms constituting the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned heteroatom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly preferred.

The alkoxy group as the substituent for the aromatic hydrocarbon group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X³ may be either a saturated aliphatic hydrocarbon group, or an unsaturated aliphatic hydrocarbon group. Further, the aliphatic hydrocarbon group may be linear, branched or cyclic.

In the aliphatic hydrocarbon group for X³, part of the carbon atoms constituting the aliphatic hydrocarbon group may be substituted with a substituent group containing a hetero atom, or part or all of the hydrogen atoms constituting the aliphatic hydrocarbon group may be substituted with a substituent group containing a hetero atom.

As the “hetero atom” for X³ there is no particular limitation as long as it is an atom other than carbon and hydrogen.

Examples of the halogen atom include a fluorine atom, a chlorine atom, an iodine atom and a bromine atom.

The substituent group containing a hetero atom may consist of a hetero atom, or may be a group containing a group or atom other than a hetero atom.

Specific examples of the substituent group for substituting a part of the carbon atoms include —O—, —C(═O)—O—, —C(═O)—, —O—C(═O)—O—, —C(═O)—NH—, —NH— (the H may be substituted with a substituent such as an alkyl group or an acyl group), —S—, —S(═O)₂— and —S(═O)₂—O—. When the aliphatic hydrocarbon group is cyclic, the aliphatic hydrocarbon group may contain any of these substituent groups in the ring structure.

Examples of the substituent group for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which a part or all of the hydrogen atoms within an alkyl group of 1 to 5 carbon atoms (e.g., a methyl group, an ethyl group, a propyl group, an n-butyl group or a tert-butyl group) have been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably has 1 to 20 carbon atoms, more preferably 1 to 15, and most preferably 1 to 10. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably has 3 to 20 carbon atoms, more preferably 3 to 15, and most preferably 3 to 10. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably has 2 to 10 carbon atoms, more preferably 2 to 5, still more preferably 2 to 4, and most preferably 3. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly preferred.

The aliphatic cyclic group may be either a monocyclic group or a polycyclic group. The aliphatic cyclic group preferably has 3 to 30 carbon atoms, more preferably 5 to 30, still more preferably 5 to 20, still more preferably 6 to 15, and most preferably 6 to 12.

As the aliphatic cyclic group, a group in which one or more hydrogen atoms have been removed from a monocycloalkane or a polycycloalkane such as a bicycloalkane, tricycloalkane or tetracycloalkane can be used. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly preferred.

When the aliphatic cyclic group contains a hetero atom-containing substituent group in the ring structure thereof, the hetero atom-containing substituent group is preferably —O—, —C(═O)—O—, —S—, —S(═O)₂ or —S(═O)₂—O—. Specific examples of such aliphatic cyclic groups include groups represented by formulas (L1) to (L6) and (S1) to (S4) shown below.

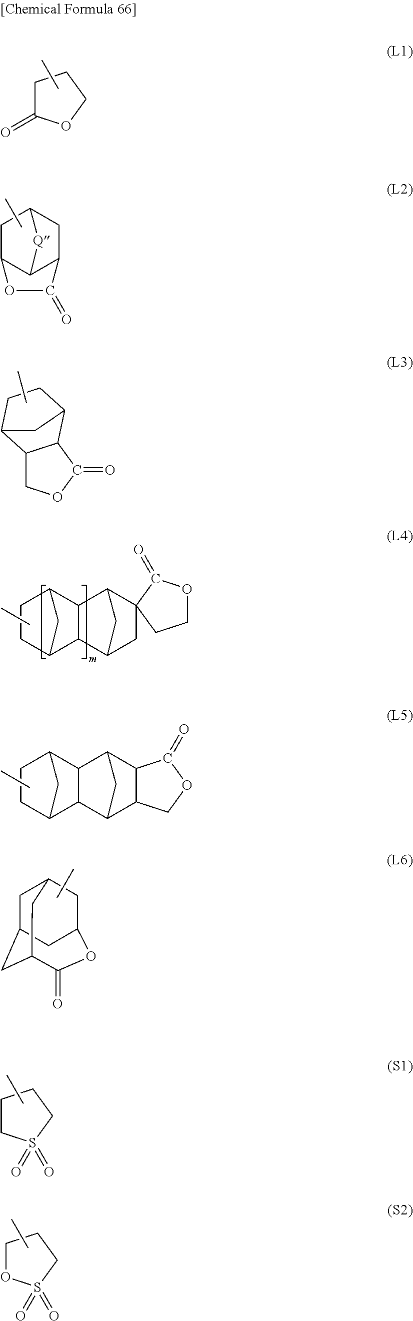

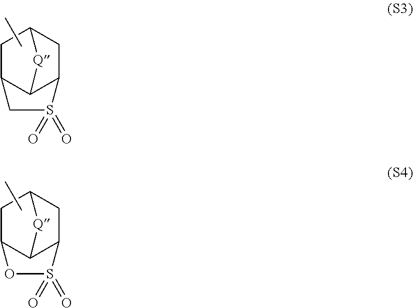

In the formulas, Q″ represents an alkylene group of 1 to 5 carbon atoms, —O—, —S—, —O—R⁹⁴— or —S—R⁹⁵— (R⁹⁴ and R⁹⁵ each independently represent an alkylene group of 1 to 5 carbon atoms); and m represents 0 or 1.

As the alkylene group for Q″, R⁹⁴ and R⁹⁵, the same alkylene groups as those described above for R⁹¹ to R⁹³ can be used.

In these aliphatic cyclic groups, part of the hydrogen atoms bonded to the carbon atoms constituting the ring structure may be substituted with a substituent. Examples of substituents include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly preferred.

As the alkoxy group and the halogen atom, the same groups as the substituent groups for substituting part or all of the hydrogen atoms can be used.

In the present invention, as X³, a cyclic group which may have a substituent is preferable. The cyclic group may be either an aromatic hydrocarbon group which may have a substituent, or an aliphatic cyclic group which may have a substituent, and an aliphatic cyclic group which may have a substituent is preferable.

As the aromatic hydrocarbon group, a naphthyl group which may have a substituent, or a phenyl group which may have a substituent is preferable.

As the aliphatic cyclic group which may have a substituent, an aliphatic polycyclic group which may have a substituent is preferable. As the aliphatic polycyclic group, the aforementioned group in which one or more hydrogen atoms have been removed from a polycycloalkane, and groups represented by the aforementioned formulas (L2) to (L6), (S3) and (S4) are preferable.

In the present invention, R⁴″ preferably has X³-Q¹- as a substituent. In this case, R⁴″ is preferably a group represented by formula X³-Q¹-Y¹⁰— [wherein Q¹ and X³ are the same as defined above; and Y¹⁰ represents an alkylene group of 1 to 4 carbon atoms which may have a substituent, or a fluorinated alkylene group of 1 to 4 carbon atoms which may have a substituent].

In the group represented by the formula X³-Q¹-Y¹⁰, as the alkylene group for Y¹⁰, the same alkylene group as those described above for Q¹ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y⁰ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—, —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)— and —C(CH₃)(CH₂CH₃)—.

As Y¹⁰, a fluorinated alkylene group is preferable, and a fluorinated alkylene group in which the carbon atom bonded to the adjacent sulfur atom is fluorinated is particularly preferred. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly preferred.

The alkylene group or fluorinated alkylene group may have a substituent. The alkylene group or fluorinated alkylene group “has a substituent” means that part or all of the hydrogen atoms or fluorine atoms in the alkylene group or fluorinated alkylene group has been substituted with groups other than hydrogen atoms and fluorine atoms.

Examples of substituents which the alkylene group or fluorinated alkylene group may have include an alkyl group of 1 to 4 carbon atoms, an alkoxy group of 1 to 4 carbon atoms, and a hydroxyl group.

Specific examples of suitable onium salt acid generators represented by formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

It is also possible to use onium salts in which the anion moiety of these onium salts is replaced by an alkyl sulfonate, such as methanesulfonate, n-propanesulfonate, n-butanesulfonate, n-octanesulfonate, 1-adamantanesulfonate, 2-norbornanesulfonate or d-camphor-10-sulfonate; or replaced by an aromatic sulfonate, such as benzenesulfonate, perfluorobenzenesulfonate or p-toluenesulfonate.

Furthermore, onium salts in which the anion moiety of these onium salts are replaced by an anion moiety represented by any one of formulas (b1) to (b9) shown below can be used.

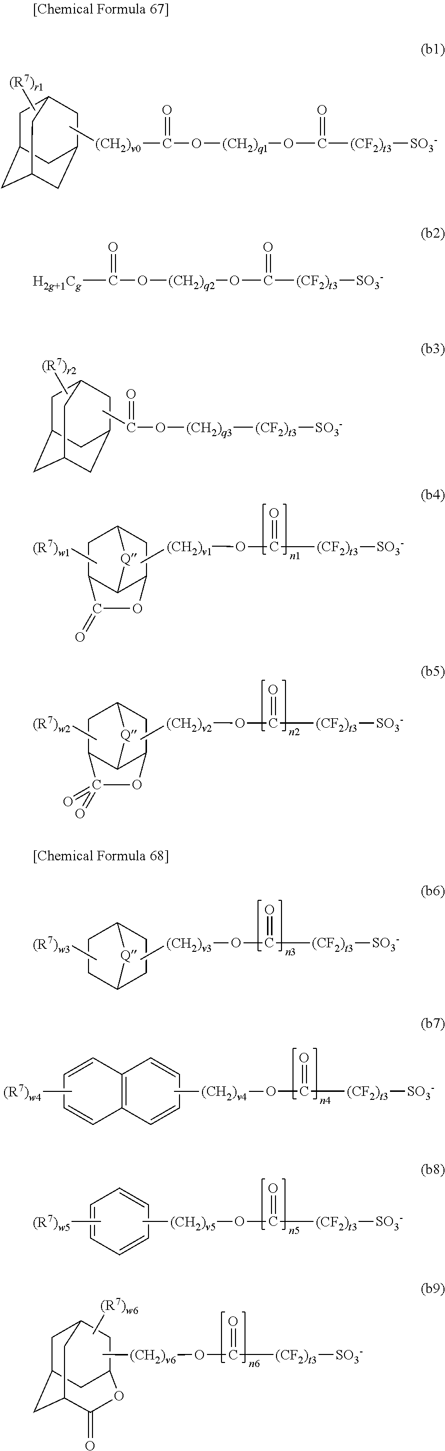

In the formulas, each of q1 and q2 independently represents an integer of 1 to 5; q3 represents an integer of 1 to 12; t3 represents an integer of 1 to 3; each of r1 and r2 independently represents an integer of 0 to 3; g represents an integer of 1 to 20; R⁷ represents a substituent; each of n1 to n5 independently represents 0 or 1; each of v0 to v6 independently represents an integer of 0 to 3; each of w1 to w6 independently represents an integer of 0 to 3; and Q″ is the same as defined above.

As the substituent for R⁷, the same groups as those which the aforementioned aliphatic hydrocarbon group or aromatic hydrocarbon group for X⁰³ may have as a substituent can be used.

If there are two or more of the R⁷ group, as indicated by the values r1, r2, and w1 to w6 then the two or more of the R⁷ groups may be the same or different from each other.

Further, onium salt-based acid generators in which the anion moiety in general formula (b-1) or (b-2) is replaced by an anion moiety represented by general formula (b-3) or (b-4) shown below (the cation moiety is the same as (b-1) or (b-2)) may be used.

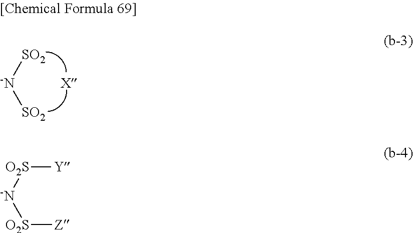

In the formulas, X″ represents an alkylene group of 2 to 6 carbon atoms in which at least one hydrogen atom has been substituted with a fluorine atom; and Y″ and Z″ each independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, and the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, and the alkyl group has 1 to 10 carbon atoms, preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved.

The fluorination ratio of the alkylene group or alkyl group is preferably from 70 to 100%, more preferably from 90 to 100%, and it is particularly preferable that the alkylene group or alkyl group be a perfluoroalkylene group or perfluoroalkyl group in which all hydrogen atoms are substituted with fluorine atoms.

Furthermore, as an onium salt-based acid generator, a sulfonium salt having a cation moiety represented by general formula (c-3) shown below may be used. The anion moiety of the sulfonium salt having a cation moiety represented by general formula (c-3) is not particularly limited, and the same anion moieties for onium salt-based acid generators which have been proposed may be used. Examples of such anion moieties include fluorinated alkylsulfonic acid ions such as anion moieties (R⁴″SO₃⁻) for onium salt-based acid generators represented by general formula (b-1) or (b-2) shown above; and anion moieties represented by general formula (b-3) or (b-4) shown above.

In the present description, an oximesulfonate-based acid generator is a compound having at least one group represented by general formula (B-1) shown below, and has a feature of generating acid by irradiation. Such oximesulfonate acid generators are widely used for a chemically amplified resist composition, and can be appropriately selected.

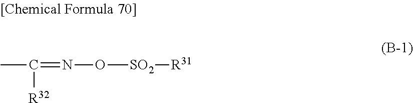

In the formula, each of R³¹ and R³² independently represents an organic group.

The organic group for R³¹ and R³² refers to a group containing a carbon atom, and may include atoms other than carbon atoms (e.g., a hydrogen atom, an oxygen atom, a nitrogen atom, a sulfur atom, a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The alkyl group or the aryl group “has a substituent” means that part or all of the hydrogen atoms of the alkyl group or the aryl group is substituted with a substituent.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly preferred. The “partially halogenated alkyl group” refers to an alkyl group in which part of the hydrogen atoms are substituted with halogen atoms and the “completely halogenated alkyl group” refers to an alkyl group in which all of the hydrogen atoms are substituted with halogen atoms. Examples of halogen atoms include fluorine atoms, chlorine atoms, bromine atoms and iodine atoms, and fluorine atoms are particularly preferred. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly preferred. The “partially halogenated aryl group” refers to an aryl group in which some of the hydrogen atoms are substituted with halogen atoms and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly preferred.

As the organic group for R³², a linear, branched, or cyclic alkyl group, aryl group, or cyano group is preferable. As the alkyl group or aryl group for R³², the same alkyl groups or aryl groups as those described above for R³¹ can be used.

As R³², a cyano group, an alkyl group of 1 to 8 carbon atoms having no substituent or a fluorinated alkyl group of 1 to 8 carbon atoms is particularly preferred.

Preferable examples of the oxime sulfonate-based acid generator include compounds represented by general formula (B-2) or (B-3) shown below.

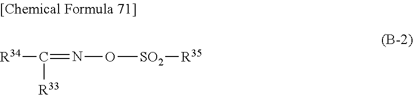

In the formula, R³³ represents a cyano group, an alkyl group having no substituent or a halogenated alkyl group; R³⁴ represents an aryl group; and R³⁵ represents an alkyl group having no substituent or a halogenated alkyl group.

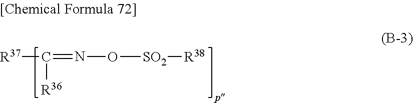

In the formula (B-3), R³⁶ represents a cyano group, an alkyl group having no substituent or a halogenated alkyl group; R³⁷ represents a divalent or trivalent aromatic hydrocarbon group; and R³⁸ represents an alkyl group having no substituent or a halogenated alkyl group. and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenantryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms fluorinated, more preferably 70% or more, still more preferably 90% or more. A completely fluorinated alkyl group in which 100% of the hydrogen atoms are substituted with fluorine atoms is particularly preferred.

In general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group for R″

As the alkyl group having no substituent or the halogenated alkyl group for R³⁸, the same one as the alkyl group having no substituent or the halogenated alkyl group for R³⁵ can be used.

p″ is preferably 2.

Specific examples of suitable oxime sulfonate acid generators include

α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.
Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

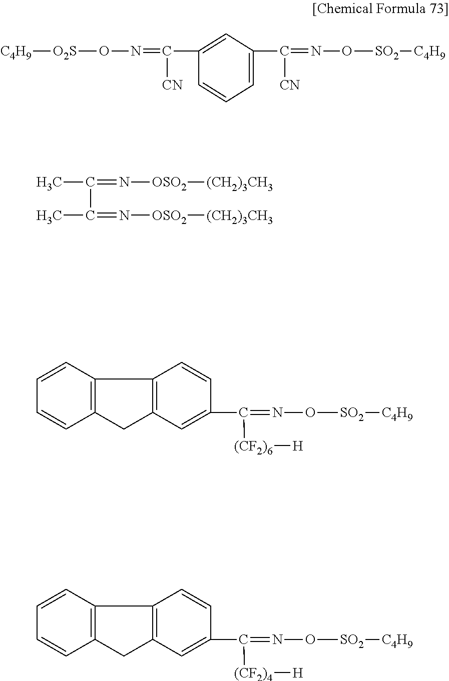

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may be preferably used. Furthermore, as poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be mentioned.

As the component (B), one type of acid generator may be used, or two or more types of acid generators may be used in combination.

When the resist composition in the present invention contains the component (B), as the component (B), it is preferable to use an onium salt having a fluorinated alkylsulfonic acid ion as the anion moiety.

When the resist composition of the present invention contains the component (B), the amount of the component (B) relative to 100 parts by weight of the component (A) is preferably 0.5 to 50 parts by weight, and more preferably 1 to 40 parts by weight. When the amount of the component (B) is within the above-mentioned range, formation of a resist pattern can be satisfactorily performed. Further, by virtue of the above-mentioned range, a uniform solution can be obtained and the storage stability becomes satisfactory.

### [Component (D)]

It is preferable that the resist composition of the present invention further includes a nitrogen-containing organic compound (D) (hereafter referred to as the component (D)) as an optional component.

As the component (D), there is no particular limitation as long as it functions as an acid diffusion control agent, i.e., a quencher which traps the acid generated from the component (A1) and component (B) upon exposure. A multitude of these components (D) have already been proposed, and any of these known compounds may be used. Among these, an aliphatic amine, particularly a secondary aliphatic amine or tertiary aliphatic amine is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of no more than 12 carbon atoms (i.e., alkylamines or alkylalcoholamines), and cyclic amines.

Specific examples of alkylamines and alkylalcoholamines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decylamine, and tri-n-dodecylamine; and alkyl alcohol amines such as diethanolamine, triethanolamine, diisopropanolamine, triisopropanolamine, di-n-octanolamine, and tri-n-octanolamine.

Among these, trialkylamines of 5 to 10 carbon atoms are preferable, and tri-n-pentylamine and tri-n-octylamine are particularly preferred.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine, and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate, and triethanolamine triacetate is preferable.

Further, as the component (D), an aromatic amine may be used.

Examples of aromatic amines include aniline, pyridine, 4-dimethylaminopyridine, pyrrole, indole, pyrazole, imidazole and derivatives thereof, as well as diphenylamine, triphenylamine, tribenzylamine, 2,6-diisopropylaniline and N-tert-butoxycarbonylpyrrolidine.

As the component (D), one type of compound may be used alone, or two or more types may be used in combination.

The component (D) is typically used in an amount within a range from 0.01 to 5.0 parts by weight, relative to 100 parts by weight of the component (A). When the amount of the component (D) is within the above-mentioned range, the shape of the resist pattern and the post exposure stability of the latent image formed by the pattern-wise exposure of the resist layer are improved.

### [Component (E)]

Furthermore, in the resist composition of the present invention, for preventing any deterioration in sensitivity, and improving the resist pattern shape and the post exposure stability of the latent image formed by the pattern-wise exposure of the resist layer, at least one compound (E) (hereafter referred to as the component (E)) selected from the group consisting of an organic carboxylic acid, or a phosphorus oxo acid or derivative thereof can be added.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid. Among these, phosphonic acid is particularly preferred.

Examples of oxo acid derivatives include esters in which a hydrogen atom within the above-mentioned oxo acids is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), salicylic acid is particularly preferred.

As the component (E), one type may be used alone, or two or more types may be used in combination.

The component (E) is typically used in an amount within a range from 0.01 to 5.0 parts by weight, relative to 100 parts by weight of the component (A).

### [Component (F)]

The resist composition may further include a fluorine additive (hereafter, referred to as “component (F)”) for imparting water repellency to the resist film. As the component (F), for example, a fluorine-containing polymeric compound described in Japanese Unexamined Patent Application, First Publication No. 2010-002870.

As the component (F), a polymer having a structural unit represented by general formula (f1-1) shown below can be used. The polymer include copolymers is preferably a polymer (homopolymer) consisting of a structural unit represented by formula (f1-1) shown below; a copolymer of a structural unit represented by formula (f1-1) shown below and the aforementioned structural unit (a1); or a copolymer of a structural unit represented by formula (f1-1) shown below, a structural unit derived from acrylic acid or methacrylic acid and the aforementioned structural unit (a1). As the structural unit (a1) to be copolymerized with a structural unit represented by formula (f1-1) shown below, a structural unit represented by the aforementioned formula (all-1) is preferable, and a structural unit represented by the aforementioned formula (a1-1-32) is particularly preferable.

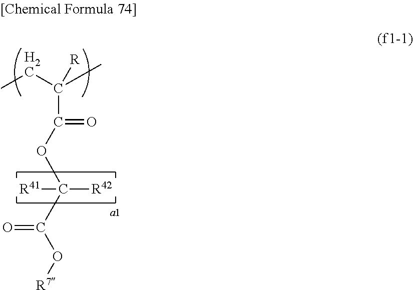

In the formula, R is the same as defined above; each of R⁴¹ and R⁴² independently represents a hydrogen atom, a halogen atom, an alkyl group of 1 to 5 carbon atoms or a halogenated alkyl group of 1 to 5 carbon atoms, provided that the plurality of R⁴¹ to R⁴² may be the same or different from each other; a1 represents an integer of 1 to 5; and R⁷″ represents an organic group containing a fluorine atom.

In formula (f1-1), R is the same as defined above. As R, a hydrogen atom or a methyl group is preferable.

In formula (f1-1), examples of the halogen atom for R⁴¹ and R⁴² include a fluorine atom, a chlorine atom, a bromine atom and an iodine atom, and a fluorine atom is particularly preferred. Examples of the alkyl group of 1 to 5 carbon atoms for R⁴¹ and R⁴² include the same alkyl group of 1 to 5 carbon atoms for R defined above, and a methyl group or an ethyl group is preferable. Specific examples of the halogenated alkyl group of 1 to 5 carbon atoms for R⁴¹ or R⁴² include groups in which part or all of the hydrogen atoms of the aforementioned alkyl groups of 1 to 5 carbon atoms have been substituted with halogen atoms. Examples of the halogen atom include a fluorine atom, a chlorine atom, a bromine atom and an iodine atom, and a fluorine atom is particularly preferred. Among these, R⁴¹ and R⁴² are preferably a hydrogen atom, a fluorine atom or an alkyl group of 1 to 5 carbon atoms, and more preferably a hydrogen atom, a fluorine atom, a methyl group or an ethyl group.

In formula (f1-1), a1 represents an integer of 1 to 5, preferably an integer of 1 to 3, and more preferably 1 or 2.

In formula (f1-1), R⁷ represents an organic group containing a fluorine atom, and is preferably a hydrocarbon group containing a fluorine atom.

The hydrocarbon group containing a fluorine atom may be linear, branched or cyclic, and is preferably linear or branched, and preferably has 1 to 20 carbon atoms, more preferably 1 to 15 carbon atoms, and most preferably 1 to 10 carbon atoms.

The hydrocarbon group having a fluorine atom preferably has 25% or more of the hydrogen atoms within the hydrocarbon group fluorinated, more preferably 50% or more, and most preferably 60% or more, as the hydrophobicity of the resist film during immersion exposure is enhanced.

Among these, as R⁷″, a fluorinated hydrocarbon group of 1 to 5 carbon atoms is preferable, and most preferably a methy group, —CH₂—CF₃, —CH₂—CF₂—CF₃, —CH(CF₃)₂, —CH₂—CH₂—CF₃ and —CH₂—CH₂—CF₂—CF₂—CF₂—CF₃.

The weight average molecular weight (Mw) (the polystyrene equivalent value determined by gel permeation chromatography) of the component (F) is preferably 1,000 to 50,000, more preferably 5,000 to 40,000, and most preferably 10,000 to 30,000. When the weight average molecular weight of the polymer is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, the dispersity (Mw/Mn) of the component (F) is preferably 1.0 to 5.0, more preferably 1.0 to 3.0, and most preferably 1.2 to 2.5.

The component (F) can be produced by a conventional radical polymerization or the like of the monomers corresponding with each of the structural units, using a radical polymerization initiator such as dimethyl 2,2′-azobis(isobutyrate) (V-601) or azobisisobutyronitrile (AIBN). By using a chain transfer agent such as HS—CH₂—CH₂—CH₂—C(CF₃)₂—OH, a —C(CF₃)₂—OH group can be introduced at the terminals. Such a copolymer having introduced a hydroxyalkyl group in which some of the hydrogen atoms of the alkyl group are substituted with fluorine atoms is effective in reducing defects and LER (line edge roughness: unevenness of the side walls of a line pattern).

As the monomers which yield the corresponding structural units, commercially available monomers may be used, or the monomers may be synthesized by a conventional method.

As the component (F), one type may be used alone, or two or more types may be used in combination.

The component (F) is typically used in an amount within a range from 0.5 to 10 parts by weight, relative to 100 parts by weight of the component (A).

If desired, other miscible additives can also be added to the resist composition of the present invention. Examples of such miscible additives include additive resins for improving the performance of the resist film, surfactants for improving the applicability, dissolution inhibitors, plasticizers, stabilizers, colorants, halation prevention agents, and dyes.

### [Component (S)]

The resist composition for immersion exposure according to the present invention can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethylbenzylether, cresylmethylether, diphenylether, dibenzylether, phenetole, butylphenylether, ethylbenzene, diethylbenzene, pentylbenzene, isopropylbenzene, toluene, xylene, cymene and mesitylene; and dimethylsulfoxide (DMSO).

These solvents can be used individually, or in combination as a mixed solvent.

Among these, propylene glycol monomethyl ether acetate (PGMEA), propylene glycol monomethyl ether (PGME), cyclohexanone and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2.

Specifically, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME is preferably from 1:9 to 9:1, more preferably from 2:8 to 8:2, and still more preferably 3:7 to 7:3.

Further, as the component (S), a mixed solvent of at least one of PGMEA and EL with γ-butyrolactone is also preferable. The mixing ratio (former:latter) of such a mixed solvent is preferably from 70:30 to 95:5.

Furthermore, as the component (S), a mixed solvent of PGMEA and cyclohexanone or a mixed solvent of PGMEA, PGME and cyclohexanone is also preferable. The former mixing ratio of such a mixed solvent is preferably PGMEA:cyclohexanone=95-5:10-90, whereas the latter mixing ratio of such a mixed solvent is preferably PGMEA:PGME:cyclohexanone=35-55:20-40:15-35.

The amount of the component (S) is not particularly limited, and is appropriately adjusted to a concentration which enables coating of a coating solution to a substrate In general, the organic solvent is used in an amount such that the solid content of the resist composition becomes within the range from 1 to 20% by weight, and preferably from 2 to 15% by weight.

The resist composition according to the present invention exhibits excellent various lithography properties such as sensitivity, exposure latitude, mask reproducibility, roughness and pattern shape. The reason why these effects can be achieved has not been elucidated yet, but is presumed as follows.

The component (A1) (polymer according to the present invention included in the resist composition according to the present invention contains an anion part which generates acid upon exposure on at least one terminal of the main chain. Therefore, it is presumed that acid is generated from the terminal of the polymer in the exposed portions, thereby improving the sensitivity.

In addition, by virtue of the polymer having a group capable of acid generation, the excessive diffusion of generated acid can be suppressed, compared to the case using only an acid generator component composed of a low molecular weight compound such as those aforementioned component (B).

Furthermore, the anion part which generates acid upon exposure on the terminal of the main chain is uniformly distributed within the resist film, and acid is uniformly generated from the anion part at exposed portions, so that the acid decomposable groups within the component (A1) are uniformly dissociated at exposed portions.

In addition, the component (A1) has an anion part which generates an acid upon exposure and an acid decomposable group in the same molecule, so an acid which generates from the anion part and the acid decomposable group are present in relatively close. Therefore, a decomposition reaction of the acid decomposable group by the action of acid is likely to occur.

Furthermore, the polymer contains two types of structural units having acid decomposable groups with an activation energy difference of at least 3.0 kJ/mol. Therefore, it is possible to design a resist composition having not only excellent resolution but also excellent properties and low dependency on pattern size.

It is presumed that lithography properties are particularly improved by the synergistic effect of these.

### <<Method of Forming a Resist Pattern>>

The method of forming a resist pattern according to the present invention includes: forming a resist film on a substrate using a resist composition of the present invention; conducting exposure of the resist film; and developing the resist film to form a resist pattern.

The method for forming a resist pattern according to the present invention can be performed, for example, as follows. Firstly, a resist composition of the present invention is applied to a substrate using a spinner or the like, and a bake treatment (post applied bake (PAB)) is conducted at a temperature of 80 to 150° C. for 40 to 120 seconds, preferably 60 to 90 seconds, to form a resist film.

Following selective exposure of the thus formed resist film, either by exposure through a mask having a predetermined pattern formed thereon (mask pattern) using an exposure apparatus such as an ArF exposure apparatus, an electron beam lithography apparatus or an EUV exposure apparatus, or by patterning via direct irradiation with an electron beam without using a mask pattern, baking treatment (post exposure baking (PEB)) is conducted under temperature conditions of 80 to 150° C. for 40 to 120 seconds, and preferably 60 to 90 seconds.

Next, the resist film is subjected to a developing treatment.

The developing treatment is conducted using an alkali developing solution in the case of an alkali developing process, whereas the developing treatment is conducted using a developing solution containing an organic solvent (organic developing solution) in the case of a solvent developing process.

After the developing treatment, it is preferable to conduct a rinse treatment. The rinse treatment is preferably conducted using pure water in the case of an alkali developing process, whereas the rinse treatment is preferably conducted using a rinse solution containing an organic solvent in the case of a solvent developing process.

In the case of a solvent developing process, after the developing treatment or the rinsing, the developing solution or the rinse liquid remaining on the pattern can be removed by a treatment using a supercritical fluid.

After the developing treatment or the rinse treatment, drying is conducted. If desired, bake treatment (post bake) can be conducted following the developing. In this manner, a resist pattern can be obtained.

The substrate is not specifically limited and a conventionally known substrate can be used. For example, substrates for electronic components, and such substrates having wiring patterns formed thereon can be used. Specific examples of the material of the substrate include metals such as silicon wafer, copper, chromium, iron and aluminum; and glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) and an organic film such as a lower-layer organic film used in a multilayer resist method can be used.

Here, a “multilayer resist method” is method in which at least one layer of an organic film (lower-layer organic film) and at least one layer of a resist film (upper resist film) are provided on a substrate, and a resist pattern formed on the upper resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is broadly classified into a method in which a double-layer structure consisting of an upper-layer resist film and a lower-layer organic film is formed (double-layer resist method), and a method in which a multilayer structure having at least three layers consisting of an upper-layer resist film, a lower-layer organic film and at least one intermediate layer (thin metal film or the like) provided between the upper-layer resist film and the lower-layer organic film (triple-layer resist method).

The wavelength to be used for exposure is not particularly limited and the exposure can be conducted using radiation such as ArF excimer laser, KrF excimer laser, F₂ excimer laser, extreme ultraviolet rays (EUV), vacuum ultraviolet rays (VUV), electron beam (EB), X-rays, and soft X-rays. The resist composition of the present invention is effective to KrF excimer laser, ArF excimer laser, EB and EUV

The exposure of the resist film can be either a general exposure (dry exposure) conducted in air or an inert gas such as nitrogen, or immersion exposure (liquid immersion lithography).

In immersion lithography, the region between the resist film and the lens at the lowermost point of the exposure apparatus is pre-filled with a solvent (immersion medium) that has a larger refractive index than the refractive index of air, and the exposure (immersion exposure) is conducted in this state.

The immersion medium preferably exhibits a refractive index larger than the refractive index of air but smaller than the refractive index of the resist film to be exposed. The refractive index of the immersion medium is not particularly limited as long at it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ and C₅H₃F₇ as the main component, which have a boiling point within a range from 70 to 180° C. and preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly preferred. Examples of these perfluoroalkyl compounds include perfluoroalkylether compounds and perfluoroalkylamine compounds.

compounds and perfluoroalkylamine compounds. Specifically, one example of a suitable perfluoroalkylether compound is perfluoro(2-butyl-tetrahydrofuran) (boiling point 102° C.), and an example of a suitable perfluoroalkylamine compound is perfluorotributylamine (boiling point 174° C.).

As the immersion medium, water is preferable in terms of cost, safety, environment and versatility.

As an example of the alkali developing solution used in an alkali developing process, a 0.1 to 10% by weight aqueous solution of tetramethylammonium hydroxide (TMAH) can be given.

As the organic solvent contained in the organic developing solution used in a solvent developing process, any of the conventional organic solvents can be used which are capable of dissolving the component (A) (prior to exposure). Specific examples of the organic solvent include polar solvents such as ketone solvents, ester solvents, alcohol solvents, amide solvents and ether solvents, and hydrocarbon solvents.

If desired, the organic developing solution may have a conventional additive blended. Examples of the additive include surfactants. The surfactant is not particularly limited, and for example, an ionic or non-ionic fluorine surfactant and/or silicon surfactant can be used.

When a surfactant is added, the amount thereof based on the total amount of the organic developing solution is generally 0.001 to 5% by weight, preferably 0.005 to 2% by weight, and more preferably 0.01 to 0.5% by weight.

The developing treatment can be performed by a conventional developing method. Examples thereof include a method in which the substrate is immersed in the developing solution for a predetermined time (a dip method), a method in which the developing solution is cast up on the surface of the substrate by surface tension and maintained for a predetermined period (a puddle method), a method in which the developing solution is sprayed onto the surface of the substrate (spray method), and a method in which the developing solution is continuously ejected from a developing solution ejecting nozzle while scanning at a constant rate to apply the developing solution to the substrate while rotating the substrate at a constant rate (dynamic dispense method).

As the organic solvent contained in the rinse liquid used in the rinse treatment after the developing treatment in the case of a solvent developing process, any of the aforementioned organic solvents contained in the organic developing solution can be used which hardly dissolves the resist pattern. In general, at least one solvent selected from the group consisting of hydrocarbon solvents, ketone solvents, ester solvents, alcohol solvents, amide solvents and ether solvents is used. Among these, at least one solvent selected from the group consisting of hydrocarbon solvents, ketone solvents, ester solvents, alcohol solvents and amide solvents is preferable, more preferably at least one solvent selected from the group consisting of alcohol solvents and ester solvents, and an alcohol solvent is particularly preferred.

The rinse treatment (washing treatment) using the rinse liquid can be performed by a conventional rinse method. Examples thereof include a method in which the rinse liquid is continuously applied to the substrate while rotating it at a constant rate (rotational coating method), a method in which the substrate is immersed in the rinse liquid for a predetermined time (dip method), and a method in which the rinse liquid is sprayed onto the surface of the substrate (spray method).

### EXAMPLES

As follows is a description of examples of the present invention, although the scope of the present invention is by no way limited by these examples.

In the NMR analysis, the internal standard for ¹H-NMR and ¹³C-NMR was tetramethylsilane. The internal standard for ¹⁹F-NMR was hexafluorobenzene (provided that the peak of hexafluorobenzene was regarded as −160 ppm).

### Synthesis Example 1

### Synthesis of Anion-A

Under a nitrogen atmosphere, 28.0 g of ACVA and 36.8 g of Anion-a were added to 280 g of dichloromethane, and the mixture was stirred at room temperature. 27.8 g of diisopropylcarbodiimide was added thereto, followed by stirring for 10 minutes. Then, 2.44 g of dimethylaminopyridine was added thereto as a catalyst, and a reaction was effected for 24 hours at 30° C. 1400 g of t-butylmethylether was added to the suspended reaction solution, followed by stirring for 30 minutes, and then the precipitated objective compound was separated by filtration, followed by drying, thereby obtaining 20.8 g of Anion-A.

The obtained compound was analyzed by NMR, and the structure thereof was identified by the following results.

¹H-NMR (400 MHz, DMSO-d6): δ (ppm)=4.61 (dt, 4H, CH₂CF₂), 2.40-2.65 (m, 8H, CH₂CH₂), 1.72 (s, 6H, CH₃), 1.66 (s, 6H, CH₃). ¹⁹F-NMR (376 MHz, DMSO-d6): δ (ppm)=−111.4.

From the results shown above, it was confirmed that Anion-A had a structure shown below.

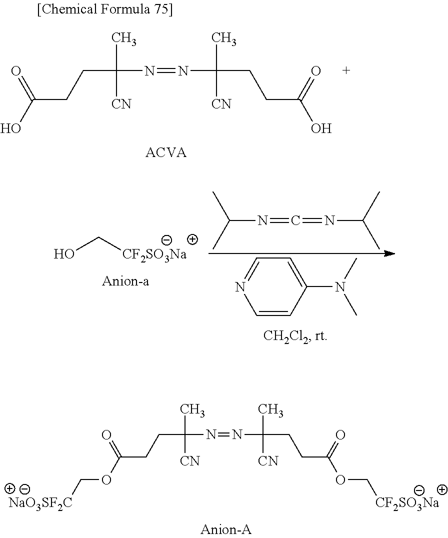

### Synthesis Example 2

### Synthesis of Compound (1-a)

10.50 g of TPS—Br, 8.70 g of Anion-A, 155.0 g of dichloromethane and 78.0 g of pure water were added to a beaker, and the mixture was stirred at room temperature for 1 hour. Then, the dichloromethane phase was separated, and repeatedly washed with 78.0 g of pure water. Thereafter, the organic layer was concentrated under reduced pressure, thereby obtaining 13.80 g of a compound (1-A) in the form of a white solid.

The obtained compound was analyzed by NMR, and the structure thereof was identified by the following results.

¹H-NMR (400 MHz, DMSO-d6): δ (ppm)=7.78-7.90 (m, 30H, ArH), 4.61 (dt, 4H, CH₂CF₂), 2.40-2.65 (m, 8H, CH₂CH₂), 1.72 (s, 6H, CH₃), 1.66 (s, 6H, CH₃). ¹⁹F-NMR (376 MHz, DMSO-d6): δ (ppm)=−111.4.

From the results shown above, it was confirmed that compound (1-A) had a structure shown below.

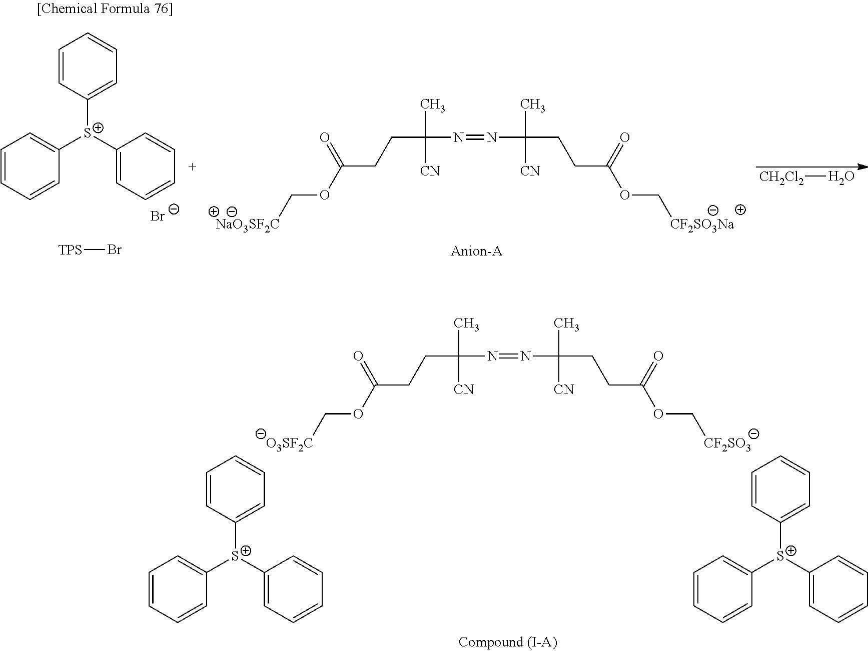

### Synthesis Examples 3 to 55

### Synthesis of Compounds (1-B) to (1-BB)

The same procedure as in Synthesis Example 2 was performed, except that the cation moiety in TPS—Br was changed to a cation moiety (equimolar amount) shown in Tables 1 to 18, respectively. In this manner, compounds (1-B) to (1-BB) shown in Tables 1 to 18 were obtained.

Each of the obtained compounds was analyzed by NMR. The results are shown in Tables 1 to 18.

TABLE 1

| Compound | NMR | Cation | Product |
|---|---|---|---|
| I-B | 1H-NMR (400 MHz, DMSO-d6): δ (ppm) = 8.50 (d, 4H, ArH), 8.37 (d, 4H, ArH), 7.93 (t, 4H, ArH), 7.55-7.75 (m, 14H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −111.4. | 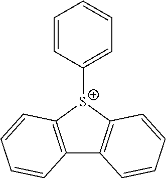 [SMILES: c1ccc(-[s+]2c3ccccc3c3ccccc32)cc1] | 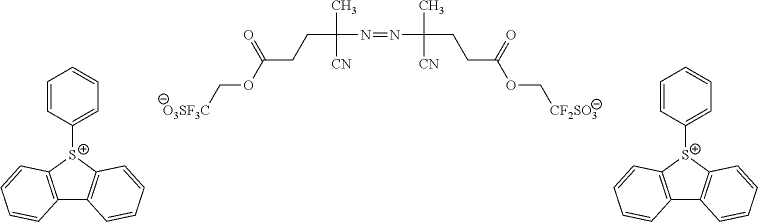 |
| I-C | 1H-NMR (400 MHz, DMSO-d6): δ (ppm) = 7.72-7.84 (m, 24H, ArH), 7.56 (d, 4H, ArH), 4.61 (dt, 4H, CH2CF2), 3.35 (s, 6H, ArCH3), 2.40- 2.65 (m, 8H, CH2CH2), 1.72 (s, 6H, CH3), 1.66 (s, 6H, CH3). 19F-NMR (376 MHz, DMSO-d6): δ (ppm) = −111.4. | 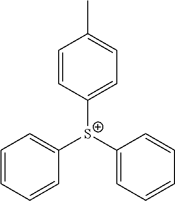 [SMILES: Cc1ccc([S+](c2ccccc2)c2ccccc2)cc1] | 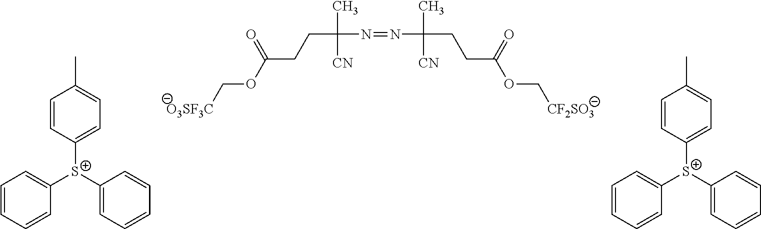 |
| I-D | 1H-NMR (400 MHz, DMSO-d6): δ (ppm) = 7.75-7.86 (m, 20H, ArH), 7.61 (s, 4H, ArH), 4.65 (s, 4H, CH2O), 4.61 (dt, 4H, CH2CF2), 2.40-2.65 (m, 8H, CH2CH2), 2.31 (s, 12H, ArCH3), 1.49-1.97 (m, 36H, Adamantane + CH3). 19F-NMR (376 MHz, DMSO-d6): δ (ppm) = −111.4. | 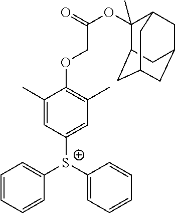 [SMILES: Cc1cc([S+](c2ccccc2)c2ccccc2)cc(C)c1OCC(=O)OC1(C)C2CC3CC(C2)CC1C3] | 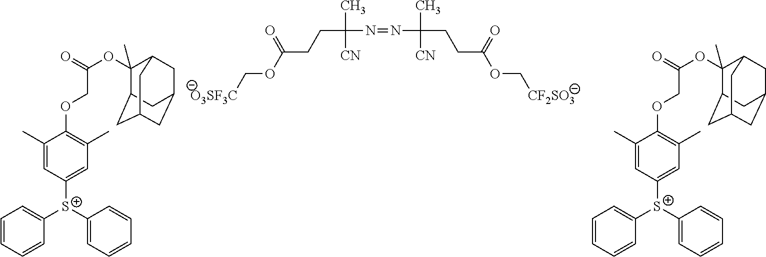 |

TABLE 2

| Compound | NMR | Cation | Product |
|---|---|---|---|
| I-E | 1H-NMR (400 MHz, DMSO-d6): δ (ppm) = 7.76-7.82 (m, 20H, ArH), 7.59 (s, 4H, ArH), 4.61 (dt, 4H, CH2CF2), 4.55 (s, 4H, OCH2), 2.40-2.65 (m, 8H, CH2CH2), 2.29 (m, 12H, ArCH3), 1.90-1.93 (m, 8H, CH2CH3, cyclopentyl), 1.48-1.75 (m, 24H, CH3 + cyclopentyl), 0.77-0.81 (t, 6H, CH2CH3). 19F-NMR (376 MHz, DMSO-d6): δ (ppm) = −111.4. | 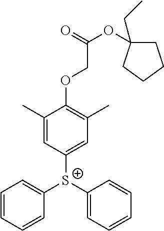 [SMILES: CCC1(OC(=O)COc2c(C)cc([S+](c3ccccc3)c3ccccc3)cc2C)CCCC1] | 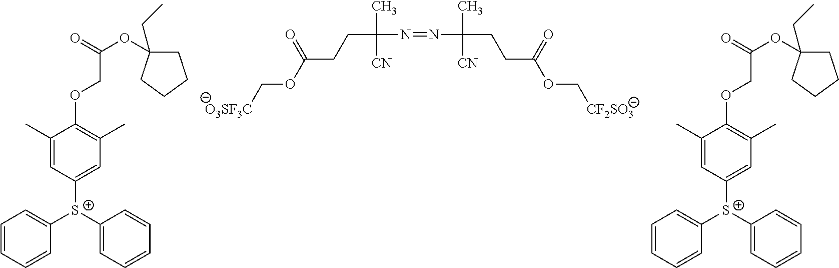 |
| I-F | 1H-NMR (400 MHz, DMSO-d6): δ (ppm) = 7.76-7.82 (m, 20H, ArH), 7.59 (s, 4H, ArH), 4.61 (dt, 4H, CH2CF2), 4.55 (s, 4H, OCH2), 2.40-2.65 (m, 8H, CH2CH2), 2.29 (m, 12H, ArCH3), 1.90-2.08 (m, 4H, cyclopentyl), 1.48-1.75 (m, 30H, Cp-CH3 + cyclopentyl + CH3). 19F-NMR (376 MHz, DMSO-d6): δ (ppm) = −111.4. | 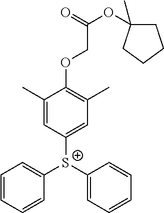 [SMILES: Cc1cc([S+](c2ccccc2)c2ccccc2)cc(C)c1OCC(=O)OC1(C)CCCC1] | 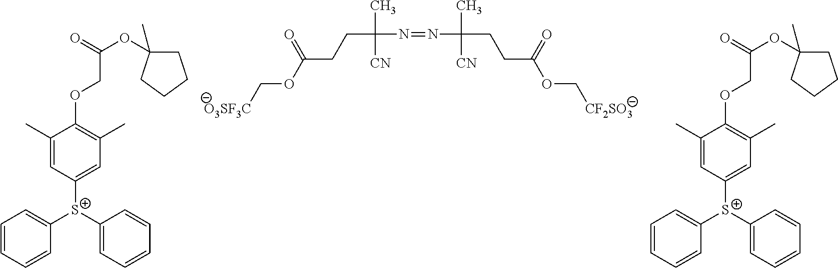 |
| I-G | 1H-NMR (400 MHz, DMSO-d6): δ (ppm) = 10.05 (s, 2H, OH), 7.64.- 7.87 (m, 20H, ArH), 7.56 (s, 4H, ArH), 4.61 (dt, 4H, CH2CF2), 2.40- 2.65 (m, 8H, CH2CH2), 2.22 (m, 12H, ArCH3), 1.72 (s, 6H, CH3), 1.66 (s, 6H, CH3). 19F-NMR (376 MHz, DMSO-d6): δ (ppm) = −111.4. | 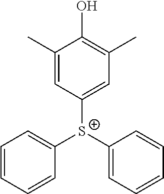 [SMILES: Cc1cc([S+](c2ccccc2)c2ccccc2)cc(C)c1O] | 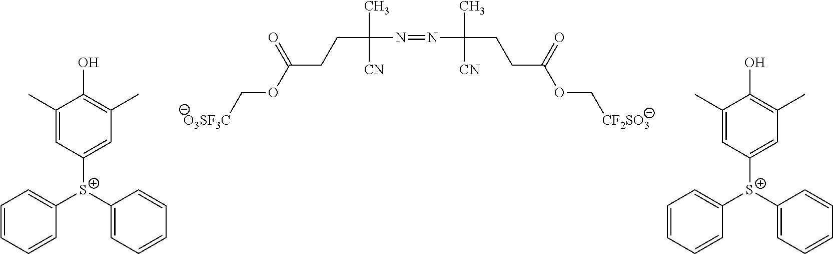 |

TABLE 3

| Compound | NMR | Cation | Product |
|---|---|---|---|
| I-H | 1H-NMR (400 MHz, DMSO-d6): δ (ppm) = 7.71-7.89 (m, 20H, ArH), 7.59 (s, 4H, ArH), 4.61 (dt, 4H, CH2CF2), 4.53 (s, 4H, OCH2), 2.40-2.65 (m, 8H, CH2CH2), 2.30 (s, 12H, ArCH3), 1.72 (s, 6H, CH3), 1.66 (s, 6H, CH3). 19F-NMR (376 MHz, DMSO-d6): δ (ppm) = −111.4. | 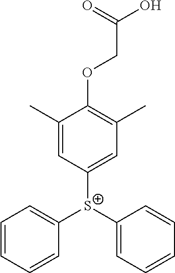 [SMILES: Cc1cc([S+](c2ccccc2)c2ccccc2)cc(C)c1OCC(=O)O] | 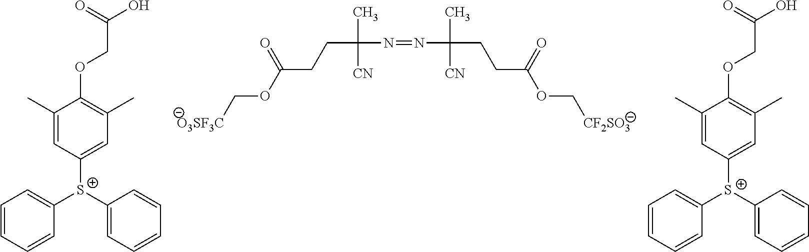 |
| I-I | 1H-NMR (400 MHz, DMSO-d6): δ (ppm) = 7.75-7.86 (m, 20H, ArH), 7.63 (s, 4H, ArH), 4.61 (dt, 4H, CH2CF2), 4.55 (s, 4H, OCH2), 2.40-2.65 (m, 8H, CH2CH2), 2.30 (s, 12H, ArCH3), 1.72 (s, 6H, CH3), 1.66 (s, 6H, CH3), 1.43 (s, 18H, t-Butyl). 19F-NMR (376 MHz, DMSO-d6): δ (ppm) = −111.4. | 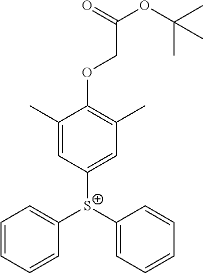 [SMILES: Cc1cc([S+](c2ccccc2)c2ccccc2)cc(C)c1OCC(=O)OC(C)(C)C] | 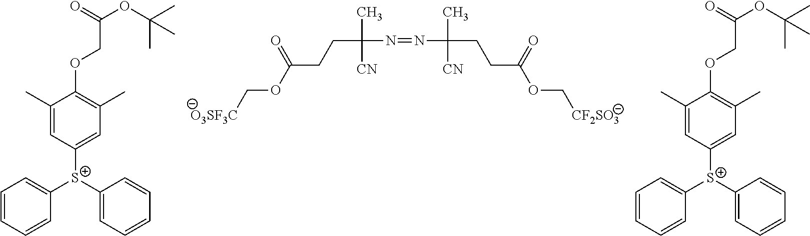 |
| I-J | 1H-NMR (400 MHz, DMSO-d6): δ (ppm) = 7.75-7.87 (m, 20H, ArH), 7.63 (s, 4H, ArH), 4.94 (t, 4H, OCH2CF2), 4.84 (s, 4H, OCH2), 4.61 (dt, 4H, CH2CF2), 2.40-2.65 (m, 8H, CH2CH2), 2.37 (s, 12H, ArCH3), 1.72 (s, 6H, CH3), 1.66 (s, 6H, CH3). 19F-NMR (376 MHz, DMSO-d6): δ (ppm) = −80.4, −111.4, −119.7. | 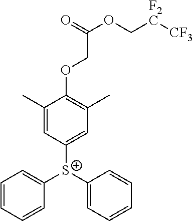 [SMILES: Cc1cc([S+](c2ccccc2)c2ccccc2)cc(C)c1OCC(=O)OCC(F)(F)C(F)(F)F] | 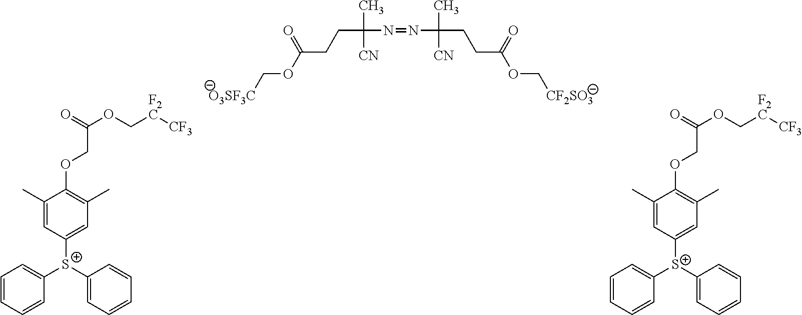 |

TABLE 4

| Compound | NMR | Cation | Product |
|---|---|---|---|
| I-K | 1H-NMR (400 MHz, DMSO-d6): δ (ppm) = 7.72-7.83 (m, 20H, ArH), 7.59 (s, 4H, ArH), 4.90 (m, 2H, sultone), 4.63-4.68 (m, 6H, CH2O + sultone), 4.61 (dt, 4H, CH2CF2), 3.83-3.89 (m, 2H, sultone), 3.43 (m, 2H, sultone), 1.75-2.55 (m, 30H, CH2CH2 + sultone + ArCH3), 1.72 (s, 6H, CH3), 1.66 (s, 6H, CH3). 19F-NMR (376 MHz, DMSO-d6): δ (ppm)= −111.4. | 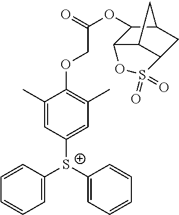 [SMILES: Cc1cc([S+](c2ccccc2)c2ccccc2)cc(C)c1OCC(=O)OC1C2CC3C1OS(=O)(=O)C3C2] | 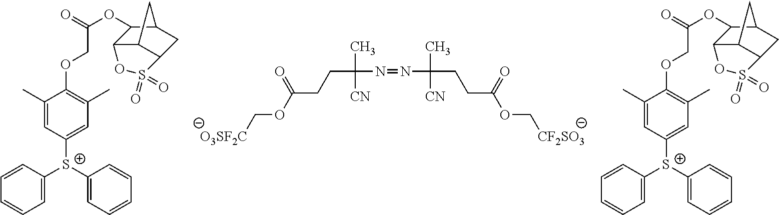 |
| I-L | 1H-NMR (400 MHz, DMSO-d6): δ (ppm) = 7.74-7.84 (m, 20H, ArH), 7.61 (s, 4H, ArH), 5.42 (t, 2H, oxo- norbornane), 4.97 (s, 2H, oxo-norbornane), 4.67-4.71 (m, 8H, OCH2 + oxo- norbornane), 4.61 (dt, 4H, CH2CF2), 2.69-2.73 (m, 2H, oxo- norbornane), 2.40-2.65 (m, 8H, CH2CH2), 2.32 (s, 12H, ArCH3), 2.06-2.16 (m, 4H, oxo-norbornane), 1.72 (s, 6H, CH3), 1.66 (s, 6H, CH3). 19F-NMR (376 MHz, DMSO-d6): δ (ppm) = −111.4. | 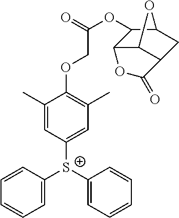 [SMILES: Cc1cc([S+](c2ccccc2)c2ccccc2)cc(C)c1OCC(=O)OC1C2CC3C(=O)OC1C3O2] | 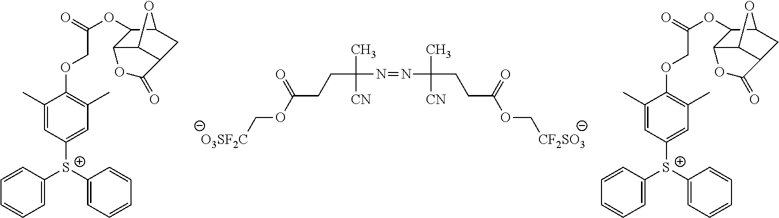 |
| I-M | 1H-NMR (400 MHz, DMSO-d6): δ (ppm) = 7.73-7.85 (m, 20H, ArH), 7.59 (S, 4H, ArH), 4.61 (dt, 4H, CH2CF2), 3.83 (t, 4H, OCH2), 2.40-2.65 (m, 8H, CH2CH2), 2.33 (s, 12H, ArCH3, 1.72 (s, 6H, CH3), 1.66 (s, 6H, CH3), 1.45 (m, 8H, CH2 in n- hexyl), 1.29 (m, 8H, CH2 in n-hexyl), 0.87 t, 6H, CH3 in n-hexyl). 19F-NMR (376 MHz, DMSO-d6): δ (ppm) = −111.4. | 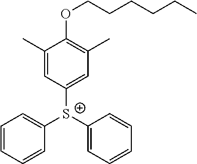 [SMILES: CCCCCCOc1c(C)cc([S+](c2ccccc2)c2ccccc2)cc1C] | 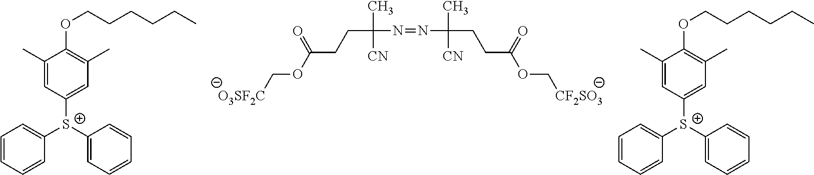 |

TABLE 5

| Compound | NMR | Cation | Product |
|---|---|---|---|
| I-N | 1H-NMR (400 MHz, DMSO-d6): δ (ppm) = 8.53 (d, 4H, ArH), 8.27 (d, 4H, ArH), 7.95 (t, 4H, ArH), 7.74 (t, 4H, ArH), 7.20 (s, 2H, ArH), 6.38 (s, 2H, ArH), 4.61 (dt, 4H, CH2CF2), 4.05 (t, 4H, OCH2), 2.40-2.65 (m, 8H, CH2CH2), 1.84 (s, 12H, ArCH3), 1.72 (s, 6H, CH3), 1.69 (quin, 4H, CH2 in n-hexyl), 1.66 (s, 6H, CH3), 1.37 (quin, 4H, CH2 in n- hexyl), 1.24-1.26 (m, 8H, CH2 in n- hexyl), 0.82 (t, 6H, CH3 in n-hexyl). 19F-NMR (376 MHz, DMSO-d6): δ (ppm) = −111.4. | 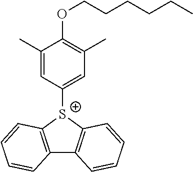 [SMILES: CCCCCCOc1c(C)cc(-[s+]2c3ccccc3c3ccccc32)cc1C] | 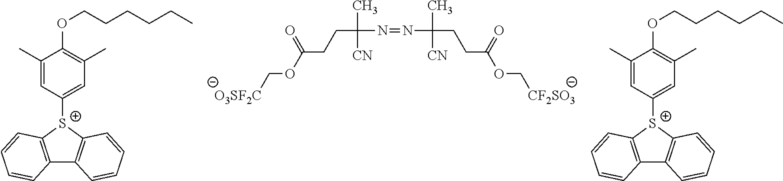 |
| I-O | 1H-NMR (400 MHz, DMSO-d6): δ (ppm) = 7.99-8.01 (d, 4H, ArH), 7.73- 7.76 (t, 2H, ArH), 7.58- 7.61 (t, 4H, ArH), 5.31 (s, 4H, SCH2C═O), 4.61 (dt, 4H, CH2CF2), 3.49-3.62 (m, 8H, CH2 in tetramethylenesulfide), 2.18-2.65 (m, 16H, CH2S + CH2CH2), 1.72 (s, 6H, CH3), 1.66 (s, 6H, CH3). 19F-NMR (376 MHz, DMSO-d6): δ (ppm) = −111.4. | 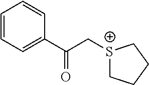 [SMILES: O=C(C[S+]1CCCC1)c1ccccc1] | 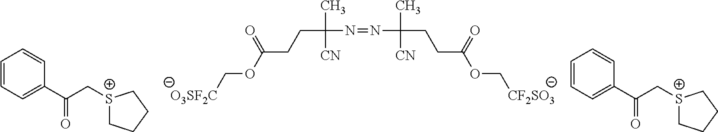 |
| I-P | 1H-NMR (400 MHz, DMSO-d6): δ (ppm) = 8.02-8.05 (m, 4H, ArH), 7.61-7.73 (m, 6H, ArH), 4.61 (dt, 4H, CH2CF2), 3.76-3.86 (m, 8H, SCH2), 2.40-2.65 (m, 8H, CH2CH2), 2.09-2.12 (m, 4H, CH2 in pentamethylenesulfide), 1.84-1.93 (m, 4H, CH2 in pentamethylenesulfide), 1.61-1.72 (m, 16H, CH3 + CH2 in pentamethylenesulfide). 19F-NMR (376 MHz, DMSO-d6): δ (ppm) = −111.4. | 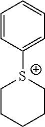 [SMILES: c1ccc([S+]2CCCCC2)cc1] | 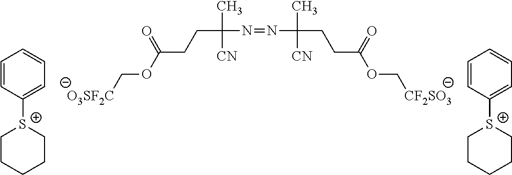 |

TABLE 6

| Compound | NMR | Cation | Product |
|---|---|---|---|
| I-Q | 1H-NMR (400 MHz, DMSO-d6): δ (ppm) = 8.04-8.09 (m, 4H, ArH), 7.69-7.79 (m, 6H, ArH), 4.61 (dt, 4H, CH2CF2), 3.29 (s, 12H, SCH3), 2.40- 2.65 (m, 8H, CH2CH2), 1.72 (s, 6H, CH3), 1.66 (s, 6H, CH3). 19F-NMR (376 MHz, DMSO-d6): δ (ppm) = −111.4. | 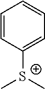 | 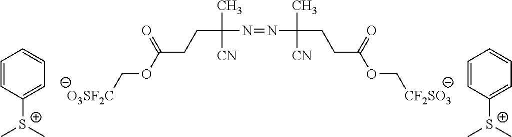 |
| I-R | 1H-NMR (400 MHz, DMSO-d6): δ (ppm) = 8.07 (d, 4H, ArH), 7.81 (d, 4H, ArH), 4.61 (dt, 4H, CH2CF2), 4.10 (t, 4H, CH2 in pentamethylenesulfide), 3.59 (d, 4H, CH2 in pentamethylenesulfide), 2.40-2.65 (m, 8H, CH2CH2), 2.20 (d, 4H, CH2 in pentamethylenesulfide), 1.71-2.19 (m, 14H, CH3 + CH2 in pentamethylenesulfide), 1.66 (s, 6H, CH3), 1.23 (s, 18H, t-Bu). 19F-NMR (376 MHz, DMSO-d6): δ (ppm) = −111.4. | 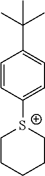 [SMILES: CC(C)(C)c1ccc([S+]2CCCCC2)cc1] | 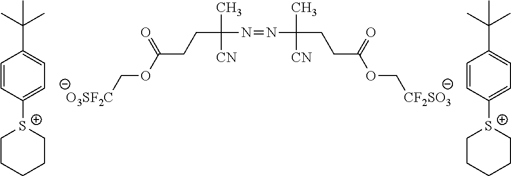 |
| I-S | 1H-NMR (400 MHz, DMSO-d6): δ (ppm) = 7.77-7.89 (m, 20H, ArH), 7.70 (s, 4H, ArH), 5.10 (s, 4H, CH2O), 4.61 (dt, 4H, CH2CF2), 2.40-2.65 (m, 8H, CH2CH2), 2.07-2.19 (m, 18H, CH3O + ArCH3), 1.72 (s, 6H, CH3), 1.66 (s, 6H, CH3). 19F-NMR (376 MHz, DMSO-d6): δ (ppm) = −111.4. | 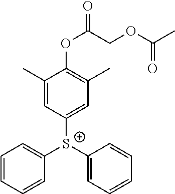 [SMILES: CC(=O)OCC(=O)Oc1c(C)cc([S+](c2ccccc2)c2ccccc2)cc1C] | 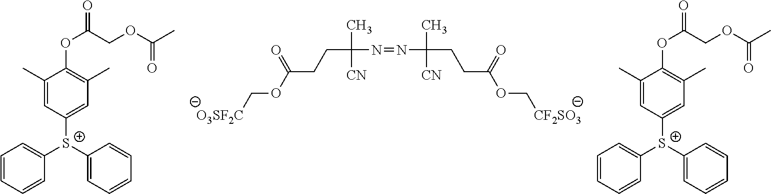 |

TABLE 7

| Com- | | | |
|---|---|---|---|
| pound | NMR | Cation | Product |
| I-T | 1H-NMR (400 MHz, DMSO-d6): δ (ppm) = 7.84 (d, 12H, ArH), 7.78 (d, 12H, ArH), 4.61 (dt, 4H, CH2CF2), 2.40-2.65 (m, 8H, CH2CH2), 1.72 (s, 6H, CH3), 1.66 (s, 6H, CH3), 1.33 (s, 54H, tBu) . 19F-NMR (376 MHz, DMSO-d6): δ (ppm) = −111.4. | 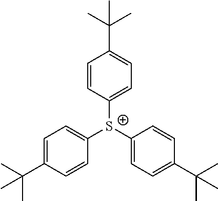 [SMILES: CC(C)(C)c1ccc([S+](c2ccc(C(C)(C)C)cc2)c2ccc(C(C)(C)C)cc2)cc1] | 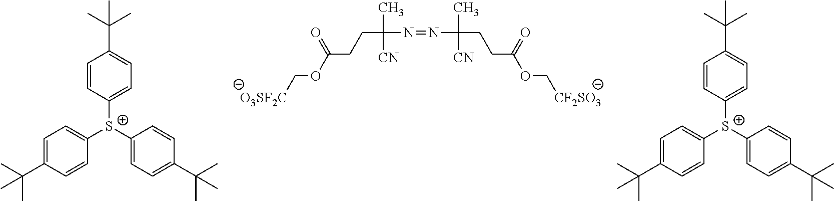 |
| I-U | 1H-NMR (400 MHz, DMSO-d6): δ (ppm) = 7.73- 7.89 (m, 24H, ArH), 4.61 (dt, 4H, CH2CF2), 2.40-2.65 (m, 8H, CH2CH2), 2.38 (s, 12H, ArCH3), 1.72 (s, 6H, CH3), 1.66 (s, 6H, CH3). 19F-NMR (376 MHz, DMSO-d6): δ (ppm) = −70.2, −111.4. | 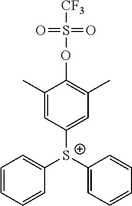 [SMILES: Cc1cc([S+](c2ccccc2)c2ccccc2)cc(C)c1OS(=O)(=O)C(F)(F)F] | 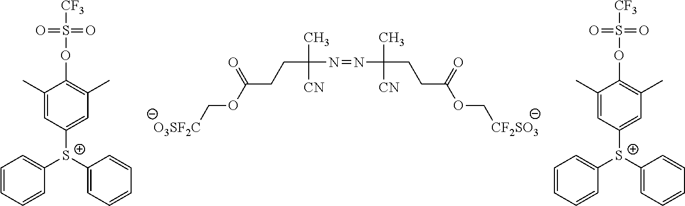 |
| I-V | 1H-NMR (400 MHz, DMSO-d6): δ (ppm) = 7.69- 7.85 (m, 20H, ArH), 7.56 (s, 4H, ArH), 4.75 (s, 8H, OCH2), 4.61 (dt, 4H, CH2CF2), 2.40-2.65 (m, 8H, CH2CH2), 2.31 (s, 12H, ArCH3), 2.19 (m, 4H, Adamantane), 1.47-1.98 (m, 42H, CH3 + Adamantane). 19F-NMR (376 MHz, DMSO-d6): δ (ppm) = 111.4. | 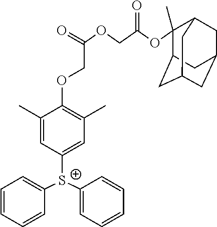 [SMILES: Cc1cc([S+](c2ccccc2)c2ccccc2)cc(C)c1OCC(=O)OCC(=O)OC1(C)C2CC3CC(C2)CC1C3] | 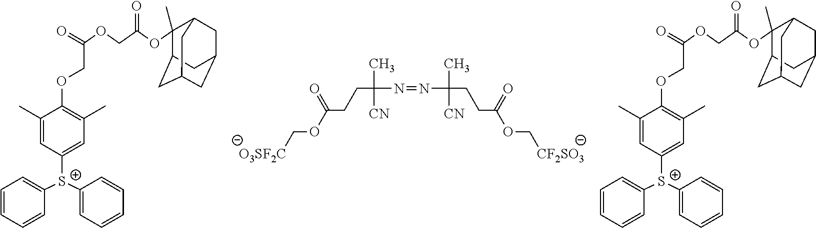 |

TABLE 8

| Compound | NMR | Cation | Product |
|---|---|---|---|
| I-W | 1H-NMR (400 MHz, DMSO-d6): δ (ppm) = 7.72-7.84 (m, 20H, ArH), 7.59 (s, 4H, ArH), 4.61 (dt, 4H, CH2CF2), 4.56 (s, 4H, OCH2), 2.40- 2.65 (m, 12H, CH2CH2 + Adamantane), 2.27-2.34 (m, 26H, ArCH3 + Adamantane), 1.94-1.97 (m, 4H, Adamantane), 1.74- 1.79 (m, 4H, Adamantane), 1.72 (s, 6H, CH3), 1.66 (s, 6H, CH3). 19F-NMR (376 MHz, DMSO-d6): δ (ppm) = −111.4. | 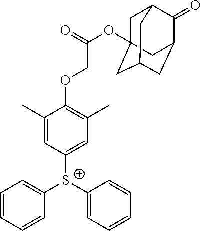 [SMILES: Cc1cc([S+](c2ccccc2)c2ccccc2)cc(C)c1OCC(=O)OC12CC3CC(C1)C(=O)C(C3)C2] | 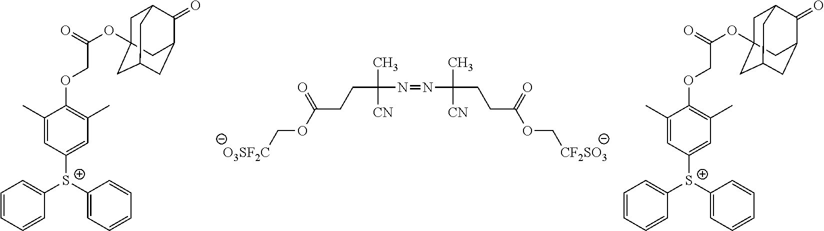 |
| I-X | 1H-NMR (400 MHz, DMSO-d6): δ (ppm) = 7.72-7.84 (m, 20H, ArH), 7.59 (s, 4H, ArH), 4.64 (s, 4H, OCH2), 4.61 (dt, 4H, CH2CF2), 3.70 (s, 6H, OCH3), 2.40-2.65 (m, 8H, CH2CH2), 2.29 (s, 12H, ArCH3), 1.72 (s, 6H, CH3), 1.66 (s, 6H, CH3). 19F-NMR (376 MHz, DMSO-d6): δ (ppm) = −111.4. | 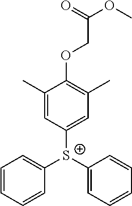 [SMILES: COC(=O)COc1c(C)cc([S+](c2ccccc2)c2ccccc2)cc1C] | 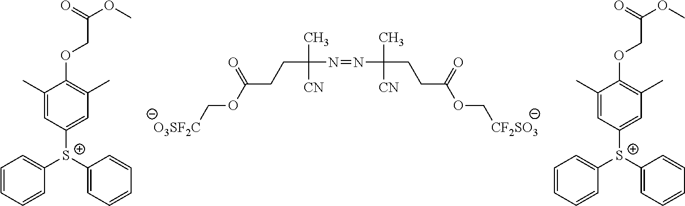 |
| I-Y | 1H-NMR (400 MHz, DMSO-d6): δ (ppm) = 7.78-7.89 (m, 20H, ArH), 7.64 (s, 4H, ArH), 4.61 (dt, 4H, CH2CF2), 3.79 (s, 6H, OCH3), 2.40- 2.65 (m, 8H, CH2CH2), 2.32 (s, 12H, ArCH3), 1.72 (s, 6H, CH3), 1.66 (s, 6H, CH3). 19F-NMR (376 MHz, DMSO-d6): δ (ppm) = −111.4. | 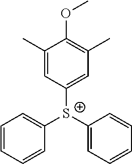 [SMILES: COc1c(C)cc([S+](c2ccccc2)c2ccccc2)cc1C] | 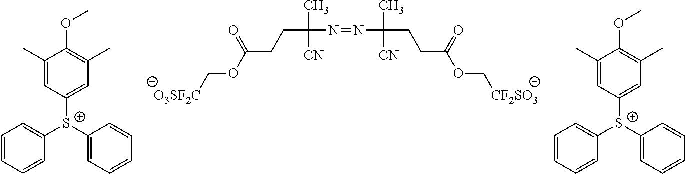 |

TABLE 9

| Com- | | | |
|---|---|---|---|
| pound | NMR | Cation | Product |
| I-Z | 1H-NMR (400 MHz, DMSO- d6): δ (ppm) = 7.76- 7.87 (m, 20H, ArH), 7.69 (s, 4H, ArH), 4.61 (dt, 4H, CH2CF2), 2.40- 2.65 (m, 8H, CH2CH2), 2.13 (s, 12H, ArCH3), 1.66-2.03 (m, 42H, CH3 + Adam- antane). 19F-NMR (376 MHz, DMSO- d6): δ (ppm) = −111.4. | 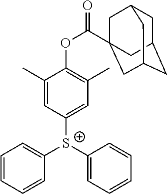 [SMILES: Cc1cc([S+](c2ccccc2)c2ccccc2)cc(C)c1OC(=O)C12CC3CC(CC(C3)C1)C2] | 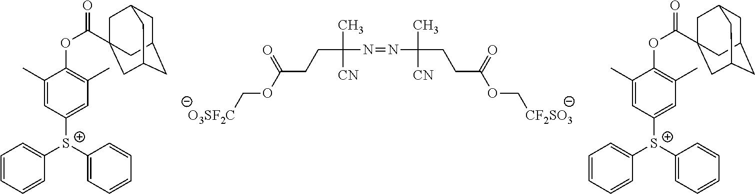 |
| I-AA | 1H-NMR (400 MHz, DMSO- d6): δ (ppm) = 7.79-7.93 (m, 24H, ArH), 4.61 (dt, 4H, CH2CF2), 2.73 (t, 4H, COCH2), 2.40-2.65 (m, 8H, CH2CH2), 2.19 (s, 12H, ArCH3) 1.65-1.72 (m, 16H, CH3 + CH2 in decanyl), 1.25-1.38 (m, 28H, CH2 in decanyl), 0.85 (t, 6H, CH3 in decanyl). 19F-NMR (376 MHz, DMSO- d6): δ (ppm) = −111.4. | 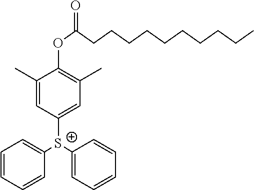 [SMILES: CCCCCCCCCCC(=O)Oc1c(C)cc([S+](c2ccccc2)c2ccccc2)cc1C] | 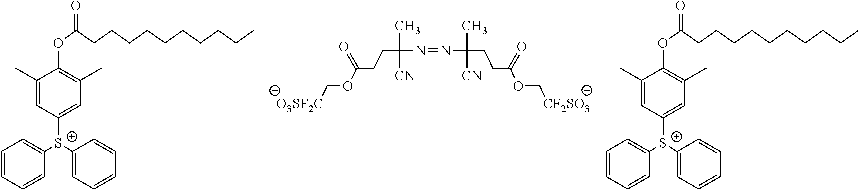 |
| I-AB | 1H-NMR (400 MHz, DMSO- d6): δ (ppm) = 8.76 (s, 2H, ArH), 8.59- 8.64 (m, 2H, ArH), 8.42 (t, 4H, ArH), 8.03-8.19 (m, 10H, ArH), 7.81 (t, 2H, ArH), 7.69 (t, 4H, ArH) 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO- d6): δ (ppm) = −62.1, −111.4. | 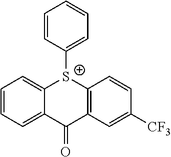 [SMILES: O=c1c2ccccc2[s+](-c2ccccc2)c2ccc(C(F)(F)F)cc12] | 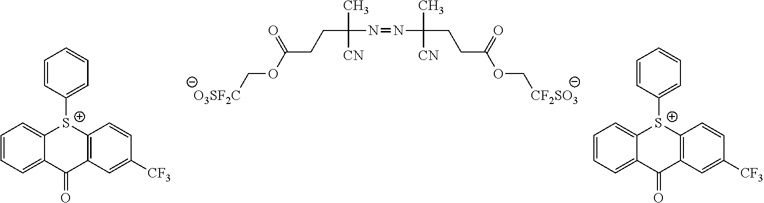 |

TABLE 10

| Compound | NMR | Cation | Product |
|---|---|---|---|
| I-AC | 1H-NMR (400 MHz, DMSO-d6): δ (ppm) = 4.61 (dt, 4H, CH2CF2), 3.36 (t, 12H, CH2 in n-butyl), 2.40-2.65 (m, 8H, CH2CH2), 1.72 (s, 6H, CH3), 1.68 (quintet, 12H, CH2 in n-butyl), 1.66 (s, 6H, CH3), 1.35-1.44 (m, 12H, CH2 in n- butyl), 0.81-0.93 (m, 18H, CH3 in n- butyl). 19F-NMR (376 MHz, DMSO-d6): δ (ppm) = −111.4. | 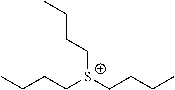 | 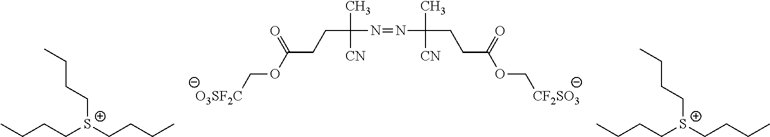 |
| I-AD | 1H-NMR (400 MHz, DMSO-d6): δ (ppm) = 8.29 (d, 8H, ArH), 7.93-8.09 (m, 12H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −47.9, −111.4. | 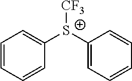 [SMILES: FC(F)(F)[S+](c1ccccc1)c1ccccc1] | 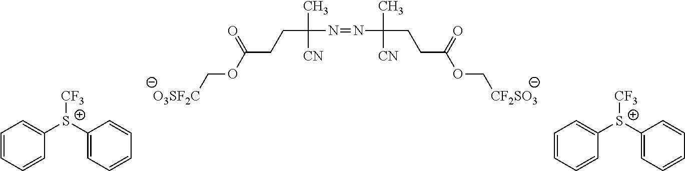 |
| I-AE | 1H-NMR (400 MHz, DMSO-d6): δ (ppm) = 7.90-8.24 (m, 14H, ArH), 4.61 (dt, 4H, CH2CF2), 3.85 (s, 6H, OCH3), 2.42 (s, 12H, ArCH3) 2.40-2.65 (m, 8H, CH2CH2), 1.72 (s, 6H, CH3), 1.66 (s, 6H, CH3). 19F-NMR (376 MHz, DMSO-d6): δ (ppm) = −48.8, −111.4. | 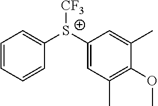 [SMILES: COc1c(C)cc([S+](c2ccccc2)C(F)(F)F)cc1C] | 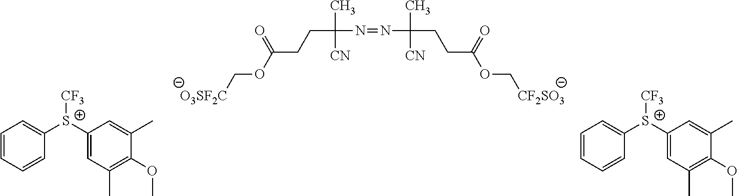 |

TABLE 11

| Compound | NMR | Cation | Product |
|---|---|---|---|
| I-AF | 1H-NMR (400 MHz, DMSO-d6): δ (ppm) = 10.12 (s, 2H, OH), 7.90-8.24 (m, 14H, ArH), 4.61 (dt, 4H, CH2CF2), 2.42 (s, 12H, ArCH3), 2.40-2.65 (m, 8H, CH2CH2), 1.72 (s, 6H, CH3), 1.66 (s, 6H, CH3). 19F-NMR (376 MHz, DMSO-d6): δ (ppm) = −48.2, −111.4. | 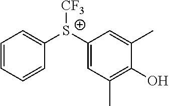 [SMILES: Cc1cc([S+](c2ccccc2)C(F)(F)F)cc(C)c1O] | 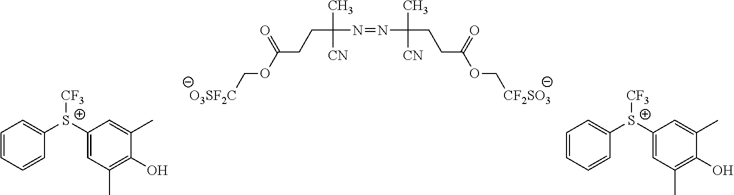 |
| I-AG | 1H-NMR (400 MHz, DMSO-d6): δ (ppm) = 8.49 (d, 4H, ArH), 8.30 (d, 4H, ArH), 7.93 (t, 4H, ArH), 7.73 (t, 4H, ArH), 7.30 (s, 4H, ArH), 4.61 (dt, 4H, CH2CF2), 4.52 (s, 4H, OCH2), 2.40- 2.65 (m, 8H, CH2CH2), 2.16-2.24 (m, 16H, ArCH3 + Adamantane), 1.44-1.92 (m, 42H, Adamantane + CH3). 19F-NMR (376 MHz, DMSO-d6): δ (ppm) = −111.4. | 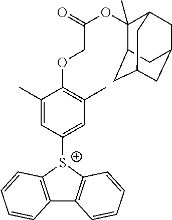 [SMILES: Cc1cc(-[s+]2c3ccccc3c3ccccc32)cc(C)c1OCC(=O)OC1(C)C2CC3CC(C2)CC1C3] | 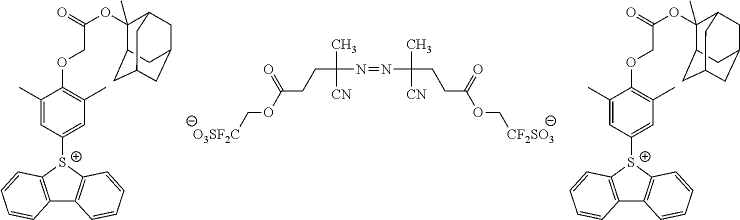 |
| I-AH | 1H-NMR (400 MHz, DMSO-d6): δ (ppm) = 9.73 (br s, 2H, OH), 8.47 (d, 4H, ArH), 8.24 (d, 4H, ArH), 7.91 (t, 4H, ArH), 7.71 (t, 4H, ArH), 7.18 (s, 4H, ArH), 4.61 (dt, 4H, CH2CF2), 2.40-2.65 (m, 8H, CH2CH2), 2.10 (s, 12H, ArCH3), 1.72 (s, 6H, CH3), 1.66 (s, 6H, CH3). 19F-NMR (376 MHz, DMSO-d6): δ (ppm) = −111.4. | 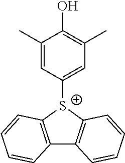 [SMILES: Cc1cc(-[s+]2c3ccccc3c3ccccc32)cc(C)c1O] | 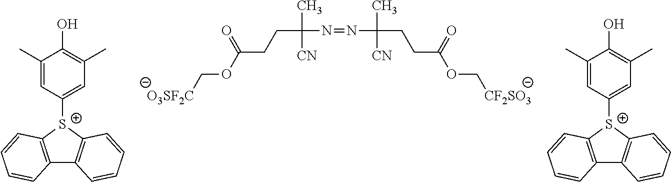 |

TABLE 12

| Com- | | | |
|---|---|---|---|
| pound | NMR | Cation | Product |
| I-AI | 1H-NMR (400 MHz, DMSO- d6): δ (ppm) = 7.75-7.87 (m, 20H, ArH), 7.62 (s, 4H, ArH), 4.61 (dt, 4H, CH2CF2), 3.97 (t, 4H, OCH2), 2.03- 2.69 (m, 28H, CH2CH2 + CH2CH2CF2 + ArCH3), 1.72 (s, 6H, CH3), 1.66 (s, 6H, CH3). 19F-NMR (376 MHz, DMSO- d6): δ (ppm) = −78.3, −111.4, −111.6, −121.8, −123.5. | 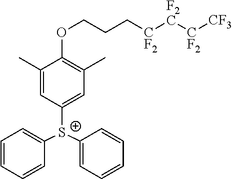 [SMILES: Cc1cc([S+](c2ccccc2)c2ccccc2)cc(C)c1OCCCC(F)(F)C(F)(F)C(F)(F)C(F)(F)F] | 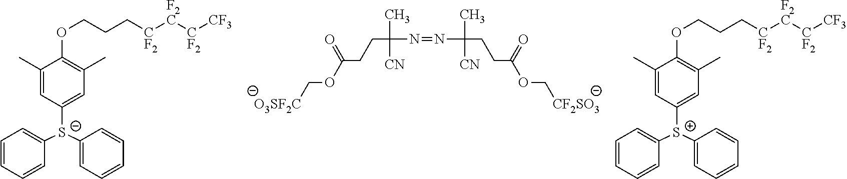 |
| I-AJ | 1H-NMR (400 MHz, DMSO- d6): δ (ppm) = 7.75-7.86 (m, 20H, ArH), 7.60 (s, 4H, ArH), 4.61 (dt, 4H, CH2CF2), 3.87 (t, 4H, OCH2), 2.40- 2.65 (m, 12H, CH2CH2 + CH2 in cation), 2.20 (s, 12H, ArCH3), 2.12 (s, 12H, NCH3), 1.86 (t, 4H, NCH2), 1.72 (s, 6H, CH3), 1.66 (s, 6H, CH3). 19F-NMR (376 MHz, DMSO- d6): δ (ppm) = −111.4. | 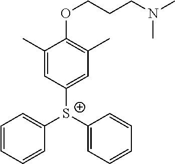 [SMILES: Cc1cc([S+](c2ccccc2)c2ccccc2)cc(C)c1OCCCN(C)C] | 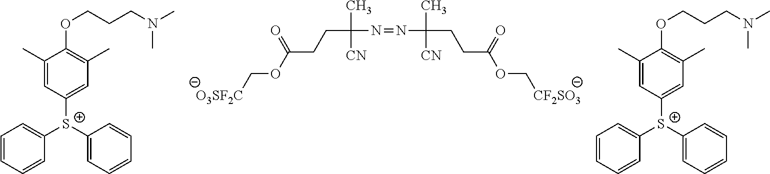 |
| I-AK | 1H-NMR (400 MHz, DMSO- d6): δ (ppm) = 7.77-7.89 (m, 20H, ArH), 7.71 (s, 4H, ArH), 4.61 (dt, 4H, CH2CF2), 2.40-2.65 (m, 12H, CH2CH2 + CH2—Ad), 2.20 (s, 12H, ArCH3), 1.97 (s, 6H, Adamantane), 1.62-1.73 (m, 36H, CH3 + Adamantane). 19F-NMR (376 MHz, DMSO-d6): δ (ppm) = −111.4. | 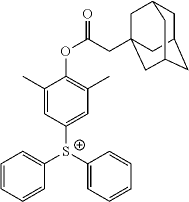 [SMILES: Cc1cc([S+](c2ccccc2)c2ccccc2)cc(C)c1OC(=O)CC12CC3CC(CC(C3)C1)C2] | 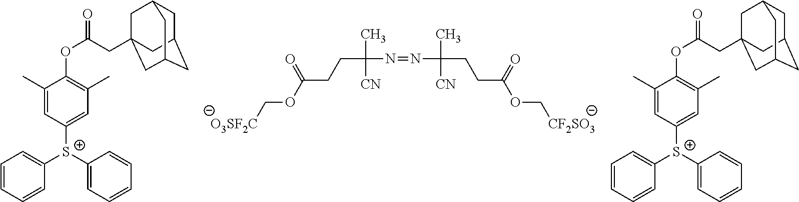 |

TABLE 13

| Compound | NMR | Cation | Product |
|---|---|---|---|
| I-AL | 1H NMR (400 MHz, DMSO-d6): δ (ppm) = 7.74-7.84 (m, 20H, ArH), 7.61 (s, 4H, ArH), 4.49-4.66 (m, 12H, CH2CF2 + norbornane + OCH2), 3.24 (m, 2H, norbornane), 2.40-2.65 (m, 12H, CH2CH2 + norbornane), 2.37 (s, 12H, ArCH3), 1.91-2.06 (m, 4H, norbornane), 1.72 (s, 6H, CH3), 1.57-1.67 (m, 10H, CH3 + norbornane). 19F-NMR (376 MHz, DMSO-d6): δ (ppm) = −111.4. | 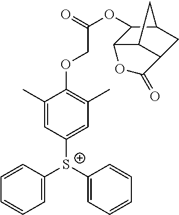 [SMILES: Cc1cc([S+](c2ccccc2)c2ccccc2)cc(C)c1OCC(=O)OC1C2CC3C(=O)OC1C3C2] | 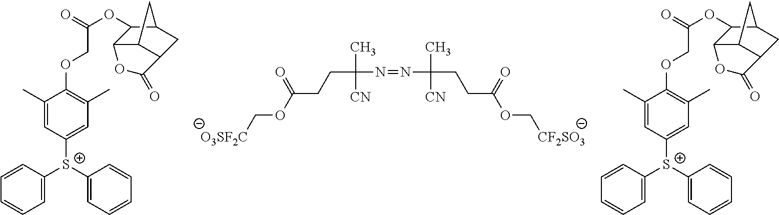 |
| I-AM | 1H-NMR (400 MHz, DMSO-d6): δ (ppm) = 7.80-7.92 (m, 20H, ArH), 7.67 (s, 4H, ArH), 4.66 (s, 4H, OCH2), 4.61 (dt, 4H, CH2CF2), 2.40-2.65 (m, 8H, CH2CH2), 2.37 (s, 12H, ArCH3), 2.13-2.16 (m, 4H, cyclohexyl), 1.93 (q, 4H, CH2 in ethyl), 1.72 (s, 6H, CH3), 1.66 (s, 6H, CH3), 1.14-1.57 (m, 16H, cyclohexyl), 0.84 (t, 6H, CH3 in ethyl). 19F-NMR (376 MHz, DMSO-d6): δ (ppm) = −111.4. | 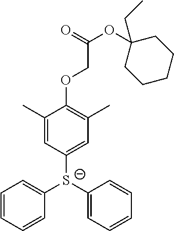 [SMILES: CCC1(OC(=O)COc2c(C)cc([S-](c3ccccc3)c3ccccc3)cc2C)CCCCC1] | 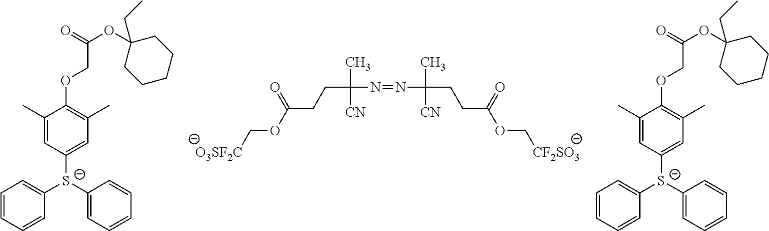 |
| I-AN | 1H-NMR (400 MHz, DMSO-d6): δ (ppm) = 8.44 (d, 2H, ArH), 8.22 (m, 4H, ArH), 7.73-7.89 (m, 26H, ArH), 7.50 (d, 2H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −111.4. | 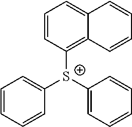 [SMILES: c1ccc([S+](c2ccccc2)c2cccc3ccccc23)cc1] | 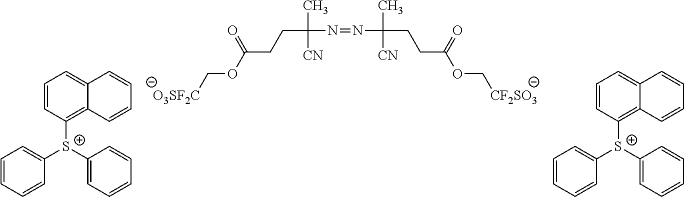 |

TABLE 14

| Compound | NMR | Cation | Product |
|---|---|---|---|
| I-AO | 1H-NMR (400 MHz, DMSO-d6): δ (ppm) = −8.24 (d, 8H, ArH), 7.59 (t, 4H, ArH), 7.47 (t, 8H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −111.4. | 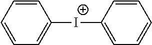 [SMILES: c1ccc([I+]c2ccccc2)cc1] | 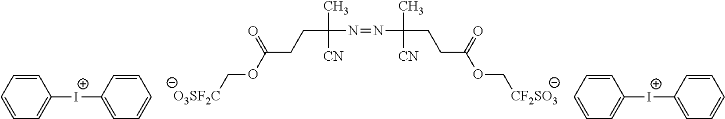 |
| 1-AP | 1H-NMR (400 MHz, DMSO-d6): δ (ppm) = 8.55 (d, 4H, ArH), 8.38 (d, 4H, ArH), 8.32 (d, 4H, ArH), 8.03 (d, 4H, ArH), 7.93-7.97 (m, 2H, ArH), 7.82-7.88 (m, 16H, ArH), 7.55 (d, 4H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −111.4. | 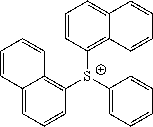 [SMILES: c1ccc([S+](c2cccc3ccccc23)c2cccc3ccccc23)cc1] | 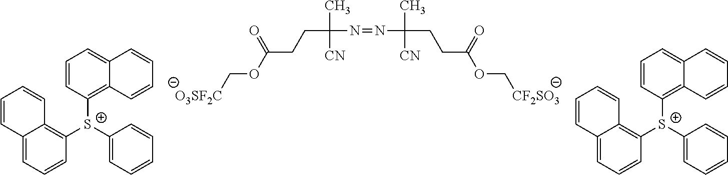 |
| I-AQ | 1H-NMR (400 MHz, DMSO-d6): δ (ppm) = 4.61 (dt, 4H, CH2CF2), 4.46 (s, 4H, CH2(C═O)), 3.38-3.58 (m, 8H, CH2SCH2), 2.40-2.65 (m, 8H, CH2CH2), 1.56-2.33 (m, 54H, CH3 + Adamantane + CH2CH2 in tetramethylenesulfide). 19F-NMR (376 MHz, DMSO-d6): δ (ppm) = −111.4. | 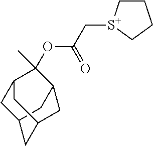 [SMILES: CC1(OC(=O)C[S+]2CCCC2)C2CC3CC(C2)CC1C3] | 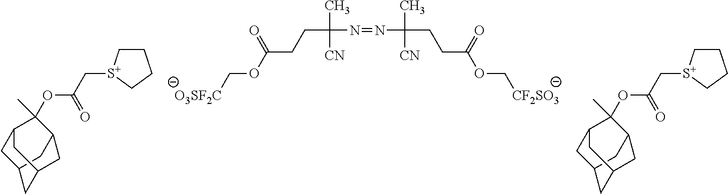 |

TABLE 15

| Compound | NMR | Cation | Product |
|---|---|---|---|
| I-AR | 1H-NMR (400 MHz, DMSO-d6): δ (ppm) = 7.75 (s, 4H, Ar), 4.61 (dt, 4H, CH2CF2), 3.91- 3.96 (m, 4H, CH2 in tetramethylene- sulfide), 3.72-3.79 (m, 4H, CH2 in tetra- methylenesulfide). 2.40-2.65 (m, 8H, CH2CH2), 2.29-2.39 (m, 8H, CH2 in tetramethylenesulfide), 1.75-2.19 (m, 42H, ArCH3 + Adamantane), 1.72 (s, 6H, CH3), 1.66 (s, 6H, CH3). 19F-NMR (376 MHz, DMSO-d6): δ (ppm) = −111.4. | 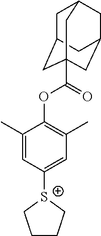 [SMILES: Cc1cc([S+]2CCCC2)cc(C)c1OC(=O)C12CC3CC(CC(C3)C1)C2] | 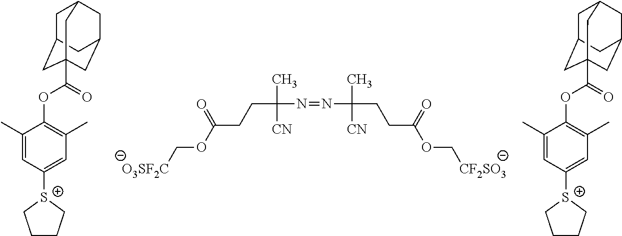 |
| I-AS | 1H-NMR (400 MHz, DMSO-d6): δ (ppm) = 7.82 (m, 4H, ArH), 4.61 (dt, 4H, CH2CF2), 3.73-3.91 (m, 8H CH2 in penta- methylenesulfide), 2.41-2.65 (m, 8H, CH2CH2), 1.56-2.40 (m, 66H, CH3 + ArCH3 + CH2 in penta- methylenesulfide + Adamantane). 19F-NMR (376 MHz, DMSO-d6): δ (ppm) = −111.4. | 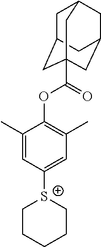 [SMILES: Cc1cc([S+]2CCCCC2)cc(C)c1OC(=O)C12CC3CC(CC(C3)C1)C2] | 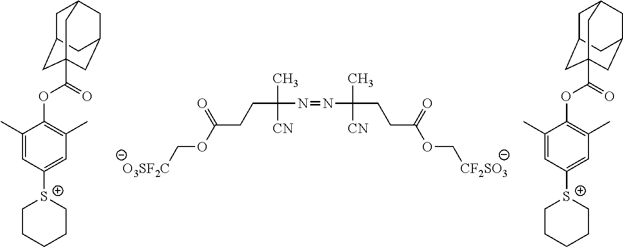 |
| I-AT | 1H-NMR (400 MHz, DMSO-d6): δ (ppm) = 8.23 (d, 8H, ArH), 7.98 (d, 8H, ArH), 4.61 (dt, 4H, CH2CF2), 2.40- 2.65 (m, 8H, CH2CH2), 1.72 (s, 6H, CH3), 1.66 (s, 6H, CH3), 1.37 (s, 36H, t-Butyl). 19F-NMR (376 MHz, DMSO-d6): δ (ppm) = −48.5, −111.4. | 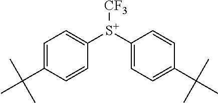 [SMILES: CC(C)(C)c1ccc([S+](c2ccc(C(C)(C)C)cc2)C(F)(F)F)cc1] | 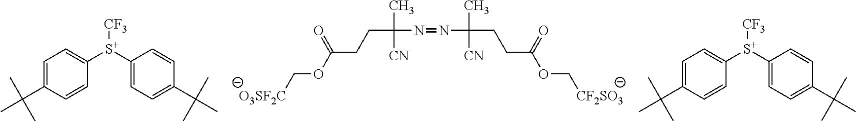 |

TABLE 16

| Com- | | | |
|---|---|---|---|
| pound | NMR | Cation | Product |
| I-AU | 1H-NMR (400 MHz, DMSO-d6): δ (ppm) = 7.77-7.98 (m, 20H, ArH), 7.64 (s, 4H, ArH), 4.61 (dt, 4H, CH2CF2), 4.57 (s, 4H, CH2O), 2.42 (s, 12H, ArCH3), 2.40-2.65 (m, 8H, CH2CH2), 2.02-2.26 (m, 18H, Adamantane), 1.76 (br, 12H, Adamantane), 1.72 (s, 6H, CH3), 1.66 (s, 6H, CH3). 19F-NMR (376 MHz, DMSO-d6): δ (ppm) = −111.4. | 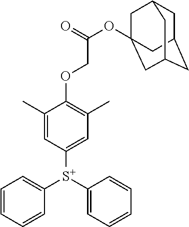 [SMILES: Cc1cc([S+](c2ccccc2)c2ccccc2)cc(C)c1OCC(=O)OC12CC3CC(CC(C3)C1)C2] | 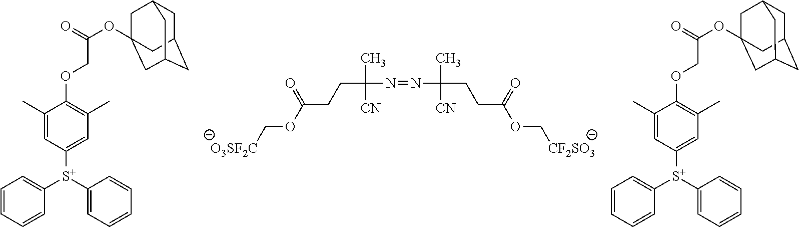 |
| I-AV | 1H-NMR (400 MHz, DMSO-d6): δ (ppm) = 7.77-7.89 (m, 20H, ArH), 7.64 (s, 4H, ArH), 5.70 (t, 2H, CH in GBL), 4.82 (s, 4H, OCH2), 4.61 (dt, 4H, CH2CF2), 4.46-4.30 (m, 4H, GBL), 2.71-2.64 (m, 2H, GBL), 2.40-2.65 (m, 8H, CH2CH2), 2.33-2.24 (m, 14H, ArCH3 + GBL), 1.72 (s, 6H, CH3), 1.66 (s, 6H, CH3). 19F-NMR (376 MHz, DMSO-d6): δ (ppm) = −111.4. | 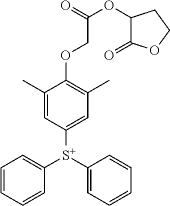 [SMILES: Cc1cc([S+](c2ccccc2)c2ccccc2)cc(C)c1OCC(=O)OC1CCOC1=O] | 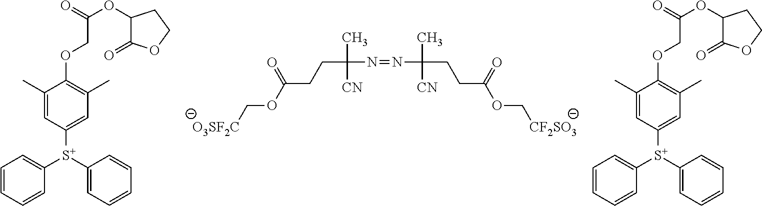 |
| I-AW | 1H-NMR (400 MHz, DMSO-d6): δ (ppm) = 8.28 (d, 4H, ArH), 8.11 (d, 2H, ArH), 7.86 (t, 2H, ArH), 7.63-7.81 (m, 14H, ArH), 4.61 (dt, 4H, CH2CF2), 2.40-2.65 (m, 8H, CH2CH2), 1.72 (s, 6H, CH3), 1.66 (s, 6H, CH3). 19F-NMR (376 MHz, DMSO-d6): δ (ppm) = −111.4. | 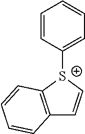 [SMILES: c1ccc(-[s+]2ccc3ccccc32)cc1] | 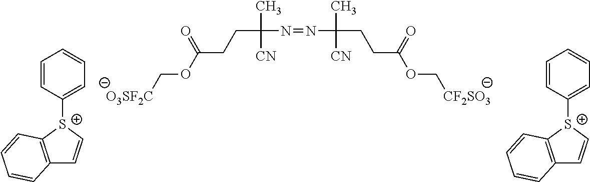 |

TABLE 17

| Compound | NMR | Cation | Product |
|---|---|---|---|
| I-AX | 1H-NMR (400 MHz, DMSO-d6): δ (ppm) = 8.05 (d, 4H, ArH), 7.74 (d, 4H, ArH), 4.61 (dt, 4H, CH2CF2), 3.85 (s, 6H, SCH3), 2.40- 2.65 (m, 8H, CH2CH2), 1.72 (s, 6H, CH3), 1.66 (s, 6H, CH3), 1.30 (s, 36H, t-Bu). 19F-NMR (376 MHz, DMSO-d6): δ (ppm) = −111.4. | 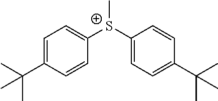 [SMILES: C[S+](c1ccc(C(C)(C)C)cc1)c1ccc(C(C)(C)C)cc1] | 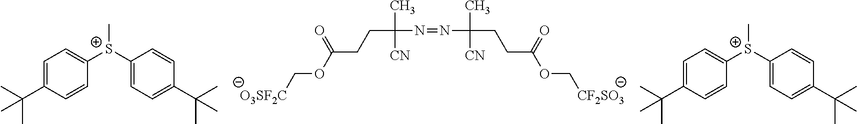 |
| I-AY | 1H-NMR (400 MHz, DMSO-d6): δ (ppm) = 8.41 (m, 4H, ArH), 8.12 (d, 2H, ArH), 7.73-7.93 (m, 4H, ArH), 7.19 (d, 2H, ArH), 5.23 (s, 4H, OCH2), 4.95 (m, 2H, Adamantane), 4.61 (dt, 4H, CH2CF2), 4.03 (m, 4H, CH2S), 3.75 (m, 4H, CH2S), 2.27- 2.65 (m, 16H, CH2CH2 + SCH2CH2), 1.42-1.99 (m, 40H, CH3 + Adamamane). 19F-NMR (376 MHz, DMSO-d6): δ (ppm) = −111.4. | 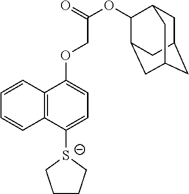 [SMILES: O=C(COc1ccc([S-]2CCCC2)c2ccccc12)OC1C2CC3CC(C2)CC1C3] | 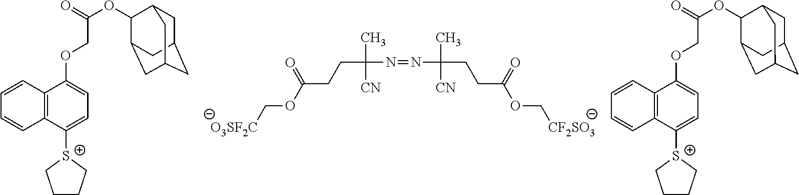 |
| I-AZ | 1H-NMR (400 MHz, DMSO-d6): δ (ppm) = 8.42 (m, 4H, ArH), 8.17 (d, 2H, ArH), 7.78-7.91 (m, 4H, ArH), 7.23 (d, 2H, ArH), 5.26 (s, 4H, CH2), 4.61 (dt, 4H, CH2CF2), 3.75-4.19 (m, 14H, SCH2 + OCH3), 2.29-2.65 (m, 16H, CH2CH2 + SCH2CH2), 1.72 (s, 6H, CH3), 1.66 (s, 6H, CH3). 19F-NMR (376 MHz, DMSO-d6): δ (ppm) = −111.4. | 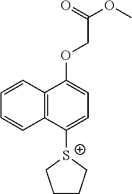 [SMILES: COC(=O)COc1ccc([S+]2CCCC2)c2ccccc12] | 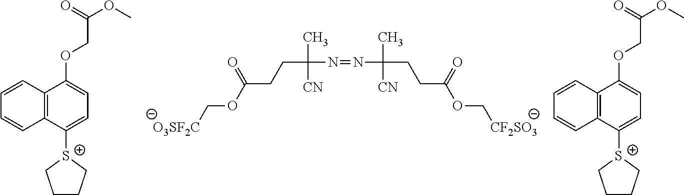 |

TABLE 18

| Compound | NMR | Cation | Product |
|---|---|---|---|
| I-BA | 1H-NMR (400 MHz, DMSO-d6): δ (ppm) = 8.28 (d, 4H, ArH), 8.12 (d, 2H, ArH), 7.88 (t, 2H, ArH), 7.80 (d, 2H, ArH), 7.62-7.74 (m, 10H, ArH), 4.61 (dt, 4H, CH2CF2), 2.40-2.65 (m, 8H, CH2CH2), 1.72 (s, 6H, CH3), 1.66 (s, 6H, CH3), 1.27 (s, 18H, t-Butyl). 19F-NMR (376 MHz, DMSO-d6): δ (ppm) = −111.4. | 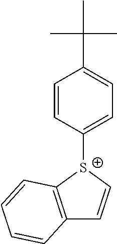 [SMILES: CC(C)(C)c1ccc(-[s+]2ccc3ccccc32)cc1] | 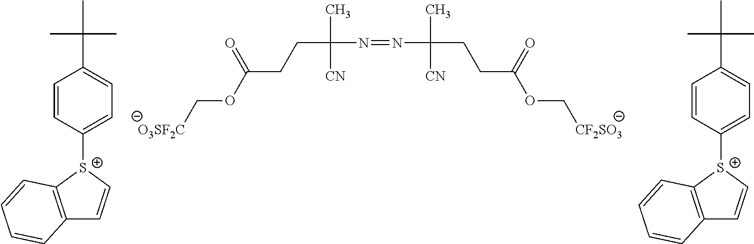 |
| I-BB | 1H-NMR (400 MHz, DMSO-d6): δ (ppm) = 7.76-7.90 (m, 24H, ArH), 4.61 (dt, 4H, CH2CF2), 2.40-2.69 (m, 10H, CH2CH2 + camphane), 2.08-2.26 (m, 16H, ArCH3 + camphane), 1.65-1.72 (m, 14H, CH3 + camphane), 1.19 (s, 6H, CH3 in camphane), 1.09 (s, 6H, CH3 in camphane), 1.04 (s, 6H, CH3 in camphane). 19F-NMR (376 MHz, DMSO-d6): δ (ppm) = −111.4. | 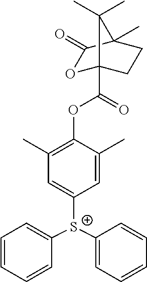 [SMILES: Cc1cc([S+](c2ccccc2)c2ccccc2)cc(C)c1OC(=O)C12CCC(C)(C(=O)O1)C2(C)C] | 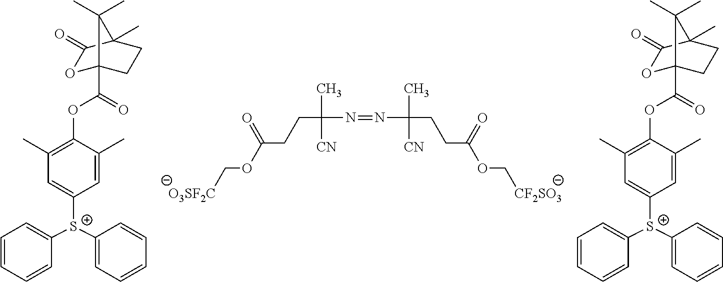 |

### Polymer Synthesis Example 1

### Synthesis of Polymeric Compound (1)

In a flask equipped with a thermometer, a reflux tube, a stirrer, and a nitrogen inlet tube, 10.6 g of γ-butyrolactone was added under a nitrogen atmosphere, and the internal temperature was raised to 85° C. while stirring.

2.0 g (11.8 mmol) of the monomer (1), 3.4 g (14.6 mmol) of the monomer (3), 2.6 g (10.0 mmol) of the monomer (12) and 1.3 g (5.4 mmol) of the monomer (14) were dissolved in 63.7 g of γ-butyrolactone to obtain a solution. Then, 3.19 g of the compound (1-A) was added as a radical polymerization initiator and dissolved in the obtained solution.

The resulting mixed solution was added to the flask in a dropwise manner at a constant rate over 4 hour, and heated while stirring for 1 hour, and then cooled to room temperature.

The obtained polymerization reaction solution was added to an excess amount of a methanol and water mixed solution in a dropwise manner, and an operation to precipitate a polymer was conducted. Thereafter, the precipitated white powder was separated by filtration, followed by washing with a methanol and water mixed solution and drying under reduced pressure, thereby obtaining 5.9 g of a polymeric compound (1) as an objective compound.

With respect to the polymeric compound (1), the weight average molecular weight (Mw) and the dispersity (Mw/Mn) were determined by the polystyrene equivalent value as measured by gel permeation chromatography (GPC). As a result, it was found that the weight average molecular weight was 7,500, and the dispersity was 1.71.

Further, as a result of an analysis by ¹³C-NMR, it was found that the composition of the copolymer (ratio (molar ratio) of the respective structural units within the structural formula) was p/q/r/s=40/20/2020.

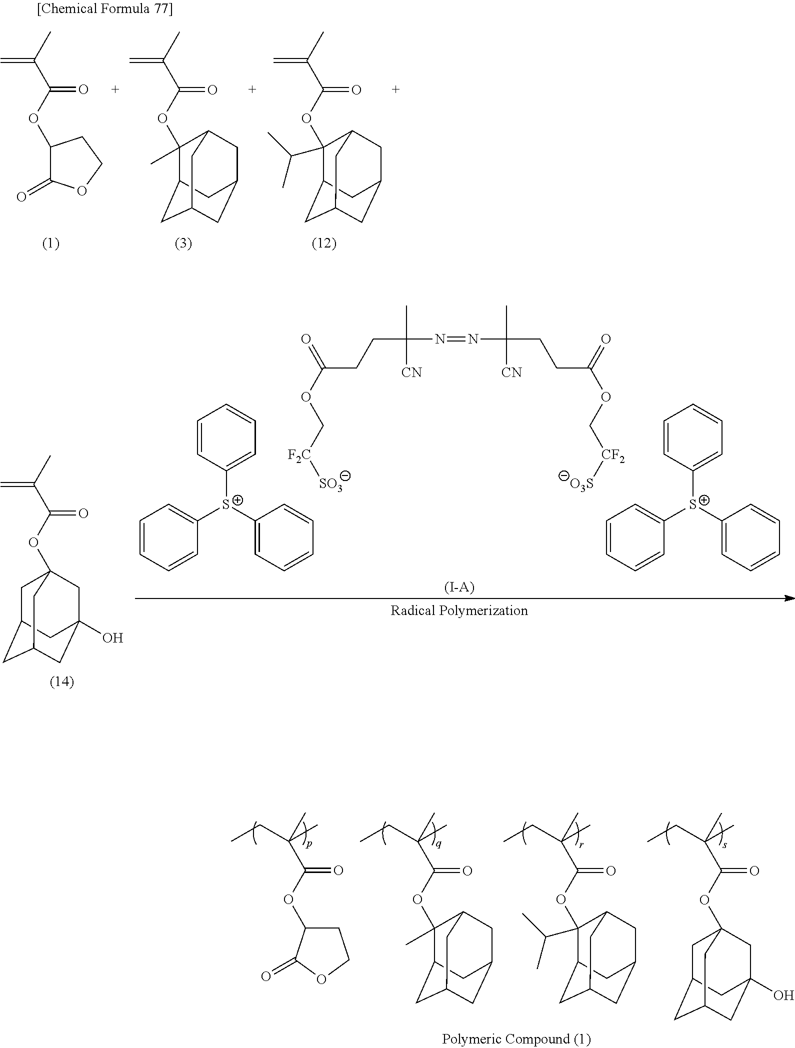

### Polymer Synthesis Examples 2 to 18

### Synthesis of Polymeric Compounds (2) to (14)

Polymeric compounds (2) to (18) were produced in the same manner as in Polymer Synthesis Example 1, except that the following monomers (1) to (14) which derived the structural units constituting each polymeric compound were used with a molar ratio indicated in Tables 19 and 20.

The weight average molecular weight (Mw) and the molecular weight distribution (Mw/Mn) of the obtained polymeric compounds (2) to (18) are shown in Tables 19 and 20.

### Comparative Polymer Synthesis Example 1

### Synthesis of Polymeric Compound (19)

In a flask equipped with a thermometer, a reflux tube, a stirrer, and a nitrogen inlet tube, 10.6 g of γ-butyrolactone was added under a nitrogen atmosphere, and the internal temperature was raised to 85° C. while stirring.

2.0 g (11.8 mmol) of the monomer (1), 3.4 g (14.6 mmol) of the monomer (3), 2.6 g (10.0 mmol) of the monomer (12) and 1.3 g (5.4 mmol) of the monomer (14) were dissolved in 63.7 g of γ-butyrolactone to obtain a solution. Then, 0.67 g of V-601 (dimethyl 2,2′-azobis(isobutyrate), manufactured by Wako Pure Chemical Industries, Ltd.) as a radical polymerization initiator was added and dissolved in the obtained solution.

The resulting mixed solution was added to the flask in a dropwise manner at a constant rate over 4 hour, and heated while stirring for 1 hour, and then cooled to room temperature.

The obtained polymerization reaction solution was added to an excess amount of a methanol and water mixed solution in a dropwise manner, and an operation to precipitate a polymer was conducted. Thereafter, the precipitated white powder was separated by filtration, followed by washing with a methanol and water mixed solution and drying under reduced pressure, thereby obtaining 5.9 g of a polymeric compound (19) as an objective compound.

With respect to the polymeric compound (19), the weight average molecular weight (Mw) and the dispersity (Mw/Mn) were determined by the polystyrene equivalent value as measured by gel permeation chromatography (GPC). As a result, it was found that the weight average molecular weight was 7,500, and the dispersity was 1.71.

Further, as a result of an analysis by ¹³C-NMR), it was found that the composition of the copolymer (ratio (molar ratio) of the respective structural units within the structural formula) was p/q/r/s=40/20/20/20.

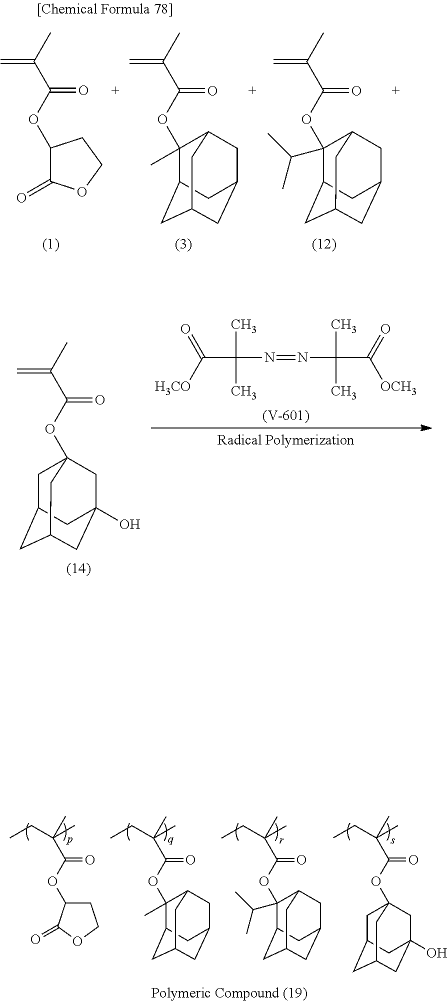

### Comparative Polymer Synthesis Example 1

### Synthesis of Polymeric Compounds (20) to (36)

Polymeric compounds (20) to (36) were produced in the same manner as in Comparative Polymer Synthesis Example 1, except that the following monomers (1) to (14) which derived the structural units constituting each polymeric compound were used with a molar ratio indicated in Tables 21 and 22.

The weight average molecular weight (Mw) and the molecular weight distribution (Mw/Mn) of the obtained polymeric compounds (20) to (36) are shown in Tables 21 and 22.

### Comparative Polymer Synthesis Examples 19 and 20

### Synthesis of Polymeric Compounds (37) and (38)

Polymeric compounds (37) and (38) were produced in the same manner as in Polymer Synthesis Example 1, except that the following monomers (1) to (14) which derived the structural units constituting each polymeric compound were used with a molar ratio indicated in Table 22.

The weight average molecular weight (Mw) and the molecular weight distribution (Mw/Mn) of the obtained polymeric compounds (37) and (38) are shown in Table 22.

The monomers used in the aforementioned polymer synthesis examples and comparative polymer synthesis examples are shown below. Of these, with respect to the monomers corresponding to the structural unit (a1), the activation energy thereof was calculated according to the following procedure. The results are shown in Tables.

In addition, with respect to the examples in which two types of monomers corresponding to the structural units (a1) were used, the activation energy difference (ΔEa) between the two acid decomposable groups within the monomers is shown in Tables 19 to 22.

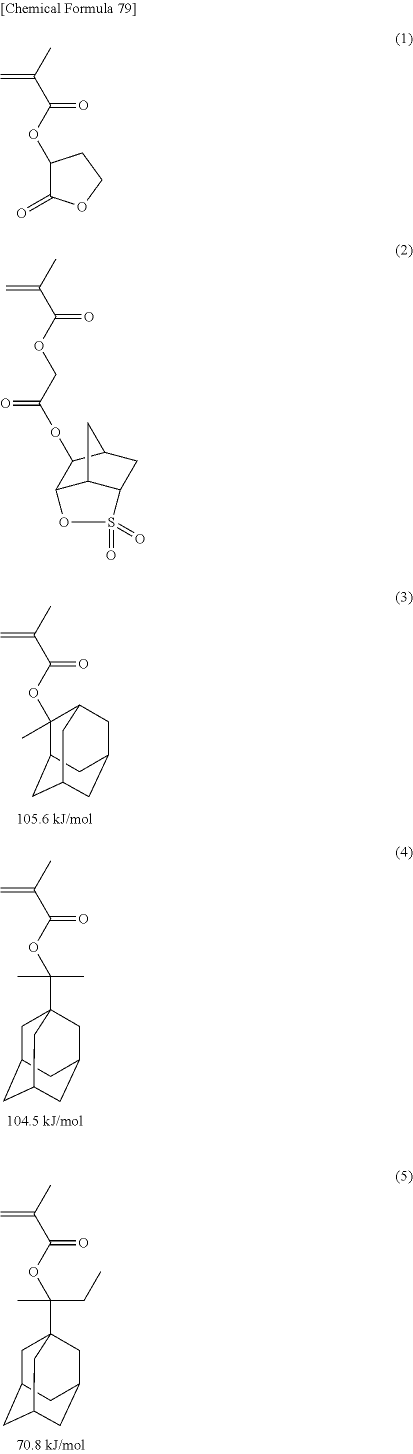

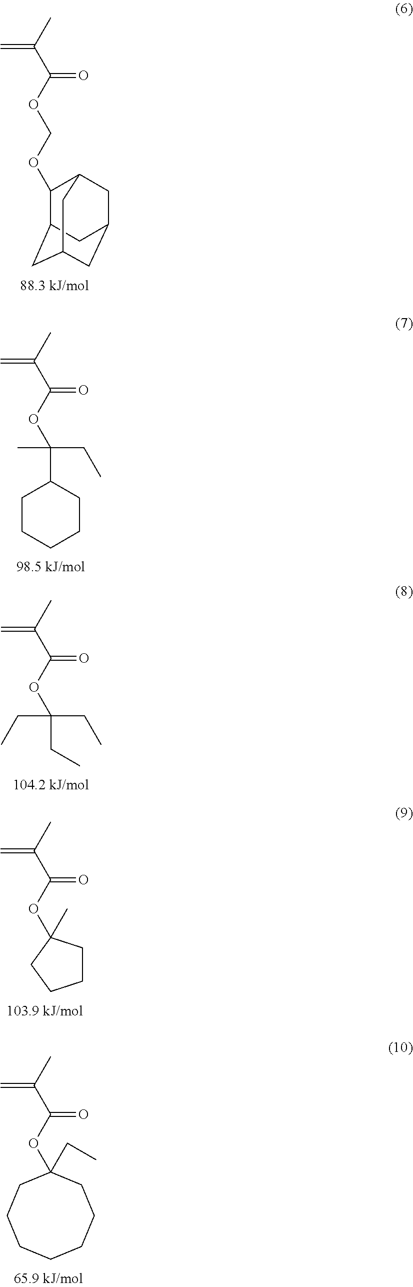

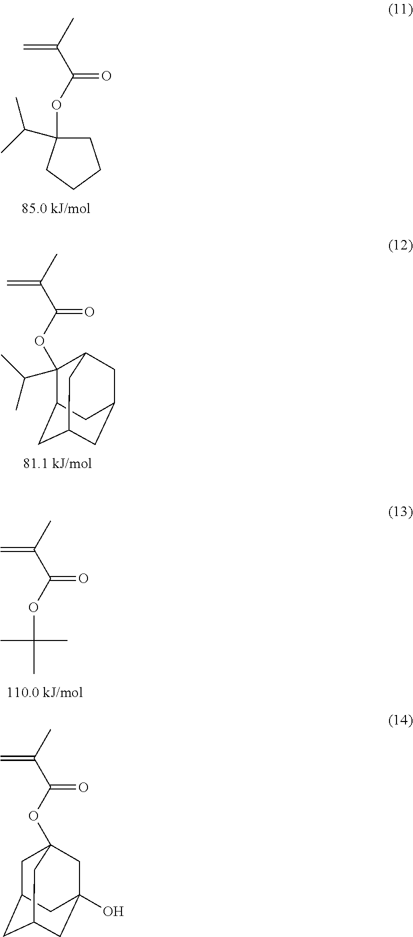

### [Method of Calculating Activation Energy]

Each monomer (2.73×10⁻⁴ mol) and benzoic acid (2.73×10⁻⁴ mol) were dissolved in 0.69 mL of tetrachloroethane in a vessel. Then the solution was respectively heated to 110° C., 120° C. and 130° C. Each of the solutions was sampled before starting the heating, 10 seconds after starting the heating, 50 seconds after starting the heating, 100 seconds after starting the heating, 200 seconds after starting the heating, 300 seconds after starting the heating, and 600 seconds after starting the heating. Then, each sample was cooled to room temperature (23° C.), followed by analyzing by ¹H-NMR, thereby determining the concentration of each monomer (undecomposed residues) and methacrylic acid (decomposed products caused by the decomposition of the acid decomposable group) within each sample. At this time, anisole was used as an internal standard. From the measurement results, the decomposition ratio of acid decomposable group within the monomer was calculated by the following formula.

Decomposition ratio=Concentration of decomposed products/(Concentration of the undecomposed residues+Concentration of decomposed products)

The reaction rate constant was calculated from the decomposition ratio of the acid decomposable group. From the reaction rate constant, the activation energy was calculated according to Arrhenius equation.

TABLE 19

| Polymeric Compound | | | | | | | | | |
|---|---|---|---|---|---|---|---|---|---|
| (1) | (2) | (3) | (4) | (5) | (6) | (7) | (8) | (9) | (10) |

| | | | | | | | | | | | |
|---|---|---|---|---|---|---|---|---|---|---|---|
| monomer | (1) | 40 | 40 | 40 | 40 | 40 | 40 | 40 | 40 | 40 | 40 |
| | (2) | | | | | | | | | | |
| | (3) | 20 | | | | | | | | | 20 |
| | (4) | | 20 | | | | | | | | |
| | (5) | | | 20 | | | | | | | |
| | (6) | | | | 20 | | | | | | 20 |
| | (7) | | | | | 20 | | | | | |
| | (8) | | | | | | 20 | | | | |
| | (9) | | | | | | | 20 | | | |
| | (10) | | | | | | | | 20 | | |
| | (11) | | | | | | | | | 20 | |
| | (12) | 20 | 20 | 20 | 20 | 20 | 20 | 20 | 20 | 20 | |
| | (13) | | | | | | | | | | |
| | (14) | 20 | 20 | 20 | 20 | 20 | 20 | 20 | 20 | 20 | 20 |

| Polymerization | I-A | | | | | | | | | |
|---|---|---|---|---|---|---|---|---|---|---|
| initiator | | | | | | | | | | |
| Mw | 7,500 | 7,700 | 6,900 | 7,000 | 6,800 | 7,200 | 7,300 | 7,100 | 6,900 | 6,600 |
| Mw/Mn | 1.71 | 1.70 | 1.68 | 1.73 | 1.66 | 1.82 | 1.79 | 1.73 | 1.80 | 1.82 |
| ΔEa | 24.5 | 23.4 | 10.3 | 7.2 | 17.4 | 23.1 | 22.8 | 15.2 | 3.9 | 17.3 |
| (kJ/mol) | | | | | | | | | | |

TABLE 20

| | | Polymeric Compound | | | | | | | |
|---|---|---|---|---|---|---|---|---|---|
| | | (11) | (12) | (13) | (14) | (15) | (16) | (17) | (18) |
| monomer | (1) | 40 | 40 | 40 | 40 | 40 | 40 | | 50 |
| | (2) | | | | | | | 40 | |
| | (3) | | | | | | | | |
| | (4) | | | | | | | | |
| | (5) | | 20 | 20 | 20 | 20 | | | |
| | (6) | 20 | | | | | | 20 | 20 |
| | (7) | | | | | | | | |
| | (8) | | | 20 | | | | | |
| | (9) | | | | 20 | | | | |
| | (10) | | | | | 20 | 20 | | |
| | (11) | 20 | 20 | | | | | | |
| | (12) | | | | | | | 20 | 20 |
| | (13) | | | | | | 20 | | |
| | (14) | 20 | 20 | 20 | 20 | 20 | 20 | 20 | |

| Polymerization | I-A | | | | | | | |
|---|---|---|---|---|---|---|---|---|
| initiator | | | | | | | | |
| Mw | 7,000 | 6,800 | 7,200 | 7,100 | 6,900 | 6,600 | 7,300 | 7,100 |
| Mw/Mn | 1.79 | 1.68 | 1.73 | 1.66 | 1.82 | 1.79 | 1.73 | 1.75 |
| ΔEa | 3.3 | 14.2 | 33.4 | 33.1 | 4.9 | 44.1 | 7.2 | 7.2 |
| (kJ/mol) | | | | | | | | |

TABLE 21

| | | Polymeric Compound | | | | | | | | | |
|---|---|---|---|---|---|---|---|---|---|---|---|
| | | (19) | (20) | (21) | (22) | (23) | (24) | (25) | (26) | (27) | (28) |
| monomer | (1) | 40 | 40 | 40 | 40 | 40 | 40 | 40 | 40 | 40 | 40 |
| | (2) | | | | | | | | | | |
| | (3) | 20 | | | | | | | | | 20 |
| | (4) | | 20 | | | | | | | | |
| | (5) | | | 20 | | | | | | | |
| | (6) | | | | 20 | | | | | | 20 |
| | (7) | | | | | 20 | | | | | |
| | (8) | | | | | | 20 | | | | |
| | (9) | | | | | | | 20 | | | |
| | (10) | | | | | | | | 20 | | |
| | (11) | | | | | | | | | 20 | |
| | (12) | 20 | 20 | 20 | 20 | 20 | 20 | 20 | 20 | 20 | |
| | (13) | | | | | | | | | | |
| | (14) | 20 | 20 | 20 | 20 | 20 | 20 | 20 | 20 | 20 | 20 |

| Polymerization | V-601 | | | | | | | | | |
|---|---|---|---|---|---|---|---|---|---|---|
| initiator | | | | | | | | | | |
| Mw | 6,900 | 6,600 | 7,000 | 6,800 | 7,100 | 6,900 | 6,600 | 6,800 | 7,500 | 7,700 |
| Mw/Mn | 1.73 | 1.66 | 1.82 | 1.79 | 1.70 | 1.68 | 1.73 | 1.68 | 1.66 | 1.64 |
| ΔEa | 24.5 | 23.4 | 10.3 | 7.2 | 17.4 | 23.1 | 22.8 | 15.2 | 3.9 | 17.3 |
| (kJ/mol) | | | | | | | | | | |

TABLE 22

| | | Polymeric Compound | | | | | | | | | |
|---|---|---|---|---|---|---|---|---|---|---|---|
| | | (29) | (30) | (31) | (32) | (33) | (34) | (35) | (36) | (37) | (38) |
| monomer | (1) | 40 | 40 | 40 | 40 | 40 | 40 | | 50 | 40 | 40 |
| | (2) | | | | | | | 40 | | | |
| | (3) | | | | | | | | | 21 | |
| | (4) | | | | | | | | | | |
| | (5) | | 20 | 20 | 20 | 20 | | | | | |
| | (6) | 20 | | | | | | 20 | 21 | | |
| | (7) | | | | | | | | | | |
| | (8) | | | 20 | | | | | | | |
| | (9) | | | | 20 | | | | | 19 | |
| | (10) | | | | | 20 | 20 | | | | |
| | (11) | 20 | 20 | | | | | | | | |
| | (12) | | | | | | | 20 | 29 | | 40 |
| | (13) | | | | | | 20 | | | | |
| | (14) | 20 | 20 | 20 | 20 | 20 | 20 | 20 | | 20 | 20 |

| Polymerization | V-601 | | | | | | | | I-A | |
|---|---|---|---|---|---|---|---|---|---|---|
| initiator | | | | | | | | | | |
| Mw | 6,900 | 7,000 | 6,900 | 6,600 | 7,300 | 7,100 | 6,900 | 6,600 | 7,400 | 7,100 |
| Mw/Mn | 1.66 | 1.68 | 1.68 | 1.73 | 1.66 | 1.82 | 1.79 | 1.73 | 1.77 | 1.75 |
| ΔEa | 3.3 | 14.2 | 33.4 | 33.1 | 4.9 | 44.1 | 7.2 | 7.2 | 1.7 | — |
| (kJ/mol) | | | | | | | | | | |

### Examples 1 to 18 and Comparative Examples 1 to 20

### Production of Resist Composition

Each of the components shown in Tables 23 and 24 was mixed together and dissolved, thereby obtaining resist compositions.

TABLE 23

| | Com- | Com- | Com- | Com- | Com- | |
|---|---|---|---|---|---|---|
| | ponent | ponent | ponent | ponent | ponent | Component |
| | (A) | (B) | (D) | (E) | (F) | (S) |
| Example 1 | (A)-1 | (B)-1 | (D)-1 | (E)-1 | (F)-1 | (S)-1 |
| | [100] | [15.00] | [1.20] | [0.50] | [1.50] | [3000] |
| Example 2 | (A)-2 | (B)-1 | (D)-1 | (E)-1 | (F)-1 | (S)-1 |
| | [100] | [15.00] | [1.20] | [0.50] | [1.50] | [3000] |
| Example 3 | (A)-3 | (B)-1 | (D)-1 | (E)-1 | (F)-1 | (S)-1 |
| | [100] | [15.00] | [1.20] | [0.50] | [1.50] | [3000] |
| Example 4 | (A)-4 | (B)-1 | (D)-1 | (E)-1 | (F)-1 | (S)-1 |
| | [100] | [15.00] | [1.20] | [0.50] | [1.50] | [3000] |
| Example 5 | (A)-5 | (B)-1 | (D)-1 | (E)-1 | (F)-1 | (S)-1 |
| | [100] | [15.00] | [1.20] | [0.50] | [1.50] | [3000] |
| Example 6 | (A)-6 | (B)-1 | (D)-1 | (E)-1 | (F)-1 | (S)-1 |
| | [100] | [15.00] | [1.20] | [0.50] | [1.50] | [3000] |
| Example 7 | (A)-7 | (B)-1 | (D)-1 | (E)-1 | (F)-1 | (S)-1 |
| | [100] | [15.00] | [1.20] | [0.50] | [1.50] | [3000] |
| Example 8 | (A)-8 | (B)-1 | (D)-1 | (E)-1 | (F)-1 | (S)-1 |
| | [100] | [15.00] | [1.20] | [0.50] | [1.50] | [3000] |
| Example 9 | (A)-9 | (B)-1 | (D)-1 | (E)-1 | (F)-1 | (S)-1 |
| | [100] | [15.00] | [1.20] | [0.50] | [1.50] | [3000] |
| Example | (A)-10 | (B)-1 | (D)-1 | (E)-1 | (F)-1 | (S)-1 |
| 10 | [100] | [15.00] | [1.20] | [0.50] | [1.50] | [3000] |
| Example | (A)-11 | (B)-1 | (D)-1 | (E)-1 | (F)-1 | (S)-1 |
| 11 | [100] | [15.00] | [1.20] | [0.50] | [1.50] | [3000] |
| Example | (A)-12 | (B)-1 | (D)-1 | (E)-1 | (F)-1 | (S)-1 |
| 12 | [100] | [15.00] | [1.20] | [0.50] | [1.50] | [3000] |
| Example | (A)-13 | (B)-1 | (D)-1 | (E)-1 | (F)-1 | (S)-1 |
| 13 | [100] | [15.00] | [1.20] | [0.50] | [1.50] | [3000] |
| Example | (A)-14 | (B)-1 | (D)-1 | (E)-1 | (F)-1 | (S)-1 |
| 14 | [100] | [15.00] | [1.20] | [0.50] | [1.50] | [3000] |
| Example | (A)-15 | (B)-1 | (D)-1 | (E)-1 | (F)-1 | (S)-1 |
| 15 | [100] | [15.00] | [1.20] | [0.50] | [1.50] | [3000] |
| Example | (A)-16 | (B)-1 | (D)-1 | (E)-1 | (F)-1 | (S)-1 |
| 16 | [100] | [15.00] | [1.20] | [0.50] | [1.50] | [3000] |
| Example | (A)-17 | (B)-1 | (D)-1 | (E)-1 | (F)-1 | (S)-1 |
| 17 | [100] | [15.00] | [1.20] | [0.50] | [1.50] | [3000] |
| Example | (A)-18 | (B)-1 | (D)-1 | (E)-1 | (F)-1 | (S)-1 |
| 18 | [100] | [15.00] | [1.20] | [0.50] | [1.50] | [3000] |

TABLE 24

| | Com- | Com- | Com- | Com- | Com- | Com- |
|---|---|---|---|---|---|---|
| | ponent | ponent | ponent | ponent | ponent | ponent |
| | (A) | (B) | (D) | (E) | (F) | (S) |
| Comparative | (A)-19 | (B)-1 | (D)-1 | (E)-1 | (F)-1 | (S)-1 |
| Example 1 | [100] | [15.00] | [1.20] | [0.50] | [1.50] | [3000] |
| Comparative | (A)-20 | (B)-1 | (D)-1 | (E)-1 | (F)-1 | (S)-1 |
| Example 2 | [100] | [15.00] | [1.20] | [0.50] | [1.50] | [3000] |
| Comparative | (A)-21 | (B)-1 | (D)-1 | (E)-1 | (F)-1 | (S)-1 |
| Example 3 | [100] | [15.00] | [1.20] | [0.50] | [1.50] | [3000] |
| Comparative | (A)-22 | (B)-1 | (D)-1 | (E)-1 | (F)-1 | (S)-1 |
| Example 4 | [100] | [15.00] | [1.20] | [0.50] | [1.50] | [3000] |
| Comparative | (A)-23 | (B)-1 | (D)-1 | (E)-1 | (F)-1 | (S)-1 |
| Example 5 | [100] | [15.00] | [1.20] | [0.50] | [1.50] | [3000] |
| Comparative | (A)-24 | (B)-1 | (D)-1 | (E)-1 | (F)-1 | (S)-1 |
| Example 6 | [100] | [15.00] | [1.20] | [0.50] | [1.50] | [3000] |
| Comparative | (A)-25 | (B)-1 | (D)-1 | (E)-1 | (F)-1 | (S)-1 |
| Example 7 | [100] | [15.00] | [1.20] | [0.50] | [1.50] | [3000] |
| Comparative | (A)-26 | (B)-1 | (D)-1 | (E)-1 | (F)-1 | (S)-1 |
| Example 8 | [100] | [15.00] | [1.20] | [0.50] | [1.50] | [3000] |
| Comparative | (A)-27 | (B)-1 | (D)-1 | (E)-1 | (F)-1 | (S)-1 |
| Example 9 | [100] | [15.00] | [1.20] | [0.50] | [1.50] | [3000] |
| Comparative | (A)-28 | (B)-1 | (D)-1 | (E)-1 | (F)-1 | (S)-1 |
| Example | [100] | [15.00] | [1.20] | [0.50] | [1.50] | [3000] |
| 10 | | | | | | |
| Comparative | (A)-29 | (B)-1 | (D)-1 | (E)-1 | (F)-1 | (S)-1 |
| Example | [100] | [15.00] | [1.20] | [0.50] | [1.50] | [3000] |
| 11 | | | | | | |
| Comparative | (A)-30 | (B)-1 | (D)-1 | (E)-1 | (F)-1 | (S)-1 |
| Example | [100] | [15.00] | [1.20] | [0.50] | [1.50] | [3000] |
| 12 | | | | | | |
| Comparative | (A)-31 | (B)-1 | (D)-1 | (E)-1 | (F)-1 | (S)-1 |
| Example | [100] | [15.00] | [1.20] | [0.50] | [1.50] | [3000] |
| 13 | | | | | | |
| Comparative | (A)-32 | (B)-1 | (D)-1 | (E)-1 | (F)-1 | (S)-1 |
| Example | [100] | [15.00] | [1.20] | [0.50] | [1.50] | [3000] |
| 14 | | | | | | |
| Comparative | (A)-33 | (B)-1 | (D)-1 | (E)-1 | (F)-1 | (S)-1 |
| Example | [100] | [15.00] | [1.20] | [0.50] | [1.50] | [3000] |
| 15 | | | | | | |
| Comparative | (A)-34 | (B)-1 | (D)-1 | (E)-1 | (F)-1 | (S)-1 |
| Example | [100] | [15.00] | [1.20] | [0.50] | [1.50] | [3000] |
| 16 | | | | | | |
| Comparative | (A)-35 | (B)-1 | (D)-1 | (E)-1 | (F)-1 | (S)-1 |
| Example | [100] | [15.00] | [1.20] | [0.50] | [1.50] | [3000] |
| 17 | | | | | | |
| Comparative | (A)-36 | (B)-1 | (D)-1 | (E)-1 | (F)-1 | (S)-1 |
| Example | [100] | [15.00] | [1.20] | [0.50] | [1.50] | [3000] |
| 18 | | | | | | |
| Comparative | (A)-37 | (B)-1 | (D)-1 | (E)-1 | (F)-1 | (S)-1 |
| Example | [100] | [15.00] | [1.20] | [0.50] | [1.50] | [3000] |
| 19 | | | | | | |
| Comparative | (A)-38 | (B)-1 | (D)-1 | (E)-1 | (F)-1 | (S)-1 |
| Example | [100] | [15.00] | [1.20] | [0.50] | [1.50] | [3000] |
| 20 | | | | | | |

In Tables 23 and 24, the reference characters indicate the following. Further, the values in brackets [ ] indicate the amount (in terms of parts by weight) of the component added.

(A)-1 to (A)-38: the aforementioned polymeric compounds (1) to (38)

(B)-1: a compound represented by chemical formula (B)-1 shown below

(D)-1: tri-n-octylamine

(E)-1: salicylic acid

(F)-1: a polymeric compound represented by chemical formula (F)-1 shown below [1=100 (molar ratio), Mw=22,000, Mw/Mn=1.58, a polymer produced by a radical polymerization using a radical polymerization initiator V-601]

(S)-1: a mixed solvent of PGMEA/PGME/cyclohexanone=1350/900/750 (weight ratio)

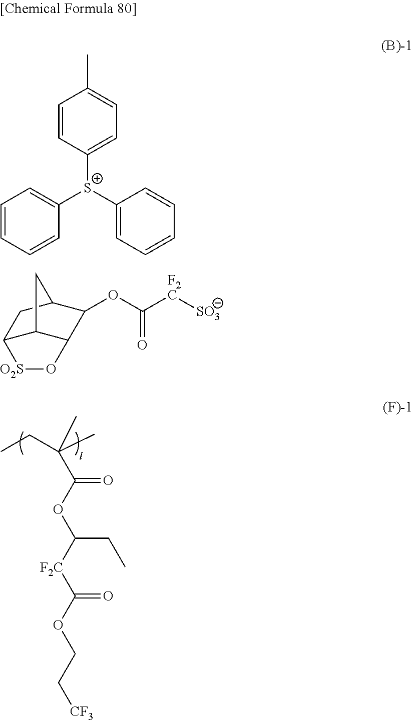

### <Evaluation>

### (Formation of Resist Pattern)

An organic anti-reflection film composition (product name: ARC95, manufactured by Brewer Science Ltd.) was applied to a 12-inch silicon wafer using a spinner, and the composition was then baked at 205° C. for 90 seconds, thereby forming an organic anti-reflection film having a film thickness of 90 nm.

Then, each resist composition obtained in the examples was applied to the organic anti-reflection film using a spinner, and was then prebaked (PAB) on a hotplate at a temperature indicated in Tables 25 and 26 for 60 seconds and dried, thereby forming a resist film having a film thickness of 100 nm.

Subsequently, the resist film was selectively irradiated with an ArF excimer laser (193 nm) through a mask pattern (6% half tone), using an ArF immersion exposure apparatus NSR-5609B (manufactured by Nikon Corporation, NA (numerical aperture)=1.07, Dipole (in/out: 0.78/0.97), w/POLANO).

Thereafter, a post exposure bake (PEB) treatment was conducted at a temperature indicated in Tables 25 and 26 for 60 seconds, followed by development for 10 seconds at 23° C. in a 2.38% by weight aqueous solution of tetramethylammonium hydroxide (TMAH) (product name: NMD-3; manufactured by Tokyo Ohka Kogyo Co., Ltd.). Then, the resist film was washed for 15 seconds with pure water, followed by drying by shaking. Further, a post bake was conducted at 100° C. for 45 seconds on the hot plate.

As a result, in each of the examples, a 1:1 line and space pattern (LS pattern) having a line width of 50 nm and a pitch of 100 nm was formed.

The optimum exposure dose Eop (mJ/cm²; sensitivity) with which the LS pattern was formed was determined. The results are shown in Tables 25 and 26.

### (Evaluation of Exposure Latitude (EL Margin))

With respect to the above Eop, the exposure dose with which an LS pattern having a dimension of the target dimension (line width: 50 nm)±5% (i.e., 47.5 nm to 52.5 nm) was determined, and the EL margin (unit: %) was determined by the following formula. The results are shown in Tables 25 and 26.

EL margin(%)=(|E1−E2|/Eop)×100

E1: Exposure dose (mJ/cm²) with which an LS pattern having a line width of 47.5 nm was formed

E2: Exposure dose (mJ/cm²) with which an L/S pattern having a line width of 52.5 nm was formed

The larger the value of the “EL margin”, the smaller the change in the pattern size by the variation of the exposure dose.

### (Evaluation of Mask Error Factor (MEF))

In the same manner as described above, with the above Eop, LS patterns were formed using a mask pattern targeting a line width of 50 nm and a pitch of 100 nm, and a mask pattern targeting a line width of 55 nm and a pitch of 100 nm, and the MEF value was calculated by the following formula. The results are shown in Tables 25 and 26.

MEF=|CD55−CD50|/|MD55−MD50|

In the formula, CD50 and CD55 represent the respective line widths (nm) of the actual LS patterns respectively formed using the mask pattern targeting a line width of 50 nm and the mask pattern targeting a line width of 55 nm. MD50 and MD55 represent the respective target line widths (nm), meaning MD50=50 nm, and MD55=55 nm. A MEF value closer to 1 indicates that a resist pattern faithful to the mask pattern was formed.

### (Evaluation of Line Width Roughness (LWR))

With respect to each of the LS patterns formed with the above optimum exposure dose Eop and having a line width of 50 nm and a pitch of 100 nm, the space width at 400 points in the lengthwise direction of the space were measured using a measuring scanning electron microscope (SEM) (product name: S-9380, manufactured by Hitachi High-Technologies Corporation; acceleration voltage: 300V). From the results, the value of 3 times the standard deviation s (i.e., 3s) was determined, and the average of the 3s values at 400 points was calculated as a yardstick of LWR. The results are shown in Tables 25 and 26.

The smaller this 3s value is, the lower the level of roughness of the line width, indicating that a LS pattern with a uniform width was obtained.

### (Evaluation of Pattern Shape)

The cross-sectional shape of the pattern formed with the above optimum exposure dose Eop was observed using a scanning electron microscope (product name: SU-8000, manufactured by Hitachi High-Technologies Corporation), and the cross-sectional shape was evaluated with the following criteria. The results are shown in Tables 25 and 26.

A: high rectangularity and excellent shape

B: moderate T-top shape

C: top with rounded shape

TABLE 25

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Example 1 | 105 | 100 | 31.8 | 8.25 | 2.25 | 5.44 | A |
| Example 2 | 105 | 100 | 30.9 | 7.84 | 2.41 | 4.91 | A |
| Example 3 | 90 | 90 | 27.5 | 7.99 | 2.49 | 4.55 | A |
| Example 4 | 100 | 90 | 28.1 | 8.03 | 2.38 | 4.81 | A |
| Example 5 | 100 | 90 | 29.9 | 8.11 | 2.52 | 4.29 | A |
| Example 6 | 100 | 90 | 30.2 | 7.79 | 2.43 | 5.01 | A |
| Example 7 | 100 | 90 | 26.3 | 7.58 | 2.51 | 4.73 | A |
| Example 8 | 90 | 85 | 23.5 | 8.00 | 2.40 | 4.91 | A |
| Example 9 | 90 | 85 | 24.4 | 7.37 | 2.54 | 4.55 | A |
| Example 10 | 110 | 100 | 33.1 | 7.48 | 2.45 | 4.81 | A |
| Example 11 | 90 | 85 | 28.0 | 7.79 | 2.53 | 4.29 | A |
| Example 12 | 90 | 85 | 25.9 | 7.40 | 2.42 | 5.01 | A |
| Example 13 | 90 | 85 | 27.1 | 7.80 | 2.56 | 4.73 | A |
| Example 14 | 90 | 85 | 26.8 | 8.03 | 2.47 | 4.92 | A |
| Example 15 | 90 | 85 | 21.5 | 8.11 | 2.55 | 4.56 | A |
| Example 16 | 100 | 95 | 27.3 | 7.79 | 2.44 | 4.82 | A |
| Example 17 | 90 | 80 | 22.6 | 7.58 | 2.58 | 4.30 | A |
| Example 18 | 95 | 85 | 23.6 | 7.49 | 2.49 | 5.02 | A |

TABLE 26

| | PAB | PEB | Eop | 5% EL | | LWR | |
|---|---|---|---|---|---|---|---|
| | (° C.) | (° C.) | (mJ/cm²) | (%) | MEF | (nm) | Shape |
| Comparative | 105 | 100 | 33.7 | 7.73 | 2.45 | 5.77 | B |
| Example 1 | | | | | | | |
| Comparative | 105 | 100 | 32.8 | 7.35 | 2.62 | 5.48 | B |
| Example 2 | | | | | | | |
| Comparative | 90 | 90 | 29.2 | 7.49 | 2.71 | 5.08 | B |
| Example 3 | | | | | | | |
| Comparative | 100 | 90 | 29.8 | 7.52 | 2.59 | 5.37 | B |
| Example 4 | | | | | | | |
| Comparative | 100 | 90 | 31.7 | 7.60 | 2.74 | 4.79 | B |
| Example 5 | | | | | | | |
| Comparative | 100 | 90 | 32.0 | 7.30 | 2.64 | 5.59 | B |
| Example 6 | | | | | | | |
| Comparative | 100 | 90 | 27.9 | 7.10 | 2.73 | 5.28 | B |
| Example 7 | | | | | | | |
| Comparative | 90 | 85 | 24.9 | 7.50 | 2.61 | 4.58 | B |
| Example 8 | | | | | | | |
| Comparative | 90 | 85 | 25.9 | 6.91 | 2.76 | 5.08 | B |
| Example 9 | | | | | | | |
| Comparative | 110 | 100 | 35.1 | 7.01 | 2.66 | 5.37 | B |
| Example 10 | | | | | | | |
| Comparative | 90 | 85 | 29.7 | 7.30 | 2.75 | 5.09 | B |
| Example 11 | | | | | | | |
| Comparative | 90 | 85 | 27.5 | 6.93 | 2.63 | 5.60 | B |
| Example 12 | | | | | | | |
| Comparative | 90 | 85 | 28.7 | 7.31 | 2.78 | 5.28 | B |
| Example 13 | | | | | | | |
| Comparative | 90 | 85 | 28.4 | 7.52 | 2.68 | 5.49 | B |
| Example 14 | | | | | | | |
| Comparative | 90 | 85 | 22.8 | 7.60 | 2.77 | 5.09 | B |
| Example 15 | | | | | | | |
| Comparative | 100 | 95 | 28.9 | 7.30 | 2.65 | 5.38 | B |
| Example 16 | | | | | | | |
| Comparative | 90 | 80 | 24.0 | 7.10 | 2.81 | 5.23 | B |
| Example 17 | | | | | | | |
| Comparative | 95 | 85 | 25.0 | 7.02 | 2.70 | 5.60 | B |
| Example 18 | | | | | | | |
| Comparative | 110 | 110 | 32.4 | 6.82 | 2.95 | 5.81 | B |
| Example 19 | | | | | | | |
| Comparative | 100 | 100 | 20.7 | 5.59 | 3.01 | 6.08 | C |
| Example 20 | | | | | | | |

As seen from the results, the resist composition of Example 1 exhibited excellent properties with respect to various properties such as sensitivity, EL, MEF, LWR and the rectangularity of the pattern shape, as compared to the resist composition of Comparative Example 1 having the same composition as that in Example 1, except that a component (A) in which the main chain had a different terminal structure was used, that is, having the same composition as that in Example 1, expect that a different polymerization initiator for synthesis of the component (A) was used.

Similarly, the resist compositions of Examples 2 to 18 exhibited excellent properties with respect to various properties such as sensitivity, EL, MEF, LWR and the rectangularity of the pattern shape, as compared to the resist compositions of Comparative Examples 2 to 18 having the same composition as that in Examples 2 to 18, expect that a different polymerization initiator for synthesis of the component (A) was used.

Despite using the compound (1-A) as a polymerization initiator, the resist composition of Comparative Example 19 using a polymer having two types of acid decomposable groups with an activation energy difference less than 3.0 kJ/mol, and the resist composition of Comparative Example 20 using a polymer having only one type of acid decomposable group exhibited low EL, large MEF, large LWR and an inferior shape of the resist pattern, as compared to the resist compositions of Examples 1 to 18.

From the results shown above, it was confirmed that a resist composition including a polymer containing two types of structural units having acid decomposable groups with an activation energy difference of at least 3.0 kJ/mol, and containing an anion part which generates acid upon exposure on at least one terminal of the main chain exhibited excellent lithography properties and a resist pattern having an excellent shape could be formed.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A polymer comprising:
an anion part which generates acid upon exposure on at least one terminal of the main chain; and
a structural unit (a1) containing an acid decomposable group that exhibits increased polarity by the action of acid, wherein
the structural unit (a1) comprises two types of structural units, and a difference in an activation energy of the acid decomposable groups within the two types of structural units is at least 3.0 kJ/mol.

2. The polymer according to claim 1, which comprises a group represented by general formula (I-1) shown below on at least one terminal of the main chain. 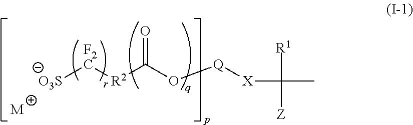
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 1 to 3;
Q represents a hydrocarbon group having a valency of (p+1), provided that, p represents 1, Q may represent a single bond;
R² represents a single bond, an alkylene group which may have a substituent or an aromatic group which may have a substituent; q represents 0 or 1; r represents an integer of 0 to 8; and M⁺ represents an organic cation.

3. The polymer according to claim 2, which is a radical polymer obtained by radial polymerization using a radical polymerization initiator comprising a compound represented by general formula (I) shown below: 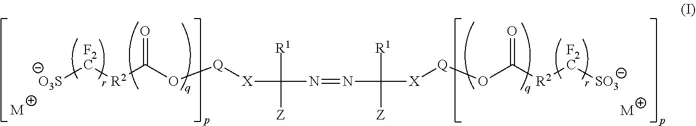
wherein R¹ represents a hydrocarbon group of 1 to 10 carbon atoms; Z represents a hydrocarbon group of 1 to 10 carbon atoms or a cyano group, provided that R¹ and Z may be mutually bonded to form a ring; X represents a divalent linking group having —O—C(═O)—, —NH—C(═O)— or —NH—C(═NH)— on at least the terminal bonded to Q; p represents an integer of 1 to 3;
Q represents a hydrocarbon group having a valency of (p+1), provided that, p represents 1, Q may represent a single bond;
R² represents a single bond, an alkylene group which may have a substituent or an aromatic group which may have a substituent; q represents 0 or 1; r represents an integer of 0 to 8; and M⁺ represents an organic cation. provided that the plurality of R¹, Z, X, p, Q, R², q, r and M⁺ may be the same or different from each other.

4. A resist composition comprising the polymer according to any one of claims 1 to 3.

5. A resist composition comprising: a base component (A) which exhibits changed solubility in a developing solution under action of acid; and an acid-generator component (B) which generates acid upon exposure, provided that the base component (A) is excluded, wherein
the base component (A) comprises the polymer according to any one of claims 1 to 3.

6. A method of forming a resist pattern, comprising: forming a resist film on a substrate using a resist composition of claim 4; conducting exposure of the resist film; and developing the resist film to form a resist pattern.
